(19) United States
(12) Patent Application Publication
(10) Pub. No.: US 2025/0159855 A1
(43) Pub. Date: May 15, 2025

(54) MEMORY DEVICE AND METHOD FOR DRIVING MEMORY DEVICE

(71) Applicant: SEMICONDUCTOR ENERGY LABORATORY CO., LTD., Atsugi-shi (JP)

(72) Inventors: Takeya HIROSE, Atsugi (JP); Takanori MATSUZAKI, Atsugi (JP)

(21) Appl. No.: 18/928,345

(22) Filed: Oct. 28, 2024

(30) Foreign Application Priority Data
Nov. 10, 2023 (JP) 2023-192403
Feb. 16, 2024 (JP) 2024-021899

(51) Int. Cl. H10B 10/00; G11C 11/419

(52) U.S. Cl. CPC H10B 10/12; H10B 10/18; G11C 11/419

(57) ABSTRACT

A novel semiconductor device is provided. One of a source and a drain of a first transistor is connected to one terminal of a first capacitor; the other of the source and the drain of the first transistor is connected to a bit line; a gate of the first transistor is connected to a word line; the other terminal of the first capacitor is connected to a first driver circuit; the first driver circuit is configured to output a first potential, output a second potential in conjunction with a timing when a potential of a selection signal that is supplied to the word line changes, and output a third potential in conjunction with a timing when a potential of data that is supplied to the bit line changes; a direction of change from the first potential to the second potential is opposite to a direction in which the potential of the selection signal changes; and a direction of change from the first potential to the third potential is opposite to a direction in which the potential of the data changes.

### BACKGROUND OF THE INVENTION

### 1. Field of the Invention

One embodiment of the present invention relates to a memory device and a method for driving a memory device.

Note that one embodiment of the present invention is not limited to the above technical field. The technical field of one embodiment of the invention disclosed in this specification and the like relates to an object, a method, a driving method, or a manufacturing method. One embodiment of the present invention relates to a process, a machine, manufacture, or a composition of matter. Specific examples of the technical field of one embodiment of the present invention disclosed in this specification and the like include a semiconductor device, a display device, a light-emitting device, a power storage device, an optical device, an image capturing device, a lighting device, an arithmetic device, a control device, a memory device, an input device, an output device, an input/output device, a signal processing unit, an arithmetic processing device, an electronic computer, an electronic device, a method for driving any of them, and a method of manufacturing any of them.

### 2. Description of the Related Art

It is known that the off-state current of a transistor including an oxide semiconductor in a channel formation region is extremely small. For example, Patent Document 1 discloses a low-power-consumption arithmetic processing device (e.g., CPU) utilizing a characteristically low off-state current of the transistor. Furthermore, for example, Patent Document 2 discloses a memory device (e.g., a main memory and a cache memory) that can retain data for a long time by utilizing a feature of a low off-state current of the transistor.

Furthermore, for example, Patent Document 3 discloses a technique for achieving an integrated circuit with higher density by stacking the transistors.

### REFERENCES

[Patent Document 1] Japanese Published Patent Application No. 2012-257187
[Patent Document 2] Japanese Published Patent Application No. 2011-151383
[Patent Document 3] PCT International Publication No. 2021/053473

### SUMMARY OF THE INVENTION

An object of one embodiment of the present invention is to provide a semiconductor device that can retain data for a long time, a memory device including the semiconductor device, a method for driving the semiconductor device, or a method for driving the memory device. Another object of one embodiment of the present invention is to provide a semiconductor device that can operate at high speed, a memory device including the semiconductor device, a method for driving the semiconductor device, or a method for driving the memory device. Another object of one embodiment of the present invention is to provide a semiconductor device that can reduce power consumption, a memory device including the semiconductor device, a method for driving the semiconductor device, or a method for driving the memory device. Another object of one embodiment of the present invention is to provide a semiconductor device that can increase the recording density, a memory device including the semiconductor device, a method for driving the semiconductor device, or a method for driving the memory device. Another object of one embodiment of the present invention is to provide a downsized semiconductor device, a memory device including the semiconductor device, a method for driving the semiconductor device, or a method for driving the memory device. Another object of one embodiment of the present invention is to provide a highly reliable semiconductor device, a memory device including the semiconductor device, a method for driving the semiconductor device, or a method for driving the memory device. Another object of one embodiment of the present invention is to provide a novel semiconductor device, a memory device including the semiconductor device, a method for driving the semiconductor device, or a method for driving the memory device.

Note that the description of the above objects does not preclude the existence of other objects. Objects other than the above objects will be apparent from the descriptions of the specification, the drawings, the claims, and the like, and objects other than the above objects can be derived from the descriptions of the specification, the drawings, the claims, and the like. Note that one embodiment of the present invention does not necessarily achieve all of these objects (the above objects and the other objects).

(1)

One embodiment of the present invention is a memory device including a memory array and a peripheral circuit; the memory array includes a first memory cell; the peripheral circuit includes a first driver circuit; the first memory cell includes a first transistor and a first capacitor; one of a source and a drain of the first transistor is electrically connected to one terminal of the first capacitor; the other of the source and the drain of the first transistor is electrically connected to a bit line; a gate of the first transistor is electrically connected to a word line; the other terminal of the first capacitor is electrically connected to the first driver circuit; the first driver circuit is configured to output a first potential, output a second potential in conjunction with a timing when a potential of a selection signal that is supplied to the word line changes, and output a third potential in conjunction with a timing when a potential of data that is supplied to the bit line changes; a direction of change from the first potential to the second potential is opposite to a direction in which the potential of the selection signal changes; and a direction of change from the first potential to the third potential is opposite to a direction in which the potential of the data changes.

(2)

One embodiment of the present invention is a memory device including a memory array and a peripheral circuit; the memory array includes a first memory cell and a second memory cell; the peripheral circuit includes a first driver circuit and a second driver circuit; the first memory cell includes a first transistor and a first capacitor; the second memory cell includes a second transistor and a second capacitor; one of a source and a drain of the first transistor is electrically connected to one terminal of the first capacitor; the other of the source and the drain of the first transistor is electrically connected to a bit line; a gate of the first transistor is electrically connected to a first word line; the other terminal of the first capacitor is electrically connected to the first driver circuit; one of a source and a drain of the second transistor is electrically connected to one terminal of the second capacitor; the other of the source and the drain of the second transistor is electrically connected to the bit line; a gate of the second transistor is electrically connected to a second word line; the other terminal of the second capacitor is electrically connected to the second driver circuit; the first driver circuit is configured to output a signal whose potential changes in a direction opposite to a direction in which a potential of a selection signal that is supplied to the first word line changes; and the second driver circuit is configured to output a signal whose potential changes in a direction opposite to a direction in which a potential of a selection signal that is supplied to the second word line changes.

(3)

One embodiment of the present invention is a memory device including a memory array and a peripheral circuit; the memory array includes a first memory cell and a second memory cell; the peripheral circuit includes a first driver circuit and a second driver circuit; the first memory cell includes a first transistor and a first capacitor; the second memory cell includes a second transistor and a second capacitor; one of a source and a drain of the first transistor is electrically connected to one terminal of the first capacitor; the other of the source and the drain of the first transistor is electrically connected to a first bit line; a gate of the first transistor is electrically connected to a word line; the other terminal of the first capacitor is electrically connected to the first driver circuit; one of a source and a drain of the second transistor is electrically connected to one terminal of the second capacitor; the other of the source and the drain of the second transistor is electrically connected to a second bit line; a gate of the second transistor is electrically connected to the word line; the other terminal of the second capacitor is electrically connected to the second driver circuit; the first driver circuit is configured to output a signal whose potential changes in a direction opposite to a direction in which a potential of data that is supplied to the first bit line changes; and the second driver circuit is configured to output a signal whose potential changes in a direction opposite to a direction in which a potential of data that is supplied to the second bit line changes.

(4)

One embodiment of the present invention is a memory device including a memory array and a peripheral circuit; the memory array includes a first memory cell, a second memory cell, a third memory cell, and a fourth memory cell; the peripheral circuit includes a first driver circuit, a second driver circuit, a third driver circuit, and a fourth driver circuit; the first memory cell includes a first transistor and a first capacitor; the second memory cell includes a second transistor and a second capacitor; the third memory cell includes a third transistor and a third capacitor; the fourth memory cell includes a fourth transistor and a fourth capacitor; one of a source and a drain of the first transistor is electrically connected to one terminal of the first capacitor; the other of the source and the drain of the first transistor is electrically connected to a first bit line; a gate of the first transistor is electrically connected to a first word line; the other terminal of the first capacitor is electrically connected to the first driver circuit; one of a source and a drain of the second transistor is electrically connected to one terminal of the second capacitor; the other of the source and the drain of the second transistor is electrically connected to the first bit line; a gate of the second transistor is electrically connected to a second word line; the other terminal of the second capacitor is electrically connected to the second driver circuit; one of a source and a drain of the third transistor is electrically connected to one terminal of the third capacitor; the other of the source and the drain of the third transistor is electrically connected to a second bit line; a gate of the third transistor is electrically connected to the first word line; the other terminal of the third capacitor is electrically connected to the third driver circuit; one of a source and a drain of the fourth transistor is electrically connected to one terminal of the fourth capacitor; the other of the source and the drain of the fourth transistor is electrically connected to the second bit line; a gate of the fourth transistor is electrically connected to the second word line; and the other terminal of the fourth capacitor is electrically connected to the fourth driver circuit.

(5)

In any one of (1) to (4) described above, the first transistor may include an oxide semiconductor in a channel formation region.

(6)

In any one of (1) to (4) described above, the first transistor may be positioned over the first capacitor.

(7)

In (6) described above, the memory device may further include a first conductor, a second conductor over the first conductor, and a third conductor over the second conductor; the first conductor may include a region functioning as the other terminal of the first capacitor; the second conductor may include a region functioning as the one terminal of the first capacitor and a region functioning as the one of the source and the drain of the first transistor; and the third conductor may include a region functioning as the other of the source and the drain of the first transistor.

(8)

In any one of (1) to (4) described above, the memory array may be positioned over the peripheral circuit.

(9)

One embodiment of the present invention is a method for driving a memory device including a memory cell in which one of a source and a drain of an n-channel transistor is electrically connected to one terminal of a capacitor, and the method includes a step of increasing a potential that is supplied to the other terminal of the capacitor after a potential of a selection signal that is supplied to a gate of the transistor is decreased.

(10)

One embodiment of the present invention is a method for driving a memory device including a memory cell in which one of a source and a drain of an n-channel transistor is electrically connected to one terminal of a capacitor, and the method includes a step of decreasing a potential that is supplied to the other terminal of the capacitor in synchronization with a timing of increasing a potential of data that is supplied to the other of the source and the drain of the transistor.

With one embodiment of the present invention, a semiconductor device that can retain data for a long time, a memory device including the semiconductor device, a method for driving the semiconductor device, or a method for driving the memory device can be provided. With one embodiment of the present invention, a semiconductor device that can operate at high speed, a memory device including the semiconductor device, a method for driving the semiconductor device, or a method for driving the memory device can be provided. With one embodiment of the present invention, a semiconductor device that can reduce power consumption, a memory device including the semiconductor device, a method for driving the semiconductor device, or a method for driving the memory device can be provided. With one embodiment of the present invention, a semiconductor device that can increase the recording density, a memory device including the semiconductor device, a method for driving the semiconductor device, or a method for driving the memory device can be provided. With one embodiment of the present invention, a downsized semiconductor device, a memory device including the semiconductor device, a method for driving the semiconductor device, or a method for driving the memory device can be provided. With one embodiment of the present invention, a highly reliable semiconductor device, a memory device including the semiconductor device, a method for driving the semiconductor device, or a method for driving the memory device can be provided. With one embodiment of the present invention, a novel semiconductor device, a memory device including the semiconductor device, a method for driving the semiconductor device, or a method for driving the memory device can be provided.

Note that the above effects do not preclude the existence of other effects. Effects other than the above effects will be apparent from the descriptions of the specification, the drawings, the claims, and the like, and effects other than the above effects can be derived from the descriptions of the specification, the drawings, the claims, and the like. Note that one embodiment of the present invention does not necessarily have all of these effects (the above effects and the other effects).

### BRIEF DESCRIPTION OF THE DRAWINGS

In the accompanying drawings:

FIG. 1 is a circuit diagram illustrating a structure example of a memory device;

FIGS. 2A and 2B are timing charts each illustrating an operation example of a display device;

FIGS. 3A to 3F are circuit diagrams illustrating an operation example of a memory device;

FIGS. 4A and 4B are timing charts each illustrating an operation example of a memory device;

FIGS. 5A to 5D are circuit diagrams illustrating an operation example of a memory device;

FIGS. 6A and 6B are timing charts each illustrating an operation example of a memory device;

FIGS. 7A and 7B are circuit diagrams each illustrating a structure example of a memory device;

FIG. 8 is a circuit diagram illustrating a structure example of a memory device;

FIG. 9 is a timing chart illustrating an operation example of a memory device;

FIG. 10 is a circuit diagram illustrating a structure example of a memory device;

FIG. 11 is a timing chart illustrating an operation example of a memory device;

FIG. 12 is a circuit diagram illustrating a structure example of a memory device;

FIG. 13 is a timing chart illustrating an operation example of a memory device;

FIGS. 14A and 14B are circuit diagrams each illustrating a structure example of a memory device;

FIG. 15 is a block diagram illustrating a structure example of a memory device;

FIG. 16 is a block diagram illustrating a structure example of a memory device;

FIG. 17A is a top view illustrating a structure example of a semiconductor device, and FIGS. 17B and 17C are cross-sectional views illustrating a structure example of the semiconductor device;

FIGS. 18A and 18B are cross-sectional views illustrating a structure example of a semiconductor device;

FIG. 19 is a cross-sectional view illustrating a structure example of a semiconductor device;

FIGS. 20A to 20C are cross-sectional views each illustrating a structure example of a semiconductor device;

FIGS. 21A to 21D are circuit diagrams each illustrating a structure example of a semiconductor device;

FIGS. 22A and 22B are top views each illustrating a structure example of a semiconductor device;

FIGS. 23A and 23B are cross-sectional views illustrating a structure example of a semiconductor device;

FIGS. 24A and 24B are cross-sectional views illustrating a structure example of a semiconductor device;

FIG. 25 is a cross-sectional view illustrating a structure example of a semiconductor device;

FIG. 26 is a cross-sectional view illustrating a structure example of a semiconductor device;

FIG. 27A is a top view illustrating a structure example of a semiconductor device and FIGS. 27B and 27C are cross-sectional views illustrating the structure example of the semiconductor device;

FIG. 28A is a top view illustrating a structure example of a semiconductor device, FIG. 28B is a schematic perspective view illustrating the structural example of the semiconductor device, and FIGS. 28C to 28E are cross-sectional views illustrating the structure example of the semiconductor device;

FIGS. 29A and 29B are cross-sectional views each illustrating the structure example of the semiconductor device;

FIG. 30A is a top view illustrating a structure example of a semiconductor device, FIG. 30B is a schematic perspective view illustrating the structural example of the semiconductor device, and FIGS. 30C to 30E are cross-sectional views illustrating the structure example of the semiconductor device;

FIG. 31 is a cross-sectional view illustrating a structure example of a semiconductor device;

FIG. 32A is a top diagram illustrating a structure example of a semiconductor device, FIG. 32B is a schematic perspective view illustrating the structural example of the semiconductor device, and FIGS. 32C to 32E are cross-sectional views illustrating the structure example of the semiconductor device;

FIGS. 33A and 33B are cross-sectional views illustrating a structure example of a semiconductor device;

FIG. 34A is a top view illustrating a structure example of a semiconductor device and FIGS. 34B to 34D are cross-sectional views illustrating the structure example of the semiconductor device;

FIG. 35 illustrates a hierarchy of various kinds of memory devices;

FIGS. 36A to 36H are circuit diagrams each illustrating a structure example of a memory cell;

FIGS. 37A and 37B are circuit diagrams each illustrating a structure example of a semiconductor device;

FIGS. 38A and 38B each illustrate an example of an electronic component;

FIGS. 39A and 39B each illustrate an example of an electronic device and FIGS. 39C to 39E illustrate an example of a large computer;

FIG. 40A illustrates an example of space equipment and FIG. 40B illustrates an example of a storage system that can be used in a data center;

FIGS. 41A1 to 41B6 are diagrams for explaining “electrical connection”;

FIG. 42A is a top view illustrating a structure example of a semiconductor device and FIGS. 42B and 42C are cross-sectional views illustrating the structure example of the semiconductor device;

FIGS. 43A and 43B are schematic perspective views each illustrating a structure example of a semiconductor device;

FIGS. 44A and 44B are cross-sectional views each illustrating a structure example of a semiconductor device;

FIGS. 45A and 45B show evaluation results of oxide semiconductors;

FIGS. 46A to 46D show evaluation results of an oxide semiconductor;

FIGS. 47A to 47H show evaluation results of oxide semiconductors;

FIGS. 48A to 48D illustrate a method for evaluating an oxide semiconductor;

FIGS. 49A to 49H show evaluation results of an oxide semiconductor;

FIG. 50 shows evaluation results of oxide semiconductors;

FIGS. 51A and 51B show evaluation results of oxide semiconductors;

FIGS. 52A to 52D show evaluation results of transistors;

FIGS. 53A and 53B show evaluation results of transistors;

FIGS. 54A and 54B show evaluation results of transistors;

FIG. 55 shows an evaluation result of transistors;

FIGS. 56A and 56B show evaluation results of transistors;

FIGS. 57A and 57B show evaluation results of transistors;

FIGS. 58A and 58B show evaluation results of transistors;

FIG. 59 shows evaluation results of transistors;

FIG. 60 shows evaluation results of transistors;

FIG. 61 shows an evaluation result of a memory device;

FIGS. 62A and 62B show evaluation results of a memory device;

FIG. 63 shows an evaluation result of a memory device;

FIGS. 64A and 64B show evaluation results of a memory device;

FIG. 65 shows evaluation results of a memory device; and

FIG. 66 shows evaluation results of a memory device.

### DETAILED DESCRIPTION OF THE INVENTION

In this specification and the like, a semiconductor device means a device that utilizes semiconductor characteristics, and refers to a circuit including a semiconductor element (e.g., a transistor or a diode), a device including the circuit, and the like. The semiconductor device also means devices that can function by utilizing semiconductor characteristics. For example, an integrated circuit including a semiconductor element, a chip provided with an integrated circuit, an electronic component including a packaged chip, and an electronic device provided with an electronic component are examples of a semiconductor device. For example, a display device, a light-emitting device, a power storage device, an optical device, an image capturing device, a lighting device, an arithmetic device, a control device, a memory device, an input device, an output device, an input/output device, a signal processing unit, an electronic computer, an electronic device, and the like themselves might be semiconductor devices, or might include semiconductor devices.

Hereinafter, embodiments will be described with reference to the drawings. However, embodiments can be implemented with various modes. Thus, it will be readily understood by those skilled in the art that the modes and details can be changed in various ways without departing from the spirit and scope thereof. Thus, the present invention should not be interpreted as being limited to the description of the embodiments.

In this specification and the like, the structure described in each embodiment can be combined with the structures described in the other embodiments as appropriate to constitute one embodiment of the present invention. In addition, in the case where a plurality of structures are described in one embodiment, the structures can be combined as appropriate to constitute one embodiment.

Note that in drawings illustrating the embodiments, the same portions or portions having similar functions are denoted by the same reference numerals in different drawings and the description of such portions is not repeated in some cases. In drawings, for example, the same hatching pattern is used for portions having similar functions, and the portions are not denoted by specific reference numerals in some cases. Moreover, some components may be omitted in a perspective view, a top view (also referred to as a “plan view”), and the like for easy understanding of the drawings. In drawings, some hidden lines or the like might be omitted. In drawings, a hatching pattern or the like might be omitted.

In the drawings, sizes, layer thicknesses, or regions are sometimes exaggerated for clarity. Thus, the drawings are not limited to the drawings with the illustrated size, aspect ratio, and the like, for example. Note that the drawings are schematic views showing ideal examples, and embodiments of the present invention are not limited to shapes or values shown in the drawings, for example. For example, in the actual manufacturing process, a layer, a resist mask, or the like might be unintentionally reduced in size by treatment such as etching, which is not illustrated in the drawings in some cases for easy understanding. For example, in the actual circuit operation, a fluctuation in voltage, current, or the like might be caused by noise, difference in timing, or the like, which is not illustrated in some cases for easy understanding.

In this specification, drawings, and the like, components are classified on the basis of the functions and shown as components independent of each other in some cases. However, it may be difficult to separate components on the basis of the functions, so that one component may be associated with a plurality of functions or several components may be associated with one function. Accordingly, the components presented in this specification, drawings, and the like are not limited to the descriptions thereof and can be described with other terms as appropriate.

In this specification, drawings, and the like, when a plurality of components are denoted by the same reference numerals, and, particularly when they need to be distinguished from each other, identification signs such as “A,” “b,” “_l,” “[n],” or “[m, n]” is sometimes added to the reference numerals, for example. When matters common to a plurality of components with identification signs are described or they do not need to be distinguished from each other, no identification sign is added in some cases.

In this specification and the like, a “conduction state” or an “on state” of a transistor refers to a state where a source and a drain of the transistor can be regarded as being electrically short-circuited, a state where a current can be made to flow between the source and the drain (or a state where a current can flow therebetween), or the like. The “conduction state” or the “on state” refers to the state of an n-channel transistor where the voltage between its gate and source is higher than the threshold voltage or the state of a p-channel transistor where the voltage between its gate and source is lower than the threshold voltage, for example, in some cases. Furthermore, a “non-conductive state,” a “cutoff state,” or an “off state,” of a transistor refers to a state where a source and a drain of the transistor can be regarded as being electrically disconnected. The “non-conductive state,” the “cutoff state,” or the “off state” refers to the state of an n-channel transistor where the voltage between its gate and source is lower than the threshold voltage or the state of a p-channel transistor where the voltage between its gate and source is higher than the threshold voltage, for example, in some cases.

In this specification and the like, “gate voltage” refers to the voltage between a gate and a source, “drain voltage” refers to the voltage between a drain and a source, and “back gate voltage” refers to the voltage between a back gate and a source in some cases. In addition, a “drain current” refers to a current flowing between the drain and the source in some cases. The terms “high gate voltage,” “high drain voltage,” “high back gate voltage,” and the like of an n-channel transistor can be replaced with the terms “low gate voltage,” “low drain voltage,” and “low back gate voltage,” and the like of a p-channel transistor, respectively, as appropriate in some cases. The terms “low gate voltage,” “low drain voltage,” “low back gate voltage,” and the like of an n-channel transistor can be replaced with the terms “high gate voltage,” “high drain voltage,” and “high back gate voltage,” and the like of a p-channel transistor, respectively, as appropriate in some cases.

In this specification and the like, an “off-state current” of a transistor refers to a drain current of the transistor in the off state unless otherwise specified. Note that an off-state current and a current that flows between a gate and a source or a drain (also referred to as a gate leakage current) are each referred to as leakage current in some times in this specification and the like.

### Embodiment 1

A semiconductor device of one embodiment of the present invention will be described with reference to drawings. At least part of the semiconductor device of one embodiment of the present invention can be used for a memory device, for example. The memory device includes a memory cell and a circuit for driving the memory cell. Another embodiment of the present invention is a method for driving the memory cell.

### Structure Example 1 of Memory Device

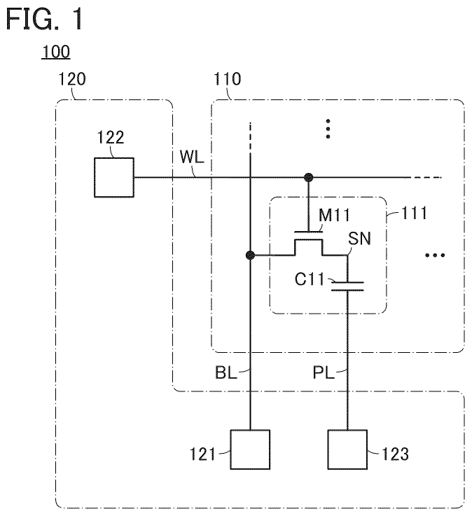

FIG. 1 is a circuit diagram illustrating a memory device of one embodiment of the present invention;

A memory device 100 illustrated in FIG. 1 includes a memory array 110 and a peripheral circuit 120. The memory array includes a plurality of memory cells 111 arranged in a matrix. Note that FIG. 1 illustrates one memory cell 111 as a representative example.

The memory cell 111 includes a transistor M11 and a capacitor C11. One of a source and a drain of the transistor M11 is connected to one terminal of the capacitor C11. The other of the source and the drain of the transistor M11 is connected to a wiring BL having a function of a bit line. A gate of the transistor M11 is connected to a wiring WL having a function of a word line. The other terminal of the capacitor C11 (sometimes referred to as a plate terminal) is connected to a wiring PL having a function of a signal line. Note that a wiring to which both the one of the source and the drain of the transistor M11 and the one terminal of the capacitor C11 are connected is referred to as a wiring SN in some cases. Note that as described later, after data is written to the memory cell 111, a potential corresponding to the data is retained in the wiring SN. Thus, the wiring is referred to as a retention node in some cases.

The peripheral circuit 120 includes a driver circuit 121 having a function of supplying a potential of data to the wiring BL, a driver circuit 122 having a function of supplying a potential of a selection signal to the wiring WL, and a driver circuit 123 having a function of supplying a potential of a control signal to the wiring PL. That is, it can be said that the driver circuit 121 has a function of outputting a potential of the data, the driver circuit 122 has a function of outputting a potential of the selection signal, and the driver circuit 123 has a function of outputting a potential of the control signal.

Here, the control signal can have a first potential (corresponding to a potential Vp0 described later), a second potential (corresponding to a potential Vp1 described later), and a third potential (corresponding to a potential Vp2 described later). The timing when the potential of the control signal changes from the first potential to the second potential may be in conjunction with the timing when the potential of the selection signal changes. The direction of change from the first potential to the second potential may be opposite to the direction in which the potential of the selection signal changes. Furthermore, the timing when the potential of the control signal changes from the first potential to the third potential may be in conjunction with the timing when the potential of the data changes. The direction of change from the first potential to the third potential may be opposite to the direction in which the potential of the data changes.

Note that in the memory cell 111, the transistor M11 is an n-channel transistor or a p-channel transistor. Here, the description is given on the assumption that the transistor M11 is an n-channel transistor. An n-channel transistor has a higher on-state current than a p-channel transistor. Thus, the data reading speed and the data writing speed can be improved in the memory cell 111.

For example, a transistor including a single crystal semiconductor, a polycrystalline semiconductor, a microcrystalline semiconductor, or an amorphous semiconductor in a channel formation region can be used as the transistor M11. Examples of the semiconductor that can be used include compound semiconductors (e.g., silicon germanium or gallium arsenide) and oxide semiconductors in addition to semiconductors including a single element (e.g., silicon or germanium) as a main component.

Transistors of various kinds can be used as the transistor M11. For example, a MOS field-effect transistor, a junction field-effect transistor, a bipolar transistor, or the like can be employed.

Transistors with various structures can be used as the transistor M11. For example, transistors with various structures such as a top-gate type (e.g., a planar type and a staggered type), a bottom-gate type (e.g., an inverted planar type and an inverted staggered type), a dual-gate type (a structure in which gates are provided on both sides of (e.g., above and below) a channel formation region), a FIN-type, a TRI-GATE-type, and a gate-all-around-type (GAA-type) structures can be used. For example, a vertical transistor (a transistor whose channel length direction is in the vertical direction (also referred to as a height direction or a direction perpendicular to a formation surface) can be used.

In one embodiment of the present invention, a transistor including an oxide semiconductor in a channel formation region (an OS transistors) can be used as the transistor M11.

An OS transistor features an extremely low off-state current because the band gap of the oxide semiconductor where the channel is formed is 2 eV or more. The off-state current per micrometer of channel width of an OS transistor can be lower than or equal to 1 aA (1×10⁻¹⁸ A), lower than or equal to 1 zA (1×10⁻²¹ A), or lower than or equal to 1 yA (1×10⁻²⁴ A) in a room-temperature environment. Note that the off-state current per micrometer of channel width of a transistor including silicon in a channel formation region (a Si transistor) is higher than or equal to 1 fA (1×10⁻¹⁵ A) and lower than or equal to 1 pA (1×10⁻¹² A) in a room-temperature environment. The off-state current of an OS transistor is therefore lower than that of a Si transistor by approximately ten orders of magnitude. Thus, for example, in the case where a wiring connected to one of a source and a drain of the OS transistor is floating, charge accumulated in the wiring can be retained for a long period. When a memory cell is formed using an OS transistor, data written to the memory cell can be retained for a long period, for example.

The off-state current of an OS transistor hardly increases even in a high-temperature environment. Specifically, the off-state current hardly increases even at an environment temperature higher than or equal to room temperature and lower than or equal to 200° C. Furthermore, the on-state current of an OS transistor hardly decreases even in a high-temperature environment. By contrast, the on-state current of a Si transistor decreases in a high-temperature environment. That is, an OS transistor has a higher on-state current than a Si transistor in a high-temperature environment. Furthermore, even at an environment temperature higher than or equal to 125° C. and lower than or equal to 150° C., an OS transistor is capable of favorable switching operation owing to its high ratio of on-state current to off-state current. Accordingly, a semiconductor device including an OS transistor achieves stable operation and high reliability even in a high-temperature environment.

An OS transistor has a high breakdown voltage between a source and a drain (also referred to as a drain breakdown voltage). Accordingly, a semiconductor device including an OS transistor achieves stable operation and high reliability even in high-voltage driving.

Here, a structure using an OS transistor as the access transistor (the transistor M11) in the memory cell 111 is referred to as a DOSRAM (registered trademark) in some cases. DOSRAM is an abbreviation for a dynamic oxide semiconductor random access memory (RAM). Since an OS transistor having an extremely low off-state current is used in the DOSRAM, data can be stored for a long period. That is, data once written can be stored for a long period, and thus the frequency of data refresh can be lowered. In addition, the capacitance of the cell capacitor (C11) can be reduced, so that the cell size can be reduced. Thus, the use of the DOSRAM can reduce power consumption of a memory device including the DOSRAM and increase the recording density of the memory device.

Data writing to the memory cell using the OS transistor and data reading therefrom are performed by charging and discharging of charge; thus, a substantially unlimited number of times of data writing and data reading are possible. The memory cell using the OS transistor is excellent in rewrite endurance because, unlike a magnetic memory or a resistive random-access memory, it does not go through atomic-level structure change. Furthermore, unlike in a flash memory, unstableness due to an increase in electron trap centers is not observed in the memory cell using the OS transistor even when writing is repeated; thus, the memory cell using the OS transistor is excellent in stability.

The memory cell using the OS transistor can be freely placed over a silicon substrate or the like where a Si transistor is provided, for example; thus, integration can be easily achieved. Furthermore, the OS transistor can be manufactured with a manufacturing apparatus similar to that for a Si transistor and thus the memory cell using the OS transistor can be manufactured at low cost.

In addition, a plurality of the memory cells using the OS transistors can be monolithically stacked; thus, the memory device using the memory cells can achieve improvements in recording density, bandwidth, and access latency, for example.

In one embodiment of the present invention, a vertical transistor can be used as the transistor M11 in the memory cell 111. This can reduce the layout area of the memory cell 111. In other words, the recording density of the memory device including the memory cell 111 can be improved.

Furthermore, the transistor M11 can be stacked over the capacitor C11 so that they can have an overlapping region. This can further reduce the layout area of the memory cell 111. In other words, the recording density of the memory device including the memory cell 111 can be further improved.

A structure example in which the transistor M11 is stacked over the capacitor C11 and a vertical transistor is used as the transistor M11 in the memory cell 111 will be described later in Embodiment 2.

As transistors included in the peripheral circuit 120, a variety of transistors can be used. For example, an n-channel transistor, a p-channel transistor, or both of the transistors may be used. For example, an OS transistor, a Si transistor, or both of the transistors may be used. For example, a planar transistor, a vertical transistor, or both of the transistors may be used. Note that a structure example of the driver circuit 123 included in the peripheral circuit 120 of one embodiment of the present invention will be described later.

### Operation Example 1

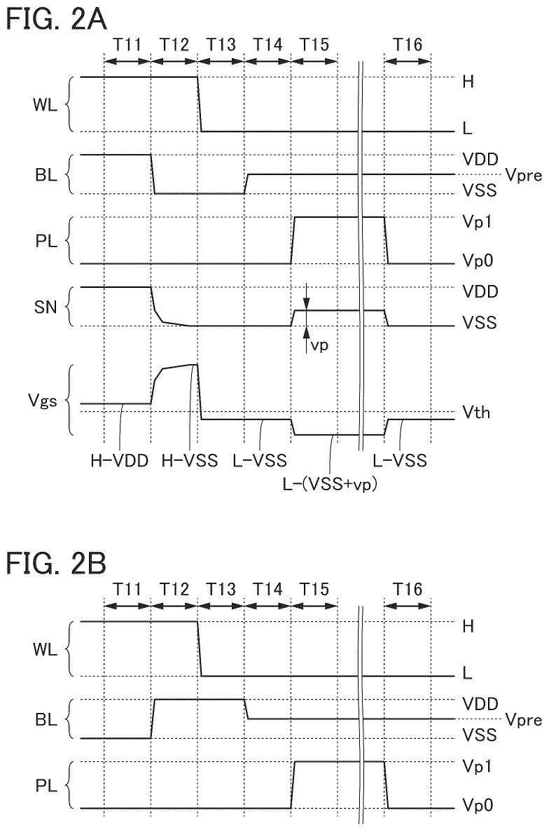

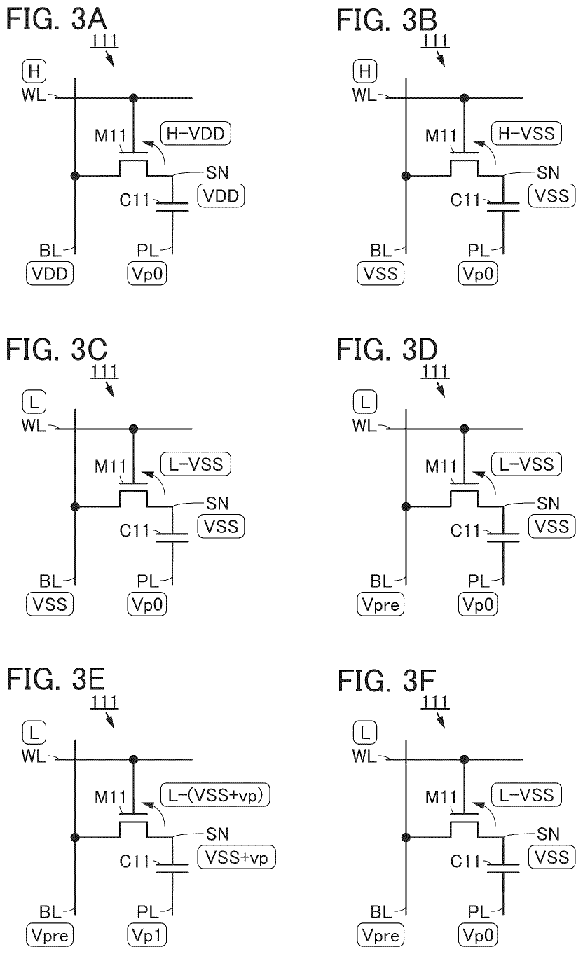

FIGS. 2A and 2B and FIGS. 3A to 3F are timing charts and circuit diagrams illustrating an example of a method for driving the memory cell 111. The timing chart in FIG. 2A illustrates an operation example in which data “0” is written to the memory cell 111 that retains data “1” and then the memory cell 111 retains the data “0”.

In the following description of the potential corresponding to binary data supplied to the wiring BL, a potential corresponding to “1” of the binary data is a high power supply potential VDD (sometimes simply referred to as VDD), and a potential corresponding to “0” of the binary data is a low power supply potential VSS (sometimes simply referred to as VSS).

The potential of the signal supplied to the wiring WL is a potential H (sometimes simply referred to as H) at which the transistor M11 can be turned on or a potential L (sometimes simply referred to as L) at which the transistor M11 can be turned off.

Note that in this operation example, the case where an n-channel transistor is used as the transistor M11 is described. In the case where a p-channel transistor is used as the transistor M11, the magnitude relationship of a voltage and a potential described here may be reversed as appropriate. For example, “high voltage” can be read as “low voltage” as appropriate, and “low voltage” can be read as “high voltage” as appropriate. For example, “increase the potential” can be read as “decrease the potential” as appropriate, and “decrease the potential” can be read as “increase the potential” as appropriate.

Here, when the threshold voltage of the transistor M11 is Vth, the potential H is determined so that the minimum gate voltage in the on state can be higher than the threshold voltage (i.e., “H-VDD>Vth”) and the transistor M11 can be turned on in the operation of the memory cell 111. In addition, the potential L is determined so that the maximum gate voltage in the off state can be lower than the threshold voltage (i.e., “L-VSS<Vth”) and the transistor M11 can be turned off.

The potential of the signal supplied to the wiring PL is the potential Vp0 or the potential Vp1 that is higher than the potential Vp0.

In the operation described below, a rise time and a fall time sometimes occur at the time of potential change owing to loads on a wiring (parasitic capacitance and parasitic resistance), for example. Furthermore, for example, two different operations that appear to occur at the same timing do not necessarily occur at exactly the same timing. The operations can be sometimes considered to occur at the same timing even though a signal delay of a wiring or the like causes a slight time lag between the operations, for example.

The periods that are shown with the same length in the timing chart for easy understanding of the description may have different lengths of time.

The timing chart in FIG. 2A illustrates the states of potentials supplied to the wiring WL, the wiring BL, and the wiring PL in each period of the operation. In addition, a change in the potential of the wiring SN is illustrated. A change in the gate voltage (sometimes referred to as Vgs) of the transistor M11 is also illustrated.

FIGS. 3A to 3F illustrate the potentials of the wiring WL, the wiring BL, the wiring PL, and the wiring SN at each point of operation. The gate voltage Vgs of the transistor M11 is indicated by an arrow. In addition, a symbol indicating a potential (also referred to as a potential symbol), such as “VDD” or “VSS”, surrounded by a line is written near a wiring or the like in some cases.

In Period T11, the potential H is supplied to the wiring WL and the potential Vp0 is supplied to the wiring PL. For example, “VDD” corresponding to “1” is supplied to the wiring BL, and the potential of the wiring SN in the memory cell 111 is also “VDD”. At this time, the gate voltage Vgs of the transistor M11 is “H-VDD”, and the transistor M11 is in the on state. This corresponds to a state after data “1” is read from and written back to the memory cell 111. FIG. 3A illustrates the potentials of the wirings at this time. Note that in the following description, unless otherwise specified, the immediately preceding state is maintained.

In Period T12, “VSS” corresponding to “0” is supplied to the wiring BL. This makes the data pass through the transistor M11 and the potential of the wiring SN gradually decrease to “VSS”. That is, data “O” is written to the memory cell 111. At this time, the gate voltage Vgs of the transistor M11 becomes “H-VSS”. FIG. 3B illustrates the potentials of the wirings at this time.

In Period T13, the potential L is supplied to the wiring WL. This makes the gate voltage Vgs of the transistor M11 “L-VSS”, so that the transistor M11 is turned off. That is, writing of data “O” to the memory cell 111 is finished, and “VSS” corresponding to the data “0” is retained in the wiring SN. FIG. 3C illustrates the potentials of the wirings at this time.

In Period T14, an intermediate potential Vpre between the potential VDD and the potential VSS is supplied to the wiring BL. That is, the wiring BL is precharged to the intermediate potential Vpre. This makes the potential of the wiring SN lower than the potential of the wiring BL, so that the wiring SN functions as the source of the transistor M11. Since “VSS” is retained in the wiring SN, the gate voltage Vgs of the transistor M11 remains at “L-VSS”. FIG. 3D illustrates the potentials of the wirings at this time. Note that the wiring BL may be precharged to “VDD”.

In Period T15, the potential Vp1 is supplied to the wiring PL. That is, the potential of the wiring PL increases from the potential Vp0 to the potential Vp1. This causes capacitive coupling of the capacitor C11 and increases the potential of the wiring SN. At this time, assuming that the potential of the wiring SN increases by “vp”, the potential of the wiring SN becomes “VSS+vp” and the gate voltage Vgs of the transistor M11 becomes “L-(VSS+vp)”. That is, the gate voltage Vgs of the transistor M11 decreases by “vp”. FIG. 3E illustrates the potentials of the wirings at this time.

Then, the potential of the wiring SN is kept at “VSS+vp”.

In Period T16, the potential Vp0 is supplied to the wiring PL. That is, the potential of the wiring PL decreases from the potential Vp1 to the potential Vp0. This also decreases the potential of the wiring SN by “vp” owing to capacitive coupling of the capacitor C11. At this time, the potential of the wiring SN becomes “VSS”, and the gate voltage Vgs of the transistor M11 becomes “L-VSS”. That is, the potential of the wiring SN returns to the state after data writing to the memory cell 111 is performed (the state corresponding to Period T13 and Period T14). The period T16 corresponds to, for example, a state before data reading from the memory cell 111 is performed. FIG. 3F illustrates the potentials of the wirings at this time.

Here, the off-state current (a drain current in the off state where the gate voltage is lower than the threshold voltage) of the transistor M11 includes a region where the off-state current changes exponentially with the gate voltage (such a region is also referred to as a subthreshold region). That is, in the transistor M11 in the off state, the off-state current decreases as the gate voltage Vgs decreases.

Therefore, as the gate voltage Vgs of the transistor M11 becomes lower in turning off the transistor M11 after data is written to the memory cell 111, the potential of the wiring SN corresponding to the written data can be retained for a longer period.

In one embodiment of the present invention, the gate voltage Vgs of the transistor M11 in the off state can be decreased by making the memory cell 111 operate as in Period T15 described above (i.e., by increasing the potential supplied to the wiring PL after decreasing the potential of the selection signal supplied to the wiring WL. Accordingly, the potential of the wiring SN corresponding to the data written to the memory cell 111 can be retained for a long period. Thus, a memory device capable of storing data for a long period can be achieved. For example, the frequency of data refresh can be lowered to reduce power consumption.

That is, in one embodiment of the present invention, the driver circuit 123 can have a function of outputting a signal whose potential changes in the direction opposite to the direction in which the potential of the selection signal that is supplied to the wiring WL changes. In this case, the timing when the potential of the signal output from the driver circuit 123 changes may be in conjunction with the timing when the potential of the selection signal changes. That is, for example, the potential of the signal output from the driver circuit 123 may increase after the potential of the selection signal decreases.

Note that an OS transistor may be used as the transistor M11 included in the memory cell 111. An OS transistor has a feature of a wider range of the gate voltage Vgs operating in the subthreshold region than that of a Si transistor. Thus, by decreasing the gate voltage Vgs, the off-state current can be made lower than that of a Si transistor. For example, when the gate voltage Vgs is lower than 0 V, the off-state current can be extremely low. In other words, in the memory cell 111 using an OS transistor as the transistor M11, the potential of the wiring SN can be retained for a longer period as the gate voltage Vgs is decreased.

Therefore, for example, in Period T15 described above, “vp”, which is the amount of increase in the potential of the wiring SN, may be increased. Accordingly, the gate voltage Vgs can be decreased, and the off-state current can become lower. For example, by increasing “vp”, the gate voltage Vgs may become lower than 0 V. Accordingly, the off-state current of the transistor M11 can be extremely low, and the potential of the wiring SN can be retained for a long period.

Here, “vp” in Period T15 described above is “(Vp1−Vp0)×the capacitance of the capacitor C11/(the capacitance of the capacitor C11+the parasitic capacitance of the wiring SN)”.

Thus, for example, as the capacitance of the capacitor C11 is larger, “vp” becomes larger and the gate voltage Vgs of the transistor M11 becomes lower. That is, a larger capacitance of the capacitor C11 enables the potential of the wiring SN to be retained for a longer period.

For that reason, the capacitance of the capacitor C11 may be set larger than the capacitance between the gate of the transistor M11 (corresponding to the wiring WL) and one of the source and the drain of the transistor M11 (corresponding to the wiring SN), for example. Furthermore, for example, the thickness of an insulator functioning as the dielectric of the capacitor C11 may be made smaller than the thickness of an insulator functioning as a gate insulating film of the transistor M11. Moreover, for example, the relative permittivity of the insulator functioning as the dielectric of the capacitor C11 may be made higher than the relative permittivity of the insulator functioning as the gate insulating film of the transistor M11.

Furthermore, for example, as the amount of change in the potential of the wiring PL (i.e., “Vp1−Vp0”) is larger, “vp” becomes larger and the gate voltage Vgs of the transistor M11 becomes lower. That is, a larger amount of change in the potential of the wiring PL enables the potential of the wiring SN to be retained for a longer period.

For that reason, the amount of change in the potential of the wiring PL may be made larger than the amount of change in the potential of the selection signal supplied to the wiring WL (i.e., “H-L”), for example. In view of suppressing an increase in power consumption due to change in the potential of the wiring PL, the amount of change in the potential of the wiring PL may be made smaller than the amount of change in the potential of the selection signal.

Although the operation example of the case where data “0” is written to the memory cell 111 that retains data “1” and then the memory cell 111 retains the data “0” is described here, the same applies to the case where data “0” is written to the memory cell 111 that retains data “0”. Furthermore, the same applies to the case where data “1” is written to the memory cell 111 that retains data “0” or “1” and then the memory cell 111 retains the data “1”.

The timing chart in FIG. 2B illustrates an operation example in which data “1” is written to the memory cell 111 that retains data “0” and then the memory cell 111 retains the data “1”, and illustrates the states of potentials supplied to the wiring WL, the wiring BL, and the wiring PL in each period of the operation. Note that a change in the potential of the wiring SN and a change in the gate voltage Vgs of the transistor M11 are not illustrated. In this case, in Period T12 for writing data “1”, the potential of the wiring SN gradually increases from “VSS” to “VDD”, and the gate voltage Vgs of the transistor M11 gradually decreases from “H-VSS” to “H-VDD”. After the data “1” is written, the potential of the wiring SN in Period T13 and Period T14 becomes “VDD” and the gate voltage Vgs of the transistor M11 becomes “L-VDD”. In the period T15, the potential of the wiring SN becomes “VDD+vp” and the gate voltage Vgs of the transistor M11 becomes “L−(VDD+vp)”. In Period T16, the potential of the wiring SN becomes “VDD” and the gate voltage Vgs of the transistor M11 becomes “L-VDD”.

That is, the gate voltage Vgs of the transistor M11 in the off state is lower in the case where data “1” is retained than in the case where data “0” is retained. Therefore, it can be said that data “1” can be retained for a long period when data “0” can be retained for a long period in the operation example described above.

In one embodiment of the present invention, operating the memory cell 111 as in Period T15 described above can lead to a reduction in power consumption in some cases, for example. That is, in the operation of the memory cell 111, in view of a reduction in power consumption, the amplitude of a signal in the peripheral circuit 120 is preferably small; for example, the amplitude of a signal supplied to the wiring WL (i.e., “H-L”) is preferably small, for example. Thus, the potential L may be set higher, for example. However, when the potential L is set higher, the gate voltage Vgs of the transistor M11 in the off state in Period T13 and Period T14 does not become sufficiently low, and it sometimes becomes difficult to retain the potential of the wiring SN for a long period with the off-state current. With the operation as in Period T15, the gate voltage Vgs of the transistor M11 in the off state can be decreased, whereby the potential of the wiring SN can be retained for a long period in some cases. Here, dynamic power consumption in the peripheral circuit 120 is proportional to the square of the signal amplitude; therefore, it can be said that a reduction in power consumption due to a reduction in signal amplitude is larger than an increase in power consumption due to the addition of the driver circuit 123. Thus, a memory device capable of storing data for a long period while reducing power consumption can be obtained in some cases. For example, the frequency of data refresh can be lowered to reduce power consumption.

In one embodiment of the present invention, operating the memory cell 111 as in Period T15 described above can lead to miniaturization of a transistor used in the peripheral circuit 120 in some cases, for example. A transistor used in the driver circuit 122 having a function of generating a signal supplied to the wiring WL can be miniaturized, for example. Here, the voltage range of a circuit using the transistor is reduced with miniaturization of the transistor; thus, the amplitude of a signal supplied to the wiring WL (i.e., “H-L”) is reduced in some cases, for example. That is, for example, the potential L is set higher in some cases. However, when the potential L is set higher, the gate voltage Vgs of the transistor M11 in the off state in Period T13 and Period T14 does not become sufficiently low, and it sometimes becomes difficult to retain the potential of the wiring SN for a long period with the off-state current. With the operation as in Period T15, the gate voltage Vgs of the transistor M11 in the off state can be decreased, whereby the potential of the wiring SN can be retained for a long period in some cases. Thus, a memory device capable of storing data for a long period while being, for example, downsized by miniaturization of the transistor used in the peripheral circuit 120 can be obtained in some cases. For example, the frequency of data refresh can be lowered to reduce power consumption.

### Operation Example 2

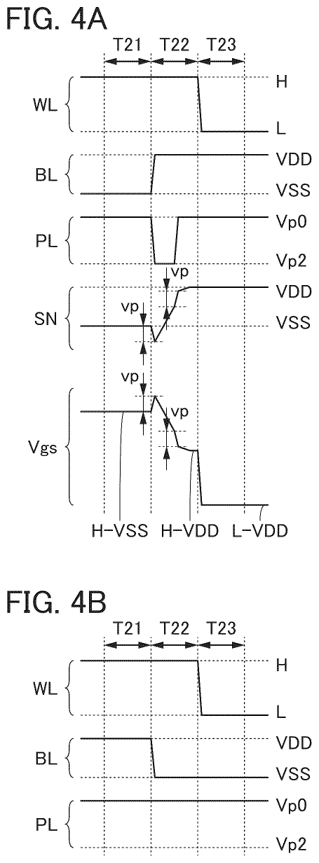

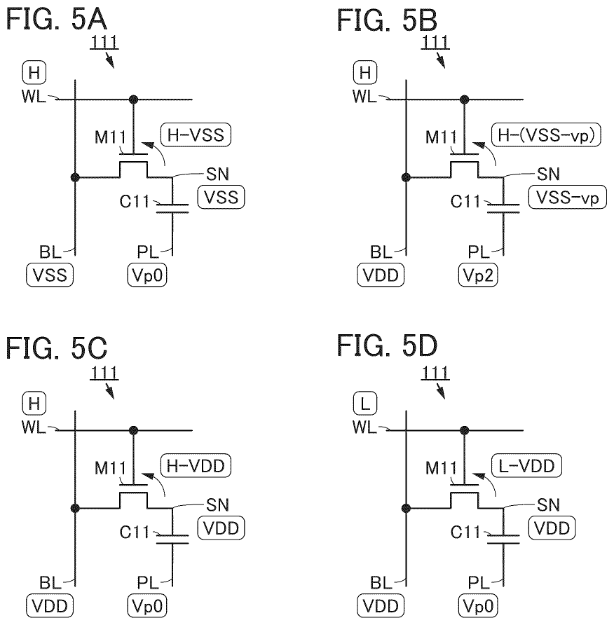

FIGS. 4A and 4B and FIGS. 5A to 5D are timing charts and circuit diagrams illustrating an example of a method for driving the memory cell 111. The timing chart in FIG. 4A illustrates an operation example in which data “1” is written to the memory cell 111 that retains data “0” and then the memory cell 111 retains the data “1”.

In the following description, the above description of the operation example 1 can be referred to as appropriate.

The potential of the signal supplied to the wiring PL is the potential Vp0 or the potential Vp2 that is lower than the potential Vp0.

In Period T21, the potential H is supplied to the wiring WL and the potential Vp0 is supplied to the wiring PL. For example, “VSS” corresponding to “0” is supplied to the wiring BL, and the potential of the wiring SN in the memory cell 111 is also “VSS”. At this time, the gate voltage Vgs of the transistor M11 is “H-VSS”, and the transistor M11 is in the on state. This corresponds to a state after data “0” is read from and written back to the memory cell 111. FIG. 5A illustrates the potentials of the wirings at this time. Note that in the following description, unless otherwise specified, the immediately preceding state is maintained.

In Period T22, “VDD” corresponding to “1” is supplied to the wiring BL. At this time, a pulse of the potential Vp2 is supplied to the wiring PL. That is, the potential of the wiring PL decreases from the potential Vp0 to the potential Vp2 at the same time when “VDD” is supplied to the wiring BL, and then increases from the potential Vp2 to the potential Vp0. This gradually increases the potential of the wiring SN to “VDD” through the operation described below. That is, data “1” is written to the memory cell 111.

When the potential of the wiring PL decreases from the potential Vp0 to the potential Vp2, the potential of the wiring SN decreases owing to capacitive coupling of the capacitor C11. At this time, assuming that the potential of the wiring SN decreases by “vp”, the potential of the wiring SN becomes “VSS-vp” and the gate voltage Vgs of the transistor M11 becomes “H-(VSS-vp)”. That is, the gate voltage Vgs of the transistor M11 increases by “vp”. FIG. 5B illustrates the potentials of the wirings at this time.

By instantaneously increasing the gate voltage Vgs at the same time as the supply of “VDD” to the wiring BL in the above-described manner, the on-state current of the transistor M11 can be increased instantaneously. Thus, the rate at which the potential of the wiring SN gradually increases can be increased.

After that, the potential of the wiring PL increases from the potential Vp2 to the potential Vp0, whereby the potential of the wiring SN increases owing to capacitive coupling of the capacitor C11. Thus, the time for the potential of the wiring SN to reach “VDD” can be shortened.

Finally, the potential of the wiring SN becomes “VDD” and the gate voltage Vgs of the transistor M11 becomes “H-VDD”. FIG. 5C illustrates the potentials of the wirings at this time.

In Period T23, the potential L is supplied to the wiring WL. This makes the gate voltage Vgs of the transistor M11 “L-VDD”, so that the transistor M11 is turned off. That is, writing of data “1” to the memory cell 111 is finished, and “VDD” corresponding to data “1” is retained in the wiring SN. FIG. 5D illustrates the potentials of the wirings at this time.

In one embodiment of the present invention, operating the memory cell 111 as in Period T22 described above (i.e., decreasing the potential supplied to the wiring PL in synchronization with the timing when the potential of the data supplied to the wiring BL is increased) can increase the rate at which the potential of the wiring SN gradually increases in writing data “1” to the memory cell 111 and can shorten the time taken for the potential of the wiring SN to reach “VDD”. That is, the speed of writing data to the memory cell 111 can be improved. Moreover, since “VDD” is reached even when the data writing speed is increased, the data reading speed can also be improved. Thus, a memory device that can operate at high speed can be obtained.

That is, in one embodiment of the present invention, the driver circuit 123 can have a function of outputting a signal whose potential changes in the direction opposite to the direction in which the potential of the data that is supplied to the wiring BL changes. In this case, the timing when the potential of the signal output from the driver circuit 123 changes may be in conjunction with the timing when the potential of the data changes. That is, for example, the potential of the signal output from the driver circuit may decrease in synchronization with the timing when the potential of the data increases.

Here, “vp” in Period T22 described above is “(Vp0−Vp2)× the capacitance of the capacitor C11/(the capacitance of the capacitor C11+the parasitic capacitance of the wiring SN)”.

Thus, for example, as the amount of change in the potential of the wiring PL (i.e., “Vp0−Vp2”) is larger, “vp” becomes larger and the speed of writing data to the memory cell 111 can be increased.

For that reason, the amount of change in the potential of the wiring PL may be made larger than the amount of change in the potential of the data supplied to the wiring BL (i.e., “VDD−VSS”), for example. In view of suppressing an increase in power consumption due to change in the potential of the wiring PL, the amount of change in the potential of the wiring PL may be made smaller than the amount of change in the potential of the data.

The operation example of the case where data “1” is written to the memory cell 111 that retains data “0” and then the memory cell 111 retains the data “1” is described here. It is preferable not to apply the operation as in Period T22 described above to the other cases.

For example, in the case of writing data “0” to the memory cell 111 that retains data “0”, the potential retained in the wiring SN remains at “VSS”. For example, in the case of writing data “1” to the memory cell 111 that retains data “1”, the potential retained in the wiring SN remains at “VDD”. In such cases, in order to avoid a change in the potential of the wiring SN due to a change in the potential of the wiring PL, it is preferable not to change the potential of the wiring PL.

For example, in the case of writing data “0” to the memory cell 111 that retains data “1”, the potential of the wiring SN is gradually decreased to reach “VSS” in Period T22. In such a case, an increase in the potential of the wiring SN is caused by an increase in the potential of the wiring PL from the potential Vp2 to the potential Vp0; thus, the effect that the time for the potential of the wiring SN to reach “VSS” is shortened cannot be obtained. Thus, it is preferable not to change the potential of the wiring PL.

The timing chart in FIG. 4B illustrates an operation example in which data “0” is written to the memory cell 111 that retains data “1” and then the memory cell 111 retains the data “0”, and illustrates the states of potentials supplied to the wiring WL, the wiring BL, and the wiring PL in each period of the operation. Note that a change in the potential of the wiring SN and a change in the gate voltage Vgs of the transistor M11 are not illustrated. In this case, in Period T22 for writing data “0”, the potential of the wiring SN gradually decreases from “VDD” to “VSS”, and the gate voltage Vgs of the transistor M11 gradually increases from “H-VDD” to “H-VSS”. At this time, the potential of the wiring PL does not change, and thus a change in the potential of the wiring SN due to capacitive coupling of the capacitor C11 is not caused. After the data “0” is written, the potential of the wiring SN in Period T23 becomes “VSS” and the gate voltage Vgs of the transistor M11 becomes “L-VSS”.

In one embodiment of the present invention, operating the memory cell 111 as in Period T22 described above can lead to a reduction in power consumption in some cases, for example. That is, in the operation of the memory cell 111, in view of a reduction in power consumption, the amplitude of a signal in the peripheral circuit 120 is preferably small; for example, the amplitude of a signal supplied to the wiring WL (i.e., “H-L”) is preferably small, for example. Thus, the potential H may be set lower, for example. However, when the potential H is set lower, the gate voltage Vgs of the transistor M11 in the on state does not become sufficiently high and the on-state current becomes low, so that the speed of writing data to the memory cell 111 is decreased in some cases. With the operation as in Period T22, the writing speed and the reading speed can be improved, for example. Here, dynamic power consumption in the peripheral circuit 120 is proportional to the square of the signal amplitude; therefore, it can be said that a reduction in power consumption due to a reduction in signal amplitude is larger than an increase in power consumption due to the addition of the driver circuit 123. Thus, a memory device capable of operating at high speed while reducing power consumption can be obtained in some cases. Alternatively, a memory device that can suppress a decrease in operation speed while reducing power consumption can be obtained in some cases.

In one embodiment of the present invention, operating the memory cell 111 as in Period T22 described above can lead to miniaturization of a transistor used in the peripheral circuit 120 in some cases, for example. A transistor used in the driver circuit 122 having a function of generating a signal supplied to the wiring WL can be miniaturized, for example. Here, the voltage range of a circuit using the transistor is reduced with miniaturization of the transistor; thus, the amplitude of a signal supplied to the wiring WL (i.e., “H-L”) is reduced in some cases, for example. That is, for example, the potential H is set lower in some cases. However, when the potential H is set lower, the gate voltage Vgs of the transistor M11 in the on state does not become sufficiently high and the on-state current becomes low, so that the speed of writing data to the memory cell 111 is decreased in some cases. With the operation as in Period T22, the writing speed and the reading speed can be improved, for example. Thus, a memory device capable of operating at high speed while being, for example, downsized by miniaturization of the transistor used in the peripheral circuit 120 can be obtained in some cases. Alternatively, a memory device that can suppress a decrease in operation speed while being downsized can be obtained in some cases.

### Operation Example 3

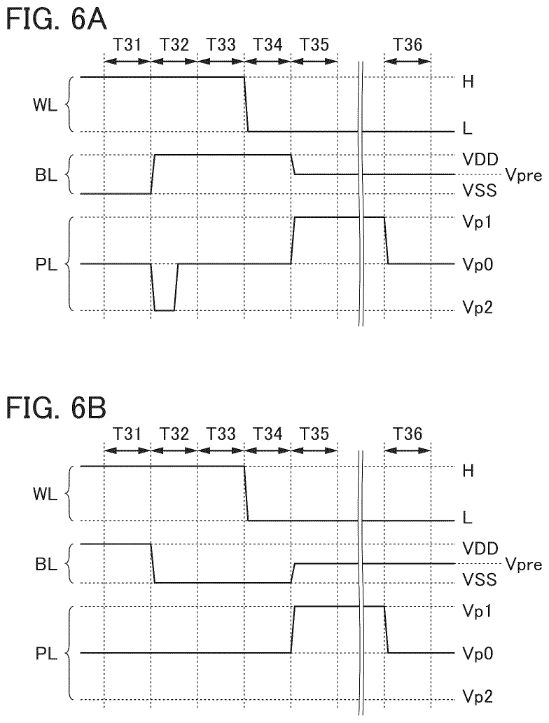

FIGS. 6A and 6B are timing charts illustrating an example of a method for driving the memory cell 111 of one embodiment of the present invention. The timing charts in FIGS. 6A and 6B illustrate an operation example in which the above-described operation examples 1 and 2 are combined. Therefore, the above description can be referred to, and the detailed description is omitted here.

The timing chart in FIG. 6A illustrates an operation example in which data “1” is written to the memory cell 111 that retains data “0” and then the memory cell 111 retains the data “1”, and is a combination of the timing chart illustrated in FIG. 2B and the timing chart illustrated in FIG. 4A. The timing chart in FIG. 6B illustrates an operation example in which data “O” is written to the memory cell 111 that retains data “1” and then the memory cell 111 retains the data “0”, and is a combination of the timing chart illustrated in FIG. 2A and the timing chart illustrated in FIG. 4B.

In one embodiment of the present invention, by operating the memory cell 111 as illustrated in the timing charts in FIGS. 6A and 6B, it is possible to achieve a memory device capable of operating at high speed and storing data for a long period while reducing power consumption and being downsized, for example. For example, the frequency of data refresh can be lowered to reduce power consumption.

### [Driver Circuit 123]

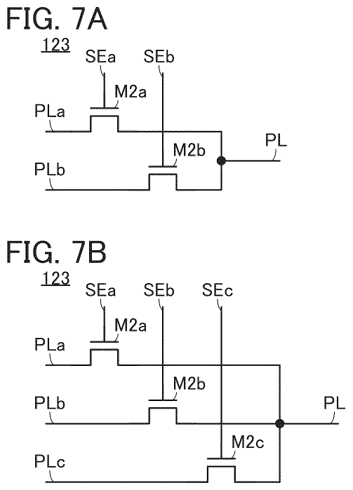

FIGS. 7A and 7B are circuit diagrams each illustrating a structure example applicable to the driver circuit 123.

The driver circuit 123 illustrated in FIG. 7A includes a transistor M2a and a transistor M2b. One of a source and a drain of the transistor M2a is connected to the wiring PL, the other of the source and the drain of the transistor M2a is connected to a wiring PLa, and a gate of the transistor M2a is connected to a wiring SEa. One of a source and a drain of the transistor M2b is connected to the wiring PL, the other of the source and the drain of the transistor M2b is connected to a wiring PLb, and a gate of the transistor M2b is connected to a wiring SEb.

The driver circuit 123 illustrated in FIG. 7A has a function of supplying a potential of one of the wiring PLa and the wiring PLb to the wiring PL. That is, in the driver circuit 123 illustrated in FIG. 7A, one of the transistor M2a and the transistor M2b is brought into the on state and the other is brought into the off state, so that the potential of one of the wiring PLa and the wiring PLb is supplied to the wiring PL.

For example, when the driver circuit 123 illustrated in FIG. 7A is employed in the memory device 100, supplying the potential Vp1 to the wiring PLa and supplying the potential Vp0 to the wiring PLb enables the memory cell 111 to operate as in the operation example 1 described above. Furthermore, for example, when the driver circuit 123 illustrated in FIG. 7A is employed in the memory device 100, supplying the potential Vp2 to the wiring PLa and supplying the potential Vp0 to the wiring PLb enables the memory cell 111 to operate as in the operation example 2 described above.

The driver circuit 123 illustrated in FIG. 7B includes a transistor M2c in addition to the driver circuit 123 illustrated in FIG. 7A. One of a source and a drain of the transistor M2c is connected to the wiring PL, the other of the source and the drain of the transistor M2c is connected to a wiring PLc, and a gate of the transistor M2c is connected to a wiring SEc.

The driver circuit 123 illustrated in FIG. 7B has a function of supplying a potential of one of the wiring PLa to the wiring PLc to the wiring PL. That is, in the driver circuit 123 illustrated in FIG. 7B, any one of the transistor M2a to the transistor M2c is brought into the on state and the others are brought into the off state, so that the potential of any one of the wiring PLa to the wiring PLc is supplied to the wiring PL.

For example, when the driver circuit 123 illustrated in FIG. 7B is employed in the memory device 100, supplying the potential Vp1 to the wiring PLa, supplying the potential Vp0 to the wiring PLb, and supplying the potential Vp2 to the wiring PLc enables the memory cell 111 to operate as in the operation example 3 described above.

Note that FIGS. 7A and 7B illustrate examples of the driver circuit 123, and the structure of the driver circuit 123 is not limited to the illustrated examples. Although an example of the structure using n-channel transistors is described here, p-channel transistors or a CMOS circuit may be used as well.

### Structure Example 2 of Memory Device

Next, the connection relation between the plurality of memory cells 111 arranged in a matrix and a plurality of the driver circuits 123 is described. Note that for simple description, a case where four memory cells 111 are arranged in a matrix of two rows and two columns is described as an example.

### Connection Example 1

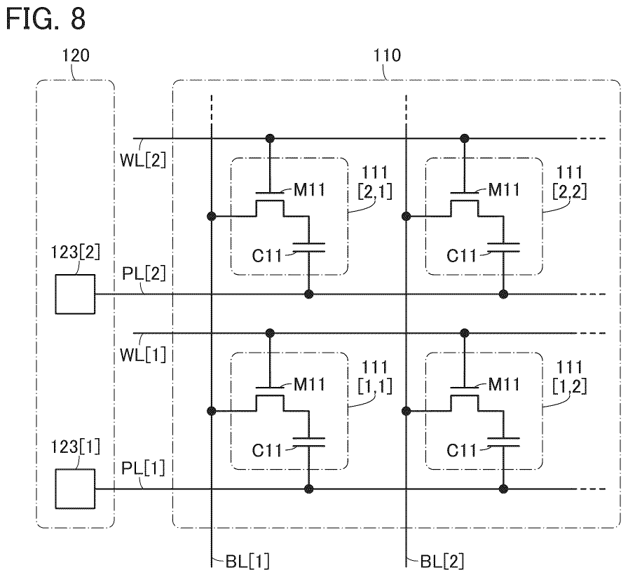

FIG. 8 is a circuit diagram illustrating an example of the connection relation between four memory cells 111 arranged in a matrix of two rows and two columns and two driver circuits 123.

FIG. 8 illustrates a memory cell 111[1, 1] positioned in the first row and the first column, a memory cell 111[1, 2] positioned in the first row and the second column, a memory cell 111[2, 1] positioned in the second row and the first column, and a memory cell 111[2, 2] positioned in the second row and the second column in the memory array 110. In the peripheral circuit 120, a driver circuit 123[1] positioned in the first row and a driver circuit 123[2] positioned in the second row are illustrated. Note that FIG. 8 does not illustrate a driver circuit 121[1] positioned in the first column, a driver circuit 121[2] positioned in the second column, a driver circuit 122 [1] positioned in the first row, and a driver circuit 122 [2] positioned in the second row.

A wiring PL[1] provided in the first row is connected to the memory cell 111[1, 1], the memory cell 111[1, 2], and the driver circuit 123[1]. A wiring PL[2] provided in the second row is connected to the memory cell 111[2, 1], the memory cell 111[2, 2], and the driver circuit 123[2]. A wiring BL[1] provided in the first column is connected to the memory cell 111[1, 1], the memory cell 111[2, 1], and the driver circuit 121[1]. A wiring BL[2] provided in the second column is connected to the memory cell 111[1, 2], the memory cell 111[2, 2], and the driver circuit 121[2]. A wiring WL[1] provided in the first row is connected to the memory cell 111[1, 1], the memory cell 111[1, 2], and the driver circuit 122 [1]. A wiring WL[2] provided in the second row is connected to the memory cell 111[2, 1], the memory cell 111[2, 2], and the driver circuit 122 [2].

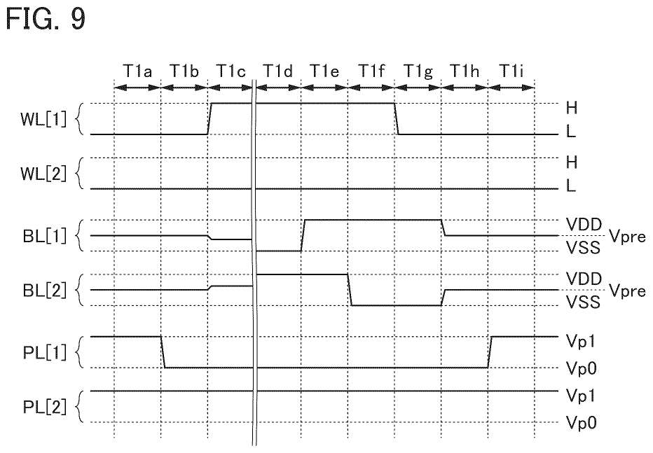

FIG. 9 is a timing chart illustrating an example of a method for driving the four memory cells 111 illustrated in FIG. 8. Illustrated here is an operation example in which the first row is selected, data “1” is written to the memory cell 111[1, 1] that retains data “0”, data “0” is written to the memory cell 111[1, 2] that retains data “1”, and the memory cells retain their respective data. The above-described operation example 1 is used as a method for driving each of the memory cells 111. The above-described operation example 1 can be suitably used for the structure illustrated in FIG. 8 as the method for driving the memory cells 111 because the wirings PL provided on the row basis of the memory cells 111 are connected to the corresponding driver circuits 123 in the structure illustrated in FIG. 8. Note that the above description of the operation example 1 can be referred to as appropriate.

Period T1a is a period when data is retained in the four memory cells 111. At this time, the wiring WL[1] and the wiring WL[2] are each at the potential L, the wiring BL[1] and the wiring BL[2] are each at an intermediate potential between the potential VDD and the potential VSS, and the wiring PL[1] and the wiring PL[2] are each at the potential Vp1.

Period T1b is a period immediately before the start of reading and writing back of data to/from the memory cells 111 in the first row and corresponds to Period T16. Here, the potential of the wiring PL[1] is decreased from the potential Vp1 to the potential Vp0.

Period T1c is a period immediately after the start of reading and writing back of data to/from the memory cells 111 in the first row. Here, the potential H is supplied to the wiring WL[1]. At this time, the potential of the wiring BL[1] decreases from the intermediate potential, and the potential of the wiring BL[2] increases from the intermediate potential. The amount of this change is amplified by a sense amplifier, whereby data reading is performed. Since the potentials retained in the memory cells 111 change by data reading (i.e., destructive reading), writing back of data is performed after the data reading.

Period T1d is a period immediately after the finish of reading and writing back of data to/from the memory cells 111 in the first row and corresponds to Period T11.

Period T1e is a period when data writing to the memory cell 111[1, 1] is performed and corresponds to Period T12.

Period T1f is a period when data writing to the memory cell 111[1, 2] is performed and corresponds to Period T12.

Period T1g is a period immediately after the finish of writing of data to the memory cells 111 in the first row and corresponds to Period T13. Here, the potential L is supplied to the wiring WL[1].

Period T1h is a period when the wiring BL[1] and the wiring BL[2] are precharged to the intermediate potential Vpre and corresponds to Period T14.

Period T1i is a period when the potential of the wiring PL[1] is increased so that data written to the memory cells 111 in the first row can be retained for a long period and corresponds to Period T15. Here, the potential of the wiring PL[1] is increased from the potential Vp0 to the potential Vp1.

In the case where the plurality of memory cells 111 arranged in a matrix and the plurality of driver circuits 123 are connected as illustrated in FIG. 8, data written to the memory cells 111 can be retained for a long period by employing the driving method illustrated in FIG. 9. Thus, a memory device capable of storing data for a long period can be achieved. For example, the frequency of data refresh can be lowered to reduce power consumption.

### Connection Example 2

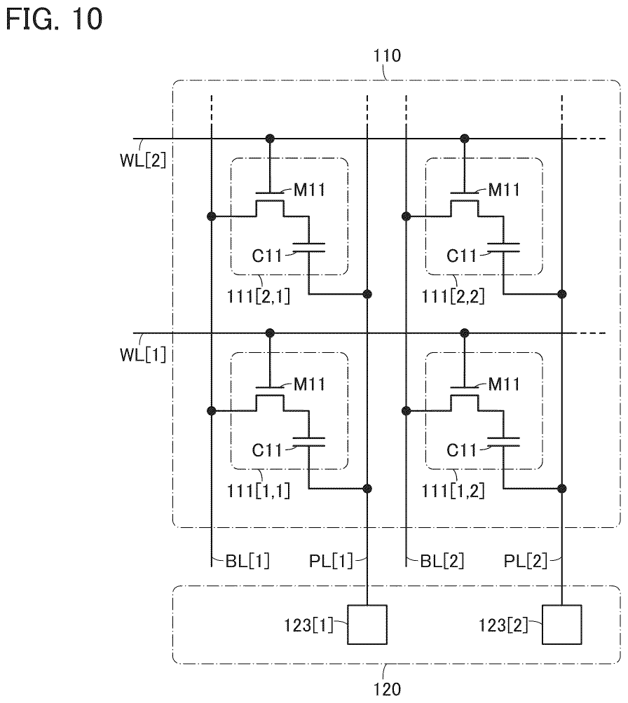

FIG. 10 is a circuit diagram illustrating another example of the connection relation between four memory cells 111 arranged in a matrix of two rows and two columns and two driver circuits 123.

FIG. 10 illustrates the memory cell 111[1, 1] positioned in the first row and the first column, the memory cell 111[1, 2] positioned in the first row and the second column, the memory cell 111[2, 1] positioned in the second row and the first column, and the memory cell 111[2, 2] positioned in the second row and the second column in the memory array 110. In the peripheral circuit 120, the driver circuit 123[1] positioned in the first column and the driver circuit 123[2] positioned in the second column are illustrated. Note that FIG. 10 does not illustrate the driver circuit 121[1] positioned in the first column, the driver circuit 121[2] positioned in the second column, the driver circuit 122 [1] positioned in the first row, and the driver circuit 122 [2] positioned in the second row.

The wiring PL[1] provided in the first column is connected to the memory cell 111[1, 1], the memory cell 111[2, 1], and the driver circuit 123[1]. The wiring PL[2] provided in the second column is connected to the memory cell 111[1, 2], the memory cell 111[2, 2], and the driver circuit 123[2]. The wiring BL[1] provided in the first column is connected to the memory cell 111[1, 1], the memory cell 111[2, 1], and the driver circuit 121[1]. The wiring BL[2] provided in the second column is connected to the memory cell 111[1, 2], the memory cell 111[2, 2], and the driver circuit 121[2]. The wiring WL[1] provided in the first row is connected to the memory cell 111[1, 1], the memory cell 111[1, 2], and the driver circuit 122 [1]. The wiring WL[2] provided in the second row is connected to the memory cell 111[2, 1], the memory cell 111[2, 2], and the driver circuit 122 [2].

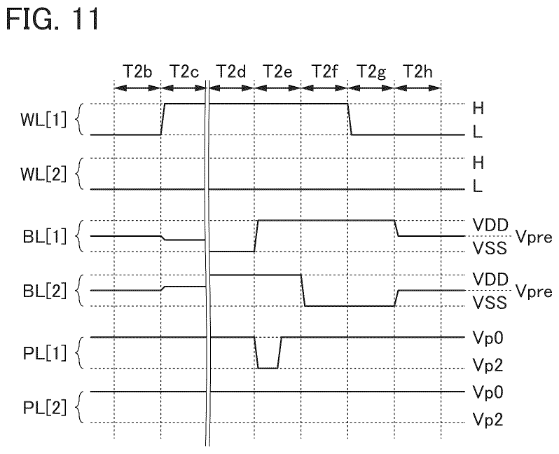

FIG. 11 is a timing chart illustrating an example of a method for driving the four memory cells 111 illustrated in FIG. 10. Illustrated here is an operation example in which the first row is selected, data “1” is written to the memory cell 111[1, 1] that retains data “0”, data “0” is written to the memory cell 111[1, 2] that retains data “1”, and the memory cells retain their respective data. The above-described operation example 2 is used as a method for driving each of the memory cells 111. The above-described operation example 2 can be suitably used for the structure illustrated in FIG. 10 as the method for driving the memory cells 111 because the wirings PL provided on the column basis of the memory cells 111 are connected to the corresponding driver circuits 123 in the structure illustrated in FIG. 10. Note that the above description of the operation example 2 can be referred to as appropriate.

Period T2b is a period when data is retained in the four memory cells 111. At this time, the wiring WL[1] and the wiring WL[2] are each at the potential L, the wiring BL[1] and the wiring BL[2] are each at an intermediate potential between the potential VDD and the potential VSS, and the wiring PL[1] and the wiring PL[2] are each at the potential Vp0.

Period T2c, Period T2d, Period T2g, and Period T2h are, respectively, similar to Period T1c, Period T1d, Period T1g, and Period T1h described above.

Period T2e is a period when data writing to the memory cell 111[1, 1] is performed and corresponds to Period T22. Here, since data “1” is written to the memory cell 111[1, 1] that retains data “0”, a pulse with the potential Vp2 is supplied to the wiring PL[1].

Period T2f is a period when data writing to the memory cell 111[1, 2] is performed and corresponds to Period T22. Here, since data “O” is written to the memory cell 111[1, 2] that retains data “1”, the potential of the wiring PL[2] is not changed.

In the case where the plurality of memory cells 111 arranged in a matrix and the plurality of driver circuits 123 are connected as illustrated in FIG. 10, the speed of writing data to the memory cells 111 can be improved by employing the driving method illustrated in FIG. 11. Moreover, since “VDD” is reached even when the data writing speed is increased, the data reading speed can also be improved. Thus, a memory device that can operate at high speed can be obtained.

### Connection Example 3

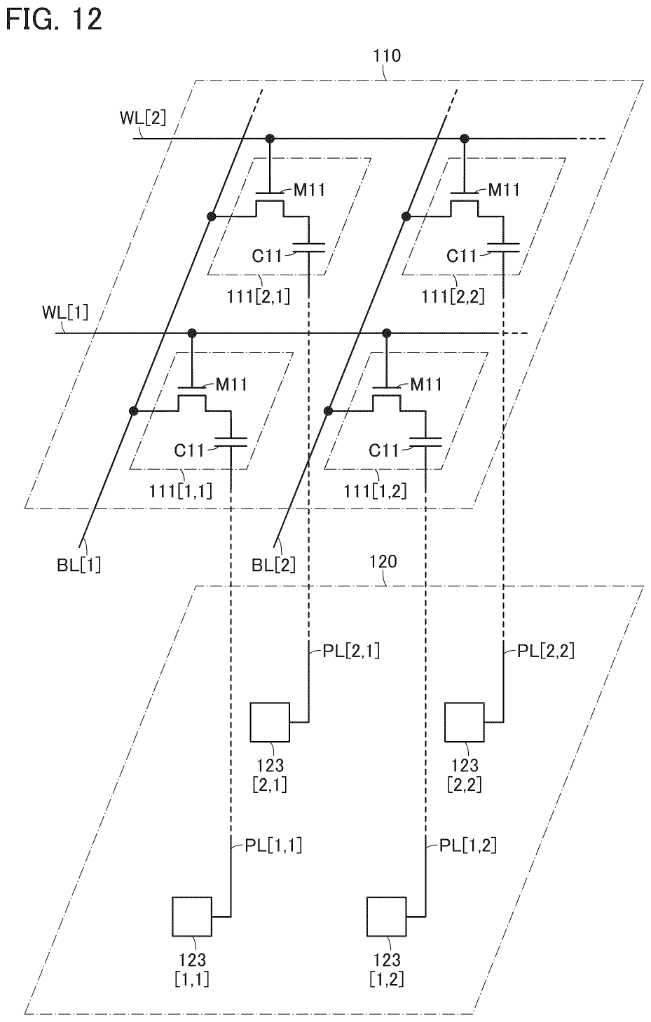

FIG. 12 is a circuit diagram illustrating an example of the connection relation between four memory cells 111 arranged in a matrix of two rows and two columns and four driver circuits 123 arranged in a matrix of two rows and two columns.

FIG. 12 illustrates the memory cell 111[1, 1] positioned in the first row and the first column, the memory cell 111[1, 2] positioned in the first row and the second column, the memory cell 111[2, 1] positioned in the second row and the first column, and the memory cell 111[2, 2] positioned in the second row and the second column in the memory array 110. In the peripheral circuit 120, a driver circuit 123[1, 1] positioned in the first row and the first column, a driver circuit 123[1, 2] positioned in the first row and the second column, a driver circuit 123[2, 1] positioned in the second row and the first column, and a driver circuit 123[2, 2] positioned in the second row and the second column are illustrated. Note that FIG. 12 does not illustrate the driver circuit 121[1] positioned in the first column, the driver circuit 121[2] positioned in the second column, the driver circuit 122 [1] positioned in the first row, and the driver circuit 122 [2] positioned in the second row.

A wiring PL[1, 1] provided in the first row and the first column is connected to the memory cell 111[1, 1] and the driver circuit 123[1, 1]. A wiring PL[1, 2] provided in the first row and the second column is connected to the memory cell 111[1, 2] and the driver circuit 123[1, 2]. A wiring PL[2, 1] provided in the second row and the first column is connected to the memory cell 111[2, 1] and the driver circuit 123[2, 1]. A wiring PL[2, 2] provided in the second row and the second column is connected to the memory cell 111[2, 2] and the driver circuit 123[2, 2]. The wiring BL[1] provided in the first column is connected to the memory cell 111[1, 1], the memory cell 111[2, 1], and the driver circuit 121[1]. The wiring BL[2] provided in the second column is connected to the memory cell 111[1, 2], the memory cell 111[2, 2], and the driver circuit 121[2]. The wiring WL[1] provided in the first row is connected to the memory cell 111[1, 1], the memory cell 111[1, 2], and the driver circuit 122 [1]. The wiring WL[2] provided in the second row is connected to the memory cell 111[2, 1], the memory cell 111[2, 2], and the driver circuit 122 [2].

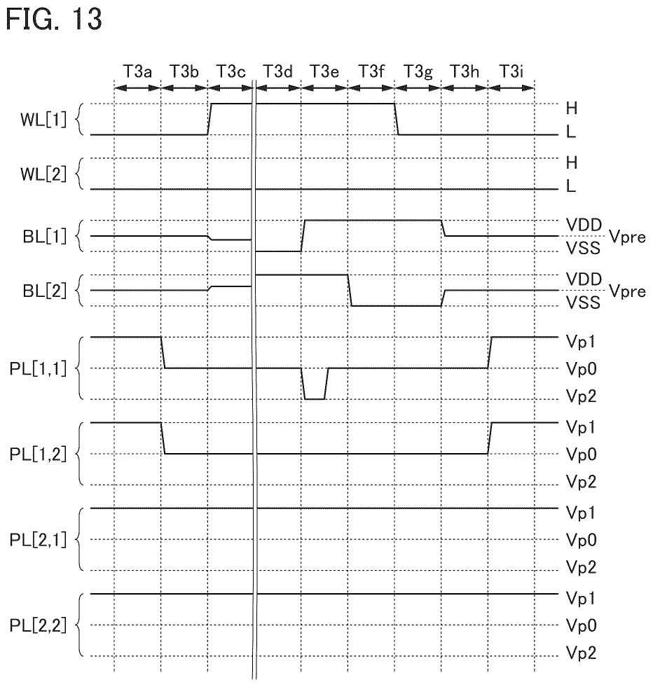

FIG. 13 is a timing chart illustrating an example of a method for driving the four memory cells 111 illustrated in FIG. 12. Illustrated here is an operation example in which the first row is selected, data “1” is written to the memory cell 111[1, 1] that retains data “0”, data “0” is written to the memory cell 111[1, 2] that retains data “1”, and the memory cells retain their respective data. The above-described operation example 3 is used as a method for driving each of the memory cells 111. The above-described operation example 3 can be suitably used for the structure illustrated in FIG. 12 as the method for driving the memory cells 111 because the wirings PL provided on the memory cell 111 basis are connected to the corresponding driver circuits 123 in the structure illustrated in FIG. 12. Note that the timing chart in FIG. 13 can be regarded as a combination of the above-described example of the driving method illustrated in FIG. 9 and the above-described example of the driving method illustrated in FIG. 11. Therefore, the above description can be referred to, and the detailed description is omitted here.

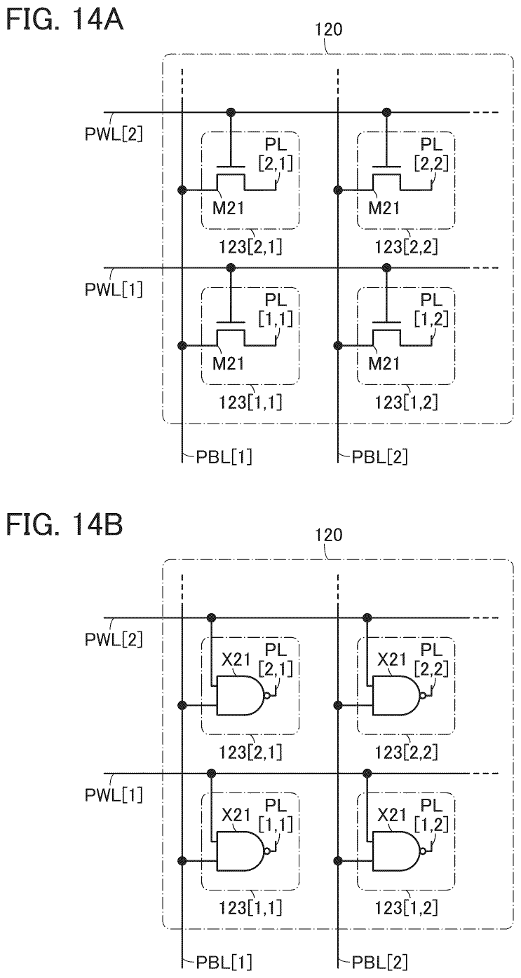

FIG. 14A is a circuit diagram illustrating a structure example of the four driver circuits 123 arranged in a matrix of two rows and two columns in the connection example illustrated in FIG. 12.

In FIG. 14A, in the peripheral circuit 120, the driver circuit 123[1, 1] positioned in the first row and the first column, the driver circuit 123[1, 2] positioned in the first row and the second column, the driver circuit 123[2, 1] positioned in the second row and the first column, and the driver circuit 123[2, 2] positioned in the second row and the second column are illustrated.

A wiring PBL[1] provided in the first column is connected to the driver circuit 123[1, 1] and the driver circuit 123[2, 1]. A wiring PBL[2] provided in the second column is connected to the driver circuit 123[1, 2] and the driver circuit 123[2, 2]. A wiring PWL[1] provided in the first row is connected to the driver circuit 123[1, 1] and the driver circuit 123[1, 2]. A wiring PWL[2] provided in the second row is connected to the driver circuit 123[2, 1] and the driver circuit 123[2, 2].

Each of the driver circuits 123 includes a transistor M21. One of a source and a drain of the transistor M21 is connected to the wiring PL, the other of the source and the drain of the transistor M21 is connected to the wiring PBL, and a gate of the transistor M21 is connected to the wiring PWL.

In FIG. 14A, a desired potential can be supplied to the wiring PL provided in a target row and a target column owing to the potentials supplied to the wiring PWL[1] and the wiring PWL[2] and the potentials supplied to the wiring PBL[1] and the wiring PBL[2]. That is, in the memory array 110, the potential of the wiring PL can be changed on the memory cell 111 basis. Thus, the driving method illustrated in FIG. 13 can be realized.

FIG. 14B is a circuit diagram illustrating another structure example of the driver circuit 123. The driver circuit 123 illustrated in FIG. 14B is different from the driver circuit 123 illustrated in FIG. 14A in including a NAND circuit X21 instead of the transistor M21. One of a pair of input terminals of the NAND circuit X21 is connected to the wiring PBL, the other of the pair of input terminals is connected to the wiring PWL, and an output terminal of the NAND circuit X21 is connected to the wiring PL. As the NAND circuit X21, a NAND gate prepared in a standard circuit library can be used.

Note that FIGS. 14A and 14B illustrate examples of the driver circuits 123, and the structure of the driver circuits 123 is not limited to the illustrated examples.

Here, in the connection example illustrated in FIG. 12, a structure in which the memory cells 111 are stacked over the corresponding driver circuits 123 may be employed. That is, for example, in the case where the driver circuit 123 has the structure illustrated in FIG. 14A, the transistor M11 and the capacitor C11 included in the memory cell 111 may be stacked over the transistor M21 included in the driver circuit 123. With the structure in which the transistor M11 and the capacitor C11 are stacked over the transistor M21, an increase in the area due to the driver circuit 123 can be inhibited.

### Structure Example 3 of Memory Device

A memory device 700 of one embodiment of the present invention is described.

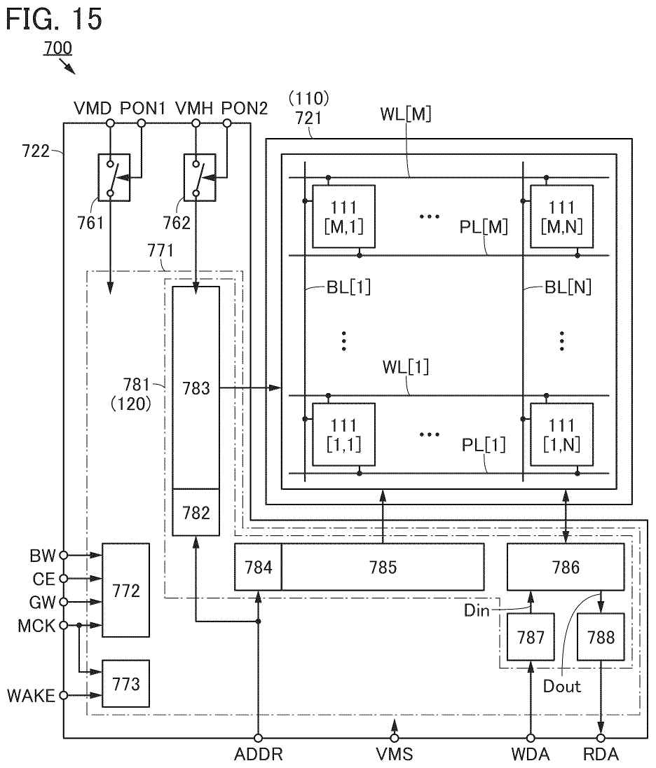

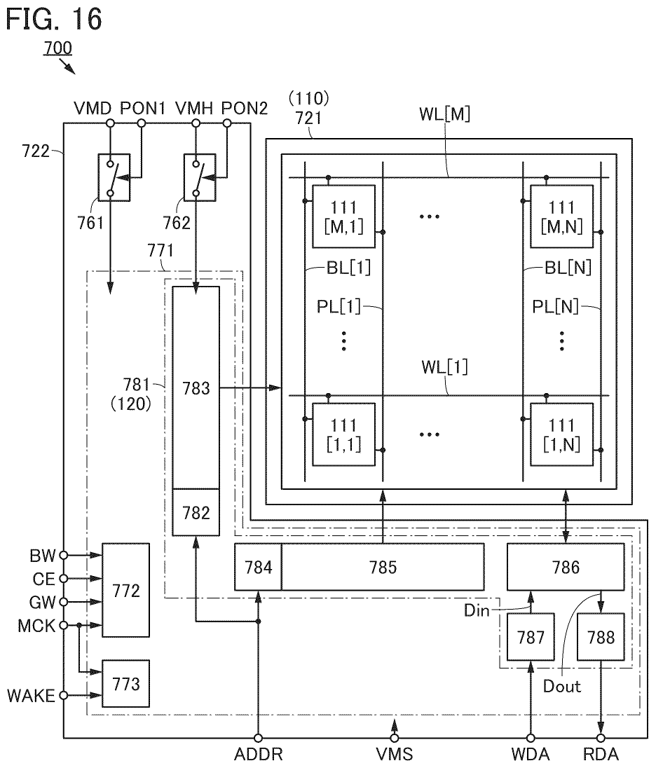

FIG. 15 and FIG. 16 are block diagrams each illustrating a structure example of the memory device 700. The memory device 700 illustrated in each of FIG. 15 and FIG. 16 includes a memory array portion 721 and a peripheral circuit portion 722.

The memory array portion 721 includes the plurality of memory cells 111. The plurality of memory cells 111 are arranged in a matrix of M rows and N columns. Here, M is an integer greater than or equal to 1, and Nis an integer greater than or equal to 1.

Note that FIG. 15 and FIG. 16 each illustrate, as representative memory cells, the memory cell 111[1, 1] positioned in the first row and the first column, a memory cell 111[1, N] positioned in the first row and the N-th column, a memory cell 111[M, 1] positioned in the M-th row and the first column, and a memory cell 111[M, N] positioned in the M-th row and the N-th column.

FIG. 15 illustrates the wiring WL[1] and the wiring PL[1] connected to the N memory cells 111 positioned in the first row, a wiring WL[M] and a wiring PL[M] connected to the N memory cells 111 positioned in the M-th row, the wiring BL[1] connected to the M memory cells 111 positioned in the first column, and a wiring BL[N] connected to the M memory cells 111 positioned in the N-th column.

FIG. 16 illustrates the wiring WL[1] connected to the N memory cells 111 positioned in the first row, the wiring WL[M] connected to the N memory cells 111 positioned in the M-th row, the wiring BL[1] and the wiring PL[1] connected to the M memory cells 111 positioned in the first column, and the wiring BL[N] and the wiring PL[N] connected to the M memory cells 111 positioned in the N-th column.

Here, the memory array portion 721 corresponds to the above-described memory array 110. Note that the structure example of the memory array portion 721 illustrated in FIG. 15 corresponds to the above-described connection example illustrated in FIG. 8. The structure example of the memory array portion 721 illustrated in FIG. 16 corresponds to the above-described connection example illustrated in FIG. 10.

The peripheral circuit portion 722 includes a power switch 761, a power switch 762, and a peripheral circuit 771. The peripheral circuit 771 includes a peripheral circuit 781, a control circuit 772, and a voltage generation circuit 773.

In one embodiment of the present invention, a Si transistor can be used as a transistor included in the peripheral circuit portion 722, for example. Thus, a CMOS circuit (e.g., a circuit where the transistors operate complementarily, a CMOS logic gate, or a CMOS logic circuit) formed by connecting a gate of an n-channel Si transistor and a gate of a p-channel Si transistor can be used in the peripheral circuit portion 722, for example.

When an OS transistor is used as a transistor included in the memory cell 111, for example, the memory array portion 721 can be stacked over the peripheral circuit portion 722 using a Si transistor. Thus, the size of the memory device 700 can be reduced. In addition, the wiring distance between the peripheral circuit portion 722 and the memory array portion 721 can be shortened. As a result, the reading speed and writing speed of the memory device 700 can be improved, for example.

Although not illustrated, a structure in which the memory array portion 721 includes a plurality of sense amplifiers arranged in a matrix and the plurality of memory cells 111 are stacked over the sense amplifiers can be employed in the memory device 700. With such a structure, data stored in the memory array portion 721 can be read out in a massively parallel manner by accessing the plurality of sense amplifiers at the same time.

Signals are supplied to a terminal BW, a terminal CE, a terminal GW, a terminal MCK, a terminal WAKE, a terminal ADDR, a terminal WDA, a terminal PON1, and a terminal PON2 from the outside of the memory device 700, for example. Furthermore, for example, a signal is output from a terminal RDA to the outside of the memory device 700.

For example, a clock signal is supplied to the terminal MCK. Control signals are supplied to the terminal BW, the terminal CE, and the terminal GW. A chip enable signal is supplied to the terminal CE. A global write enable signal is supplied to the terminal GW. A byte write enable signal is supplied to the terminal BW. An address signal is supplied to the terminal ADDR. Data to be written is supplied to the terminal WDA. The read data is supplied to the terminal RDA. Power gating control signals are supplied to the terminal PON1 and the terminal PON2. Note that the signals supplied to the terminal PON1 and the terminal PON2 may be generated in the control circuit 772, for example.

The control circuit 772 has a function of controlling the operation of the memory device 700. The control circuit 772 has a function of performing a logic operation of the signals supplied to the terminal CE, the terminal GW, and the terminal BW to determine an operation mode (e.g., a writing operation or a reading operation) of the memory device 700, for example. The control circuit 772 also has a function of generating a signal for controlling the peripheral circuit 781 so that the operation mode is executed.

The voltage generation circuit 773 has a function of generating a potential for operating the peripheral circuit portion 722. The voltage generation circuit 773 has a function of generating a potential in response to the input of a clock signal supplied to the terminal MCK in accordance with the signal supplied to the terminal WAKE, for example. To the terminal WAKE, a signal for controlling whether the clock signal supplied to the terminal MCK is input to the voltage generation circuit 773 is supplied, for example.

The peripheral circuit 781 has a function of writing and reading data to/from the memory cells 111. The peripheral circuit 781 has a function of generating a variety of signals for controlling the operation of the memory cells 111 or the like, for example. The peripheral circuit 781 includes a row decoder 782, a column decoder 784, a row driver 783, a column driver 785, a data driver 786, an input circuit 787, and an output circuit 788.

The row decoder 782 and the column decoder 784 have a function of decoding an address signal supplied to the terminal ADDR. The row decoder 782 has a function of specifying a row to be accessed. The column decoder 784 has a function of specifying a column to be accessed. The row driver 783 has a function of selecting the row specified by the row decoder 782 and supplying a desired signal to the corresponding memory cells 111 or the like, for example. The column driver 785 has a function of selecting the column specified by the column decoder 784 and supplying a desired signal to the corresponding memory cells 111 or the like, for example.

The data driver 786 has a function of writing and reading data to/from the memory cells 111 selected by the row driver and the column driver. The input circuit 787 has a function of retaining data supplied to the terminal WDA from the outside of the memory device 700. Data (data Din) retained in the input circuit 787 is written to the memory cells 111 through the data driver 786. Data stored in the memory cells 111 is read out to the output circuit 788 through the data driver 786. The output circuit 788 has a function of retaining the read data (data Dout). In addition, the output circuit 788 has a function of outputting the retained data from the terminal RDA to the outside of the memory device 700.

Note that the peripheral circuit 781 can have a function corresponding to the above-described peripheral circuit 120. In other words, the peripheral circuit 781 can have a function corresponding to the driver circuit 121, a function corresponding to the driver circuit 122, and a function corresponding to the driver circuit 123.

In the memory device 700 illustrated in FIG. 15, for example, the row driver 783 may have a function corresponding to the driver circuit 122 and a function corresponding to the driver circuit 123, and the column driver 785 and the data driver 786 may have a function corresponding to the driver circuit 121. In other words, the row driver 783 may have a function of supplying a desired signal to the wiring WL[1] to the wiring WL[M] and a function of supplying a desired potential to the wiring PL[1] to the wiring PL[M], and the column driver 785 and the data driver 786 may have a function of transmitting and receiving data to/from the wiring BL[1] to the wiring BL[N].

In the memory device 700 illustrated in FIG. 16, for example, the row driver 783 may have a function corresponding to the driver circuit 122, and the column driver 785 and the data driver 786 may have a function corresponding to the driver circuit 121 and a function corresponding to the driver circuit 123. In other words, the row driver 783 may have a function of supplying a desired signal to the wiring WL[1] to the wiring WL[M], and the column driver 785 and the data driver 786 may have a function of transmitting and receiving data to/from the wiring BL[1] to the wiring BL[N] and a function of supplying a desired potential to the wiring PL[1] to the wiring PL[M].

The power switch 761 has a function of controlling whether a potential supplied to a terminal VMD is supplied to the peripheral circuit 771. The power switch 762 has a function of controlling whether a potential supplied to a terminal VMH is supplied to the row driver 783. Here, for example, a high power supply potential (e.g., the potential VDD) for operating the peripheral circuit portion 722 is supplied to the terminal VMD, and a low power supply potential (e.g., the potential VSS) is supplied to a terminal VMS. For example, a high power supply potential (e.g., a potential higher than the potential VDD) for operating the memory cells 111 or the like is supplied to the terminal VMH. The power switch 761 is controlled to be in the conduction state or the non-conduction state by the signal supplied to the terminal PON1. The power switch 762 is controlled to be in the conduction state or the non-conduction state by the signal supplied to the terminal PON2.

Note that circuits and terminals are selected as appropriate in the peripheral circuit portion 722. Another circuit and another terminal may be added as appropriate.

The structure, operation, and the like of one embodiment of the present invention are not limited to the structure examples, operation examples, and the like described in this embodiment. At least part of the structure examples and operation examples exemplified in this embodiment, the corresponding drawings, and the like can be combined as appropriate with other structure examples, other operation examples, other drawings, other embodiments, and the like described in this specification and the like.

### Embodiment 2

In this embodiment, a structure example of a memory cell that can be used in the memory device described above in Embodiment 1 will be described. Furthermore, a structure example of a transistor that can be used in the memory device described above in Embodiment 1 will be described.

### <Structure Example of Memory Cell>

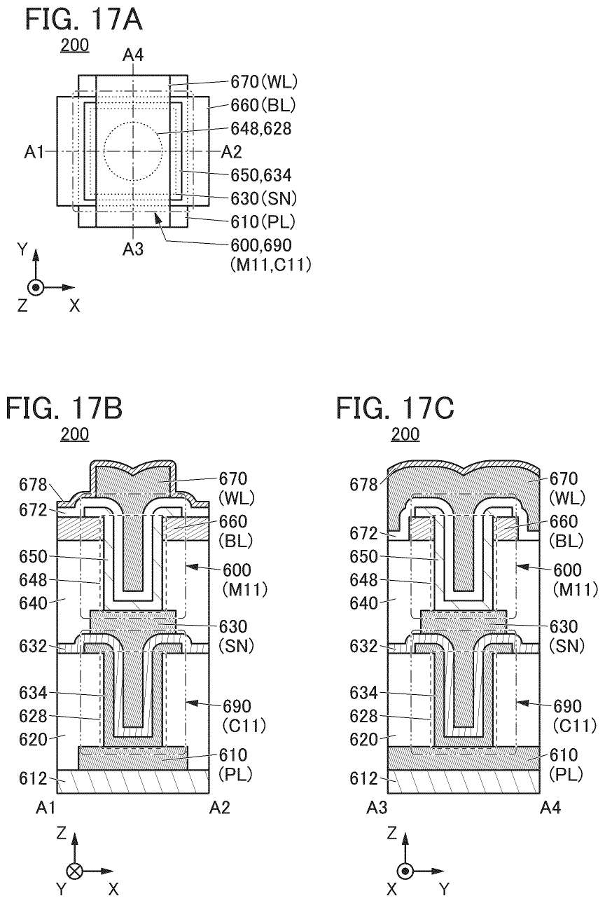

FIGS. 17A to 17C are a top view and cross-sectional views illustrating a structure example of a semiconductor device 200 including a transistor 600 and a capacitor 690. At least part of the semiconductor device 200 can be used in the memory cell of one embodiment of the present invention, for example, in the memory cell 111 described above in Embodiment 1.

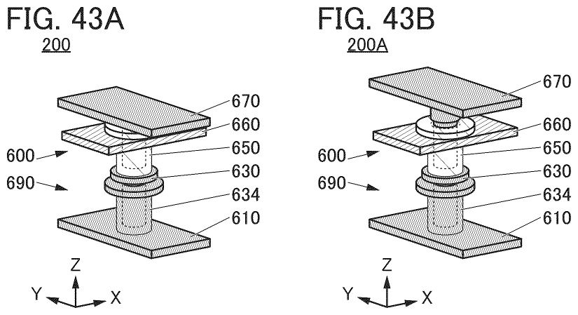

FIG. 17A is a top view of the semiconductor device 200. FIG. 17B is a cross-sectional view taken along the dashed-dotted line A1-A2 in FIG. 17A. FIG. 17C is a cross-sectional view taken along the dashed-dotted line A3-A4 in FIG. 17A. Note that for simplification, some components are not illustrated in the top view of FIG. 17A. In FIG. 43A that is a schematic perspective view of the semiconductor device 200, some components are not illustrated. FIG. 43A illustrates an example of the case where the outer edge of each of a conductor 630, a conductor 634, and an oxide 650 is circular in the top view.

FIGS. 17A to 17C illustrate an insulator 612, a conductor 610 over the insulator 612, the transistor 600 and the capacitor 690 over the conductor 610, an insulator 620 over the conductor 610, an insulator 640 over the insulator 620, and an insulator 678 over the transistor 600 and the capacitor 690. The insulator 612, the insulator 620, the insulator 640, and the insulator 678 function as interlayer films. The conductor 610 functions as a wiring.

As illustrated in FIGS. 17A to 17C, the transistor 600 is provided to overlap with the capacitor 690. An opening 648 where part of the components of the transistor 600 is provided includes a region overlapping with an opening 628 where part of the components of the capacitor 690 is provided. In particular, since the conductor 630 has a function of one of a source electrode and a drain electrode of the transistor 600 and a function of one electrode of a pair of electrodes of the capacitor 690, the transistor 600 and the capacitor 690 share part of the structure. With such a structure, the transistor 600 and the capacitor 690 can be provided without an increase in the area in the top view.

### [Capacitor 690]

The capacitor 690 includes the conductor 634 over the conductor 610, an insulator 632 over the conductor 634, and the conductor 630 over the insulator 632. The conductor 630 functions as the one of the pair of electrodes (sometimes referred to as an upper electrode), the conductor 634 functions as the other of the pair of electrodes (sometimes referred to as a lower electrode), and the insulator 632 functions as a dielectric. That is, the capacitor 690 is a metal-insulator-metal (MIM) capacitor.

As illustrated in FIGS. 17B and 17C, the opening 628 reaching the conductor 610 is provided in the insulator 620. At least part of the conductor 634 is provided in the opening 628.

Note that the conductor 634 includes a region in contact with a top surface of the conductor 610 in the opening 628, a region in contact with a side surface of the insulator 620 in the opening 628, and a region in contact with at least part of a top surface of the insulator 620. The insulator 632 is placed so that at least part of the insulator 632 is positioned in the opening 628. The conductor 630 is placed so that at least part of the conductor 630 is positioned in the opening 628. Note that the conductor 630 is preferably provided to fill the opening 628 as illustrated in FIGS. 17B and 17C.

The upper electrode and the lower electrode of the capacitor 690 face each other with the dielectric positioned therebetween, along a side surface of the opening 628 as well as a bottom surface thereof; thus, the capacitance per unit area can be increased. Accordingly, when the opening 628 is deeper, the capacitance of the capacitor 690 can be larger.

The side surface of the opening 628 (sometimes referred to as the side surface of the insulator 620 in the opening 628) is preferably perpendicular to the top surface of the conductor 610. In other words, the insulator 620 includes the opening 628 that is provided to extend in the direction perpendicular to the top surface of the conductor 610. At this time, the opening 628 has a cylindrical shape.

Although an example where the opening 628 is circular in the top view is described in this embodiment, one embodiment of the present invention is not limited thereto. For example, the opening 628 may have an almost circular shape such as an elliptical shape, a polygonal shape such as a square, or a polygonal shape with rounded corners such as a square with rounded corners. In such cases, the maximum width of the opening 628 can be calculated as appropriate in accordance with the shape of the uppermost portion of the opening 628 in the top view.

For example, in the case where the opening 628 is square in the top view, the maximum width of the opening 628 may be the length of a diagonal line of the square. Alternatively, for example, in the case where the opening 628 has an almost circular shape such as an elliptical shape, a polygonal shape, or a polygonal shape with rounded corners in the top view, the maximum width of the opening 628 may be the maximum width of the shape of the opening 628 in the top view.

Portions of the conductor 634, the insulator 632, and the conductor 630 that are provided in the opening 628 reflect the shape of the opening 628. Thus, the conductor 634 is provided along the opening 628, the insulator 632 is provided to cover the conductor 634, and the conductor 630 is provided to fill a depressed portion of the insulator 632 that reflects the shape of the opening 628.

That is, part of the dielectric (corresponding to the insulator 632) of the capacitor 690 is provided along the side surface of the opening 628. In other words, part of the dielectric of the capacitor 690 is provided in the direction perpendicular to the top surface of the conductor 610. In other words, a surface where the upper electrode and the dielectric of the capacitor 690 are in contact with each other and a surface where the lower electrode and the dielectric of the capacitor 690 are in contact with each other each include a component in a direction perpendicular to the top surface of the conductor 610.

Although the opening 628 is provided so that the side surface of the opening 628 is perpendicular to the top surface of the conductor 610 in FIGS. 17B and 17C, one embodiment of the present invention is not limited thereto. For example, the side surface of the opening 628 may have a tapered shape.

In this specification and the like, a tapered shape indicates a shape in which at least part of a side surface of a structure is inclined to a substrate surface. An angle formed between the inclined side surface and the substrate surface is referred to as a taper angle. In particular, in this specification and the like, a tapered shape with a taper angle of greater than 0° and less than 90° is referred to as a forward tapered shape, and a tapered shape with a taper angle of greater than 90° and less than 180° is referred to as an inverse tapered shape, in some cases.

The conductor 634 and the insulator 632 are stacked along the side surface of the opening 628 and the top surface of the conductor 610. The conductor 630 is provided over the insulator 632 to fill the opening 628. In this specification and the like, the capacitor 690 having such a structure is sometimes referred to as a trench-shaped capacitor, a trench capacitor, a deep-trench stacked capacitor, or the like.

The insulator 640 is placed over the capacitor 690. That is, the insulator 640 is placed above the conductor 634, the insulator 632, and the conductor 630. In other words, the conductor 630 is placed below the insulator 640.

The conductor 610 is provided below the conductor 634. The conductor 634 includes a region in contact with the conductor 610.

The conductor 610 is provided over the insulator 612. The conductor 610 can be provided in a planar shape, for example.

As the insulator 612, a material that can be used as an insulator 514 described later may be used, for example.

The conductor 610 is preferably formed using a conductive material with high conductivity. Note that the conductor 610 may have a single-layer structure or a structure in which different materials are stacked. As the conductor 610, a material that can be used as a conductor 503 or a conductor 560, which are described later, may be used, for example. For example, tungsten can be used.

As the conductor 634, a single layer or stacked layers of a conductive material that is unlikely to be oxidized, a conductive material having a function of inhibiting diffusion of oxygen, or the like is preferably used. Thus, in the case where an oxide insulator is used as the insulator 632, oxidation of the conductor 634 by the insulator 632 can be inhibited. Furthermore, in the case where an oxide insulator is used as the insulator 620, oxidation of the conductor 634 by the insulator 620 can be inhibited.

As the conductor 634, a material that can be used as the conductor 503 or the conductor 560, which are described later, may be used, for example. For example, titanium nitride, indium tin oxide to which silicon is added, or the like may be used. For example, a structure in which titanium nitride is stacked over tungsten may be used. Alternatively, a structure in which tungsten is stacked over first titanium nitride and second titanium nitride is stacked over the tungsten may be used, for example.

The insulator 632 is provided over the conductor 634. The insulator 632 is provided in contact with a top surface and a side surface of the conductor 634. That is, the insulator 632 preferably covers a side end portion of the conductor 634. This can prevent a short circuit between the conductor 634 and the conductor 630.

Note that as illustrated in FIGS. 17B and 17C, the insulator 632 may be provided to extend and be in contact with the top surface of the insulator 620.

Alternatively, a side end portion of the insulator 632 and the side end portion of the conductor 634 may be aligned with each other. With this structure, the insulator 632 and the conductor 634 can be formed using the same mask, so that the manufacturing process can be simplified.

As the insulator 632, a material with a high dielectric constant (what is called a high-k material) is preferably used. Using a high-k material as the insulator 632 allows the insulator 632 to be thick enough to inhibit a gate leakage current and the capacitor 690 to have a sufficiently high capacitance.

As the insulator of high dielectric constant material, an oxide, an oxynitride, a nitride oxide, or a nitride containing one or more kinds of metal element selected from aluminum, hafnium, zirconium, gallium, and the like can be used, for example. These materials may contain silicon. Insulators each formed of any of the above-described materials can be stacked to be used.

As the insulator of the high dielectric constant material, aluminum oxide, hafnium oxide, zirconium oxide, an oxide containing aluminum and hafnium, an oxynitride containing aluminum and hafnium, an oxide containing silicon and hafnium, an oxynitride containing silicon and hafnium, an oxide containing silicon and zirconium, an oxynitride containing silicon and zirconium, an oxide containing hafnium and zirconium, or an oxynitride containing hafnium and zirconium can be used, for example.

Insulators each formed of any of the above-described materials can be stacked to be used. In that case, a structure in which a high dielectric constant material and a material having a higher dielectric strength than the high dielectric constant material are stacked is preferably used.

For example, as such an insulator, an insulator in which zirconium oxide, aluminum oxide, and zirconium oxide are stacked in this order can be used. For another example, an insulator in which zirconium oxide, aluminum oxide, zirconium oxide, and aluminum oxide are stacked in this order can be used. For another example, an insulator in which hafnium zirconium oxide, aluminum oxide, hafnium zirconium oxide, and aluminum oxide are stacked in this order can be used. The stacking of an insulator having relatively high dielectric strength, such as aluminum oxide, as the insulator can increase the dielectric strength and inhibit electrostatic breakdown of the capacitor including the insulator.

The conductor 630 is provided in contact with part of a top surface of the insulator 632. A side end portion of the conductor 630 is preferably positioned inside the side end portion of the conductor 634 in both the X direction and the Y direction. Note that in the structure where the insulator 632 covers the side end portion of the conductor 634, the side end portion of the conductor 630 may be positioned outside the side end portion of the conductor 634.

A single layer of a conductive material or stacked layers of conductive materials can be used for the conductor 630. A conductive material that is not easily oxidized, a conductive material having a function of inhibiting diffusion of oxygen, or the like is preferably used for the conductor 630, for example.

As the conductor 630, a material that can be used as the conductor 503, the conductor 560, or a conductor 542, which are described later, may be used, for example. For example, titanium nitride, tantalum nitride, or the like can be used.

The insulator 620 functions as an interlayer film and preferably has a low dielectric constant. In the case where a material with a low dielectric constant is used for an interlayer film, parasitic capacitance generated between wirings can be reduced. As the insulator 620, a single layer of an insulator containing a material with a low dielectric constant or stacked layers of such insulators can be used.

As the insulator 620, a material that can be used as an insulator 516 described later may be used, for example. For example, silicon oxide or silicon oxynitride is preferably used in terms of thermal stability.

### [Transistor 600]

The transistor 600 includes the conductor 630, a conductor 660 over the insulator 640, the oxide 650, an insulator 672 over the oxide 650, and a conductor 670 over the insulator 672. The oxide 650 functions as a semiconductor film including a channel formation region, the conductor 670 functions as a gate electrode, the insulator 672 functions as a gate insulating film, the conductor 630 functions as one of a source electrode and a drain electrode, and the conductor 660 functions as the other of the source electrode and the drain electrode.

In the transistor 600, a metal oxide functioning as an oxide semiconductor is used as the oxide 650 including the channel formation region. As the oxide 650, a metal oxide that can be used as an oxide 530 described later may be used, for example.

Note that a semiconductor that can be used as the oxide 650 including the channel formation region is not limited to a metal oxide functioning as an oxide semiconductor. The same applies to the oxide 530, an oxide 830, and the like which are described later. Therefore, in this specification and the like, the term “oxide” may be replaced with the term “semiconductor”, “semiconductor layer”, or “semiconductor film” as appropriate.

As illustrated in FIGS. 17B and 17C, the opening 648 reaching the conductor 630 is provided in the insulator 640 and the conductor 660. At least part of the oxide 650 is provided in the opening 648. Note that the oxide 650 includes a region in contact with a top surface of the conductor 630 in the opening 648, a region in contact with a side surface of the conductor 660 in the opening 648, and a region in contact with at least part of a top surface of the conductor 660. The insulator 672 is placed so that at least part of the insulator 672 is positioned in the opening 648. The conductor 670 is placed so that at least part of the conductor 670 is positioned in the opening 648. Note that the conductor 670 is preferably provided to fill the opening 648 as illustrated in FIGS. 17B and 17C.

For example, the conductor 630 may have a structure in which tantalum nitride is stacked over titanium nitride. In that case, titanium nitride may be in contact with the insulator 632 and tantalum nitride may be in contact with the oxide 650. With such a structure, the conductor 630 can be inhibited from being excessively oxidized by the oxide 650. In the case of using an oxide insulator as the insulator 632, the excessive oxidation of the conductor 630 due to the insulator 632 can be inhibited. Note that the conductor 630 may have a structure in which tungsten is stacked over titanium nitride, for example.

The conductor 630 includes a region in contact with the oxide 650 and thus is preferably formed using a conductive material containing oxygen. With such a structure, the conductivity can be maintained even when the conductor 630 absorbs oxygen. Also in the case where a material containing oxygen is used as the insulator 632, the conductivity of the conductor 630 can be maintained.

As the conductor 630, a single layer or stacked layers of indium tin oxide (also referred to as ITO), indium tin oxide to which silicon is added (also referred to as ITSO), indium zinc oxide (IZO (registered trademark)), or the like can be used, for example.

The oxide 650 includes the region in contact with the side surface of the conductor 660 in the opening 648 and the region in contact with part of the top surface of the conductor 660. When the oxide 650 is in contact with not only the side surface but also the top surface of the conductor 660 in this manner, the area where the oxide 650 and the conductor 660 are in contact with each other can be increased.

FIG. 17C illustrates a structure in which a side end portion of the oxide 650 is positioned inside a side end portion of the conductor 660. Note that one embodiment of the present invention is not limited to the structure. For example, in the Y direction, the side end portion of the oxide 650 and the side end portion of the conductor 660 may be aligned with each other. Alternatively, the side end portion of the oxide 650 may be positioned outside the side end portion of the conductor 660.

As illustrated in FIGS. 17A to 17C, it is preferable that the conductor 670 be provided to extend in the Y direction and the conductor 660 be provided to extend in the X direction. With such a structure, the conductor 670 and the conductor 660 are provided to intersect with each other. Although the conductor 610 is provided in a plane shape in FIG. 17A, one embodiment of the present invention is not limited thereto. For example, the conductor 610 may be provided parallel to the conductor 670 or the conductor 660.

A side surface of the opening 648 (sometimes referred to as a side surface of the insulator 640 in the opening 648) is preferably perpendicular to the top surface of the conductor 610. In other words, the insulator 640 includes the opening 648 that is provided to extend in the direction perpendicular to the top surface of the conductor 610. At this time, the opening 648 has a cylindrical shape.

Although an example where the opening 648 is circular in the top view is described in this embodiment, one embodiment of the present invention is not limited thereto. For example, the opening 648 may have an almost circular shape such as an elliptical shape, a polygonal shape such as a square, or a polygonal shape with rounded corners such as a square with rounded corners. In such cases, the maximum width of the opening 648 can be calculated as appropriate in accordance with the shape of the uppermost portion of the opening 648 in the top view.

For example, in the case where the opening 648 is square in the top view, the maximum width of the opening 648 may be the length of a diagonal line of the square. Alternatively, for example, in the case where the opening 648 has an almost circular shape such as an elliptical shape, a polygonal shape, or a polygonal shape with rounded corners in the top view, the maximum width of the opening 648 may be the maximum width of the shape of the opening 648 in the top view.

Portions of the oxide 650, the insulator 672, and the conductor 670 that are provided in the opening 648 reflect the shape of the opening 648. Thus, the oxide 650 is provided along the opening 648, the insulator 672 is provided to cover the oxide 650, and the conductor 670 is provided to fill a depressed portion of the insulator 672 that reflects the shape of the opening 648.

That is, part of the semiconductor film (corresponding to the oxide 650) including the channel formation region of the transistor 600 is provided along the side surface of the opening 648. In other words, part of the semiconductor film is provided in a direction perpendicular to the top surface of the conductor 610. In other words, the channel length direction of the transistor 600 includes a component in a direction perpendicular to the top surface of the conductor 610. That is, the channel length direction includes a component in the vertical direction (which is the Z direction in FIGS. 17A to 17C and is also referred to as the height direction or the direction perpendicular to a formation surface). In other words, the source electrode and the drain electrode are positioned at different heights, and a drain current flows in the vertical direction. Thus, the transistor of one embodiment of the present invention is a transistor whose channel length direction includes a component in the vertical direction (i.e., a transistor in which a drain current flows in the vertical direction), and can be referred to as a vertical field effect transistor (VFET), a vertical transistor, a transistor of a vertical type, a vertical channel transistor, a transistor of a vertical channel type, or the like, for example.

Here, as the conductor 660, a material that can be used as the conductor 630 can be used, for example. As the conductor 670, a material that can be used as the conductor 630 may be used, for example. As the insulator 672, a material that can be used as an insulator 522, an insulator 524, or an insulator 545, which are described later, may be used, for example. As the insulator 640, a material that can be used as the insulator 620 may be used, for example. As the insulator 678, a material that can be used as the insulator 514 described later or the above-described insulator 612 may be used, for example.

Although the opening 648 is provided so that the side surface of the opening 648 is perpendicular to the top surface of the conductor 610 in FIGS. 17B and 17C, one embodiment of the present invention is not limited thereto. For example, the side surface of the opening 648 may have a tapered shape.

Although the oxide 650 has a single-layer structure in FIGS. 17B and 17C, one embodiment of the present invention is not limited thereto. The oxide 650 may have a stacked-layer structure of a plurality of oxide layers with different chemical compositions.

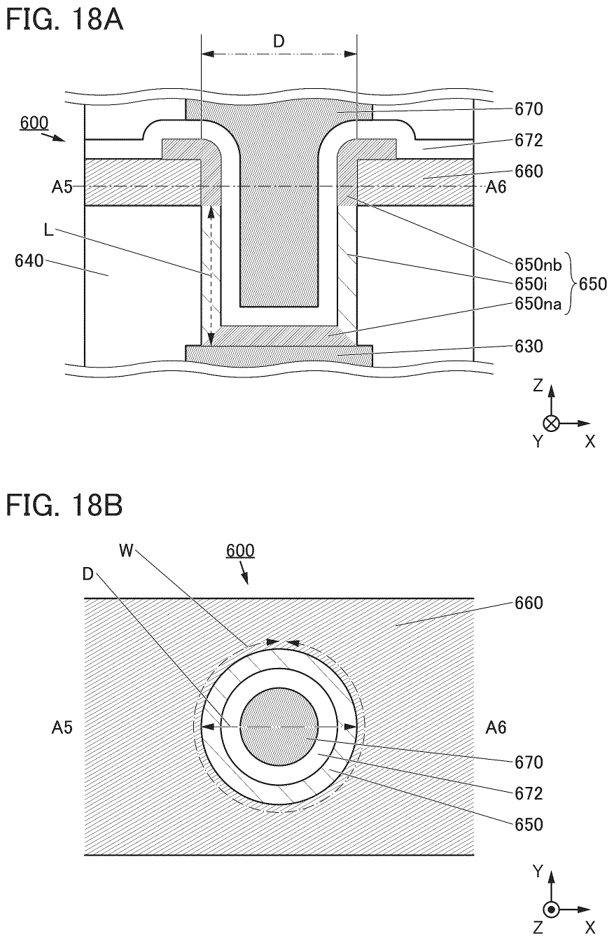

FIG. 18A is an enlarged view of the oxide 650 and its vicinity in FIG. 17B. FIG. 18B is the cross-sectional view taken along the XY plane including the conductor 660.

As illustrated in FIG. 18A, the oxide 650 includes a region 650i and regions 650na and 650nb provided with the region 650i positioned therebetween.

The region 650na is a region of the oxide 650 that is in contact with the conductor 630.

At least part of the region 650na functions as one of a source region and a drain region of the transistor 600. The region 650nb is a region of the oxide 650 that is in contact with the conductor 660. At least part of the region 650nb functions as the other of the source region and the drain region of the transistor 600. As illustrated in FIG. 18B, the conductor 660 is in contact with the entire outer circumference of the oxide 650. Thus, the other of the source region and the drain region of the transistor 600 can be formed along the entire outer circumference of a portion formed in the same layer as the conductor 660 in the oxide 650.

The region 650i is a region of the oxide 650 between the region 650na and the region 650nb. At least part of the region 650i functions as the channel formation region of the transistor 600. That is, the channel formation region of the transistor 600 is positioned in a region of the oxide 650 between the conductor 630 and the conductor 660. It can also be said that the channel formation region of the transistor 600 is positioned in a region in contact with the insulator 640 or a region in the vicinity thereof in the oxide 650.

The channel length of the transistor 600 is a distance between the source region and the drain region. That is, the channel length of the transistor 600 is determined by the thickness of the insulator 640 over the conductor 630. In FIG. 18A, the channel length L of the transistor 600 is indicated by a dashed double-headed arrow. The channel length L is a distance between an end portion of a region where the oxide 650 and the conductor 630 are in contact with each other and an end portion of a region where the oxide 650 and the conductor 660 are in contact with each other in a cross-sectional view. That is, the channel length L corresponds to the length of a side surface of the insulator 640 on the opening 648 side in the cross-sectional view.

Here, the channel length of a planar transistor is limited by the light exposure limit of photolithography, and further miniaturization is difficult. In contrast, in one embodiment of the present invention, the channel length can be determined by the thickness of the insulator 640. Thus, the transistor 600 can have an extremely small channel length less than or equal to the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 1 nm, or greater than or equal to 5 nm). Accordingly, the transistor 600 can have a higher on-state current and higher frequency characteristics.

In addition, as described above, the channel formation region, the source region, and the drain region can be formed in the opening 648. Thus, the area occupied by the transistor 600 can be reduced as compared with a planar transistor in which the channel formation region, the source region, and the drain region are provided separately on the XY plane.

Furthermore, in the XY plane including the channel formation region of the oxide 650, as illustrated in FIG. 18B, the oxide 650, the insulator 672, and the conductor 670 are provided concentrically. Therefore, a side surface of the conductor 670 provided at the center faces a side surface of the oxide 650 with the insulator 672 therebetween. That is, in the top view, all the perimeter of the oxide 650 serves as the channel formation region. In this case, for example, the channel width of the transistor 600 is determined by the length of the outer circumference of the oxide 650. In other words, the channel width of the transistor 600 is determined by the maximum width of the opening 648 (the maximum diameter in the case where the opening 648 is circular in the top view). In FIGS. 18A and 18B, the maximum width D of the opening 648 is indicated by a dashed double-dotted double-headed arrow. In FIG. 18B, the channel width W of the transistor 600 is indicated by a dashed-dotted double-headed arrow. By increasing the maximum width D of the opening 648, the channel width per unit area can be increased and the on-state current can be increased.

In the case where the opening 648 is formed by a photolithography method, the maximum width D of the opening 648 is limited by the light exposure limit of photolithography, and further miniaturization is difficult. The maximum width D of the opening 648 is determined by the thicknesses of the oxide 650, the insulator 672, and the conductor 670 provided in the opening 648. The maximum width D of the opening 648 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening 648 is circular in the top view, the maximum width D of the opening 648 corresponds to the diameter of the opening 648, and the channel width W can be “D×π”.

The channel length L of the transistor 600 in one embodiment of the present invention is preferably shorter than at least the channel width W of the transistor 600. The channel length L of the transistor 600 in one embodiment of the present invention is greater than or equal to 0.1 times and less than or equal to 0.99 times, preferably greater than or equal to 0.5 times and less than or equal to 0.8 times the channel width W of the transistor 600. This structure enables a transistor with favorable electrical characteristics and high reliability.

In the case where the opening 648 is formed to be circular in the top view, the oxide 650, the insulator 672, and the conductor 670 are formed concentrically. This makes the distance between the conductor 670 and the oxide 650 substantially uniform, so that a gate electric field can be substantially uniformly applied to the oxide 650.

In one embodiment of the present invention, at least part of the semiconductor device 200 can be used in the memory cell 111 described above in Embodiment 1. That is, the transistor 600 corresponds to the transistor M11, and the capacitor 690 corresponds to the capacitor C11. That is, the conductor 670 includes a region functioning as the gate of the transistor M11, the conductor 660 includes a region functioning as the other of the source and the drain of the transistor M11, the conductor 630 includes a region functioning as the one of the source and the drain of the transistor M11 and a region functioning as the one terminal of the capacitor C11, and the conductor 610 includes a region functioning as the other terminal of the capacitor C11. Furthermore, the conductor 670 corresponds to the wiring WL, the conductor 660 corresponds to the wiring BL, the conductor 610 corresponds to the wiring PL, and the conductor 630 corresponds to the wiring SN. Note that in FIGS. 17A to 17C, portions corresponding to the transistor M11, the capacitor C11, the wiring WL, the wiring BL, the wiring PL, and the wiring SN are denoted by reference numerals with parentheses.

Note that the transistor 600 and the capacitor 690 illustrated in FIGS. 17A to 17C are examples and the structures are not limited thereto.

### [Transistor 600B]

In the above-described semiconductor device 200 of one embodiment of the present invention, a transistor including a back gate may be used.

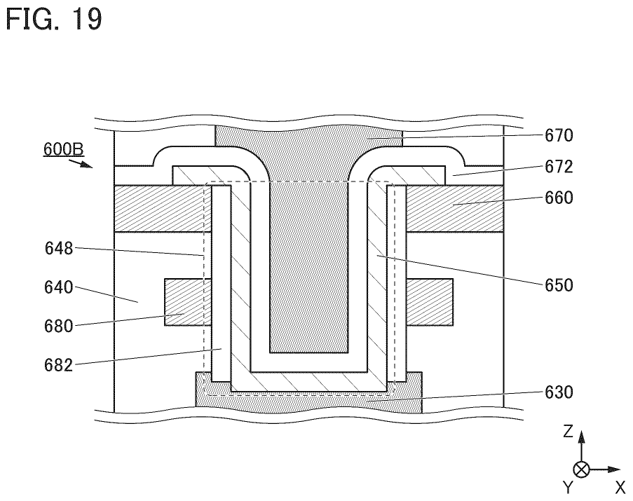

FIG. 19 is a cross-sectional view illustrating a structure example of a transistor including a back gate as one embodiment of the present invention. A transistor 600B illustrated in FIG. 19 is a modification example of the above-described transistor 600. The transistor 600B includes two gates (a gate and a back gate) corresponding to each other with a channel formation region therebetween.

The transistor 600B is different from the transistor 600 in including a conductor 680 and an insulator 682. In the transistor 600B, along the side surface of the opening 648, the insulator 682 is provided between the insulator 640 and the oxide 650, and the conductor 680 is provided in part of the insulator 640 so as to surround the outer circumference of the oxide 650 with the insulator 682 therebetween.

Here, the conductor 670 has a function of a first gate (also simply referred to as a gate) electrode, and the conductor 680 has a function of a second gate (also referred to a back gate) electrode, in some cases. In that case, the insulator 672 has a function of a first gate insulating film, and the insulator 682 has a function of a second gate insulating film.

Moreover, the transistor 600B is different from the transistor 600 in that the conductor 630 has a depressed portion in a position overlapping with the opening 648. In the transistor 600B, part of the oxide 650 and part of the insulator 682 are provided in the depressed portion of the conductor 630. In that case, the bottom surface of the oxide 650 is positioned below the bottom surface of the insulator 682.

Such a structure can increase the area where the oxide 650 and the conductor 630 are in contact with each other. Thus, the contact resistance between the oxide 650 and the conductor 630 can be reduced.

Here, as the conductor 680, a material that can be used as the conductor 670 may be used, for example. As the insulator 682, a material that can be used as the insulator 672 may be used, for example.

Here, the threshold voltage of a transistor including a back gate is shifted by the back gate voltage. The back gate of the transistor may be connected to the gate, one of the source and the drain, or the other thereof.

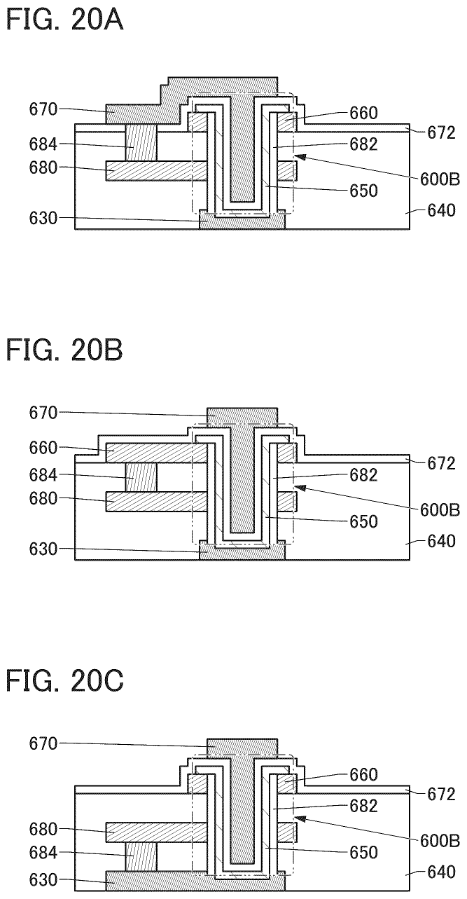

FIG. 20A is a cross-sectional view illustrating a structure example in which the back gate of the transistor 600B (corresponding to the conductor 680) is connected to the gate of the transistor 600B (corresponding to the conductor 670) through a conductor 684 embedded in the insulator 672 and the insulator 640. FIG. 20B is a cross-sectional view illustrating a structure example in which the back gate of the transistor 600B (corresponding to the conductor 680) is connected to the other of the source and the drain of the transistor 600B (corresponding to the conductor 660) through the conductor 684 embedded in the insulator 640. FIG. 20C is a cross-sectional view illustrating a structure example in which the back gate of the transistor 600B (corresponding to the conductor 680) is connected to one of the source and the drain of the transistor 600B (corresponding to the conductor 630) through the conductor 684 embedded in the insulator 640.

Note that the conductor 684 has a function of a plug or a wiring. The details of the conductor functioning as a plug or a wiring are described later.

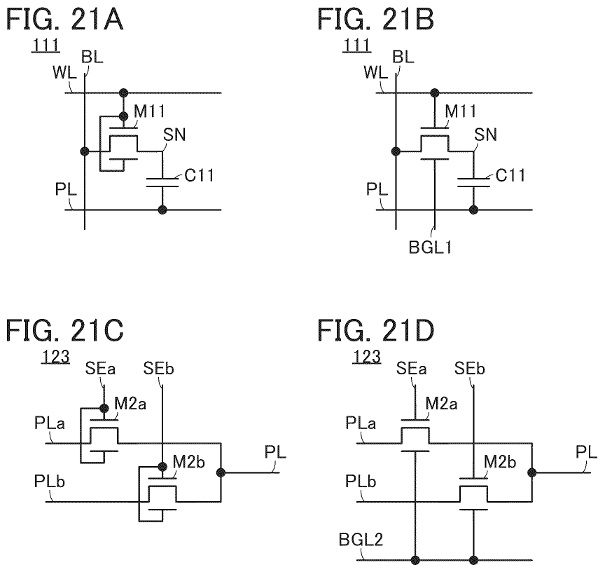

FIGS. 21A and 21B are examples of a circuit diagram in which the transistor included in the memory cell 111 described above in Embodiment 1 is replaced with a transistor including a back gate. In the example in FIG. 21A, the back gate of the transistor M11 is connected to the gate thereof. In the example in FIG. 21B, the back gate of the transistor M11 is connected to a wiring BGL1, for example.

FIGS. 21C and 21D are examples of a circuit diagram in which the transistors included in the driver circuit 123 described above in Embodiment 1 are replaced with transistors including back gates. In the example in FIG. 21C, the back gates of the transistor M2a and the transistor M2b are connected to the gates thereof. In the example in FIG. 21D, the back gates of the transistor M2a and the transistor M2b are connected to a wiring BGL2.

Here, when the back gate of the transistor is connected to the gate of the transistor, the on-state current of the transistor can be increased. Supplying an arbitrary potential to the back gate of the transistor can change the threshold voltage of the transistor.

In one embodiment of the present invention, the structure illustrated in FIG. 21B can be applied to the memory cell 111 of the memory device described above in Embodiment 1. In this case, a potential that increases the threshold voltage of the transistor M11 may be supplied to the wiring BGL1. Accordingly, the off-state current of the transistor M11 can be reduced, and data written to the memory cell 111 (i.e., the potential of the wiring SN) can be retained for a long period. Furthermore, the potential supplied to the wiring BGL1 may be changed so that the threshold voltage of the transistor M11 can be low at the time of data writing and data reading. Accordingly, the on-state current of the transistor can be increased, and the writing speed and the reading speed can be improved.

The driver circuit 123 can have the structure illustrated in FIG. 21C. Accordingly, the on-state current of the transistor M2a and the transistor M2b can be increased, so that the operation speed at the time of driving the memory cell 111 can be improved. The driver circuit 123 can have the structure illustrated in FIG. 21D. In this case, a potential that decreases the threshold voltage of each of the transistor M2a and the transistor M2b may be supplied to the wiring BGL2. Accordingly, the on-state current of the transistor M2a and the transistor M2b can be increased, so that the operation speed at the time of driving the memory cell 111 can be improved.

### [Modification Example of Semiconductor Device 200]

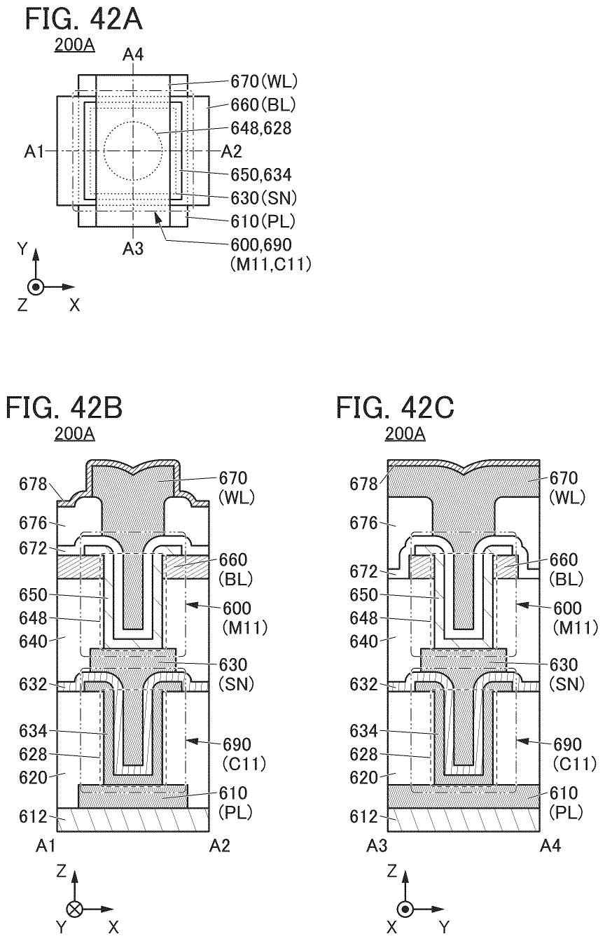

The structure of the semiconductor device including the transistor and the capacitor that can be used in one embodiment of the present invention is not limited to the structure of the semiconductor device 200 illustrated in FIGS. 17A to 17C and FIG. 43A. For example, the structure of a semiconductor device 200A illustrated in FIGS. 42A to 42C and FIG. 43B may be employed.

FIG. 42A is a top view of the semiconductor device 200A. FIG. 42B is a cross-sectional view taken along the dashed-dotted line A1-A2 in FIG. 42A. FIG. 42C is a cross-sectional view taken along the dashed-dotted line A3-A4 in FIG. 42A. Note that for simplification, some components are not illustrated in the top view of FIG. 42A. In FIG. 43B that is a schematic perspective view of the semiconductor device 200A, some components are not illustrated. FIG. 43B illustrates an example of the case where the outer edge of each of the conductor 630, the conductor 634, and the oxide 650 is circular in the top view.

The semiconductor device 200A is different from the semiconductor device 200 in including an insulator 676. The insulator 676 is provided over the insulator 672 and has an opening overlapping with the opening 648. A region functioning as a wiring of the conductor 670 is provided in contact with a side surface and a top surface of the opening in the insulator 676. As the insulator 676, any of the above-described materials that can be used as the insulator 620 or the insulator 640 may be used, for example.

In the semiconductor device 200A, the insulator 672 and the insulator 676 are provided between the conductor 670 and the conductor 660 in a region where the conductor 670 and the conductor 660 overlap with each other. Thus, the distance between the conductor 670 and the conductor 660 can be longer than that of the semiconductor device 200. Thus, the parasitic capacitance between the conductor 660 and the conductor 670 can be reduced. In addition, the conductor 670 can be easily made thick, so that the resistance can be reduced. Thus, in the case where the semiconductor device 200A is used in a memory cell, for example, the writing speed and the reading speed can be improved.

### [Modification Examples of Transistor 600 and Capacitor 690]

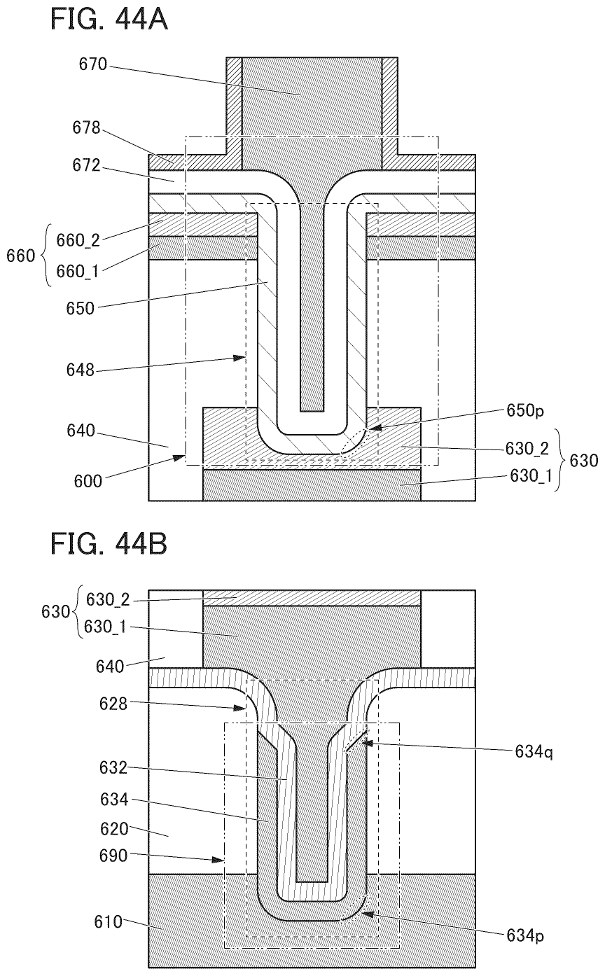

The transistor and the capacitor that can be used in one embodiment of the present invention are not limited to the transistor 600 and the capacitor 690 illustrated in FIGS. 17A to 17C. For example, the transistor 600 having the structure illustrated in FIG. 44A and the capacitor 690 having the structure illustrated in FIG. 44B may be used.

FIGS. 44A and 44B each illustrate the conductor 630 having a stacked-layer structure of a conductor 630_1 and a conductor 630_2 over the conductor 630_1. The conductor 630_1 functions as one electrode of the pair of electrodes of the capacitor 690, and the conductor 630_2 functions as one of the source electrode and the drain electrode of the transistor 600.

The conductor 660 having a stacked-layer structure of a conductor 660_1 and a conductor 660_2 over the conductor 660_1 is illustrated. For example, the conductor 660_1 can have a function of a wiring, and the conductor 660_2 can have a function of the other of the source electrode and the drain electrode of the transistor 600.

In the transistor 600 illustrated in FIG. 44A, the conductor 630_2 has a depressed portion in a position overlapping with the opening 648, and part of the oxide 650, part of the insulator 672, and part of the conductor 670 are provided in the depressed portion of the conductor 630_2. In that case, the bottom surface of the conductor 670 in the depressed portion can be positioned below the top surface of the conductor 630_2 outside the depressed portion.

When the oxide 650 is provided in a depressed portion that the conductor 630_2 has, the area where the oxide 650 and the conductor 630_2 are in contact with each other can be increased. Thus, the contact resistance between the oxide 650 and the conductor 630_2 can be reduced.

When the level of the bottom surface of the conductor 670 is set low, a gate electric field is more easily applied to the channel formation region of the oxide 650. Accordingly, the transistor 600 can have excellent electrical characteristics. In addition, a gate electric field is more easily applied also to a region that is of the oxide 650 and is in contact with the conductor 630_2. Accordingly, the amount of on-state current of the transistor 600 can be increased. Whichever of the conductors 630 and 660 functions as the drain electrode, the transistor 600 can have excellent electrical characteristics.

Here, as illustrated in FIG. 44A, the oxide 650 may include a region 650p with a curved corner in the depressed portion of the conductor 630_2. Thus, the concentration of electric field in the insulator 672 in the vicinity of the region 650p can be inhibited as compared with the case where the region 650p has a right-angle or acute-angle corner (in the case where the region 650p has an angular portion), for example. When the concentration of electric field in the insulator 672 is inhibited in this manner, the dielectric breakdown of the insulator 672 is inhibited, so that a highly reliable semiconductor device can be provided.

In the capacitor 690 illustrated in FIG. 44B, the conductor 610 has a depressed portion in a position overlapping with the opening 628, and part of the conductor 634, part of the insulator 632, and part of the conductor 630_1 are provided in the depressed portion of the conductor 610. In that case, the bottom surface of the conductor 630_1 in the depressed portion can be positioned below the top surface of the conductor 610 outside the depressed portion.

When the conductor 634 is provided in the depressed portion that the conductor 610 has, the area where the conductor 634 and the conductor 610 are in contact with each other can be increased. Thus, the contact resistance between the conductor 634 and the conductor 610 can be reduced.

Here, as illustrated in FIG. 44B, the conductor 634 may include a region 634p with a curved corner in the depressed portion of the conductor 610. Thus, the concentration of electric field in the insulator 632 in the vicinity of the region 634p can be inhibited as compared with the case where the region 634p has a right-angle or acute-angle corner (in the case where the region 634p has an angular portion), for example. An end portion 634q of the conductor 634 may be positioned below the top surface of the insulator 620. Accordingly, electric field concentration in the insulator 632 in the vicinity of the end portion 634q can be inhibited as compared with the case where the end portion 634q is positioned above the insulator 620. When the concentration of electric field in the insulator 632 is inhibited in this manner, the dielectric breakdown of the insulator 632 can be inhibited, so that a highly reliable semiconductor device can be provided.

### <Layout Example of Memory Array>

Here, layout examples of the case where the semiconductor devices 200 are arranged in a matrix are described.

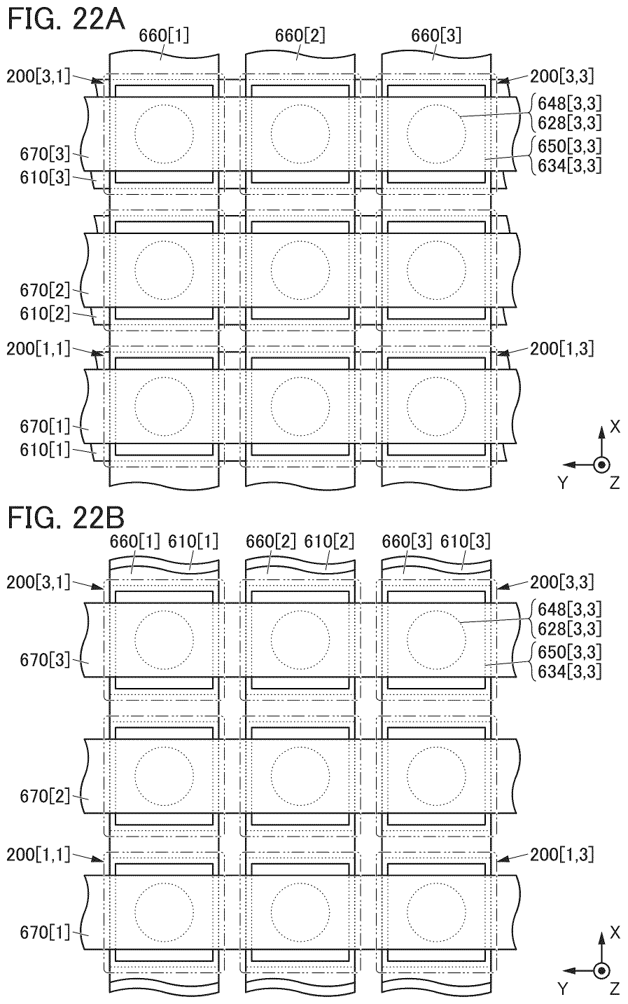

FIGS. 22A and 22B are top views each illustrating a layout example of the semiconductor devices 200 arranged in a matrix. In other words, for example, these are each a layout example of the memory array 110 that can be used in the case where the semiconductor device 200 is used as the memory cell 111 described above in Embodiment 1.

In each of FIGS. 22A and 22B, nine semiconductor devices 200 are arranged in a matrix of three rows and three columns. Here, the semiconductor device 200 placed in the first row and the first column is referred to as a semiconductor device 200[1, 1], the semiconductor device 200 placed in the first row and the third column is referred to as a semiconductor device 200[1, 3], the semiconductor device 200 placed in the third row and the first column is referred to as the semiconductor device 200[3, 1], and the semiconductor device 200 placed in the third row and the third column is referred to as a semiconductor device 200[3, 3].

In addition, the oxide 650, the conductor 634, the opening 648, and the opening 628 included in the semiconductor device 200[3, 3] are representatively denoted by 650[3, 3], 634[3, 3], 648[3, 3], and 628[3, 3], respectively.

The three semiconductor devices 200 positioned in the first row are connected to a conductor 670[1] extending in the row direction (Y direction). The three semiconductor devices 200 positioned in the second row are connected to a conductor 670[2] extending in the row direction (Y direction). The three semiconductor devices 200 positioned in the third row are connected to a conductor 670[3] extending in the row direction (Y direction).

The three semiconductor devices 200 positioned in the first column are connected to a conductor 660[1] extending in the column direction (X direction). The three semiconductor devices 200 positioned in the second column are connected to a conductor 660[2] extending in the column direction (X direction). The three semiconductor devices 200 positioned in the third column are connected to a conductor 660[3] extending in the column direction (X direction).

Here, FIG. 22A illustrates a layout example applicable to the above-described connection example illustrated in FIG. 8 in Embodiment 1, for example. Thus, in FIG. 22A, the three semiconductor devices 200 positioned in the first row are connected to a conductor 610[1] extending in the row direction (Y direction). The three semiconductor devices 200 positioned in the second row are connected to a conductor 610[2] extending in the row direction (Y direction). The three semiconductor devices 200 positioned in the third row are connected to a conductor 610[3] extending in the row direction (Y direction).

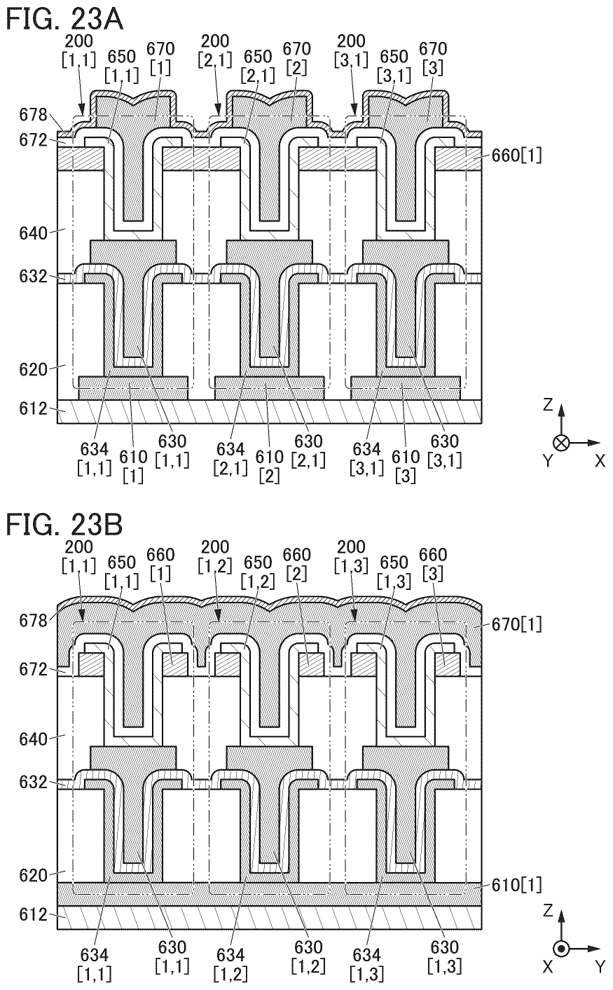

FIG. 23A is a cross-sectional view in the column direction (X direction) of the semiconductor device 200[1, 1], a semiconductor device 200[1, 2], and the semiconductor device 200[1, 3] in the layout illustrated in FIG. 22A. As illustrated in FIG. 23A, the conductor 660[1] extending in the column direction (X direction) is shared by the semiconductor device 200[1, 1], the semiconductor device 200[2, 1], and the semiconductor device 200[3, 1]. FIG. 23B is a cross-sectional view in the row direction (Y direction) of the semiconductor device 200[1, 1], the semiconductor device 200[2, 1], and the semiconductor device 200[3, 1]. As illustrated in FIG. 23B, each of the conductor 610[1] and the conductor 670[1] extending in the row direction (Y direction) is shared by the semiconductor device 200[1, 1], the semiconductor device 200[1, 2], and the semiconductor device 200[1, 3].

That is, the direction in which the conductor 610[1] to the conductor 610[3] extend is parallel to the direction in which the conductor 670[1] to the conductor 670[3] extend, and is perpendicular to the direction in which the conductor 660[1] to the conductor 660[3] extend.

In the top view, there is a region where the conductor 610[1] and the conductor 670[1] overlap with each other, a region where the conductor 610[2] and the conductor 670[2] overlap with each other, and a region where the conductor 610[3] and the conductor 670[3] overlap with each other. Note that in the top view, the end portions of the conductor 610[1] and the conductor 670[1] are not necessarily aligned with each other, the end portions of the conductor 610[2] and the conductor 670[2] are not necessarily aligned with each other, and the end portions of the conductor 610[3] and the conductor 670[3] are not necessarily aligned with each other.

Furthermore, FIG. 22B illustrates a layout example applicable to the above-described connection example illustrated in FIG. 10 in Embodiment 1, for example. Thus, in FIG. 22B, the three semiconductor devices 200 positioned in the first column are connected to the conductor 610[1] extending in the column direction (X direction). The three semiconductor devices 200 positioned in the second column are connected to the conductor 610[2] extending in the column direction (X direction). The three semiconductor devices 200 positioned in the third column are connected to the conductor 610[3] extending in the column direction (X direction).

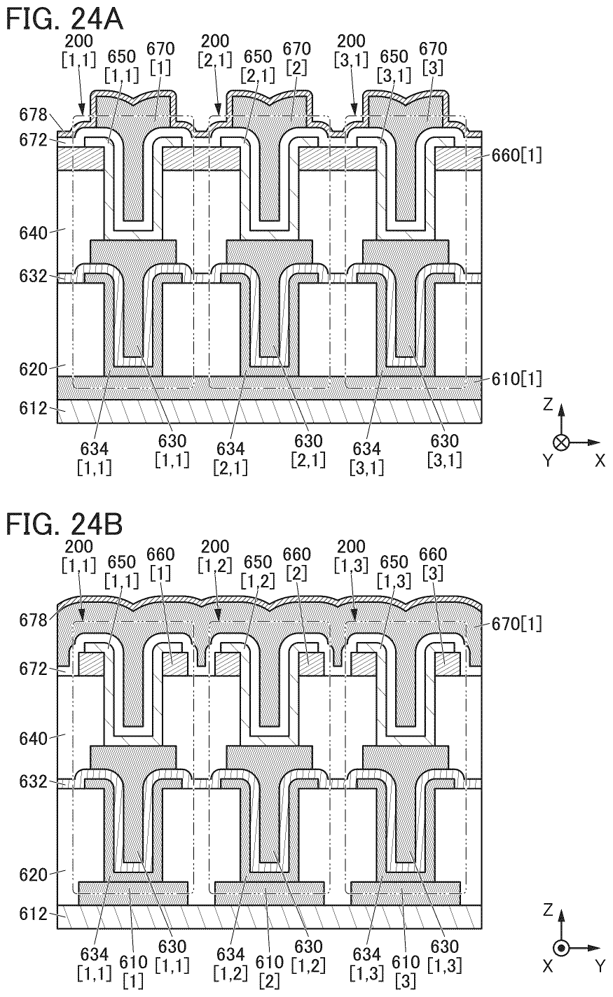

FIG. 24A is a cross-sectional view in the column direction (X direction) of the semiconductor device 200[1, 1], the semiconductor device 200[1, 2], and the semiconductor device 200[1, 3] in the layout illustrated in FIG. 22B. As illustrated in FIG. 24A, each of the conductor 610[1] and the conductor 660[1] extending in the column direction (X direction) is shared by the semiconductor device 200[1, 1], the semiconductor device 200[2, 1], and the semiconductor device 200[3, 1]. FIG. 24B is a cross-sectional view in the row direction (Y direction) of the semiconductor device 200[1, 1], the semiconductor device 200[2, 1], and the semiconductor device 200[3, 1]. As illustrated in FIG. 24B, the conductor 670[1] extending in the row direction (Y direction) is shared by the semiconductor device 200[1, 1], the semiconductor device 200[1, 2], and the semiconductor device 200[1, 3].

That is, the direction in which the conductor 610[1] to the conductor 610[3] extend is parallel to the direction in which the conductor 660[1] to the conductor 660[3] extend, and is perpendicular to the direction in which the conductor 660[1] to the conductor 660[3] extend.

In the top view, there is a region where the conductor 610[1] and the conductor 660[1] overlap with each other, a region where the conductor 610[2] and the conductor 660[2] overlap with each other, and a region where the conductor 610[3] and the conductor 660[3] overlap with each other. Note that in the top view, the end portions of the conductor 610[1] and the conductor 660[1] are not necessarily aligned with each other, the end portions of the conductor 610[2] and the conductor 660[2] are not necessarily aligned with each other, and the end portions of the conductor 610[3] and the conductor 660[3] are not necessarily aligned with each other.

As described above, when the semiconductor devices 200 arranged in a matrix are used in the memory array 110 described above in Embodiment 1 in one embodiment of the present invention, the conductor 670 corresponding to the wiring WL and the conductor 610 corresponding to the wiring PL can be provided to overlap with each other as illustrated in FIG. 22A. Furthermore, as illustrated in FIG. 22B, the conductor 660 corresponding to the wiring BL and the conductor 610 corresponding to the wiring PL can be provided to overlap with each other. Thus, the area occupied by the memory cell 111 can be reduced and the recording density can be improved.

Although the nine semiconductor devices 200 are arranged in a matrix of three rows and three columns here, one embodiment of the present invention is not limited thereto. The plurality of semiconductor devices 200 may be arranged in two rows or four or more rows. Furthermore, the plurality of semiconductor devices 200 may be arranged in two columns or four or more columns.

### <Stacking Example of Transistors>

The memory device of one embodiment of the present invention can employ transistors with various structures. In addition, a stacking structure of transistors with various structures can be employed.

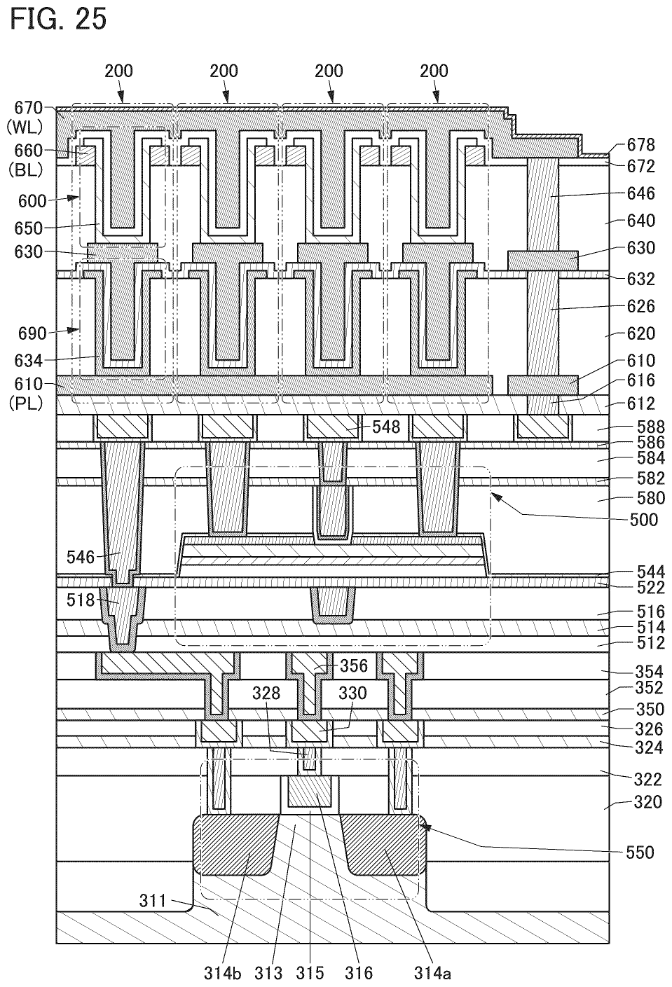

FIG. 25 is a cross-sectional view of a semiconductor device including a transistor 550, a transistor 500, the transistor 600, and the capacitor 690 (i.e., the semiconductor device 200). Note that FIG. 25 is a cross-sectional view in the channel length direction of the transistor 550.

As illustrated in FIG. 25, the transistor 500 is provided above the transistor 550. The semiconductor devices 200 (four representative semiconductor devices 200 are illustrated here) are provided above the transistor 500.

A conductor 328 over the transistor 550 may be connected to a conductor 548 over the transistor 500 through a conductor 330, a conductor 356, a conductor 518, a conductor 546, and the like. The conductor 548 may be connected to the conductor 670 through a conductor 616, the conductor 610, a conductor 626, the conductor 630, a conductor 646, and the like. Note that these conductors may be formed using conductors having a function of plugs or wirings.

Note that in this specification and the like, a plurality of structures of conductors functioning as plugs or wirings are collectively denoted by the same reference numeral in some cases. Furthermore, the wiring and the plug may be a single component. That is, in some cases, part of a conductor functions as a wiring and part of the conductor functions as a plug.

As each plug or wiring, a conductive material such as a metal material, an alloy material, a metal nitride material, or a metal oxide material can be used in a single-layer structure or a stacked-layer structure, for example.

It is particularly preferable to use, as each plug or wiring, a high-melting-point material that has both heat resistance and conductivity. As such a material, tungsten, molybdenum, or the like can be used, for example. Furthermore, as each plug or wiring, a low-resistance conductive material that can reduce wiring resistance is preferably used. As such a material, aluminum, copper, or the like can be used, for example.

### [Transistor 550]

The transistor 550 is described.

As illustrated in FIG. 25, the transistor 550 is provided on a substrate 311 and includes a conductor 316 functioning as a gate electrode, an insulator 315 functioning as a gate insulating film, a semiconductor region 313 functioning as a channel formation region, a low-resistance region 314a functioning as one of a source region and a drain region, and a low-resistance region 314b functioning as the other of the source region and the drain region.

Note that the transistor 550 may be either a p-channel transistor or an n-channel transistor. For example, the gate of an n-channel transistor 550 and the gate of a p-channel transistor 550 are connected to each other, whereby a CMOS circuit (for example, a circuit where the transistors operate complementarily, a CMOS logic gate, or a CMOS logic circuit) can be formed.

Thus, in the case where the transistor 550 is used in a memory device, for example, the transistor 550 may be used as a transistor included in the peripheral circuit for operating the memory device. That is, for example, in the memory device 100 described above in Embodiment 1, the transistors 550 may be used as at least some of the transistors included in the peripheral circuit 120. Moreover, for example, in the memory device 700 described above in Embodiment 1, the transistors 550 may be used as at least some of the transistors included in the peripheral circuit portion 722.

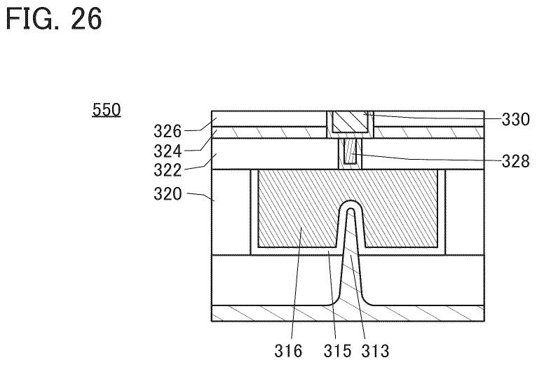

As illustrated in FIG. 26, for example, the transistor 550 can have what is called a Fin-type structure in which the top surface and the side surface in the channel width direction of the semiconductor region 313 that is part of the substrate 311 are covered with the conductor 316 with the insulator 315 therebetween. Thus, the effective channel width is increased, whereby the on-state characteristics of the transistor 550 can be improved. In addition, contribution of the electric field of the gate electrode can be increased, so that the off-state characteristics of the transistor 550 can be improved.

In the transistor 550, it is preferable that a region of the semiconductor region 313 where a channel is formed, a region in the vicinity thereof, the low-resistance region 314a which is one of the source and drain regions, the low-resistance region 314b which is the other of the source and drain regions, and the like include a semiconductor such as a silicon-based semiconductor, further preferably single crystal silicon. Alternatively, the transistor 550 may be formed using a material containing germanium, silicon germanium, gallium arsenide, gallium aluminum arsenide, or the like, for example. Alternatively, the transistor 550 may include silicon whose effective mass is adjusted by applying stress to the crystal lattice and thereby changing the lattice spacing. Alternatively, the transistor 550 may be a high electron mobility transistor (HEMT) using gallium arsenide, gallium aluminum arsenide, or the like, for example.

The low-resistance region 314a and the low-resistance region 314b contain, for example, an element that imparts n-type conductivity, such as arsenic or phosphorus, or an element that imparts p-type conductivity, such as boron, in addition to a semiconductor material used for the semiconductor region 313.

The conductor 316 can be formed using a semiconductor material such as silicon containing the element that imparts n-type conductivity, such as arsenic or phosphorus, or the element that imparts p-type conductivity, such as boron. For example, the conductor 316 can be formed using a conductive material such as a metal material, an alloy material, or a metal oxide material.

Note that a material used for a conductor determines the work function; thus, selecting the material used for the conductor can adjust the threshold voltage of a transistor.

As the conductor 316, a material such as titanium nitride or tantalum nitride is preferably used, for example. Furthermore, in order to ensure both conductivity and embeddability, it is preferable to use stacked layers of metal materials such as tungsten and aluminum, for example. It is particularly preferable to use tungsten in stacked layers in terms of heat resistance.

An insulator 320, an insulator 322, an insulator 324, and an insulator 326 are stacked sequentially to cover the transistor 550.

As the insulator 320, the insulator 322, the insulator 324, and the insulator 326, silicon oxide, silicon oxynitride, silicon nitride oxide, silicon nitride, aluminum oxide, aluminum oxynitride, aluminum nitride oxide, or aluminum nitride is preferably used, for example. It is particularly preferably to use silicon oxide or silicon oxynitride in terms of thermal stability.

Note that in this specification and the like, silicon oxynitride refers to a material which contains oxygen at a higher proportion than nitrogen, and silicon nitride oxide refers to a material which contains nitrogen at a higher proportion than oxygen. Moreover, in this specification and the like, aluminum oxynitride refers to a material which contains oxygen at a higher proportion than nitrogen, and aluminum nitride oxide refers to a material which contains nitrogen at a higher proportion than oxygen.

The insulator 322 may function as a planarization film for eliminating a level difference caused by the transistor 550 or the like underlying the insulator 322. For example, a top surface of the insulator 322 may be planarized by planarization treatment using a chemical mechanical polishing (CMP) method or the like to increase the level of planarity.

As the insulator 324, it is preferable to use an insulator having a barrier property that prevents diffusion of impurities such as hydrogen from the substrate 311, the transistor 550, or the like positioned below the insulator 324 into a region positioned above the insulator 324.

As the insulator having a barrier property against hydrogen, silicon nitride deposited by a chemical vapor deposition (CVD) method can be used, for example. Furthermore, metal oxide such as aluminum oxide, hafnium oxide, or tantalum oxide can be used, for example.

Here, diffusion of hydrogen into a semiconductor element including an oxide semiconductor, such as the transistor 600 for example, degrades the characteristics of the semiconductor element in some cases. Therefore, an insulator that inhibits hydrogen diffusion is preferably provided between a region where the transistor 600 is provided and a region where the transistor 550 is provided. Specifically, the insulator that inhibits hydrogen diffusion is an insulator from which a small amount of hydrogen is released.

The dielectric constant of the insulator 326 is preferably lower than that of the insulator 324. For example, the dielectric constant of the insulator 326 is preferably lower than 4, further preferably lower than 3. For example, the dielectric constant of the insulator 326 is preferably lower than 0.7 times that of the insulator 324, further preferably lower than 0.6 times that of the insulator 324. When a material with a low dielectric constant is used for an interlayer film, parasitic capacitance generated between wirings can be reduced.

The conductor 328 is embedded in the insulator 320 and the insulator 322. The conductor 330 is embedded in the insulator 324 and the insulator 326.

The conductor 328 and the conductor 330 each function as a plug or a wiring.

A wiring layer may be provided over the insulator 326 and the conductor 330. For example, in FIG. 25, an insulator 350, an insulator 352, and an insulator 354 are stacked in this order. Furthermore, the conductor 356 is embedded in the insulator 350, the insulator 352, and the insulator 354.

The conductor 356 functions as a plug or a wiring. As the conductor 356, a material similar to that of the conductor 328, the conductor 330, or the like can be used, for example. It is particularly preferable to use a conductor having a barrier property against hydrogen.

As the insulator 350, the insulator 352, and the insulator 354, materials similar to those of the insulator 324, the insulator 322, the insulator 326, and the like can be used, for example. It is particularly preferable to use an insulator having a barrier property against hydrogen.

Here, the conductor having a barrier property against hydrogen is formed in the opening of the insulator 350 having a barrier property against hydrogen. With this structure, the region where the transistor 550 is provided and the outside of the region can be separated by the conductor having a barrier property against hydrogen. Thus, diffusion of hydrogen to the outside of the region where the transistor 550 is provided can be inhibited.

As the conductor having a barrier property against hydrogen, tantalum nitride or the like may be used, for example. Stacked layers of tantalum nitride and tungsten, which has high conductivity, may be used. When the conductor is a stack of tantalum nitride and tungsten, the conductor can inhibit hydrogen diffusion while holding the conductivity as a wiring.

Accordingly, when the conductor 356 is stacked layers of tantalum nitride and tungsten, hydrogen diffusion from the transistor 550 can be inhibited while the conductivity as a wiring is ensured. In that case, a tantalum nitride layer having a barrier property against hydrogen of the conductor 356 is preferably in contact with the insulator 350 having a barrier property against hydrogen.

Although the wiring layer including the conductor 356 is described here, one embodiment of the present invention is not limited thereto. No wiring layer including the conductor 356 may be provided, or two or more wiring layers similar to the wiring layer including the conductor 356 may be provided.

Note that the transistor 550 illustrated in FIG. 25 is an example and the structure is not limited thereto.

### [Transistor 500]

The transistor 500 is described.

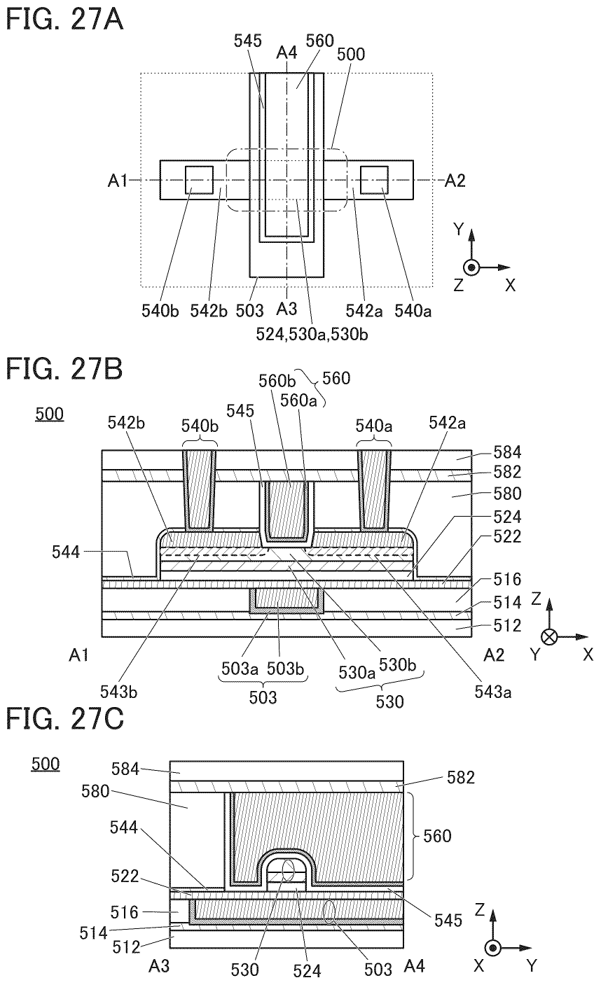

FIG. 27A is a top view of the transistor 500. FIG. 27B is a cross-sectional view taken along the dashed-dotted line A1-A2 in FIG. 27A, which corresponds to a cross-sectional view in the channel length direction (shown as the X direction) of the transistor 500. FIG. 27C is a cross-sectional view taken along the dashed-dotted line A3-A4 in FIG. 27A, which corresponds to a cross-sectional view in the channel width direction (shown as the Y direction) of the transistor 500. Note that for simplicity, some components are not illustrated in the top view of FIG. 27A.

The transistor 500 is what is called a planar transistor having a structure in which the channel length can be increased easily compared with a vertical transistor like the above-described transistor 600. Therefore, the structure can easily suppress short-channel effects such as drain-induced barrier lowering (DIBL), for example. That is, a transistor with the structure can easily have favorable saturation (the change in drain current with respect to drain voltage is small in a saturation region of the transistor).

Thus, in the case where the transistor 500 is used in a memory device, for example, the transistor 500 may be used as a transistor included in a sense amplifier for reading data from a memory cell included in the memory device. That is, for example, in the memory device 100 described above in Embodiment 1, the transistors 500 may be used as at least some of the transistors included in the peripheral circuit 120. Moreover, for example, in the memory device 700 described above in Embodiment 1, the transistors 500 may be used as at least some of the transistors included in the peripheral circuit portion 722.

As illustrated in FIGS. 27B and 27C, the insulator 514 and the insulator 516 are sequentially stacked over an insulator 512.

An insulator having a barrier property against oxygen, hydrogen, and the like is preferably used as any of the insulators 512, 514, and 516.

As the insulator 514, it is preferable to use an insulator having a barrier property that prevents impurities such as hydrogen from diffusing from the outside of a region where the transistor 500 is provided or the like into a region where the transistor 500 is provided, for example. As the insulator 514, a material similar to that of the above-described insulator 324 or the like can be used, for example.

As the insulator having a barrier property against hydrogen, a metal oxide such as aluminum oxide, hafnium oxide, or tantalum oxide is preferably used, for example.

Aluminum oxide especially has a high barrier property against both oxygen and impurities such as hydrogen and water. Accordingly, aluminum oxide can prevent entry of impurities such as hydrogen and water into the transistor 500 during and after the manufacturing process of the transistor, and can inhibit release of oxygen from the oxide included in the transistor 500. Therefore, aluminum oxide is suitably used as a protective film for the transistor 500.

The use of materials with relatively low dielectric constants as the insulator 512 and the insulator 516 can reduce parasitic capacitance generated between wirings. The insulator 512 and the insulator 516 can be formed using materials similar to that of the above-described insulator 326 or the like, for example.

As illustrated in FIGS. 27B and 27C, the transistor 500 includes the conductor 503 embedded in the insulator 514 and the insulator 516, the insulator 522 over the insulator 516 and the conductor 503, the insulator 524 over the insulator 522, an oxide 530a over the insulator 524, an oxide 530b over the oxide 530a, a conductor 542a and a conductor 542b apart from each other over the oxide 530b, an insulator 580 that is over the conductor 542a and the conductor 542b and has an opening between the conductor 542a and the conductor 542b, the insulator 545 formed along the opening, and the conductor 560 on a surface of the insulator 545.

Note that the oxide 530a and the oxide 530b may be collectively referred to as the oxide 530.

The oxide 530 has a function of a semiconductor film including a channel formation region of the transistor 500.

The conductor 503 is placed to overlap with the oxide 530 and the conductor 560.

Here, the conductor 503 preferably includes a conductor 503a provided in contact with the insulator 514 and the insulator 516 and a conductor 503b provided to be embedded inside the conductor 503a. An insulator 544 is preferably provided between the insulator 580 and the oxide 530a, the oxide 530b, the conductor 542a, and the conductor 542b. Furthermore, the conductor 560 preferably includes a conductor 560a provided inside the insulator 545 and a conductor 560b provided to be embedded inside the conductor 560a. An insulator 582 is preferably provided over the insulator 580, the conductor 560, and the insulator 545.

Although the transistor 500 illustrated in FIGS. 27B and 27C has a structure in which two layers of the conductor 503a and the conductor 503b are stacked as the conductor 503, one embodiment of the present invention is not limited thereto. For example, the conductor 503 may have a single-layer structure or a stacked-layer structure of three or more layers.

Although end portions of the conductor 542a and the conductor 542b and end portions of the oxide 530 are aligned with each other in the illustrated structure, one embodiment of the present invention is not limited thereto. For example, the conductor 542a and the conductor 542b may extend beyond the end portions of the oxide 530.

Although the oxide 530 having a structure in which two layers of the oxide 530a and the oxide 530b are stacked is illustrated, the oxide 530 is not limited thereto. For example, the oxide 530 may have a single-layer structure or a stacked-layer structure of three or more layers.

Although the conductor 560 having a structure in which two layers of the conductor 560a and the conductor 560b are stacked is illustrated, the conductor 560 is not limited thereto. For example, the conductor 560 may have a single-layer structure or a stacked-layer structure of three or more layers.

Here, in the transistor 500, the conductor 560 has a function of a gate electrode, the insulator 545 has a function of a gate insulating film, and the conductor 542a and the conductor 542b each have a function of one or the other of a source electrode and a drain electrode.

As described above, the conductor 560 is formed to be embedded in an opening formed in a region that is of the insulator 580 and sandwiched between the conductor 542a and the conductor 542b (the opening is also referred to as an opening of the insulator 580 in some cases). Thus, the conductor 560, the conductor 542a, and the conductor 542b are placed in a self-aligned manner in accordance with the position of the opening of the insulator 580. That is, in the transistor 500, the gate electrode can be placed between the source electrode and the drain electrode in a self-aligned manner. With this structure, the conductor 560 can be formed without an alignment margin. Thus, the area occupied by the transistor 500 can be reduced. Accordingly, miniaturization and higher integration of the semiconductor device can be achieved.

In addition, since the conductor 560 is formed in the region between the conductor 542a and the conductor 542b in a self-aligned manner, the conductor 560 has neither a region overlapping with the conductor 542a nor a region overlapping with the conductor 542b. Thus, parasitic capacitance generated between the conductor 560 and the conductors 542a and 542b can be reduced. As a result, the switching speed of the transistor 500 can be improved. Thus, frequency characteristics of the semiconductor device can be improved.

The gate length of the transistor 500 needs to be short for miniaturization of the semiconductor device; in this case, reducing the conductivity of the conductor 560 needs to be avoided. When the conductor 560 is made thick to achieve this, the conductor 560 might have a shape with a high aspect ratio. Providing the conductor 560 such that the conductor 560 is embedded in the opening of the insulator 580 enables the conductor 560 having a shape with a high aspect ratio to be formed without collapsing during the process.

Here, the conductor 560 has a function of a first gate (also referred to as a top gate) electrode and the conductor 503 has a function of a second gate (also referred to a back gate) electrode, in some cases. In that case, the insulator 545 has a function of a first gate insulating film, and the insulator 522 and the insulator 524 have a function of a second gate insulating film.

As described above, the conductor 503 is placed to overlap with the oxide 530 and the conductor 560. Accordingly, in the case where potentials are supplied to the conductor 560 and the conductor 503, an electric field generated from the conductor 560 and an electric field generated from the conductor 503 are connected, so that the channel formation region in the oxide 530 can be covered.

In that case, for example, by changing the potential applied to the conductor 503 independently of the potential applied to the conductor 560, the threshold voltage of the transistor 500 can be controlled. Specifically, when a negative potential is applied to the conductor 503, the threshold voltage of the transistor 500 can be increased and the off-state current can be reduced. Thus, for example, by applying a negative potential to the conductor 503, a drain current at the time when the potential applied to the conductor 560 is 0 V (sometimes referred to as a cutoff current) can be reduced.

In this specification and the like, a transistor structure in which a channel formation region is electrically surrounded by the electric field of a gate electrode is referred to as a surrounded channel (S-channel) structure. The S-channel structure disclosed in this specification and the like is different from a Fin structure or a planar structure. From another perspective of view, however, the S-channel structure disclosed in this specification and the like can be regarded as a kind of the Fin structure or a kind of the planar structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to the short-channel effects can be obtained. In other words, a transistor in which the short-channel effects are unlikely to occur can be obtained.

When the transistor has the above-described S-channel structure, the channel formation region can be electrically surrounded by an electric field of a gate electrode. Since the S-channel structure is a structure where the channel formation region is electrically surrounded by the electric field of the gate electrode, the S-channel structure is, in a sense, equivalent to a gate all around (GAA) structure or a lateral gate all around (LGAA) structure. In the transistor having any of the S-channel structure, GAA structure, and LGAA structure, the channel formation region that is usually provided at the interface between the semiconductor film and the gate insulating film or in the vicinity of the interface spreads throughout the entire bulk of the semiconductor film. Consequently, the density of current flowing through the transistor can be improved, so that the on-state current or the field-effect mobility of the transistor can be expected to be increased.

In the conductor 503, as described above, the conductor 503a is formed in contact with the insulator 514 and the insulator 516 and the conductor 503b is formed inside the conductor 503a.

As the conductor 503a, a conductive material having a barrier property against impurities such as hydrogen (e.g., at least one of a hydrogen atom, a hydrogen molecule, and the like), water, and copper (a conductive material having a function of inhibiting diffusion of the impurities; i.e., a conductive material through which the impurities are unlikely to pass) is preferably used, for example. As the conductor 503a, a conductive material having a barrier property against oxygen (e.g., at least one of an oxygen atom, an oxygen molecule, and the like) (a conductive material having a function of inhibiting diffusion of oxygen; i.e., a conductive material through which oxygen is unlikely to pass) is preferably used. That is, the conductor 503a preferably has a barrier property against any one or all of the above-described impurities and the above-described oxygen.

When the conductor 503a has a barrier property against oxygen in this manner, the conductivity of the conductor 503b can be prevented from being lowered because of oxidation, for example. Thus, the conductor 503 can also have a function of a wiring.

In that case, a conductive material with high conductivity is preferably used as the conductor 503b. For example, a conductive material containing tungsten, copper, or aluminum as its main component can be used.

Note that the transistor 500 may have a structure not including the conductor 503 (i.e., a structure not including a back gate).

Here, an insulator containing oxygen more than that in the stoichiometric composition is preferably used as the insulator that is in contact with the oxide 530. Such oxygen is easily released from the insulator by heating. In this specification and the like, oxygen released by heating is sometimes referred to as “excess oxygen”.

The insulator 524 is in contact with the oxide 530. That is, a region containing excess oxygen (also referred to as an “excess-oxygen region”) is preferably formed in the insulator 524.

When such an insulator containing excess oxygen is provided in contact with the oxide 530, oxygen vacancies (also referred to as V_{O}) in the oxide 530 can be reduced, leading to an improvement in reliability of the transistor 500.

Here, an oxide semiconductor that can be used as the oxide 530 will be described. The oxide semiconductor layer includes a metal oxide.

The metal oxide preferably contains at least one of indium and zinc. The metal oxide preferably contains indium, M (M is one or more of gallium, aluminum, yttrium, tin, silicon, boron, copper, vanadium, beryllium, titanium, iron, nickel, germanium, zirconium, molybdenum, lanthanum, cerium, neodymium, hafnium, tantalum, tungsten, magnesium, and cobalt), and zinc, for example. In particular, M is preferably one or more kinds selected from gallium, aluminum, yttrium, and tin.

It is particularly preferable that an oxide containing indium (In), gallium (Ga), and zinc (Zn) (also referred to as IGZO) be used as the metal oxide. Alternatively, an oxide containing indium (In), aluminum (Al), and zinc (Zn) (also referred to as IAZO) may be used. Further alternatively, an oxide containing indium (In), aluminum (Al), gallium (Ga), and zinc (Zn) (also referred to as IAGZO) may be used. Alternatively, an oxide containing indium (In), tin (Sn), and zinc (Zn) (also referred to as ITZO (registered trademark)) may be used. Further alternatively, it is preferable to use an oxide containing indium (In), gallium (Ga), zinc (Zn), and tin (Sn) (also referred to as IGZTO).

By increasing the proportion of indium atoms in the total number of atoms of all the metal elements included in the metal oxide, a transistor using the metal oxide in a semiconductor film including a channel formation region can have excellent characteristics such as a high on-state current, high field-effect mobility, and high frequency characteristics.

When the metal oxide is an In-M-Zn oxide, the proportion of In atoms is preferably higher than or equal to that M atoms in the In-M-Zn oxide. Examples of the atomic ratio of the metal elements in such an In-M-Zn oxide are In:M:Zn=1:1:1, 1:1:1.2, 2:1:3, 3:1:2, 4:2:3, 4:2:4.1, 5:1:3, 5:1:6, 5:1:7, 5:1:8, 6:1:6, and 5:2:5 and a composition in the neighborhood of any of the above atomic ratios. In some cases, the atomic ratio of In may be smaller than the atomic ratio of M in the In-M-Zn oxide. Examples of the atomic ratio of the metal elements in such an In-M-Zn oxide include In:M:Zn=1:3:2 or a composition in the neighborhood thereof or In:M:Zn=1:3:4 or a composition in the neighborhood thereof. Note that a composition in the neighborhood of an atomic ratio includes ±30% of an intended atomic ratio.

For example, when the atomic ratio is described as In:Ga:Zn=4:2:3 or a composition in the neighborhood thereof, the case is included where the atomic ratio of Ga is greater than or equal to 1 and less than or equal to 3 and the atomic ratio of Zn is greater than or equal to 2 and less than or equal to 4 with the atomic ratio of In being 4. In addition, when the atomic ratio is described as In:Ga:Zn=5:1:6 or a composition in the neighborhood thereof, the case is included where the atomic ratio of Ga is greater than 0.1 and less than or equal to 2 and the atomic ratio of Zn is greater than or equal to 5 and less than or equal to 7 with the atomic ratio of In being 5. Furthermore, when the atomic ratio is described as In:Ga:Zn=1:1:1 or a composition in the neighborhood thereof, the case is included where the atomic ratio of Ga is greater than 0.1 and less than or equal to 2 and the atomic ratio of Zn is greater than 0.1 and less than or equal to 2 with the atomic ratio of In being 1.

In the case where a metal oxide is used in a stacked-layer structure, a three-layer structure in which a metal oxide with an atomic ratio of metal elements In:Ga:Zn being 1:1:1 is the first layer, a metal oxide with an atomic ratio of metal elements In:Zn being 4:1 is the second layer, and a metal oxide with an atomic ratio of metal elements In:Ga:Zn being 1:1:1 is the third layer can be used, for example. Note that the band gaps of the metal oxides in the first layer and the third layer are preferably larger than the band gap of the metal oxide in the second layer. In this structure, the metal oxide in the second layer can be the main current path, so that what is called a buried channel structure can be formed.

Analysis of the composition of a metal oxide can be performed by secondary ion mass spectrometry (SIMS), energy dispersive X-ray spectrometry (EDX), X-ray photoelectron spectrometry (XPS), inductively coupled plasma-mass spectrometry (ICP-MS), or inductively coupled plasma-atomic emission spectrometry (ICP-AES), for example. Alternatively, these methods may be combined as appropriate for the analysis. Note that as for an element whose content is low, the actual content may be different from the content obtained by analysis because of the influence of the analysis accuracy. In the case where the content of the element M is low, for example, the content of the element M obtained by analysis may be lower than the actual content.

A sputtering method or an atomic layer deposition (ALD) method can be used for depositing the metal oxide. Note that in the case where the metal oxide is deposited by a sputtering method, the composition of the deposited metal oxide may be different from that of a sputtering target. In particular, the zinc content of the deposited metal oxide may be reduced to approximately 50% of that of the sputtering target.

The oxide semiconductor preferably has crystallinity. Examples of an oxide semiconductor having crystallinity include a c-axis aligned crystalline oxide semiconductor (CAAC-OS), a nanocrystalline oxide semiconductor (nc-OS), a polycrystalline oxide semiconductor, and a single-crystal oxide semiconductor. For the oxide semiconductor, CAAC-OS or nc-OS is preferably used, and CAAC-OS is particularly preferably used.

CAAC-OS preferably includes a plurality of layers of crystal regions and a c-axis is preferably aligned in a normal direction of a surface where the CAAC-OS is deposited. For example, the oxide semiconductor preferably includes a layered crystal that is parallel to the surface where the CAAC-OS is deposited. With this structure, the layered crystal of the oxide semiconductor is formed parallel with the channel length direction of the transistor, so that the on-state current of the transistor can be increased.

In the method for depositing an oxide semiconductor in one embodiment of the present invention, the crystallinity of oxide semiconductors formed above and below CAAC-OS, which is an oxide semiconductor having high crystallinity, can be increased with the use of the CAAC-OS as a nucleus or a seed. Accordingly, the crystallinity of the whole oxide semiconductor can be increased. In other words, the CAAC-OS serves as a nucleus or a seed to cause solid-phase growths of the oxide semiconductors above and below the CAAC-OS, so that the oxide semiconductor with high crystallinity can be formed. An oxide semiconductor formed by such a deposition method can be referred to as an axial growth CAAC (AG CAAC).

By increasing the crystallinity of the oxide semiconductor, a transistor that uses the oxide semiconductor in a semiconductor film including a channel formation region can have excellent characteristics (e.g., a high on-state current, high field-effect mobility, a small S value, high frequency characteristics (also referred to as f characteristics), and high reliability).

Note that treatment for increasing the crystallinity of the oxide semiconductor is preferably performed during or after the deposition of the oxide semiconductor. Examples of the treatment for increasing the crystallinity of the oxide semiconductor include heat treatment, plasma treatment, microwave (typically, 2.45 GHz) treatment, microwave plasma treatment, and light (e.g., ultraviolet light) irradiation treatment. Some of these treatments may be performed concurrently or sequentially. For example, heat treatment and microwave plasma treatment can be performed concurrently. Alternatively, microwave plasma treatment can be performed after heat treatment.

In this specification and the like, a microwave refers to an electromagnetic wave having a frequency greater than or equal to 300 MHz and less than or equal to 300 GHz. The microwave plasma treatment refers to, for example, treatment using an apparatus including a power source for generating high-density plasma using microwaves. The microwave plasma treatment can also be referred to as microwave excitation high-density plasma treatment.

It is further preferable that the treatment for increasing the crystallinity of the oxide semiconductor be performed a plurality of times during the deposition of the oxide semiconductor film. For example, in the case where the oxide semiconductor film is formed by an ALD method, microwave plasma treatment is preferably performed every time an atomic layer is formed. Alternatively, the treatment for increasing crystallinity is preferably performed every time the oxide semiconductor film with a thickness in a predetermined range is formed, in which case the productivity can be increased. Specifically, the oxide semiconductor film is preferably formed in the following manner: a first oxide semiconductor film with a thickness greater than or equal to 1 nm and less than or equal to 10 nm is formed, first microwave plasma treatment is performed, a second oxide semiconductor film with a thickness greater than or equal to 1 nm and less than or equal to 10 nm is formed, and then second microwave plasma treatment is performed. Note that methods for depositing the first oxide semiconductor film and the second oxide semiconductor film are not particularly limited, and may each be an ALD method or a sputtering method. It is particularly preferable to deposit the first oxide semiconductor film by an ALD method, in which case entry (also referred to as mixing) of an element of a layer on which the first oxide semiconductor film is formed into the first and second oxide semiconductor films can be prevented. Forming the first oxide semiconductor film by an ALD method is particularly preferable in the case where the element contained in the layer on which the first oxide semiconductor film is formed hinders crystallization of an oxide semiconductor (e.g., the case where silicon, carbon, or the like is contained in the layer). The first oxide semiconductor film and the second oxide semiconductor film may have different compositions. Although the stacked-layer structure of the first oxide semiconductor film and the second oxide semiconductor film is exemplified here, one embodiment of the present invention is not limited thereto. Treatment similar to the above treatment can be performed on the oxide semiconductor film having a single-layer structure or a stacked-layer structure of three or more layers.

The treatment for increasing the crystallinity of the oxide semiconductor may be performed after the deposition of the oxide semiconductor. Specifically, after the deposition of the oxide semiconductor, the treatment may be performed directly on the oxide semiconductor, or may be performed on the oxide semiconductor through another film such as an insulating film formed over the oxide semiconductor layer. For example, microwave plasma treatment may be performed on the oxide semiconductor after the deposition of the oxide semiconductor; alternatively, an insulating film (e.g., a silicon nitride film, a silicon oxide film, or an aluminum oxide film) may be formed after the deposition of the oxide semiconductor, and then heat treatment or microwave plasma treatment may be performed on the oxide semiconductor through the insulating film.

Note that the treatment for increasing the crystallinity of the oxide semiconductor can also serve as treatment for removing impurities contained in the oxide semiconductor. For example, carbon, hydrogen, nitrogen, and the like contained in the oxide semiconductor can be suitably removed. Alternatively, by performing the treatment for increasing the crystallinity of the oxide semiconductor in an oxygen gas atmosphere, oxygen vacancies (also referred to as V_{O}) in the oxide semiconductor can be reduced.

During the treatment for increasing the crystallinity of the oxide semiconductor, the substrate temperature is preferably higher than or equal to room temperature (e.g., 25° C.), higher than or equal to 100° C. and lower than or equal to 600° C., or higher than or equal to 300° C. and lower than or equal to 450° C. The heat treatment temperature is preferably higher than or equal to 100° C. and lower than or equal to 700° C., or higher than or equal to 300° C. and lower than or equal to 450° C.

By increasing the crystallinity of the oxide semiconductor, a highly reliable transistor can be obtained.

The crystallinity of the oxide semiconductor can be analyzed with an X-ray diffraction (XRD) pattern, a transmission electron microscope (TEM) image, or an electron diffraction (ED) pattern, for example. Alternatively, these methods may be combined as appropriate for the analysis.

Note that hydrogen in the oxide semiconductor is preferably reduced as much as possible. Hydrogen in the oxide semiconductor is bonded to an oxygen vacancy to form a defect (also referred to as V_{O}H) generated by entry of hydrogen into the oxygen vacancy, and, as a result, transistor characteristics (e.g., initial I_{d}-V_{g} characteristics of the transistor or I_{d}-V_{g} characteristics in a long-term reliability test) might be degraded. Therefore, a material that releases little hydrogen is preferably used as a material surrounding the oxide semiconductor, e.g., a material used as the insulator in contact with the oxide semiconductor. Examples of the material that releases little hydrogen include silicon nitride, silicon nitride oxide, aluminum oxide, and hafnium oxide. The use of such a material can inhibit entry of hydrogen into the oxide semiconductor. In particular, the use of silicon nitride as at least one of the insulators in contact with the oxide semiconductor can improve the reliability of the transistor. Note that the material that releases little hydrogen sometimes has a function of capturing or fixing (also referred to as gettering) hydrogen in the insulator.

In the oxide 530, V_{O}H functions as a donor and generates an electron serving as a carrier in some cases. In other cases, bonding of part of hydrogen to oxygen bonded to a metal atom generates an electron serving as a carrier. Thus, a transistor including an oxide semiconductor that contains a large amount of hydrogen is likely to have normally-on characteristics. Moreover, hydrogen in an oxide semiconductor is easily transferred by a stress such as heat or an electric field, for example; thus, a large amount of hydrogen in an oxide semiconductor might degrade the reliability of a transistor. In one embodiment of the present invention, V_{O}H in the oxide 530 is preferably reduced as much as possible so that the oxide 530 becomes a highly purified intrinsic or substantially highly purified intrinsic oxide.

In order to obtain such an oxide semiconductor with sufficiently reduced V_{O}H, it is important to remove impurities such as hydrogen and water in the oxide semiconductor (this treatment is also referred to as dehydration or dehydrogenation treatment) and supply oxygen to the oxide semiconductor to fill oxygen vacancies (this treatment is also referred to as oxygen adding treatment). For example, when an oxide semiconductor with a sufficiently reduced amount of impurities such as V_{O}H is used for the channel formation region of a transistor, the transistor can have stable electrical characteristics.

Furthermore, when the insulator 524 includes an excess-oxygen region, the insulator 522 preferably has a barrier property against oxygen. When the insulator 522 has a barrier property against oxygen, diffusion of oxygen contained in the oxide 530 to the insulator 516 side can be inhibited, for example. In addition, the conductor 503 can be inhibited from reacting with oxygen in the insulator 524, the oxide 530, or the like, for example.

Here, it is preferable that a channel formation region of a transistor including an oxide semiconductor in a semiconductor film contain less oxygen vacancies or have a lower impurity concentration (e.g., concentration of hydrogen, nitrogen, and a metal element) than a source region and a drain region. In addition, in some cases, V_{O}H is formed with hydrogen in the vicinity of an oxygen vacancy and an electron serving as a carrier is generated; therefore, it is also preferable that the amount of V_{O}H be small. Thus, the channel formation region of the transistor is a high-resistance region having a low carrier concentration. Accordingly, the channel formation region of the transistor can be regarded as an i-type (intrinsic) or substantially i-type region.

The source region and the drain region of the transistor preferably include more oxygen vacancies, include more V_{O}H, or have a higher impurity concentration than the channel formation region. Thus, the source region and the drain region of the transistor are n-type regions having higher carrier concentrations and lower resistances than the channel formation region.

The band gap of the metal oxide used as the oxide semiconductor is preferably greater than or equal to 2.0 eV, further preferably greater than or equal to 2.5 eV. The use of such a metal oxide having a wide band gap as the oxide semiconductor can reduce the off-state current of the transistor.

As the insulator 522, an insulator of a high dielectric constant (high-k) material (material with a high relative permittivity) is preferably used.

As miniaturization and high integration of a transistor progress, a problem such as generation of gate leakage current may arise because of a thinner gate insulating film. When a high-k material is used as an insulator functioning as the gate insulating film, a gate potential at the time of operating the transistor can be reduced while the physical thickness of the gate insulating film is kept.

For an insulator functioning as a gate insulating film, a single-layer structure or a stacked-layer structure using an insulator containing aluminum oxide, hafnium oxide, an oxide containing aluminum and hafnium (hafnium aluminate), tantalum oxide, zirconium oxide, lead zirconate titanate (PZT), strontium titanate (SrTiO₃), or barium strontium titanate (BST), for example.

It is particularly preferable to use an insulator containing an oxide of one or both of aluminum and hafnium because it is an insulator having a barrier property against oxygen, impurities, and the like. As the insulator, aluminum oxide, hafnium oxide, an oxide containing aluminum and hafnium (hafnium aluminate), or the like is preferably used, for example.

Furthermore, aluminum oxide, bismuth oxide, germanium oxide, niobium oxide, silicon oxide, titanium oxide, tungsten oxide, yttrium oxide, or zirconium oxide may be added to the insulator, for example. The insulator may be subjected to nitriding treatment. Silicon oxide, silicon oxynitride, or silicon nitride may be stacked on the insulator.

The insulator 522 formed of such a material can function as an insulator that inhibits release of oxygen from the oxide 530 and entry of impurities such as hydrogen from the periphery of the transistor 500 into the oxide 530.

Although the transistor 500 illustrated in FIGS. 27B and 27C has a structure in which two layers of the insulator 522 and the insulator 524 are stacked as the second gate insulating film, one embodiment of the present invention is not limited thereto. For example, the second gate insulating film may have a single-layer structure or a stacked-layer structure of three or more layers. In that case, either a structure in which the same materials are stacked or a structure in which different materials are stacked may be employed.

In the transistor 500, a single-layer structure or a stacked-layer structure using a metal oxide functioning as an oxide semiconductor is used for the oxide 530 including a channel formation region. As the oxide 530, a semiconductor that can be used as the above-described oxide 650 may be used, for example. Note that the semiconductor that can be used as the oxide 530 is not limited to the metal oxide.

When the oxide 530a is provided below the oxide 530b in the oxide 530, impurities can be inhibited from diffusing into the oxide 530b from the components formed below the oxide 530a.

The oxide 530 preferably has a structure including oxide layers that differ in the atomic ratio of metal atoms. Specifically, the atomic ratio of the element M to constituent elements in the metal oxide used as the oxide 530a is preferably greater than that in the metal oxide used as the oxide 530b. Moreover, the atomic ratio of the element M to In in the metal oxide used as the oxide 530a is preferably greater than that in the metal oxide used as the oxide 530b. Moreover, the atomic ratio of In to the element M in the metal oxide used as the oxide 530b is preferably greater than that in the metal oxide used as the oxide 530a.

The energy of the conduction band minimum of the oxide 530a is preferably higher than that of the oxide 530b. In other words, the electron affinity of the oxide 530a is preferably smaller than that of the oxide 530b.

Here, the energy level of the conduction band minimum gradually change at a junction portion between the oxide 530a and the oxide 530b. In other words, the energy level of the conduction band minimum at the junction portion between the oxide 530a and the oxide 530b continuously change or is continuously connected. To change the conduction band minimum gradually, the density of defect states in a mixed layer formed at the interface between the oxide 530a and the oxide 530b may be made low.

Specifically, when the oxide 530a and the oxide 530b contain the same element (as a main component) in addition to oxygen, the mixed layer with a low density of defect states can be formed. For example, in the case where the oxide 530b is an In—Ga—Zn oxide, an In—Ga—Zn oxide, a Ga—Zn oxide, gallium oxide, or the like may be used as the oxide 530a.

At this time, the oxide 530b serves as a main carrier path. When the oxide 530a has the above-described structure, the density of defect states at the interface between the oxide 530a and the oxide 530b can be made low. Thus, the influence of interface scattering on carrier conduction is small, and the transistor 500 can have high on-state current.

The conductor 542a and the conductor 542b functioning as the source electrode and the drain electrode are provided over the oxide 530b.

As the conductor 542a and the conductor 542b, a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, and lanthanum; an alloy containing any of the above metal elements as its component; an alloy containing a combination of the above metal elements; or the like can be used, for example. For example, it is particularly preferable to use tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like, which are each a conductive material that is not easily oxidized or a material that maintains its conductivity even after absorbing oxygen. Moreover, in terms of having a barrier property against oxygen, hydrogen, and the like, a metal nitride film of tantalum nitride or the like is preferably used, for example.

Although the transistor 500 illustrated in FIGS. 27B and 27C has a structure in which the conductor 542a and the conductor 542b each have a single-layer structure, one embodiment of the present invention is not limited thereto. The conductor 542a and the conductor 542b may each have a structure in which two or more layers are stacked, for example.

For the conductor 542a and the conductor 542b, a structure in which a tantalum nitride film and a tungsten film are stacked, a structure in which a titanium film and an aluminum film are stacked, a structure in which an aluminum film is stacked over a tungsten film, a structure in which a copper film is stacked over a copper-magnesium-aluminum alloy film, a structure in which a copper film is stacked over a titanium film, or a structure in which a copper film is stacked over a tungsten film may be employed, for example.

Furthermore, a three-layer structure consisting of a titanium film or a titanium nitride film, an aluminum film or a copper film stacked over the titanium film or the titanium nitride film, and a titanium film or a titanium nitride film formed thereover; or a three-layer structure consisting of a molybdenum film or a molybdenum nitride film, an aluminum film or a copper film stacked over the molybdenum film or the molybdenum nitride film, and a molybdenum film or a molybdenum nitride film formed thereover may be employed, for example.

Note that a transparent conductive material containing indium oxide, tin oxide, or zinc oxide may be used as the conductor 542a and the conductor 542b, for example.

Here, as illustrated in FIG. 27B, as a low-resistance region, a region 543a is sometimes formed in the oxide 530 at and near the interface between the oxide 530 and the conductor 542a. In addition, as a low-resistance region, a region 543b is sometimes formed in the oxide 530 at and near the interface between the oxide 530 and the conductor 542b. In that case, the region 543a functions as one of a source region and a drain region, and the region 543b functions as the other of the source region and the drain region. A channel formation region is formed in a region between the region 543a and the region 543b.

When the conductor 542a and the conductor 542b are provided in contact with the oxide 530 in this manner, the oxygen concentration in the region 543a and the region 543b sometimes decrease. In addition, a metal compound layer that contains the metal contained in the conductor 542a and the conductor 542b and the component of the oxide 530 is sometimes formed in the region 543a and the region 543b. In such a case, the region 543a and the region 543b each have increased carrier concentration to become a low-resistance region.

The insulator 544 is provided to cover the conductor 542a and the conductor 542b and inhibits oxidation of the conductor 542a and the conductor 542b. Here, the insulator 544 may be provided to cover the side surfaces of the oxide 530 and the insulator 524 and to be in contact with the insulator 522.

A metal oxide containing one kind or two or more kinds selected from hafnium, aluminum, gallium, yttrium, zirconium, tungsten, titanium, tantalum, nickel, germanium, neodymium, lanthanum, magnesium, and the like can be used as the insulator 544, for example. Moreover, silicon nitride oxide or silicon nitride can be used, for example.

An insulator containing oxide of one or both of aluminum and hafnium may be used. Aluminum oxide, hafnium oxide, an oxide containing aluminum and hafnium (hafnium aluminate), or the like can be used, for example. For example, it is particularly preferable to use hafnium aluminate because it has high heat resistance and is unlikely to be crystallized by heat treatment in a later step.

Note that the insulator 544 is not necessarily provided when the conductor 542a and the conductor 542b are oxidation-resistant or do not significantly lose the conductivity even after absorbing oxygen.

The insulator 544 can inhibit impurities such as hydrogen and water contained in the insulator 580 from diffusing into the oxide 530b. Moreover, oxidation of the conductor 542a and the conductor 542b due to excess oxygen in the insulator 580 can be inhibited.

The insulator 545 is preferably formed using an insulator which contains excess oxygen and from which oxygen is released by heating, like the insulator 524. Thus, oxygen can be effectively supplied to the channel formation region of the oxide 530b from the insulator 545.

Specifically, for example, it is possible to use any of silicon oxide, silicon oxynitride, silicon nitride oxide, silicon nitride, silicon oxide to which fluorine is added, silicon oxide to which carbon is added, silicon oxide to which carbon and nitrogen are added, and porous silicon oxide, each of which contains excess oxygen, as the insulator 545. It is particularly preferable to use silicon oxide or silicon oxynitride in terms of thermal stability.

As the insulator 545, like the above-described insulator 524, an insulator having a low concentration of impurities such as hydrogen and water is preferably used. The thickness of the insulator 545 is preferably greater than or equal to 1 nm and less than or equal to 20 nm.

Furthermore, in order that excess oxygen of the insulator 545 can be efficiently supplied to the oxide 530, a metal oxide may be provided between the insulator 545 and the conductor 560. The metal oxide preferably has a barrier property against oxygen. Accordingly, diffusion of excess oxygen from the insulator 545 into the conductor 560 is inhibited. That is, a reduction in the amount of excess oxygen supplied to the oxide 530 can be suppressed. Moreover, oxidization of the conductor 560 due to excess oxygen can be suppressed. As the metal oxide, a material that can be used as the insulator 544 may be used, for example.

Although the transistor 500 illustrated in FIGS. 27B and 27C has a structure in which the insulator 545 is a single layer, one embodiment of the present invention is not limited thereto. For example, the insulator 545 functioning as the first gate insulating film may have a structure in which two or more layers are stacked, like the insulator 522 and the insulator 524 functioning as the second gate insulating film. For example, the insulator 545 may have a structure in which a high-k material and a thermally stable material are stacked. This can reduce the gate voltage during the operation of the transistor 500 while keeping the physical thickness of the insulator 545.

As the conductor 560a included in the conductor 560, a conductive material having a barrier property against impurities such as hydrogen, water, nitrogen, nitrogen oxide (e.g., N₂O, NO, and NO₂), and copper is preferably used, for example. Furthermore, a conductive material having a barrier property against oxygen is preferably used. When the conductor 560a has a barrier property against oxygen, the conductivity of the conductor 560b can be prevented from being lowered because of oxidization due to oxygen in the insulator 545.

As a conductive material having a barrier property against oxygen, tantalum, tantalum nitride, ruthenium, or ruthenium oxide is preferably used, for example.

The conductor 560a can be formed using an oxide semiconductor that can be used for the oxide 530. In that case, when the conductor 560b is deposited by a sputtering method, the conductor 560a can have a reduced electric resistance and become a conductor. Such a conductor can be referred to as an oxide conductor (OC) electrode.

The conductor 560 can also have a function of a wiring. Thus, as the conductor 560b, a conductive material having high conductivity, is preferably used as in the conductor 503b. For example, a conductive material containing tungsten, copper, or aluminum as its main component can be used.

Note that the conductor 560b may have a structure in which different materials are stacked. For example, a structure in which titanium or titanium nitride and the above-described conductive material are stacked may be employed.

The insulator 580 is provided over the conductor 542a and the conductor 542b with the insulator 544 positioned therebetween.

The insulator 580 preferably includes an excess-oxygen region.

For example, as the insulator 580, silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, a resin, or the like can be used. It is particularly preferable to use silicon oxide or silicon oxynitride in terms of thermal stability. Moreover, it is preferable to use silicon oxide or porous silicon oxide, in which case an excess-oxygen region can be easily formed in a later step.

In the case where the insulator 580 including an excess-oxygen region is provided, oxygen is released by heating, so that oxygen in the insulator 580 can be efficiently supplied to the oxide 530. The concentration of impurities such as hydrogen and water in the insulator 580 is preferably lowered.

The insulator 582 is preferably provided in contact with the top surfaces of the insulator 580, the conductor 560, and the insulator 545. When the insulator 582 is deposited by a sputtering method, the insulator 545 and the insulator 580 can include an excess-oxygen region. Therefore, oxygen can be supplied from the excess-oxygen region to the oxide 530.

As the insulator 582, a metal oxide containing one kind or two or more kinds selected from hafnium, aluminum, gallium, yttrium, zirconium, tungsten, titanium, tantalum, nickel, germanium, magnesium, and the like can be used, for example.

Aluminum oxide especially has a high barrier property against impurities such as hydrogen, so that even a thin aluminum oxide film with a thickness greater than or equal to 0.5 nm and less than or equal to 3.0 nm can inhibit diffusion of impurities such as hydrogen. Thus, aluminum oxide deposited by a sputtering method can serve as not only an oxygen supply source but also an insulator having a barrier property against impurities such as hydrogen.

An insulator 584 functioning as an interlayer film is preferably provided over the insulator 582. As in the insulator 524 or the like, for example, the concentration of impurities such as hydrogen or water in the insulator 584 is preferably lowered.

A conductor 540a and a conductor 540b are provided in openings formed in the insulator 584, the insulator 582, the insulator 580, and the insulator 544. The conductors 540a and 540b are provided to face each other with the conductor 560 positioned therebetween. The conductors 540a and 540b have the same structure as that of the conductor 546 that will be described later.

An insulator 586 is provided over the insulator 584.

As the insulator 586, an insulating material having a barrier property against oxygen, hydrogen, and the like is preferably used. As the insulator 586, a material similar to that of the insulator 514 or the like can be used, for example.

An insulator 588 is provided over the insulator 586.

The use of, for example, a material with a relatively low dielectric constant as the insulator 588 can reduce the parasitic capacitance generated between wirings. As the insulator 588, a material similar to that of the insulator 512, the insulator 516, or the like can be used, for example.

The conductor 546 or the like is embedded in the insulator 580, the insulator 582, the insulator 584, and the insulator 586, for example. The conductor 548 or the like is embedded in the insulator 588, for example.

The conductor 546 and the conductor 548 each have a function of a plug or a wiring.

After the transistor 500 is formed, an opening may be formed to surround the transistor 500, and an insulator having a high barrier property against hydrogen and water may be formed to cover the opening. Surrounding the transistor 500 with the above-described insulator having a high barrier property can prevent entry of hydrogen and water from the outside. Alternatively, a plurality of transistors 500 may be collectively surrounded by the insulator having a high barrier property against hydrogen and water. When the opening is formed to surround the transistor 500, for example, the opening may be formed to reach the insulator 522 or the insulator 514 and the above-described insulator having a high barrier property may be formed in contact with the insulator 522 or the insulator 514, in which case these formation steps can also serve as some of the manufacturing steps of the transistor 500. The insulator having a high barrier property against hydrogen and water may be formed using a material similar to that of the insulator 522, the insulator 514, or the like, for example.

Note that the transistor 500 illustrated in FIGS. 27A to 27C is an example and the structure is not limited thereto.

### [Transistor 500F]

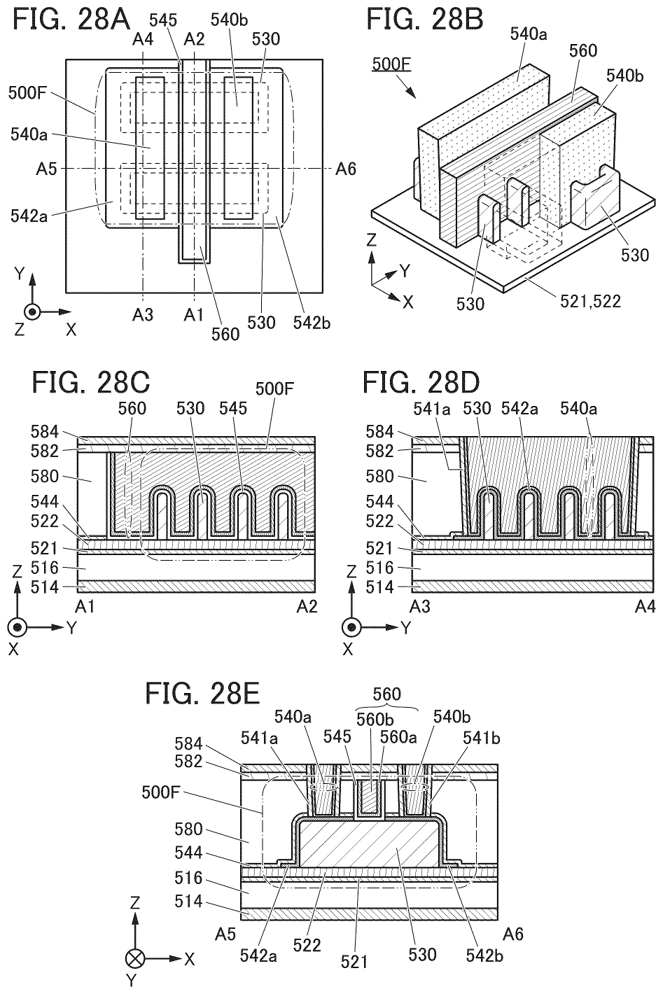

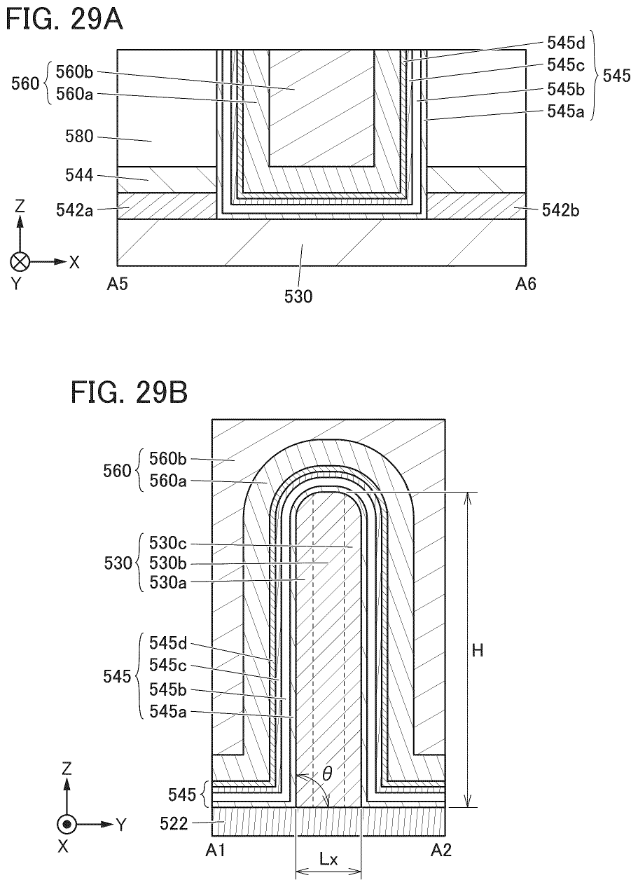

A structure example of a transistor having a structure different from that of the transistor 500 is described with reference to FIG. 28A to FIG. 32E. FIG. 28A is a top view of a transistor 500F. FIG. 28B is a schematic perspective view of the transistor 500F. FIGS. 28C to 28E are cross-sectional views of the transistor 500F. FIG. 28C is a cross-sectional view taken along the dashed-dotted line A1-A2 in FIG. 28A, which corresponds to a cross-sectional view of the transistor 500F in the channel length direction (illustrated as the Y direction here). FIG. 28D is a cross-sectional view taken along the dashed-dotted line A3-A4 in FIG. 28A, which corresponds to a cross-sectional view in the channel width direction of the transistor 500F. FIG. 28E is a cross-sectional view taken along the dashed-dotted line A5-A6 in FIG. 28A, which corresponds to a cross-sectional view of the transistor 500F in the channel length direction (illustrated as the X direction here). The dashed-dotted line A5-A6 is orthogonal to the dashed-dotted line A1-A2 and the dashed-dotted line A3-A4, and the dashed-dotted line A1-A2 is parallel to the dashed-dotted line A3-A4. Note that some components are not illustrated in the top view of FIG. 28A and the schematic perspective view of FIG. 28B. FIG. 29A is an enlarged view of the conductor 560 in FIG. 28E and its vicinity. FIG. 29B is an enlarged view of the oxide 530 in FIG. 28C and its vicinity.

The structure of the transistor 500F can increase the channel width without significantly increasing the occupied area, compared with the structure of the transistor 500. That is, the structure of the transistor 500F can increase the on-state current without significantly increasing the occupied area.

Thus, when the transistor 500F is used in a memory device, for example, the operation speed of the memory device, such as the speed of writing or reading data to/from a memory cell included in the memory device, can be increased. That is, for example, in the memory device 100 described above in Embodiment 1, the transistors 500F may be used as at least some of the transistors included in the peripheral circuit 120. Moreover, for example, in the memory device 700 described above in Embodiment 1, the transistors 500F may be used as at least some of the transistors included in the peripheral circuit portion 722.

The transistor 500F includes the insulator 514 over a substrate (not illustrated), the insulator 516 over the insulator 514, an insulator 521 over the insulator 516, the insulator 522 over the insulator 521, the oxide 530 over the insulator 522, the conductor 542a and the conductor 542b over the oxide 530 and the insulator 522, the insulator 545 over the oxide 530, and the conductor 560 (the conductor 560a and the conductor 560b) over the insulator 545. In this specification and the like, the conductor 542a and the conductor 542b are collectively referred to as the conductor 542 in some cases.

The insulator 544 is provided over the conductor 542, and the insulator 580 is provided over the insulator 544. The insulator 545 and the conductor 560 are provided inside a first opening portion that penetrates the insulator 580 and the insulator 544 and reaches the oxide 530. In the top view, the first opening portion includes a region overlapping with the oxide 530 and a region extending along the channel width direction beyond the end portion of the oxide 530. Thus, the insulator 545 and the conductor 560 provided inside the first opening portion also include, in the top view, a region overlapping with the oxide 530 and a region extending along the channel width direction beyond the end portion of the oxide 530. The conductor 560 also functions as a wiring. The insulator 545 includes a region in contact with the oxide 530 in the first opening portion. The insulator 582 is provided over the insulator 580 and the conductor 560. The insulator 584 is provided over the insulator 582.

An insulator 541a is provided in contact with a side surface of a second opening portion that penetrates the insulator 584, the insulator 582, the insulator 580, and the insulator 544 and reaches the conductor 542a, and the conductor 540a is provided in contact with the insulator 541a. The conductor 540a includes a region in contact with the conductor 542a at the bottom of the first opening portion.

An insulator 541b is provided in contact with a side surface of a third opening portion that penetrates the insulator 584, the insulator 582, the insulator 580, and the insulator 544 and reaches the conductor 542b, and the conductor 540b is provided in contact with the insulator 541b. The conductor 540b includes a region in contact with the conductor 542b at the bottom of the second opening portion.

In this specification and the like, the conductor 540a and the conductor 540b are sometimes collectively referred to as a conductor 540. In addition, the insulator 541a and the insulator 541b are sometimes collectively referred to as an insulator 541.

The oxide 530 includes a channel formation region of the transistor 500F. The conductor 560 includes a region that functions as a gate electrode of the transistor 500F. The insulator 545 includes a region functioning as a gate insulating film of the transistor 500F. In the transistor 500F, a region that is of the oxide 530 and overlaps with the conductor 560 functions as the channel formation region. The region that is of the conductor 560 and overlaps with the oxide 530 functions as a gate electrode. The region of the insulator 545 where the insulator 545 and the oxide 530 overlap with each other and the insulator 545 and the conductor 560 overlap with each other functions as the gate insulating film.

The conductor 542a includes a region functioning as one of a source electrode and a drain electrode of the transistor 500F. The conductor 540a functions as a plug connected to the conductor 542a. The conductor 542b includes a region functioning as the other of the source electrode and the drain electrode of the transistor 500F. The conductor 540b functions as a plug connected to the conductor 542b.

The oxide 530 is formed over the insulator 522. As illustrated in FIG. 29B, the oxide 530 has a shape with a high aspect ratio in the cross-sectional view in the channel width direction. Thus, the oxide 530 can be regarded as having a fin shape.

In this specification and the like, the maximum length of the oxide 530 in the channel width direction in the channel formation region is a length Lx, and the maximum length of the oxide 530 in the direction (illustrated as the Z direction here) perpendicular to the formation surface (e.g., the top surface of the insulator 522) in the channel formation region is a length H. The ratio of the length H to the length Lx is referred to as the aspect ratio of the oxide 530. A fin shape refers to a shape of the oxide 530 having a high aspect ratio (a large length H with respect to the length Lx) in a cross-sectional view in the channel width direction. Here, a transistor in which a semiconductor layer including a channel formation region has a fin shape is referred to as a transistor of a Fin type, a Fin-type transistor, a Fin transistor, or the like in some cases.

Note that the length Lx can also be referred to as the maximum width of the oxide 530 in the channel formation region. Thus, “length Lx” can be replaced with “width Lx”. The length H can also be referred to as the maximum height of the oxide 530 in the channel formation region. Thus, “length H” can be replaced with “height H”.

The aspect ratio of the oxide 530 is preferably as high as possible to an extent that the oxide 530 does not collapse in the manufacturing process of the transistor 500F. The aspect ratio of the oxide 530 may be higher than 1 and lower than or equal to 400, preferably higher than or equal to 2 and lower than or equal to 100, further preferably higher than or equal to 5 and lower than or equal to 40, still further preferably higher than or equal to 10 and lower than or equal to 20. That is, in the channel formation region of the oxide 530, the height H of the oxide 530 is preferably larger than at least the length Lx of the oxide 530. The height H of the oxide 530 is greater than 1 time and less than or equal to 400 times, preferably greater than or equal to 2 times and less than or equal to 100 times, further preferably greater than or equal to 5 times and less than or equal to 40 times, still further preferably greater than or equal to 10 times and less than or equal to 20 times the length Lx of the oxide 530. For example, the height H may be greater than or equal to 2 times and less than or equal to 10 times the length Lx. The length Lx may be, for example, greater than or equal to 5 nm and less than or equal to 100 nm, preferably greater than or equal to 5 nm and less than or equal to 50 nm, further preferably greater than or equal to 10 nm and less than or equal to 30 nm. The height H may be, for example, greater than or equal to 50 nm and less than or equal to 2000 nm, preferably greater than or equal to 100 nm and less than or equal to 1000 nm. For another example, the height H may be greater than or equal to 50 nm and less than or equal to 100 nm.

In a cross-sectional view in the channel width direction as illustrated in FIG. 29B, an angle θ between the surface of the insulator 522 on which the oxide 530 is formed and the side surface of the oxide 530 is preferably perpendicular.

The insulator 545, the conductor 560, and the conductor 542 are provided to cover the oxide 530 having such a high aspect ratio. The insulator 545 and the conductor 560 are provided in the transistor 500F such that part of each of the insulator 545 and the conductor 560 is folded in half to sandwich the oxide 530, as illustrated in FIG. 29B. Thus, in a cross-sectional view in the channel width direction, the oxide 530 and the conductor 560 face each other with the insulator 545 therebetween in the upper portion, the side surface on the A1 side, and the side surface on the A2 side of the oxide 530. That is, the upper portion, the side surface on the A1 side, and the side surface on the A2 side of the oxide 530 function as a channel formation region. Accordingly, the channel width of the transistor 500F is greater than that of the case where the oxide 530 has a planar shape by the side surface on the A1 side and the side surface on the A2 side of the oxide 530.

The transistor 500F having such a large channel width can have a high on-state current, high mutual conductance, excellent frequency characteristics, and the like. Thus, a semiconductor device that operates at high speed can be provided. In the structure of the transistor 500F, the channel width can be increased without increasing the area occupied by the oxide 530. Accordingly, scaling down or high integration of the semiconductor device can be achieved.

As illustrated in FIG. 29B and the like, the upper portion of the oxide 530 may have a curved shape. Such a curved shape can prevent formation of a defect such as a void in the insulator 545 and the conductor 542 in the vicinity of the upper portion of the oxide 530. Although the upper portion of the oxide 530 has a symmetrical structure with a curved shape on both the A1 side and the A2 side of the upper portion in FIG. 29B and the like, one embodiment of the present invention is not limited thereto. For example, the upper portion of the oxide 530 can have an asymmetrical structure with a curved shape on either the A1 side or the A2 side of the upper portion.

Here, a structure example in which the oxide 530 includes the oxide 530a, the oxide 530b in contact with the oxide 530a, and an oxide 530c in contact with the oxide 530b is illustrated.

In that case, for example, films to be the oxide 530a and the oxide 530c may be deposited by an atomic layer deposition (ALD) method and a film to be the oxide 530b may be deposited by a sputtering method. Specifically, the film to be the oxide 530a can be deposited to have an atomic ratio of In:Zn=2:1 or in the neighborhood thereof. Alternatively, indium oxide may be used as the film to be the oxide 530a. The film to be the oxide 530b can be deposited using an oxide target having an atomic ratio of In:Sn:Zn=4:0.1:1 or in the neighborhood thereof. The film to be the oxide 530c can be deposited to have an atomic ratio of In:Zn=2:1 or in the neighborhood thereof. Alternatively, indium oxide may be used as the film to be the oxide 530c.

Next, heat treatment is preferably performed. The heat treatment is preferably performed in a temperature range where the oxide 530 does not become polycrystal.

For example, heat treatment can be performed at 450° C. for one hour at a flow rate ratio of a nitrogen gas to an oxygen gas of 4:1.

When the oxide 530 is formed by the above-described method and heat treatment is performed, the oxide 530 can be the AG CAAC. Accordingly, the on-state current, the S value, the field-effect mobility, the frequency characteristics, and the like of the transistor 500F can be improved, so that a semiconductor device can have excellent electrical characteristics. Moreover, a highly reliable semiconductor device can be provided.

In the case where an oxide semiconductor is used as the oxide 530, the insulator 545 preferably has a stacked-layer structure of an insulator 545a in contact with the oxide 530, an insulator 545b over the insulator 545a, an insulator 545c over the insulator 545b, and an insulator 545d over the insulator 545c, as illustrated in FIGS. 29A and 29B. In that case, the insulator 545a and the insulator 545c preferably have a function of capturing or fixing hydrogen.

An example of the insulator having a function of capturing or fixing hydrogen is a metal oxide having an amorphous structure. As each of the insulator 545a and the insulator 545c, for example, a metal oxide, such as magnesium oxide or an oxide containing aluminum and/or hafnium, is preferably used. In such a metal oxide having an amorphous structure, an oxygen atom has a dangling bond with which hydrogen is captured or fixed in some cases. That is, the metal oxide having an amorphous structure has high capability of capturing or fixing hydrogen.

Moreover, a high-k material is preferably as for each of the insulator 545a and the insulator 545c. An example of the high-k material is an oxide containing aluminum and/or hafnium. With the use of the high-k material as each of the insulator 545a and the insulator 545c, a gate potential applied during operation of the transistor can be reduced while the physical thickness of the gate insulating film is being maintained. Furthermore, the equivalent oxide thickness (EOT) of the insulator functioning as the gate insulating film can be reduced.

As each of the insulator 545a and the insulator 545c, an oxide containing aluminum and/or hafnium is preferably used, and an oxide containing aluminum and/or hafnium and having an amorphous structure is further preferably used.

As the insulator 545a, an aluminum oxide film can be used, for example. The aluminum oxide preferably has an amorphous structure. When the insulator 545a is provided in contact with the oxide 530, hydrogen contained in the oxide 530 or the like can be captured and fixed in the insulator 545a more effectively.

As the insulator 545c, hafnium oxide can be used, for example. When the insulator 545c is provided between the insulator 545b and the insulator 545d, hydrogen contained in the insulator 545b or the like can be captured and fixed more effectively.

An insulator having thermal stability, such as silicon oxide or silicon oxynitride, is preferably used as the insulator 545b. A silicon oxide film used as the insulator 545b is preferably formed by a PEALD method.

In order to inhibit oxidation of the conductor 542a, the conductor 542b, and the conductor 560, a barrier insulator against oxygen is preferably provided in the vicinity of each of the conductor 542a, the conductor 542b, and the conductor 560. For example, a barrier insulator against oxygen may be provided as the insulator 545a, the insulator 545d, the insulator 545c, and the insulator 544.

In this specification and the like, a barrier insulator refers to an insulator having a barrier property. In this specification and the like, “having a barrier property” means having a property of hindering transmission of a target substance (also referred to as having a low permeability). For example, an insulator having a barrier property hardly allows a target substance to be diffused into the insulator. For another example, an insulator having a barrier property has a function of capturing or fixing (also referred to as gettering) a target substance in the insulator.

Examples of a barrier insulator against oxygen include an oxide containing aluminum and/or hafnium, magnesium oxide, gallium oxide, silicon nitride, and silicon nitride oxide. Examples of the oxide containing aluminum and/or hafnium include aluminum oxide, hafnium oxide, an oxide containing aluminum and hafnium (hafnium aluminate), and an oxide containing hafnium and silicon (hafnium silicate). For example, each of the insulator 545a, the insulator 545c, the insulator 545d, and the insulator 544 preferably has a single-layer structure of the barrier insulator against oxygen or a stacked-layer structure of the barrier insulators against oxygen.

The insulator 545a preferably has a barrier property against oxygen. The insulator 545a is preferably less permeable to oxygen than at least the insulator 580 is. The insulator 545a includes a region in contact with the side surface of the conductor 542a and a region in contact with the side surface of the conductor 542b. When the insulator 545a has a barrier property against oxygen, oxidation of the side surfaces of the conductors 542a and 542b, which forms oxide films on the side surfaces, can be inhibited. Accordingly, a reduction in on-state current or field-effect mobility of the transistor 500F can be inhibited.

The insulator 545a is provided in contact with the top and side surfaces of the oxide 530 and the top surface of the insulator 522. When the insulator 545a has a barrier property against oxygen, release of oxygen from the channel formation region of the oxide 530 caused by heat treatment or the like can be prevented. This can inhibit formation of oxygen vacancies in the oxide 530.

By providing the insulator 545a, excessive supply of oxygen from the insulator 580 to the oxide 530 can be inhibited and an appropriate amount of oxygen can be supplied to the oxide 530. Thus, excessive oxidation of the source and drain regions can be prevented, and a reduction in on-state current or field-effect mobility of the transistor 500F can be inhibited.

An oxide containing aluminum and/or hafnium has a barrier property against oxygen and thus is suitable as the insulator 545a.

The insulator 545d also preferably has a barrier property against oxygen. The insulator 545d is provided between the conductor 560 and the channel formation region in the oxide 530 and between the insulator 580 and the conductor 560. Such a structure can prevent oxygen contained in the channel formation region of the oxide 530 from diffusing into the conductor 560 and thus can prevent formation of oxygen vacancies in the channel formation region of the oxide 530. Oxygen contained in the oxide 530 and oxygen contained in the insulator 580 can be inhibited from diffusing into the conductor 560 and oxidizing the conductor 560. The insulator 545d is preferably less permeable to oxygen than at least the insulator 580 is. For example, a silicon nitride film is preferably used as the insulator 545d. In this case, the insulator 545d is an insulator containing at least nitrogen and silicon.

The insulator 545d preferably has a barrier property against hydrogen. This can prevent diffusion of impurities contained in the conductor 560, such as hydrogen, into the oxide 530.

The insulator 544 also preferably has a barrier property against oxygen. The insulator 544 is provided between the insulator 580 and each of the conductor 542a and the conductor 542b. The insulator 544 is provided in contact with the side surface of the conductor 542, the side surface of the oxide 530, and the top surface of the insulator 522. This structure can inhibit diffusion of oxygen contained in the insulator 580 into the conductor 542. Accordingly, oxidation of the conductor 542 by oxygen contained in the insulator 580 can be inhibited, so that an increase in resistivity due to the oxidation can be inhibited. The insulator 544 is preferably less permeable to oxygen than at least the insulator 580 is. For example, silicon nitride is preferably used as the insulator 544. In this case, the insulator 544 is an insulator containing at least nitrogen and silicon.

In order to prevent a reduction in hydrogen concentration in the source and drain regions in the oxide 530, a barrier insulator against hydrogen is preferably provided in the vicinity of each of the source and drain regions. For example, a barrier insulator against hydrogen may be used as the insulator 544.

Examples of the barrier insulator against hydrogen include oxides such as aluminum oxide, hafnium oxide, and tantalum oxide and nitrides such as silicon nitride. For example, the insulator 544 preferably has a single-layer structure of the barrier insulator against hydrogen or a stacked-layer structure of the barrier insulators against hydrogen.

Providing the above-described insulator 544 can reduce the amount of hydrogen diffused from the source and drain regions to the outside, so that a reduction in the hydrogen concentration in the source and drain regions can be inhibited. Thus, the source and drain regions can be n-type regions.

With the above-described structure, the i-type or substantially i-type channel formation region and the n-type source and drain regions can be formed; therefore, a semiconductor device with favorable electrical characteristics can be provided. The semiconductor device with the above-described structure can have excellent electrical characteristics even when being scaled down or highly integrated. Furthermore, scaling down of the transistor 500F can improve the high-frequency characteristics. Specifically, the cutoff frequency can be improved.

The insulators 545a to 545d function as part of the gate insulating film. The insulators 545a to 545d are provided together with the conductor 560 in an opening formed in the insulator 580. The thickness of each of the insulators 545a to 545d is preferably small for scaling down of the transistor 500F. The thickness of each of the insulators 545a to 545d is preferably greater than or equal to 0.1 nm and less than or equal to 10 nm, further preferably greater than or equal to 0.1 nm and less than or equal to 5.0 nm, still further preferably greater than or equal to 0.5 nm and less than or equal to 5.0 nm, yet further preferably greater than or equal to 1.0 nm and less than 5.0 nm, yet still further preferably greater than or equal to 1.0 nm and less than or equal to 3.0 nm. Note that each of the insulators 545a to 545d at least partly includes a region with the above-described thickness.

The thickness of the silicon oxide film used as the insulator 545 is preferably greater than or equal to 0.7 nm and less than or equal to 3 nm.

To reduce the thicknesses of the insulators 545a to 545d as described above, an ALD method is preferably used for deposition. Furthermore, to provide the insulators 545a to 545d in the opening of the insulator 580 and the like, an ALD method is preferably used. By an ALD method, the insulator 545 can be deposited on a side surface of the first opening portion formed in the insulator 580, a side end portion of the conductor 542a, a side end portion of the conductor 542b, and the like with good coverage.

Although the case where the insulator 545 has a four-layer structure of the insulators 545a to 545d is described here, one embodiment of the present invention is not limited to this structure. The insulator 545 can have a structure including at least one of the insulators 545a to 545d. When the insulator 545 is formed of one, two, or three layers of the insulators 545a to 545d, the manufacturing process of the transistor 500F can be simplified and the productivity of the semiconductor device including the transistor 500F can be improved.

As illustrated in FIG. 28A, the shape of the oxide 530 in the top view is preferably an annular shape (also referred to as a frame shape, a ring shape, a doughnut shape, or a closed-curve shape). That is, the oxide 530 preferably includes a plurality of portions extending in the channel width direction and a plurality of portions extending in the channel length direction. This can inhibit the oxide 530 formed to have a high aspect ratio from collapsing during the manufacturing process of the transistor. Note that the shape of the oxide 530 illustrated in FIG. 28A can also be regarded as having an opening in the center portion. Although the shape of the oxide 530 in the top view is a line-symmetrical shape with respect to the line A1-A2 in FIG. 28A, one embodiment of the present invention is not limited thereto. For example, the shape of the oxide 530 in the top view may be an asymmetrical shape.

The structure illustrated in FIG. 28A is a structure in which two annular-shaped oxides 530 are formed in the channel width direction. As illustrated in FIG. 28A, the oxide 530 preferably overlaps with the conductor 560 at two or more points in a top view. Thus, the conductor 560 preferably includes two or more regions overlapping with the oxide 530. That is, two or more regions where the oxide 530 and the conductor 560 overlap with each other are preferably included.

With such a structure, the plurality of fin-shaped oxides 530 are formed in a cross-sectional view in the channel width direction as illustrated in FIG. 28B. The plurality of fin-shaped oxides 530 each include a channel formation region. That is, the transistor 500F functions as a multi-channel transistor. Thus, the channel width can be further increased in the transistor 500F, so that the amount of on-state current can be increased. Accordingly, the operation speed of the semiconductor device including the transistor 500F can be increased.

Although the structure in which the two annular-shaped oxides 530 are provided is described here, one embodiment of the present invention is not limited thereto. For example, one or three or more annular-shaped oxides 530 may be provided. Alternatively, the annular-shaped oxides 530 may be bonded to each other to form the oxide 530 having a plurality of openings. The oxide 530 having a lattice shape in the top view may be used.

Each of the insulator 584, the insulator 582, the insulator 522, and the insulator 521 preferably includes an insulator having a function of inhibiting diffusion of oxygen and impurities such as water and hydrogen. Examples of the insulator include aluminum oxide, magnesium oxide, hafnium oxide, zirconium oxide, an oxide containing aluminum and hafnium (hafnium aluminate), an oxide containing hafnium and zirconium (a hafnium zirconium oxide), gallium oxide, silicon nitride, and silicon nitride oxide. For example, silicon nitride, which has a higher hydrogen barrier property, is preferably used as each of the insulator 584 and the insulator 521. For example, aluminum oxide, which has high capability of capturing or fixing hydrogen, is preferably used as the insulator 582. For example, hafnium oxide, which has high capability of capturing or fixing hydrogen and is a high-k material, is preferably used as the insulator 522.

Note that at least one of the insulator 521 and the insulator 522 can have a stacked-layer structure of the above-described material and silicon oxide or silicon oxynitride. For example, the insulator 521 can have a stacked-layer structure of silicon nitride and silicon oxide. For example, the insulator 522 can be a stack of hafnium oxide and silicon oxide.

Such a structure can inhibit impurities such as water and hydrogen from diffusing into the transistor 500F or the like from an interlayer insulating film or the like positioned above the insulator 584. Furthermore, impurities such as water and hydrogen can be inhibited from diffusing into the transistor 500F or the like from an interlayer insulating film or the like positioned below the insulator 521. Moreover, hydrogen contained in the insulator 580, the insulator 545, and the like can be captured and fixed in the insulator 582 or the insulator 522. Providing the insulator 582 and the insulator 584 can inhibit oxygen contained in the insulator 580 or the like from diffusing into an area above the transistor 500F or the like. Providing the insulator 522 and the insulator 521 can inhibit oxygen contained in the oxide 530 or the like from diffusing into an area below the transistor 500F or the like. With such a structure in which the transistor 500F is surrounded from above and below by the insulators having a function of inhibiting diffusion of oxygen and impurities such as water and hydrogen, excess oxygen and excess hydrogen can be inhibited from diffusing into the oxide semiconductor. This can improve the electrical characteristics and reliability of the semiconductor device.

The insulators 516 and 580 each preferably have a lower dielectric constant than the insulator 522. In the case where materials with low dielectric constants are used for the interlayer films, parasitic capacitance generated between wirings can be reduced.

For example, each of the insulator 516 and the insulator 580 preferably includes one or more of silicon oxide, silicon oxynitride, silicon oxide to which fluorine is added, silicon oxide to which carbon is added, silicon oxide to which carbon and nitrogen are added, and porous silicon oxide.

Silicon oxide and silicon oxynitride are particularly preferable because of their thermal stability. In particular, materials such as silicon oxide, silicon oxynitride, and porous silicon oxide are preferably used, in which case a region containing oxygen that is released by heating can be easily formed.

The top surfaces of the insulator 516 and the insulator 580 may be planarized.

The concentration of impurities such as water and hydrogen in the insulator 580 is preferably reduced. For example, the insulator 580 preferably includes an oxide containing silicon, such as silicon oxide or silicon oxynitride.

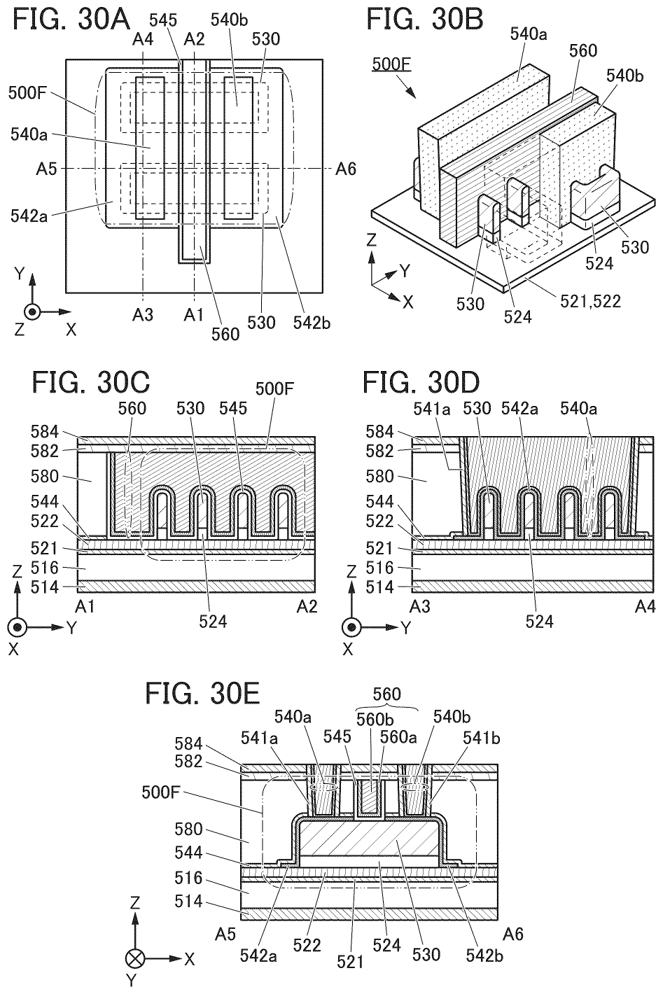

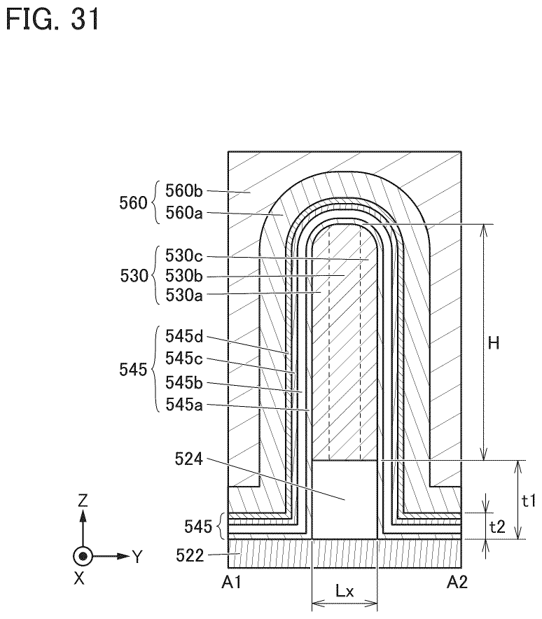

As illustrated in FIGS. 30A to 30E, the insulator 524 may be provided below the oxide 530 in the transistor 500F. The planar shape (the shape seen from the Z direction, here) of the insulator 524 is similar to that of the oxide 530, and the insulator 524 overlaps with the oxide 530 in the top view. A bottom surface of the insulator 524 is in contact with the insulator 522, a side surface of the insulator 524 is in contact with the insulator 545 and the conductor 542a, and a top surface of the insulator 524 is in contact with a bottom surface of the oxide 530. As the insulator 524, an insulating material that can be used as the insulator 545b may be used. For example, silicon oxide can be used as the insulator 524. Here, FIGS. 30A to 30E correspond to FIGS. 28A to 28E. FIG. 31 corresponds to FIG. 29B. The above description of FIGS. 28A to 28E and FIG. 29B and the like can be referred to for the structures that are illustrated in FIGS. 30A to 30E and FIG. 31 and are not described below.

Here, as illustrated in FIG. 31, a thickness t2 of the insulator 545 in the bottom portion of the first opening portion is preferably smaller than a thickness t1 of the insulator 524 (the length of the insulator 524 in the direction perpendicular to the surface on which the insulator 524 is formed). With such a structure, the level of the bottom surface of the conductor 560 (the conductor 560a) positioned in the first opening portion can be lower than the level of the bottom surface of the oxide 530 by a difference between the thickness t1 and the thickness t2 (t1-t2).

When the level of the bottom surface of the conductor 560 is lower than the level of the bottom surface of the oxide 530, a gate electric field can be adequately applied to the oxide 530 from its upper end portion to its lower end portion. In other words, in the opening of the insulator 580 and the like, the oxide 530 can be wholly electrically surrounded by an electric field of the conductor 560 to function as a channel formation region. Such a structure can prevent the lower end portion of the oxide 530 from functioning as a parasitic channel, thereby reducing an off-state current between the source electrode and the drain electrode. In addition, normally-on characteristics of the transistor due to the parasitic channel can be inhibited, for example. That is, the transistor 500F can have excellent electrical characteristics.

When a region from the upper end portion to the lower end portion of the oxide 530 functions as a channel formation region as described above, the channel width can be increased. Thus, the transistor 500F can have a high on-state current, high mutual conductance, excellent frequency characteristics, and the like.

In this specification and the like, a transistor structure in which a channel formation region is electrically surrounded by the electric field of a gate electrode as in the above structure is referred to as a surrounded channel (S-channel) structure. In the S-channel structure, a gate electrode is provided to cover at least two surfaces (specifically, two surfaces, three surfaces, four surfaces, or the like) of a channel. With the use of the S-channel structure, a transistor with high resistance to the short-channel effects, i.e., a transistor in which the short-channel effects are unlikely to occur, can be obtained.

Since the S-channel structure is a structure where the channel formation region is electrically surrounded, the S-channel structure is, in a sense, equivalent to a gate all around (GAA) structure or a lateral gate all around (LGAA) structure. In the transistor 500F having any of the S-channel structure, GAA structure, and LGAA structure, the channel formation region that is usually provided at the interface between the oxide 530 and the insulator 545 functioning as the gate insulating film or in the vicinity of the interface spreads throughout the entire bulk of the oxide 530. Consequently, the density of current flowing through the transistor can be improved, so that the on-state current or the field-effect mobility of the transistor can be expected to be increased. In one embodiment of the present invention, the oxide 530 has a CAAC structure and a fin-shaped structure. With such structures, the source-drain current path in the transistor and the a-b plane of the crystal axis can be parallel to each other. In other words, an oxide semiconductor having the CAAC structure and the fin-shaped structure seems to have a conduction path equivalent to that of a two-dimensional semiconductor material. Furthermore, with the use of such an oxide semiconductor, a device having two-dimensional conduction can be formed.

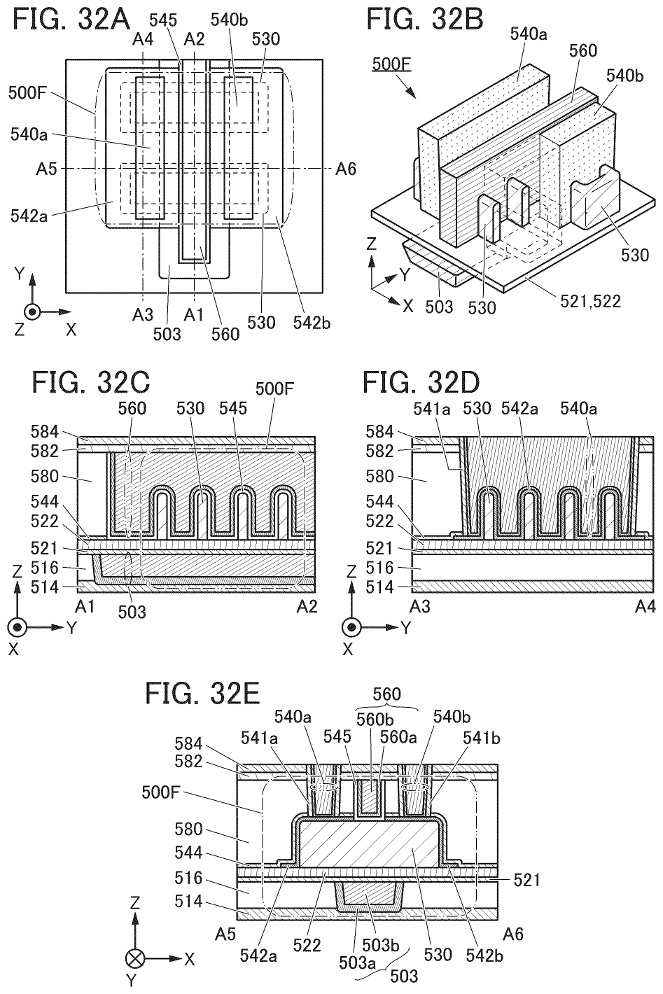

As illustrated in FIGS. 32A to 32E, the conductor 503 may be provided below the insulator 521 in the transistor 500F. Note that FIGS. 32A to 32E correspond to FIGS. 28A to 28E. The above description of FIGS. 28A to 28E and the like can be referred to for the structures that are illustrated in FIGS. 32A to 32E and are not described below.

Like the conductor 560, the conductor 503 includes a region functioning as a gate electrode. The conductor 560 may be referred to as a first gate electrode (an upper gate electrode) of the transistor 500F, and the conductor 503 may be referred to as a second gate electrode (a lower gate electrode) of the transistor 500F. In the case where the conductor 560 is referred to as a gate electrode of the transistor 500F, the conductor 503 is referred to as a back gate electrode of the transistor 500F in some cases.

In the case where the transistor 500F includes the conductor 503 under the insulator 521, each of the insulator 522 and the insulator 521 includes a region functioning as a gate insulating film like the insulator 545. Specifically, a region that is of the insulator 522 and overlaps with the conductor 503 and a region that is of the insulator 521 and overlaps with the conductor 503 function as a gate insulating film. The insulator 545 may be referred to as a first gate insulating film (an upper gate insulating film), and the insulator 522 and the insulator 521 may be referred to as a second gate insulating film (a lower gate insulating film).

In the transistor 500F, the conductor 503 is provided to overlap with the oxide 530 and the conductor 560. In FIGS. 32C and 32E, the conductor 503 is provided inside a fourth opening portion that penetrates the insulator 516 and reaches the insulator 514. In the top view, the fourth opening portion includes a region overlapping with the oxide 530 and a region extending along the channel width direction beyond the end portion of the oxide 530. Thus, the conductor 503 provided inside the fourth opening portion also includes, in the top view, a region overlapping with the oxide 530 and a region extending along the channel width direction beyond the end portion of the oxide 530. The conductor 503 also functions as a wiring.

As illustrated in FIGS. 32C and 32E, the conductor 503 preferably includes the conductor 503a and the conductor 503b. The conductor 503a is provided in contact with a bottom portion and a side surface of the fourth opening portion. The conductor 503b is provided to fill a depressed portion of the conductor 503a formed along the bottom portion and the side surface of the fourth opening portion. Here, the top surface of the conductor 503 is level or substantially level with the top surface of the insulator 516.

The conductor 503a preferably includes a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductor 503a preferably includes a conductive material having a function of inhibiting diffusion of oxygen (e.g., at least one of an oxygen atom and an oxygen molecule).

When the conductor 503a is formed using a conductive material having a function of inhibiting diffusion of hydrogen, impurities such as hydrogen contained in the conductor 503b can be prevented from diffusing into the oxide 530 through the insulator 516 or the like. When a conductive material having a function of inhibiting diffusion of oxygen is used as the conductor 503a, a reduction in conductivity of the conductor 503b due to oxidation of the conductor 503b can be inhibited. Examples of the conductive material having a function of inhibiting diffusion of oxygen include titanium, titanium nitride, tantalum, tantalum nitride, ruthenium, and ruthenium oxide. The conductor 503a can have a single-layer structure or a stacked-layer structure of the above-described conductive materials. For example, the conductor 503a preferably contains titanium nitride.

Furthermore, the conductor 503b is preferably formed using a conductive material containing tungsten, copper, or aluminum as its main component. For example, the conductor 503b preferably contains tungsten.

As described above, the conductor 503 can function as a second gate electrode. In that case, by changing the potential applied to the conductor 503 independently of the potential applied to the conductor 560, the threshold voltage of the transistor 500F can be controlled. Specifically, when a negative potential is applied to the conductor 503, the threshold voltage of the transistor 500F can be further increased and the off-state current can be reduced. Thus, a drain current at the time when the potential applied to the conductor 560 is 0 V can be smaller in the case where a negative potential is applied to the conductor 503 than in the case where the negative potential is not applied to the conductor 503.

The electrical resistivity of the conductor 503 is designed in consideration of the potential applied to the conductor 503, and the thickness of the conductor 503 is determined in accordance with the electrical resistivity. The thickness of the insulator 516 is substantially equal to that of the conductor 503. The conductor 503 and the insulator 516 are preferably as thin as possible in the allowable range of the design of the conductor 503. The insulator 516 with a reduced thickness contains a smaller absolute amount of impurities such as hydrogen, inhibiting diffusion of the impurities into the oxide 530.

Although the stacked-layer structure of the conductor 503a and the conductor 503b is described above, one embodiment of the present invention is not limited to this structure. The conductor 503 may have a single-layer structure or a stacked-layer structure of three or more layers. For example, in the case where the conductor 503 has a three-layer structure, a conductor that contains the same material as the conductor 503a can be further provided over the conductor 503b of the above-described stacked-layer structure of the conductor 503a and the conductor 503b. In that case, the level of the top surface of the conductor 503b is lower than that of an uppermost portion of the conductor 503a, and the above-described conductor may be formed to fill the depressed portion formed by the conductor 503a and the conductor 503b.

### [Transistor 800]

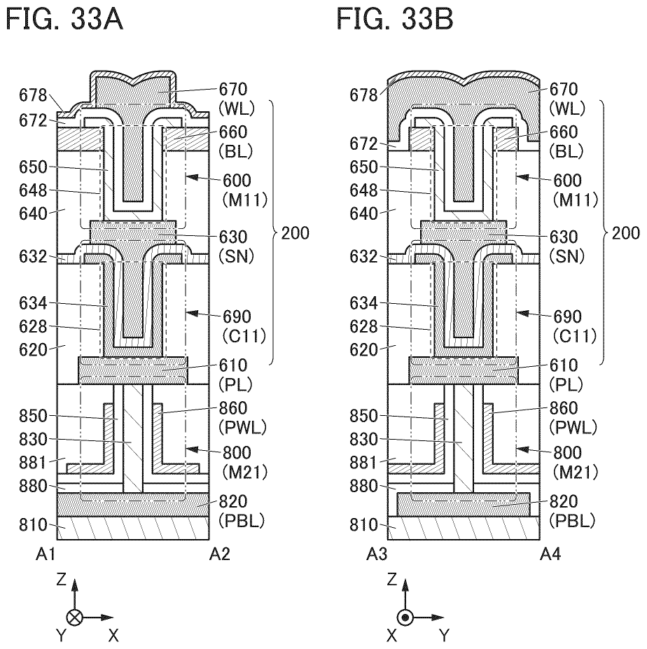

FIGS. 33A and 33B are cross-sectional views illustrating another transistor that can be used in the memory device of one embodiment of the present invention.

FIGS. 33A and 33B illustrate a transistor 800 over an insulator 810, an insulator 880, an insulator 881 over the insulator 880, and the semiconductor device 200 (the transistor 600 and the capacitor 690) over the transistor 800. The insulator 810, the insulator 880, and the insulator 881 function as interlayer films.

A conductor 820, the oxide 830, an insulator 850, and a conductor 860 included in the transistor 800 are illustrated. In the transistor 800, the oxide 830 functions as a semiconductor film including a channel formation region, the conductor 860 functions as a gate electrode, the insulator 850 functions as a gate insulating film, the conductor 820 functions as one of a source electrode and a drain electrode, and the conductor 610 functions as the other of the source electrode and the drain electrode. The conductor 610 also has a function of the other electrode of a pair of electrodes of the capacitor 690. The conductor 820 and the conductor 860 also have a function of a wiring.

The structure example illustrated in FIGS. 33A and 33B can be employed in the case where the driver circuit 123 uses the structure illustrated in FIG. 14A in the connection example illustrated in FIG. 12 in Embodiment 1, for example. In this case, the transistor 600 corresponds to the transistor M11, the capacitor 690 corresponds to the capacitor C11, and the transistor 800 corresponds to the transistor M21. That is, the conductor 670 includes a region functioning as the gate of the transistor M11, the conductor 660 includes a region functioning as the other of the source and the drain of the transistor M11, the conductor 630 includes a region functioning as the one of the source and the drain of the transistor M11 and a region functioning as the one terminal of the capacitor C11, the conductor 610 includes a region functioning as the other terminal of the capacitor C11 and a region functioning as the one of the source and the drain of the transistor M21, the conductor 860 includes a region functioning as the gate of the transistor M21, and the conductor 820 includes a region functioning as the other of the source and the drain of the transistor M21. The conductor 670 corresponds to the wiring WL, the conductor 660 corresponds to the wiring BL, the conductor 610 corresponds to the wiring PL, the conductor 630 corresponds to the wiring SN, the conductor 860 corresponds to the wiring PWL, and the conductor 820 corresponds to the wiring PBL. Note that in FIGS. 33A to 33B, portions corresponding to the transistor M11, the capacitor C11, the transistor M21, the wiring WL, the wiring BL, the wiring PL, the wiring SN, the wiring PWL, and the wiring PBL are denoted by reference numerals with parentheses.

That is, in the structure example illustrated in FIGS. 33A and 33B, the capacitor C11 is stacked over the transistor M21, and the transistor M11 is stacked over the capacitor C11. That is, the transistor M21, the capacitor C11, and the transistor M11 are placed to overlap with each other in a region in the top view. Thus, for example, in the case where the driver circuit 123 uses the structure illustrated in FIG. 14A in the connection example illustrated in FIG. 12 in Embodiment 1 described above, an increase in the area by the provision of the driver circuit 123 can be inhibited by employing the structure illustrated in FIGS. 33A and 33B.

The transistor 800 is described. Note that the above description can be referred to for the transistor 600 and the capacitor 690; thus, the description thereof is omitted here.

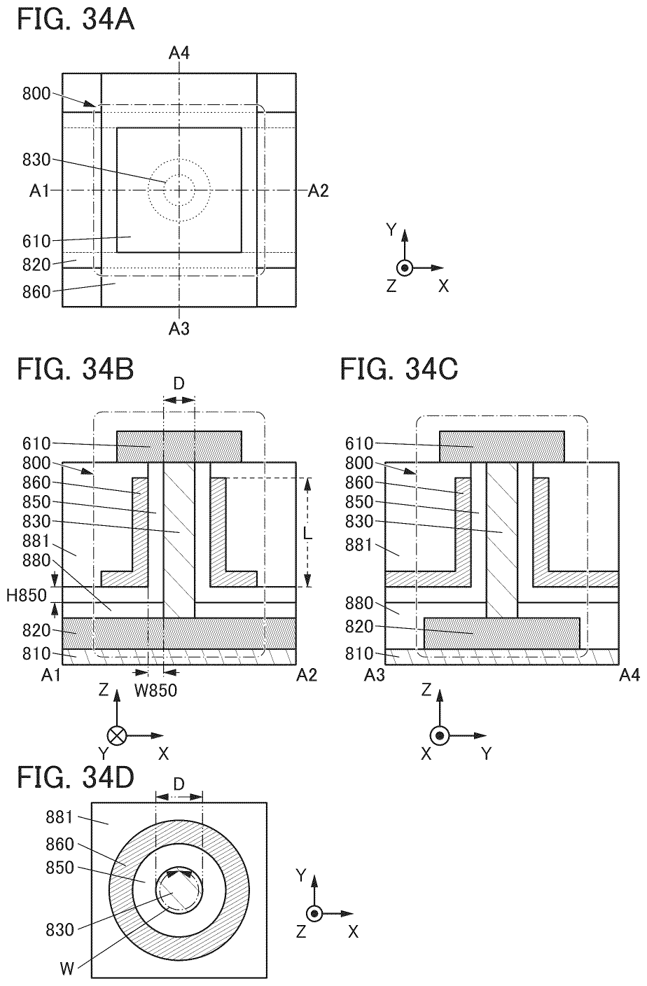

FIG. 34A is a top view of the transistor 800. FIG. 34B is a cross-sectional view of the transistor 800 taken along the dashed-dotted line A1-A2 in FIG. 34A. FIG. 34C is a cross-sectional view of the transistor 800 taken along the dashed-dotted line A3-A4 in FIG. 34A. Note that the dashed-dotted line A1-A2 is a straight line parallel to the X direction in the drawing, and the dashed-dotted line A3-A4 is a straight line parallel to the Y direction in the drawing. In the top views, some components are not illustrated for simplification of the drawings. Some components may be omitted also in the following top views.

FIGS. 34B and 34C illustrate the transistor 800 over the insulator 810, the insulator 880, and the insulator 881 over the insulator 880. The insulator 810, the insulator 880, and the insulator 881 function as interlayer films.

The transistor 800 includes the conductor 820 over the insulator 810, the oxide 830 over the conductor 820, the insulator 850 over the insulator 880, the conductor 860 over the insulator 850, and the conductor 610 over the oxide 830, the insulator 850, and the insulator 881.

The insulator 880 is provided over the conductor 820 and the insulator 810. The insulator 881 is provided over the insulator 850 and the conductor 860.

A side surface of the oxide 830 is preferably perpendicular to a top surface of the insulator 810. Such a structure enables miniaturization or high integration of the transistor 800. In that case, each of the films provided outside the oxide 830 is preferably formed by an ALD method. An ALD method enables atomic layers to be deposited one by one, and has various advantages such as formation of an extremely thin film, deposition on a component with a high aspect ratio, formation of a film with few defects such as pinholes, deposition with excellent coverage, and low-temperature deposition. Thus, the film can be formed on the side surface of the oxide 830 with favorable coverage. For example, the insulator 850 and the conductor 860 are each preferably formed by an ALD method.

In the case where the side surface of the oxide 830 is perpendicular to the top surface of the insulator 810, the oxide 830 has a cylindrical shape as illustrated in FIGS. 34B and 34C. The oxide 830 is provided to extend in the Z direction. In other words, the normal of the bottom surface and the normal of the top surface of the oxide 830 are parallel to the Z direction. The bottom surface of the oxide 830 is in contact with part of the top surface of the conductor 820, the top surface of the oxide 830 is in contact with part of the bottom surface of the conductor 610, and at least part of the side surface of the oxide 830 is in contact with the insulator 850. In the structure illustrated in FIGS. 34B and 34C, another part of the side surface of the oxide 830 is in contact with the insulator 880.

The top surface of the oxide 830 is level with the top surface of the insulator 850 and the top surface of the insulator 881.

The insulator 850 covers at least part of the side surface of the oxide 830. The insulator 850 includes a region in contact with the conductor 610. The insulator 850 includes a first region between the oxide 830 and the conductor 860 and a second region between the conductor 820 and the conductor 860. In other words, the second region is positioned between the insulator 880 and the conductor 860. In FIG. 34B, the width of the first region included in the insulator 850 in the direction from the oxide 830 toward the conductor 860 (the X direction or the Y direction) is denoted by W850. The width of the second region included in the insulator 850 in the direction from the conductor 820 toward the conductor 860 (the Z direction) is denoted by H850. For example, in the case where the insulator 850 is formed by an ALD method, the width W850 is the same as the width H850.

The top surface of the conductor 860 in a portion along the side surface of the oxide 830 is positioned below the top surface of the oxide 830 (on the insulator 810 side). The conductor 860 includes a first region facing the side surface of the oxide 830 with the insulator 850 therebetween and a second region overlapping with the conductor 820 with the insulator 850 therebetween. For example, in the case where the conductor 860 is formed by an ALD method, the width of the first region of the conductor 860 in the X direction or the Y direction is the same as the width of the second region of the conductor 860 in the Z direction.

In the transistor 800 illustrated in FIGS. 34B and 34C, the conductor 860 is provided to extend in the Y direction, and the conductor 820 is provided to extend in the X direction.

In the transistor 800, the oxide 830 functions as a semiconductor film including a channel formation region, the conductor 860 functions as a gate electrode, the insulator 850 functions as a gate insulating film, the conductor 820 functions as one of a source electrode and a drain electrode, and the conductor 610 functions as the other of the source electrode and the drain electrode.

The transistor 800 has a structure in which a current flows in the vertical direction since one of the source electrode and the drain electrode (here, the conductor 820) is positioned below and the other of the source electrode and the drain electrode (here, the conductor 610) is positioned above. That is, a channel is formed along the side surface of the oxide 830. The transistor 800 has a structure in which the channel formation region is surrounded by the gate electrode. Thus, the transistor 800 can be referred to as a transistor having a gate-all-around (GAA) structure.

In the transistor 800, the oxide 830 including the channel formation region preferably includes a metal oxide (also referred to as an oxide semiconductor) functioning as a semiconductor. As the oxide 830, a metal oxide that can be used as the above-described oxide 650 may be used, for example. Note that semiconductors that can be used as the oxide 830 are not limited to the metal oxides.

Here, as the insulator 850, any of the above-described materials that can be used as the insulator 672 may be used, for example. As the conductor 860, any of the above-described materials that can be used as the conductor 610 may be used, for example. As the conductor 820, any of the above-described materials that can be used as the conductor 610 may be used, for example. As the insulator 810, any of the above-described materials that can be used as the insulator 612 may be used, for example. As the insulator 880 and the insulator 881, any of the above-described materials that can be used as the insulator 620 or the insulator 640 may be used, for example.

In the transistor 800, a region that is of the oxide 830 and is covered with the conductor 860 with the insulator 850 therebetween functions as the channel formation region. A region that is of the oxide 830 and is in contact with the conductor 820 functions as one of a source region and a drain region, and a region that is of the oxide 830 and is in contact with the conductor 610 functions as the other of the source region and the drain region. That is, the channel formation region is sandwiched between the source region and the drain region.

When the oxide 830 and the conductor 820 are in contact with each other, a metal compound or oxygen vacancies are formed, so that the resistance of the region that is of the oxide 830 and is in contact with the conductor 820 is reduced. Accordingly, the contact resistance between the oxide 830 and the conductor 820 can be reduced. Similarly, when the oxide 830 and the conductor 610 are in contact with each other, the resistance of a region that is of the oxide 830 and is in contact with the conductor 610 is reduced. Accordingly, the contact resistance between the oxide 830 and the conductor 610 can be reduced.

In the case where the conductor 860 functions as a gate electrode, the channel length of the transistor 800 is the length of a region that is of the oxide 830 and overlaps with the conductor 860 with the insulator 850 therebetween in a cross-sectional view. That is, the channel length of the transistor 800 is determined by the height of the conductor 860. In FIG. 34B, the channel length L of the transistor 800 is indicated by a dashed double-headed arrow.

In the transistor 800, the channel length can be determined by the height of the conductor 860. Thus, the channel length L of the transistor 800 can be less than or equal to the light exposure limit of photolithography allowing a quite minute structure (e.g., greater than or equal to 0.1 nm and less than or equal to 100 nm, greater than or equal to 1 nm and less than or equal to 100 nm, greater than or equal to 1 nm and less than or equal to 50 nm, greater than or equal to 1 nm and less than or equal to 40 nm, greater than or equal to 1 nm and less than or equal to 30 nm, greater than or equal to 5 nm and less than or equal to 30 nm, greater than or equal to 5 nm and less than or equal to 20 nm, or greater than or equal to 5 nm and less than or equal to 10 nm). Accordingly, the transistor 800 can have a higher on-state current and higher frequency characteristics.

In addition, as described above, the channel formation region, the source region, and the drain region can be formed in the oxide 830. Thus, the area occupied by the transistor 800 can be reduced as compared with a planar transistor in which the channel formation region, the source region, and the drain region are provided separately on the XY plane. Thus, the transistor 800 can be highly integrated. In the case where the transistor 800 of one embodiment of the present invention is used in a memory device, the memory capacity per unit area can be increased.

The height of the oxide 830 needs to be larger than the channel length L of the transistor 800. Meanwhile, the height of the oxide 830 needs to be set so that the oxide 830 processed into a cylindrical shape does not collapse. Thus, the height of the oxide 830 is preferably greater than or equal to 20 nm and less than or equal to 200 nm, further preferably greater than or equal to 50 nm and less than or equal to 200 nm, still further preferably greater than or equal to 80 nm and less than or equal to 200 nm, still further preferably greater than or equal to 80 nm and less than or equal to 150 nm, yet still further preferably greater than or equal to 80 nm and less than or equal to 120 nm, for example.

FIG. 34D is an enlarged cross-sectional view of an XY plane including the oxide 830, the insulator 850, the conductor 860, and the insulator 881. Note that FIG. 34D can be regarded as a cross-sectional view along the XY plane including the channel formation region of the oxide 830. As illustrated in FIG. 34D, the insulator 850 and the conductor 860 are provided concentrically. Therefore, the side surface of the oxide 830 provided at the center faces a side surface of the conductor 860 with the insulator 850 therebetween. That is, in the top view, all the perimeter of the oxide 830 serves as the channel formation region. In this case, for example, the channel width of the transistor 800 is determined by the length of the outer circumference of the oxide 830. In other words, the channel width of the transistor 800 is determined by the width of the oxide 830 (the diameter in the case where the oxide 830 is circular in the top view). In FIGS. 34B and 34D, the width D of the oxide 830 is indicated by a dashed double-dotted double-headed arrow. In FIG. 34D, the channel width W of the transistor 800 is indicated by a dashed-dotted double-headed arrow. By increasing the width D of the oxide 830, the channel width can be increased and the on-state current can be increased.

In the case where the oxide 830 is formed by a photolithography method, the width D of the oxide 830 is determined by the light exposure limit of photolithography. The width D of the oxide 830 can be greater than or equal to 5 nm and less than or equal to 100 nm, greater than or equal to 5 nm and less than or equal to 60 nm, greater than or equal to 5 nm and less than or equal to 50 nm, or greater than or equal to 5 nm and less than or equal to 40 nm. In the case where the oxide 830 is circular in the top view, the width D of the oxide 830 corresponds to the diameter of the oxide 830, and the channel width W can be “D×π”.

Thus, the ratio of the height of the oxide 830 to the width D of the oxide 830 can be greater than or equal to 0.2 and less than or equal to 40, or greater than or equal to 1 and less than or equal to 40, for example.

The height of the oxide 830 is preferably larger than the width D of the oxide 830. In other words, the width D of the oxide 830 is preferably smaller than the height of the oxide 830. Such a structure enables miniaturization or high integration of the transistor 800. In the case where the channel length L of the transistor 800 is made longer by increasing the height of the oxide 830, a variation in the threshold voltage of the transistor 800 can be reduced. In the case where the physical distance between the conductor 860 and the conductor 610 is increased by increasing the height of the oxide 830, parasitic capacitance generated between the conductor 860 and the conductor 610 can be reduced. Note that the height of the oxide 830 can be equal to or smaller than the width D of the oxide 830.

The channel length L of the transistor 800 can be shorter than the channel width W of the transistor 800. The channel length L of the transistor 800 is preferably greater than or equal to 0.1 times and less than or equal to 0.99 times, further preferably greater than or equal to 0.5 times and less than or equal to 0.8 times the channel width W of the transistor 800. This structure enables a transistor with favorable electrical characteristics and high reliability.

Although an example where the oxide 830 is circular in the top view is described in this embodiment, the present invention is not limited thereto. For example, the oxide 830 may have, in the top view, an almost circular shape such as an ellipse, a polygonal shape such as a square, or a polygonal shape with rounded corners such as a square with rounded corners.

The insulator 880 is in contact with another part of the side surface of the oxide 830. The insulator 880 is in contact with the top surface and a side surface of the conductor 820. The insulator 880 includes a region positioned between the conductor 820 and the insulator 850. The thickness of the insulator 880 over the conductor 820 is preferably greater than or equal to 1 nm and less than or equal to 50 nm, further preferably greater than or equal to 3 nm and less than or equal to 30 nm, still further preferably greater than or equal to 5 nm and less than or equal to 30 nm, yet still further preferably greater than or equal to 10 nm and less than or equal to 20 nm. With this structure, the physical distance between the conductor 820 and the conductor 860 can be increased, so that the parasitic capacitance generated between the conductor 820 and the conductor 860 can be reduced.

The insulator 881 includes a region positioned between the bottom surface of the conductor 610 and the top surface of the portion of the conductor 860 along the side surface of the oxide 830. This structure can prevent a short circuit between the conductor 860 and the conductor 610. When the height of the above-described region (the shortest distance between the bottom surface of the conductor 610 and the top surface of the portion of the conductor 860 along the side surface of the oxide 830) is increased, parasitic capacitance generated between the conductor 860 and the conductor 610 can be reduced. The height of the above-described region can be, for example, greater than or equal to 5 nm and less than or equal to 50 nm, greater than or equal to 5 nm and less than or equal to 30 nm, or greater than or equal to 5 nm and less than or equal to 20 nm. Note that the height (thickness) of the insulator 881 in a region not overlapping with the conductor 860 is the sum of the height of the above-described region and the height (channel length L) of the conductor 860.

Note that the transistor 800 illustrated in FIGS. 34A to 34D is an example and the structure is not limited thereto.

### <Constituent Materials of Memory Device>

Constituent materials that can be used for a semiconductor device including a transistor and a capacitor are not limited to those in the above-described structure examples. In addition to the above-described constituent materials, any of the following constituent materials can be used as appropriate in one embodiment of the present invention.

### [Substrate]

Examples of a substrate on which the semiconductor device of one embodiment of the present invention, the memory device including the semiconductor device, and the like can be provided include a glass substrate, a quartz substrate, a sapphire substrate, a ceramic substrate, a metal substrate (e.g., a stainless steel substrate, a substrate including stainless steel foil, a tungsten substrate, and a substrate including tungsten foil), a semiconductor substrate (e.g., a single crystal semiconductor substrate, a polycrystalline semiconductor substrate, and a compound semiconductor substrate), and a silicon on insulator (SOI) substrate. As the substrate, a plastic substrate having heat resistance may be used. Examples of a glass substrate include a barium borosilicate glass substrate, an aluminosilicate glass substrate, an aluminoborosilicate glass substrate, and a soda lime glass substrate. Alternatively, crystallized glass or the like may be used as the glass substrate, for example.

Alternatively, a flexible substrate, an attachment film, paper including a fibrous material, a base film, or the like can be used as the substrate. Examples of materials for the flexible substrate, the attachment film, or the base film include plastic typified by polyethylene terephthalate (PET), polyethylene naphthalate (PEN), polyethersulfone (PES), and polytetrafluoroethylene (PTFE). Another example is a synthetic resin such as acrylic. Other examples are substrates of polypropylene, polyester, polyvinyl fluoride, and polyvinyl chloride. Alternatively, polyamide, polyimide, an aramid resin, an epoxy resin, an inorganic vapor deposition film, and paper can be used, for example. Specifically, the use of a semiconductor substrate, a single crystal substrate, an SOI substrate, or the like enables the manufacture of small-sized transistors with a small variation in characteristics, size, shape, or the like and with high current capability, for example. A circuit using such transistors achieves lower power consumption or higher integration.

A flexible substrate may be used as the substrate, and one or more of a transistor, a resistor, a capacitor, and the like may be formed directly over the flexible substrate. Alternatively, a separation layer may be provided between the substrate and, for example, one or more of the transistor, the resistor, the capacitor, and the like. The separation layer can be used when part or the whole of a semiconductor device formed over the separation layer is separated from the substrate and transferred to another substrate. In such a case, one or more of the transistor, the resistor, the capacitor, and the like can be transferred to a substrate having low heat resistance, a flexible substrate, or the like, for example. As the separation layer, a stack of inorganic films, namely a tungsten film and a silicon oxide film, an organic resin film of polyimide or the like formed over a substrate, or a silicon film containing hydrogen can be used, for example.

That is, a semiconductor device may be formed over a substrate and then transferred to another substrate. Examples of the substrate to which the semiconductor device is transferred include, in addition to the above-described substrates over which transistors can be formed, a paper substrate, a cellophane substrate, an aramid film substrate, a polyimide film substrate, a stone substrate, a wood substrate, a cloth substrate (including a natural fiber (e.g., silk, cotton, or hemp), a synthetic fiber (e.g., nylon, polyurethane, or polyester), a regenerated fiber (e.g., acetate, cupro, rayon, or regenerated polyester), or the like), a leather substrate, and a rubber substrate. With the use of any of these substrates, a flexible semiconductor device or a highly durable semiconductor device can be manufactured. In addition, the semiconductor device can have heat resistance. In addition, the weight or thickness of the semiconductor device can be reduced.

Providing a semiconductor device over a flexible substrate can suppress an increase in weight and can produce a non-breakable semiconductor device.

### [Ferroelectric]

A material that can show ferroelectricity may be used as an insulator functioning as a dielectric (e.g., the insulator 632) that can be used for the semiconductor device of one embodiment of the present invention. Examples of the material that can show ferroelectricity include metal oxides such as hafnium oxide, zirconium oxide, and HfZrO_{X} (X is a real number greater than 0). Examples of the material that can show ferroelectricity also include a material obtained by adding an element J1 (the element J1 here is for example one or more of zirconium, silicon, aluminum, gadolinium, yttrium, lanthanum, strontium, and the like) to hafnium oxide. Note that the atomic ratio of hafnium to the element J1 can be set as appropriate. For example, the atomic ratio of hafnium to the element J1 can be 1:1 or in the neighborhood thereof. Examples of the material that can show ferroelectricity also include a material obtained by adding an element J2 (the element J2 here is for example one or more of hafnium, silicon, aluminum, gadolinium, yttrium, lanthanum, strontium, and the like) to zirconium oxide. Note that the atomic ratio of zirconium to the element J2 can be set as appropriate. For example, the atomic ratio of zirconium to the element J2 can be 1:1 or in the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used, for example.

Examples of the material that can show ferroelectricity also include a metal nitride containing an element M1, an element M2, and nitrogen. Here, the element M1 is one or more of aluminum, gallium, indium, and the like, for example. The element M2 is one or more of boron, scandium, yttrium, lanthanum, cerium, neodymium, europium, titanium, zirconium, hafnium, vanadium, niobium, tantalum, chromium, and the like, for example. Note that the atomic ratio of the element M1 to the element M2 can be set as appropriate. A metal nitride containing the element M1 and nitrogen shows ferroelectricity in some cases even when the metal oxide does not contain the element M2. Examples of the material that can show ferroelectricity also include the above metal nitride to which an element M3 is added. Here, the element M3 is one or more of magnesium, calcium, strontium, zinc, cadmium, and the like, for example. Note that the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Although metal oxides and metal nitrides are described above as examples, one embodiment of the present invention is not limited thereto. For example, a metal oxynitride obtained by adding nitrogen to any of the above-described metal oxides, a metal nitride oxide obtained by adding oxygen to any of the above-described metal nitrides, or the like may be used.

As the material that can show ferroelectricity, a mixture or compound containing a plurality of materials selected from the above-listed materials can be used, for example. Alternatively, the insulator using the material that can show ferroelectricity can have a stacked-layer structure of a plurality of materials selected from the above-listed materials. The above-listed materials and the like may change their crystal structures (characteristics) according to a variety of processes and the like as well as film formation conditions. Therefore, in this specification and the like, not only a material that exhibits ferroelectricity but also a material that can show ferroelectricity may be referred to as a ferroelectric.

A metal oxide containing one or both of hafnium and zirconium is preferable because the metal oxide can show ferroelectricity even when being a thin film of several nanometers. Here, the thickness of the insulator using the material that can show ferroelectricity can be less than or equal to 100 nm, preferably less than or equal to 50 nm, further preferably less than or equal to 20 nm, still further preferably less than or equal to 10 nm (typically greater than or equal to 2 nm and less than or equal to 9 nm). For example, the thickness of the insulator is preferably greater than or equal to 8 nm and less than or equal to 12 nm. When an insulator functioning as a dielectric of a capacitor is the ferroelectric layer that can have a small thickness, the capacitor can be combined with a miniaturized semiconductor element such as a transistor to fabricate a semiconductor device, for example. Note that in this specification and the like, the material that can show ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

A metal oxide containing one or both of hafnium and zirconium is preferable because the metal oxide can show ferroelectricity even with a minute area. For example, a ferroelectric layer can show ferroelectricity even with an area (occupied area) less than or equal to 100 μm², less than or equal to 10 μm², less than or equal to 1 μm², or less than or equal to 0.1 μm² in a top view. Furthermore, even with an area of less than or equal to 10000 nm² or less than or equal to 1000 nm², a ferroelectric layer can show ferroelectricity in some cases. With a small-area ferroelectric layer, the area occupied by the capacitor can be reduced.

Note that the ferroelectric refers to an insulator having a property of causing internal polarization by application of an electric field from the outside and maintaining the polarization even after the electric field is made zero. Thus, with the use of a capacitor that contains this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like, for example. For example, a ferroelectric memory includes a transistor and a ferroelectric capacitor, and one of a source and a drain of the transistor is electrically connected to one terminal of the ferroelectric capacitor.

Note that ferroelectricity is exhibited by displacement of oxygen or nitrogen of a crystal included in a ferroelectric layer due to an electric field applied from the outside. Ferroelectricity is presumably exhibited depending on a crystal structure of a crystal included in a ferroelectric layer. Thus, in order for the insulator using the material that can show ferroelectricity to exhibit ferroelectricity, the insulator needs to include a crystal. It is particularly preferable that the insulator include a crystal having an orthorhombic crystal structure, in which case ferroelectricity is exhibited. A crystal included in the insulator may have one or more of crystal structures selected from cubic, tetragonal, orthorhombic, monoclinic, and hexagonal crystal structures. Alternatively, the insulator may have an amorphous structure. In that case, the insulator may have a composite structure including an amorphous structure and a crystal structure.

The structure, operation, and the like of one embodiment of the present invention are not limited to the structure examples, operation examples, and the like described in this embodiment. At least part of the structure examples and operation examples exemplified in this embodiment, the corresponding drawings, and the like can be combined as appropriate with other structure examples, other operation examples, other drawings, other embodiments, and the like described in this specification and the like.

### Embodiment 3

In this embodiment, a transistor including an oxide semiconductor in a channel formation region (OS transistor) is described. In the description of the OS transistor, comparison with a transistor including silicon in a channel formation region (also referred to as a Si transistor) is also described simply.

### [OS Transistor]

An oxide semiconductor having a low carrier concentration is preferably used in an OS transistor. For example, the carrier concentration of an oxide semiconductor in the channel formation region is lower than or equal to 1×10¹⁸ cm⁻³, preferably lower than 1× 10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration in an oxide semiconductor, the impurity concentration in the oxide semiconductor may be reduced so that the density of defect states in the oxide semiconductor can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

In addition, a highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of the impurity include hydrogen and nitrogen. Note that impurities in an oxide semiconductor refer to, for example, elements other than the main components of an oxide semiconductor. For example, an element with a concentration lower than 0.1 atomic % can be regarded as an impurity.

When impurities or oxygen vacancies are in a channel formation region of the oxide semiconductor included in an OS transistor, electrical characteristics of the OS transistor may vary easily and the reliability thereof may worsen. In some cases, a defect that is an oxygen vacancy into which hydrogen enters (hereinafter sometimes referred to as V_{O}H) is formed in the oxide semiconductor of the OS transistor, which generates an electron serving as a carrier. Formation of V_{O}H in the channel formation region may increase the donor concentration in the channel formation region of the OS transistor. An increase in the donor concentration in the channel formation region of the OS transistor may lead to a variation in threshold voltage. Thus, the oxygen vacancies in the channel formation region of the oxide semiconductor allow the OS transistor to easily have normally-on characteristics (to cause the drain current to flow at a gate voltage of 0 V). Therefore, impurities, oxygen vacancies, and V_{O}H are preferably reduced as much as possible in the channel formation region in the oxide semiconductor.

The band gap of the oxide semiconductor is preferably wider than the band gap of silicon (typically 1.1 eV), further preferably greater than or equal to 2 eV, still further preferably greater than or equal to 2.5 eV, yet still further preferably greater than or equal to 3.0 eV. With use of an oxide semiconductor having a wider band gap than silicon, the off-state current of the transistor (also referred to as Ioff) can be reduced.

In a Si transistor, a short-channel effect (SCE) appears as miniaturization of the transistor proceeds. This hinders miniaturization of a Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the OS transistor is a transistor in which the short-channel effect does not appear or hardly appears.

The short-channel effect refers to degradation of electrical characteristics that becomes obvious along with miniaturization of a transistor (a decrease in channel length). Specific examples of the short-channel effect include a decrease in threshold voltage, an increase in subthreshold swing value (sometimes referred to as S value), and an increase in leakage current. Here, the S value means the amount of change in gate voltage in the subthreshold region when the drain voltage is constant and the drain current is changed by one order of magnitude.

The characteristic length is widely used as an indicator of resistance to the short-channel effect. The characteristic length is an indicator of curving of a potential in a channel formation region. The smaller the characteristic length is, the more sharply the potential rises; thus, a smaller characteristic length indicates higher resistance to the short-channel effect.

The OS transistor is an accumulation-type transistor and the Si transistor is an inversion-type transistor. Thus, the OS transistor has a shorter characteristic length between the source region and the channel formation region and a shorter characteristic length between the drain region and the channel formation region than the Si transistor has. Accordingly, the OS transistor has higher resistance to the short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region each become an n⁺-type region in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be more suitably used as a short-channel transistor than the Si transistor. Note that the gate length refers to the length of a gate electrode in a direction in which carriers move inside a channel formation region during operation of the transistor and to the width of the bottom surface of the gate electrode in a top view of the transistor.

Miniaturization of the OS transistor can improve the high frequency characteristics of the transistor. Specifically, the cutoff frequency of the transistor can be improved. When the gate length of the OS transistor is within the above-described range, the cutoff frequency of the transistor can be greater than or equal to 50 GHz, preferably greater than or equal to 100 GHz, further preferably greater than or equal to 150 GHz at room temperature, for example.

The above-described comparison of the OS transistor with the Si transistor demonstrates that the OS transistor has an effect superior to the Si transistor, such as a low off-state current and capability of short-channel transistor formation.

The structures, configurations, methods, and the like described in this embodiment can be used in combination as appropriate with the structures, configurations, methods, and the like described in the other embodiments and the like.

### Embodiment 4

In this embodiment, application examples of the memory device of one embodiment of the present invention will be described.

### <Hierarchical Structure Example of Memory Device>

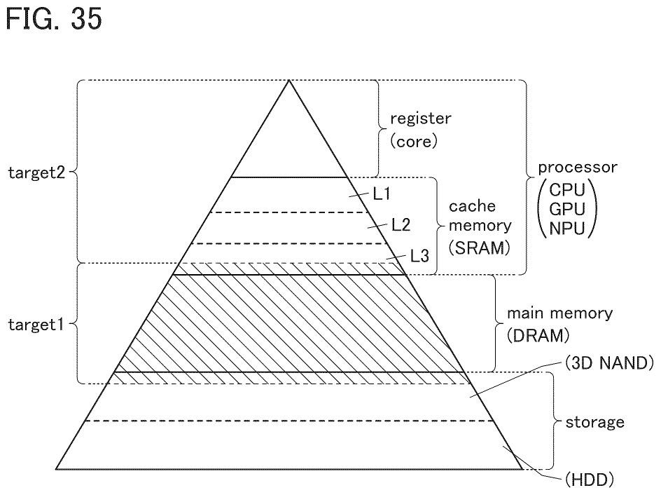

In general, a variety of memory devices are used in computers or the like in accordance with the intended use. FIG. 35 illustrates a hierarchy of memory devices. The memory devices at the upper levels require higher operating speed, whereas the memory devices at the lower levels require higher memory capacity and higher recording density. FIG. 35 illustrates a register, a cache memory, a main memory, and a storage in this order from the uppermost layer. The cache memory may include a primary cache (L1), a secondary cache (L2), a tertiary cache (L3), and the like in this order from above. Although the caches up to the tertiary cache are included in this example, a lower-level cache memory may be further included. The lowest-level cache memory may be referred to as a last level cache (LLC) or a final level cache (FLC). For example, a storage-class memory may be provided between the main memory and the storage.

A register mounted on an arithmetic processing device (also referred to as a processor) such as a central processing unit (CPU), a graphics processing unit (GPU), a neural processing unit (NPU), or a tensor processing unit (TPU) is used for temporary storage of results of an arithmetic operation conducted in a core, for example. The register also has a function of retaining setting information of the arithmetic processing device, for example. Thus, the frequency of access from the arithmetic processing device is high. Therefore, high operation speed is required for the register.

A static random access memory (SRAM) is used as the cache memory, for example. The cache memory has a function of duplicating and retaining part of data retained in the main memory. Copying data which is frequently used and retaining the copy of the data in the cache memory enables rapid access to the data. Higher operating speed than that of the main memory is required for the cache memory.

A dynamic random access memory (DRAM) is used as the main memory, for example. The main memory has a function of retaining a program and data that are read from the storage. Larger memory capacity and higher recording density than those of the cache memory are required for the main memory.

The storage has a function of retaining data that needs to be stored for a long time and programs used in the arithmetic processing device, for example. Thus, large memory capacity and high recording density are required for the storage. As the storage, a hard disk drive (HDD), a solid state drive (SSD) positioned in the layer above the HDD, or the like can be used, for example. As the SSD, a large-capacity and nonvolatile memory device such as a NAND flash memory (e.g., 3D NAND) can be used, for example.

The memory device of one embodiment of the present invention (e.g., a memory device using an oxide semiconductor) is excellent not only in being capable of operating at high speed and retaining data for a long period, but also in having high rewrite endurance and low-voltage driving capability.

The memory device of one embodiment of the present invention is, owing to its capability of retaining data for a long period, suitable as a memory device positioned in a region target1 which includes the layer where the cache memory is positioned, the layer where the main memory is positioned, and the layer where the storage is positioned. In other words, the memory device of one embodiment of the present invention is suitably used in the region target1 which includes, in addition to the region where the main memory is positioned, the boundary region between the main memory and the storage and the boundary region between the main memory and the cache memory.

Thus, for example, it is preferable to replace a DRAM used as the main memory with the memory device of one embodiment of the present invention. Refresh operation is essential in the DRAM, and the DRAM is a destructive read memory device and thus consumes higher power than other memory devices. Therefore, power consumption can be reduced by not using the DRAM. Furthermore, for example, it is also preferable to replace part of an SRAM used as the cache memory and part of a 3D NAND used as the storage with the memory device of one embodiment of the present invention.

Furthermore, the memory device of one embodiment of the present invention is, owing to its high speed operation that allows excellent writing and reading operations, suitable as a memory device positioned in a region target2 which includes the layer where the cache memory is positioned and the layer where the register is positioned. In other words, the memory device of one embodiment of the present invention is suitably used in the region target2 which includes part of the region where the cache memory is positioned and the region where the register is positioned.

Thus, for example, the memory device of one embodiment of the present invention is suitably used as at least part of a register included in a CPU, a GPU, an NPU, or the like. For example, the memory device of one embodiment of the present invention is suitably used as at least part of a cache memory (e.g., L1, L2, L3, LLC, or FLC).

In one embodiment of the present invention, a structure not using a DRAM, which has been conventionally used as a main memory or the like, can be employed. In that case, the memory device of one embodiment of the present invention can replace the DRAM. With such a structure, the power consumption can be dramatically reduced (e.g., reduced to 1/100 or 1/1000 or less). Thus, global expansion of information processing devices, such as supercomputers (also referred to as a high performance computer (HPC)), computers, and servers, having such a structure will greatly contribute to global warming mitigation.

### <Structure Example of Memory Cell>

The memory device of one embodiment of the present invention is a memory device including an oxide semiconductor. The memory device includes a memory cell including an OS transistor. As examples of the memory cell, other than the memory cell 111 described above in Embodiment 1 and the like, the structures described below can be given.

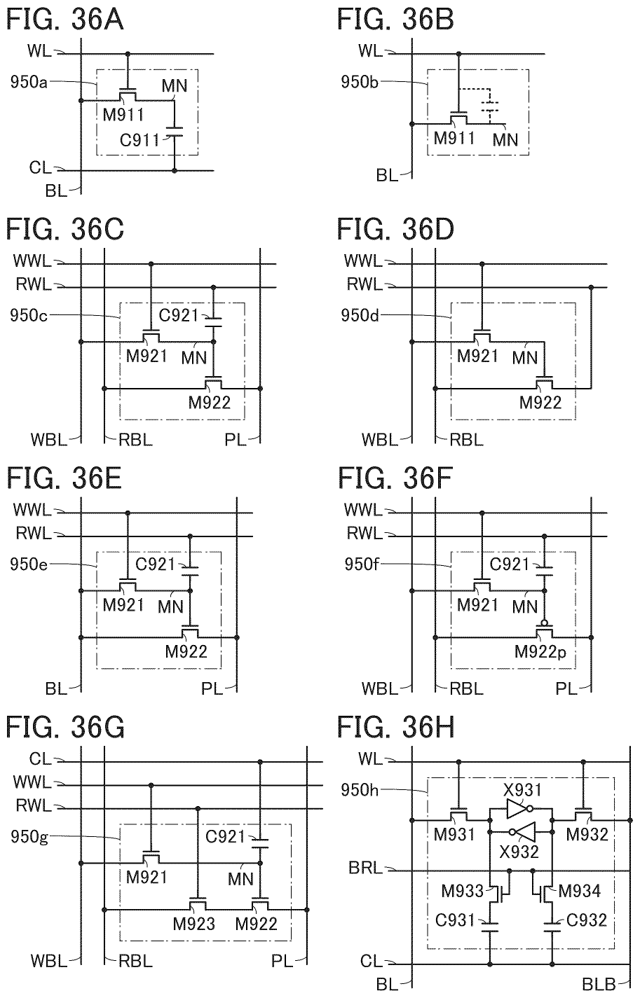

A memory cell 950a illustrated in FIG. 36A includes a transistor M911 and a capacitor C911. One of a source and a drain of the transistor M911 is electrically connected to one terminal of the capacitor C911. The other of the source and the drain of the transistor M911 is connected to the wiring BL functioning as a bit line. A gate of the transistor M911 is connected to the wiring WL functioning as a word line. The other terminal of the capacitor C911 is connected to a wiring CL. Note that a wiring to which both the one of the source and the drain of the transistor M911 and the one terminal of the capacitor C911 are connected is referred to as a wiring MN in some cases.

The memory cell 950a can store binary data when the potential corresponding to the amount of charge accumulated in the capacitor C911, that is, the amount of charge retained in the wiring MN, is made to correspond to “1” or “0”. Furthermore, data having three (ternary) or more levels may be stored, for example. In the case where data is written to the memory cell 950a, the conduction state of the transistor M911 is controlled, whereby a potential corresponding to data can be supplied from the wiring BL to the wiring MN and charge corresponding to the potential can be retained. In the case where data is read from the memory cell 950a, the conduction state of the transistor M911 is controlled, whereby charge retained in the wiring MN can be extracted to the wiring BL.

Note that reading of data from the memory cell 950a means extraction of the charge retained in the wiring MN to the wiring BL and thus changes the potential of the wiring MN. In other words, by reading data from the memory cell 950a, stored data is destructed. That is, reading of data from the memory cell 950a is destructive reading. Therefore, the memory cell 950a needs writing back (refresh) of data after data reading.

In one embodiment of the present invention, an n-channel OS transistor can be used as the transistor M911, for example.

Note that the memory cell 950a illustrated in FIG. 36A is a memory cell of a dynamic random access memory (DRAM), and a structure using an OS transistor as the transistor M911 is particularly referred to as a DOSRAM (registered trademark) in some cases. Since an OS transistor having an extremely low off-state current is used in the DOSRAM, data can be stored for a long period. In addition, multilevel data or analog data can be stored. Furthermore, data once written can be stored for a long period, and thus the frequency of data refresh can be lowered. In addition, the capacitance of the cell capacitor (the capacitor C911) can be reduced, so that the cell size can be reduced. Thus, the use of the DOSRAM can reduce power consumption of a semiconductor device and a memory device and increase the recording density thereof.

A memory cell 950b illustrated in FIG. 36B is a modification example of the memory cell 950a illustrated in FIG. 36A and is different from the memory cell 950a in not including the capacitor C911.

In the memory cell 950b illustrated in FIG. 36B, charge can be accumulated in a parasitic capacitor (capacitance between the gate and one of the source and the drain of the transistor M911) indicated by a dashed line or the like. With such a structure, for example, the cell size can be reduced, so that the recording density of a semiconductor device and a memory device can be increased.

A memory cell 950c illustrated in FIG. 36C includes a transistor M921, a transistor M922, and a capacitor C921. One of a source and a drain of the transistor M921 is connected to a gate of the transistor M922 and one terminal of the capacitor C921. The other of the source and the drain of the transistor M921 is connected to a wiring WBL functioning as a write bit line. A gate of the transistor M921 is connected to a wiring WWL functioning as a write word line. One of a source and a drain of the transistor M922 is connected to a wiring RBL functioning as a read bit line. The other of the source and the drain of the transistor M922 is connected to the wiring PL. The other terminal of the capacitor C921 is connected to a wiring RWL functioning as a read word line. Note that a wiring to which the one of the source and the drain of the transistor M921, the gate of the transistor M922, and the one terminal of the capacitor C921 are each connected is referred to as the wiring MN in some cases.

The memory cell 950c can store binary data when the potential corresponding to the amount of charge accumulated in the capacitor C921, that is, the amount of charge retained in the wiring MN, is made to correspond to “1” or “0”. Furthermore, data having three (ternary) or more levels may be stored, for example. In the case where data is written to the memory cell 950c, the conduction state of the transistor M921 is controlled, whereby a potential corresponding to data can be supplied from the wiring WBL to the wiring MN and charge corresponding to the potential can be retained. In the case where data is read from the memory cell 950c, the transistor M922 is brought into the conduction state or the non-conduction state in accordance with the potential of the wiring MN, whereby a potential corresponding to the data can be extracted to the wiring RBL.

In one embodiment of the present invention, an n-channel OS transistor can be used as the transistor M921, for example. As the transistor M922, an n-channel transistor (e.g., an OS transistor or a Si transistor) can be used, for example.

Note that the memory cell 950c illustrated in FIG. 36C is a gain-cell memory cell; in particular, a structure in which an OS transistor is used as the transistor M921 is referred to as a NOSRAM (registered trademark) in some cases. “NOSRAM” is an abbreviation for Nonvolatile Oxide Semiconductor RAM. Since an OS transistor having an extremely low off-state current is used in the NOSRAM, data can be stored for a long period. In addition, multilevel data or analog data can be stored. Since the transistor for writing (the transistor M921) and the transistor for reading (the transistor M922) are different from each other, non-destructive reading is performed in data reading. Thus, the memory cell can be used as a nonvolatile memory, for example.

A memory cell 950d illustrated in FIG. 36D is a modification example of the memory cell 950c illustrated in FIG. 36C and is different from the memory cell 950c in that the capacitor C921 is not included and in that the other of the source and the drain of the transistor M922 is connected to the wiring RWL.

In the memory cell 950d illustrated in FIG. 36D, charge can be accumulated in a parasitic capacitor added to the wiring MN. With such a structure, for example, the cell size can be reduced, so that the recording density of a semiconductor device and a memory device can be increased.

A memory cell 950e illustrated in FIG. 36E is a modification example of the memory cell 950c illustrated in FIG. 36C and is different from the memory cell 950c in that the other of the source and the drain of the transistor M921 is connected to the wiring BL and the one of the source and the drain of the transistor M922 is connected to the wiring BL.

In the memory cell 950e illustrated in FIG. 36E, the wiring BL can function as a bit line for both writing and reading. With such a structure, for example, the cell size can be reduced, so that the recording density of a semiconductor device and a memory device can be increased.

A memory cell 950f illustrated in FIG. 36F is a modification example of the memory cell 950c illustrated in FIG. 36C and is different from the memory cell 950c in including a transistor

M922p instead of the transistor M922. As the transistor M922p, a p-channel Si transistor can be used, for example.

In the memory cell 950f illustrated in FIG. 36F, data is read using the p-channel transistor; thus, the structure, operation, and the like of the sense amplifier can be simplified in some cases, for example. With such a structure, for example, the layout area of the driver circuit can be reduced, so that a semiconductor device and a memory device can be downsized.

A memory cell 950g illustrated in FIG. 36G is a modification example of the memory cell 950c illustrated in FIG. 36C and is different from the memory cell 950c in including a transistor M923. One of the source and the drain of the transistor M922 is connected to one of a source and a drain of the transistor M923, the other of the source and the drain of the transistor M922 is connected to the wiring PL, the other of the source and the drain of the transistor M923 is connected to the wiring RBL, and a gate of the transistor M923 is connected to the wiring RWL. The other terminal of the capacitor C921 is connected to the wiring CL instead of to the wiring RWL. As the transistor M923, an n-channel transistor (e.g., an OS transistor or a Si transistor) can be used, for example.

In the memory cell 950g illustrated in FIG. 36G, the parasitic capacitance between the wiring MN and the wiring RBL can be reduced. Such a structure can, for example, inhibit noise from being mixed into the wiring MN via the gate capacitance of the transistor M922 and improve the reliability of a semiconductor device and a memory device.

A memory cell 950h illustrated in FIG. 36H includes a transistor M931, a transistor M932, a transistor M933, a transistor M934, a capacitor C931, a capacitor C932, an inverter X931, and an inverter X932. One of a source and a drain of the transistor M931 is connected to one of a source and a drain of the transistor M933, an input terminal of the inverter X931, and an output terminal of the inverter X932. One of a source and a drain of the transistor M932 is connected to one of a source and a drain of the transistor M934, an output terminal of the inverter X931, and an input terminal of the inverter X932. The other of the source and the drain of the transistor M933 is connected to one terminal of the capacitor C931. The other of the source and the drain of the transistor M934 is connected to one terminal of the capacitor C932. The other of the source and the drain of the transistor M931 is connected to the wiring BL functioning as one of a pair of bit lines. The other of the source and the drain of the transistor M932 is connected to a wiring BLB functioning as the other of the pair of bit lines. A gate of the transistor M931 and a gate of the transistor M932 are connected to the wiring WL functioning as a word line. A gate of the transistor M933 and a gate of the transistor M934 are connected to a wiring BRL. The other terminal of the capacitor C931 and the other terminal of the capacitor C932 are connected to the wiring CL.

In the memory cell 950h, binary data of “1” or “0” can be stored in an inverter loop composed of the inverter X931 and the inverter X932. In writing data to the memory cell 950h, the conduction states of the transistor M931 and the transistor M932 are controlled, so that a potential corresponding to data can be supplied from each of the wiring BL and the wiring BLB to the inverter loop. In reading data from the memory cell 950h, the conduction states of the transistor M931 and the transistor M932 are controlled, so that a potential corresponding to the data stored in the inverter loop can be extracted to each of the wiring BL and the wiring BLB.

In the memory cell 950h, by controlling the conduction states of the transistor M933 and the transistor M934, a potential corresponding to the data stored in the inverter loop can be supplied to each of the one terminal of the capacitor C931 and the one terminal of the capacitor C932 and charge corresponding to the potential can be retained. That is, data backup can be performed. Furthermore, in the memory cell 950h, charge retained in the one terminal of the capacitor C931 and the one terminal of the capacitor C932 can be extracted to the inverter loop by controlling the conduction states of the transistor M933 and the transistor M934. That is, data recovery can be performed.

In one embodiment of the present invention, n-channel OS transistors can be used as the transistor M931, the transistor M932, the transistor M933, and the transistor M934, for example. As each of the inverter X931 and the inverter X932, an inverter circuit prepared in a standard circuit library can be used. That is, as transistors included in the inverter X931 and the inverter X932, n-channel and p-channel Si transistors can be used, for example.

Note that the memory cell 950h illustrated in FIG. 36H is a memory cell of a static random access memory (SRAM) capable of backup operation; in particular, a structure in which OS transistors are used as the transistor M931, the transistor M932, the transistor M933, and the transistor M934 is referred to as an oxide semiconductor-SRAM (OS-SRAM) in some cases.

Note that one embodiment of the present invention is not limited to the memory cell 950a to the memory cell 950h, and a memory cell in which the structures of the memory cells are combined as appropriate can be formed.

Note that this embodiment can be combined with any of the other embodiments in this specification and the like as appropriate.

### Embodiment 5

In this embodiment, an example of a circuit structure including OS transistors of one embodiment of the present invention will be described.

### <Circuit Structure Example>

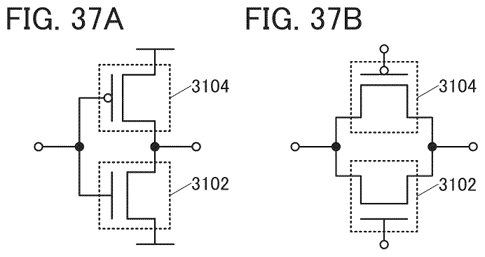

FIGS. 37A and 37B each illustrate an example of a circuit structure including OS transistors of one embodiment of the present invention. The circuit diagram in FIG. 37A illustrates a structure of an inverter circuit formed of what is called a CMOS (Complementary Metal Oxide Semiconductor) circuit in which an n-channel transistor 3102 and a p-channel transistor 3104 are connected in series and their gates are connected. The circuit diagram in FIG. 37B illustrates a circuit structure that functions as what is called an analog switch, in which a source of the n-channel transistor 3102 and a drain of the p-channel transistor 3104 are connected to each other and a drain of the n-channel transistor 3102 and a source of the p-channel transistor 3104 are connected to each other.

### <Transistor Structure>

Any of various types of transistors can be used as the n-channel transistor 3102 and the p-channel transistor 3104 illustrated in FIGS. 37A and 37B. Specifically, a planar transistor, a vertical field effect transistor (VFET), a Fin-type transistor, a gate all around (GAA) transistor, or the like can be used as the n-channel transistor 3102 and the p-channel transistor 3104. A complementary field effect transistor (CFET) in which the n-channel transistor 3102 and the p-channel transistor 3104 are combined may be used.

In this specification and the like, a planar transistor has a structure in which a source electrode and a drain electrode are positioned at the same height and a current flowing through a semiconductor contains components in the lateral direction. In this specification and the like, a VFET has a structure in which a source electrode and a drain electrode are positioned at different heights and a current flowing through a semiconductor contains components in the vertical direction. Since two or more of the source electrode, the semiconductor, and the drain electrode of the VFET can be provided to overlap with each other, the area occupied by the VFET can be significantly smaller than the area occupied by the planar transistor.

In this specification and the like, a Fin-type transistor has a structure in which two or more surfaces of a channel are covered with a gate electrode with a gate insulating film therebetween in a cross-sectional view in the channel width direction. In particular, when the channel height (H) is larger than the channel width (W) in the cross-sectional view in the channel width direction, the channel width per unit area can be increased, which is preferable. In this specification and the like, a GAA transistor has a structure in which a gate electrode covers four surfaces of a channel with a gate insulating film therebetween in a cross-sectional view in the channel width direction.

Here, for example, the transistor 500 described above in Embodiment 2 can be regarded as a kind of planar transistor. Furthermore, for example, the transistor 600 and the transistor 600B described above in Embodiment 2 can each be regarded as a kind of vertical transistor. Furthermore, for example, the transistor 500F described above in Embodiment 2 can be regarded as a kind of Fin-type transistor. Moreover, for example, it can be said that the transistor 800 described above in Embodiment 2 is a kind of vertical transistor and is also a kind of GAA transistor.

### <N-Channel Transistor>

An OS transistor of one embodiment of the present invention can be used as the n-channel transistor 3102 illustrated in FIGS. 37A and 37B. The OS transistor has an extremely low off-state current, and thus the leakage current of the transistor 3102 can be extremely low. In the n-channel transistor 3102, a single element semiconductor such as silicon or germanium, a compound semiconductor such as gallium arsenide, a layered material functioning as a semiconductor, or the like can be used as a semiconductor material. In particular, a layered material functioning as a semiconductor may be used as a semiconductor material.

In this specification and the like, the layered material is a group of materials having a layered crystal structure. In the layered crystal structure, layers formed by covalent bonding or ionic bonding are stacked with bonding such as the van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

In this specification and the like, the above-described layered material is sometimes referred to as a two-dimensional material. Examples of a two-dimensional material that can be used in one embodiment of the present invention include graphene, silicene (a substance in which a carbon atom of graphene is replaced with a silicon atom), germanene (a substance in which a carbon atom of graphene is replaced with a germanium atom), transition metal chalcogenides or transition metal dichalcogenides (TMDs), boron nitride (BN), and black phosphorus. Using the above-described two-dimensional material can improve one or more physical properties of electron mobility, mechanical strength, and thermal conductivity, compared with the case of using a single element semiconductor such as silicon or germanium. The above-described two-dimensional material has excellent physical properties compared with a single element semiconductor such as silicon; thus, the two-dimensional material may be referred to as a new material channel (NMC).

Examples of the layered material include chalcogenide. Chalcogenide is a compound containing chalcogen. Chalcogen is a general term of elements belonging to Group 16, which includes oxygen, sulfur, selenium, tellurium, polonium, and livermorium. Examples of chalcogenide include transition metal chalcogenide and chalcogenide of Group 13 elements.

As a material that can be used in the transistor 3102, a transition metal chalcogenide functioning as a semiconductor is preferably used, for example. Specific examples of the transition metal chalcogenide include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

### <P-Channel Transistor>

In the p-channel transistor 3104 illustrated in FIGS. 37A and 37B, a single element semiconductor such as silicon or germanium, a compound semiconductor such as gallium arsenide, a layered material functioning as a semiconductor, or the like can be used as a semiconductor material. In particular, a layered material functioning as a semiconductor may be used as a semiconductor material; any of the above-described two-dimensional materials can be used.

As a material that can be used in the transistor 3104, a transition metal chalcogenide functioning as a semiconductor is preferably used, for example. Specific examples of the transition metal chalcogenide include molybdenum sulfide (typically MoS₂), molybdenum selenide (typically MoSe₂), tungsten sulfide (typically WS₂), and tungsten selenide (typically WSe₂).

As materials that can be used in the transistor 3102 and the transistor 3104, other than the above-described two-dimensional material, a Group III-IV compound semiconductor (typically, a gallium-arsenic compound semiconductor, an indium-phosphorus compound semiconductor, an indium-gallium-arsenic compound semiconductor, an indium-arsenic compound semiconductor, or the like), a carbon nanotube (CNT), tin sulfide (typically, SnS), tin selenide (typically, SnSe), or the like can be used.

This embodiment can be combined with any of the other embodiments as appropriate. In this specification and the like, in the case where a plurality of structure examples are shown in one embodiment, the structure examples can be combined as appropriate.

### Embodiment 6

In this embodiment, electronic components, electronic devices, a large computer, space equipment, and a data center (also referred to as DC) in which the semiconductor device described in the above embodiments can be used will be described. An electronic component, an electronic device, a large computer, space equipment, and a data center each employing the semiconductor device of one embodiment of the present invention are effective in improving performance, for example, reducing power consumption.

### [Electronic Component]

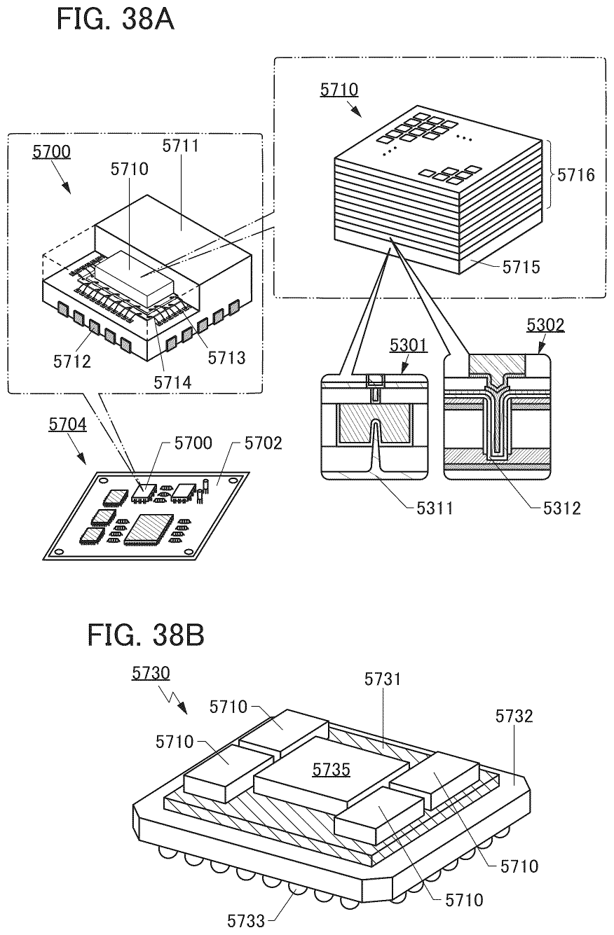

FIG. 38A is a perspective view of an electronic component 5700 and a substrate (circuit board 5704) on which the electronic component 5700 is mounted. The electronic component 5700 illustrated in FIG. 38A includes a semiconductor device 5710 in a mold 5711. FIG. 38A omits some components to show the inside of the electronic component 5700. The electronic component 5700 includes a land 5712 outside the mold 5711. The land 5712 is connected to an electrode pad 5713. The electrode pad 5713 is connected to the semiconductor device 5710 through a wire 5714. The electronic component 5700 is mounted on a printed circuit board 5702, for example. A plurality of such electronic components are combined and connected to each other on the printed circuit board 5702, which forms the circuit board 5704.

The semiconductor device 5710 includes a layer 5715 including an arithmetic core and a layer 5716 including a memory. For example, the above-described n-channel transistors and p-channel transistors can be used for both the layer 5715 and the layer 5716. It is particularly preferable that a p-channel transistor be used for the layer 5715 and an n-channel transistor be used for the layer 5716 to form a CMOS circuit. However, one embodiment of the present invention is not limited thereto, and both an n-channel transistor and a p-channel transistor may be included in the layer 5715 and an n-channel transistor may be used in the layer 5716.

Specifically, it is preferable that the layer 5715 include a p-channel transistor 5301 and the layer 5716 include an n-channel transistor 5302. In FIG. 38A, when a semiconductor layer 5311 included in the transistor 5301 is p-channel silicon and a semiconductor layer 5312 included in the transistor 5302 is an n-channel oxide semiconductor, a stacked-layer structure of a Si transistor and an OS transistor can be obtained.

Alternatively, in FIG. 38A, when the semiconductor layer 5311 included in the transistor 5301 is a p-channel two-dimensional material (e.g., WS₂) and the semiconductor layer 5312 included in the transistor 5302 is an n-channel oxide semiconductor, a stacked-layer structure of a WS₂ transistor and an OS transistor can be obtained. With such a stacked-layer structure, a memory device with low power consumption and high performance can be provided.

The stack of the two kinds of transistors reduces the area occupied by the circuit, allowing a plurality of circuits to be placed at high density. Although FIG. 38A illustrates the structure in which the transistor 5301 is a Fin-type transistor and the transistor 5302 is a VFET, one embodiment of the present invention is not limited thereto, and the above-described various types of transistors can be used as the transistor 5301 and the transistor 5302. When the transistor 5301 and the transistor 5302 have different structures, characteristics according to the respective transistor structures can be obtained, which is excellent. When the structures of the transistor 5301 and the transistor 5302 are the same, some manufacturing apparatuses can be used in common, which is excellent.

The layer 5716 including the memory has a structure where a plurality of memory cell arrays are stacked. The layer 5715 including the arithmetic core and the layer 5716 including the memory can be stacked monolithically. In the monolithic stacked-layer structure, layers can be connected to each other without using a through electrode technique such as a through silicon via (TSV) technique and a bonding technique such as Cu-to-Cu direct bonding, for example. The monolithic stacked-layer structure of the layer 5715 including the arithmetic core and the layer 5716 including the memory enables, for example, what is called an on-chip memory structure where a memory is directly formed on a processor. The on-chip memory structure allows an interface portion between the processor and the memory to operate at high speed. Note that part of the function (part of the arithmetic function) of the layer 5715 including the arithmetic core may be provided in part of the layer 5716 including the memory.

With the on-chip memory structure, for example, the sizes of a connection wiring and the like can be smaller than those in the case where the through electrode technique such as TSV is employed; thus, the number of connection pins can be increased. The increase in the number of connection pins enables parallel operations, which can improve the bandwidth of the memory (also referred to as a memory bandwidth).

It is preferable that the plurality of memory cell arrays included in the layer 5716 including the memory be formed with OS transistors and be monolithically stacked. The monolithic stacked-layer structure of the plurality of memory cell arrays can improve the bandwidth of the memory and/or the access latency of the memory. Note that the bandwidth refers to the data transfer volume per unit time. The access latency refers to a period of time from data access to the start of data transmission. Note that in the case where the memory layer 5716 including the memory is formed with Si transistors, the monolithic stacked-layer structure is difficult to form as compared with the case where the layer 5716 including the memory is formed with OS transistors. Therefore, an OS transistor is superior to a Si transistor in the monolithic stacked-layer structure.

That is, an OS transistor has an excellent effect of achieving a wide memory bandwidth as compared with a Si transistor.

Note that the semiconductor device 5710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon, silicon carbide, and gallium nitride. For example, a die obtained from a silicon substrate (also referred to as a silicon wafer) is referred to as a silicon die in some cases.

FIG. 38B is a perspective view of an electronic component 5730. The electronic component 5730 is an example of a system in package (SiP) or a multi-chip module (MCM). In the electronic component 5730, an interposer 5731 is provided over a package substrate 5732 (printed circuit board), and a semiconductor device 5735 and a plurality of the semiconductor devices 5710 are provided over the interposer 5731.

In the electronic component 5730, the semiconductor devices 5710 can be used as a memory device such as a high bandwidth memory (HBM), for example. The semiconductor device 5735 can be used as an integrated circuit (e.g., an arithmetic device, a control device, or a signal processing unit) such as a central processing unit (CPU), a graphics processing unit (GPU), or a field programmable gate array (FPGA), for example.

As the package substrate 5732, a ceramic substrate, a plastic substrate, or a glass epoxy substrate can be used, for example. As the interposer 5731, a silicon interposer or a resin interposer can be used, for example.

The interposer 5731 includes a plurality of wirings and has a function of electrically connecting a plurality of integrated circuits with different terminal pitches through the plurality of wirings. The plurality of wirings are provided in a single layer or multiple layers. In addition, the interposer 5731 has a function of connecting an integrated circuit provided on the interposer 5731 to an electrode provided on the package substrate 5732. Accordingly, the interposer 5731 is referred to as a “redistribution substrate” or an “intermediate substrate” in some cases. Furthermore, a through electrode is provided in the interposer 5731 and the through electrode is used to connect an integrated circuit and the package substrate 5732 in some cases. Moreover, in the case of using a silicon interposer as the interposer 5731, a TSV can also be used as the through electrode.

A silicon interposer is preferably used as the interposer 5731. The silicon interposer can be fabricated at a lower cost than an integrated circuit because it is not necessary to provide an active element. Moreover, since wirings of the silicon interposer can be formed through a semiconductor process, the formation of minute wirings, which is difficult for a resin interposer, is easily achieved.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In an SiP, an MCM, and the like using a silicon interposer, for example, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, for example, in the case where a plurality of integrated circuits with different terminal pitches are connected with use of a silicon interposer, TSV, or the like, a space for a width of the terminal pitch and the like is needed. Accordingly, in the case where the size of the electronic component 5730 is reduced, the width of the terminal pitch becomes an issue, which sometimes makes it difficult to provide a large number of wirings for obtaining a wide memory bandwidth. For this reason, the monolithic stacked-layer structure using the OS transistors is suitable. A composite structure combining memory cell arrays stacked using TSV and monolithically stacked memory cell arrays may be employed.

The substrate on which the electronic component 5730 is mounted may be provided with a heat sink (a radiator plate) overlapping with the electronic component 5730. In the case of providing a heat sink, the heights of integrated circuits provided on the interposer 5731 are preferably equal to each other. For example, in the electronic component 5730, the heights of the semiconductor devices 5710 and the semiconductor device 5735 are preferably equal to each other.

To mount the electronic component 5730 on another substrate, an electrode 5733 may be provided on a bottom portion of the package substrate 5732. FIG. 38B illustrates an example where the electrode 5733 is formed of a solder ball. In the electronic component 5730, solder balls are provided in a matrix on the bottom portion of the package substrate 5732, so that BGA (Ball Grid Array) mounting can be achieved. Note that the electrode 5733 may be formed of a conductive pin. When conductive pins are provided in a matrix on the bottom portion of the package substrate 5732, PGA (Pin Grid Array) mounting can be achieved in the electronic component 5730.

The electronic component 5730 can be mounted on another substrate by various mounting methods other than BGA and PGA. For example, a staggered pin grid array (SPGA), a land grid array (LGA), a quad flat package (QFP), a quad flat J-leaded package (QFJ), or a quad flat non-leaded package (QFN) can be employed.

### [Electronic Device]

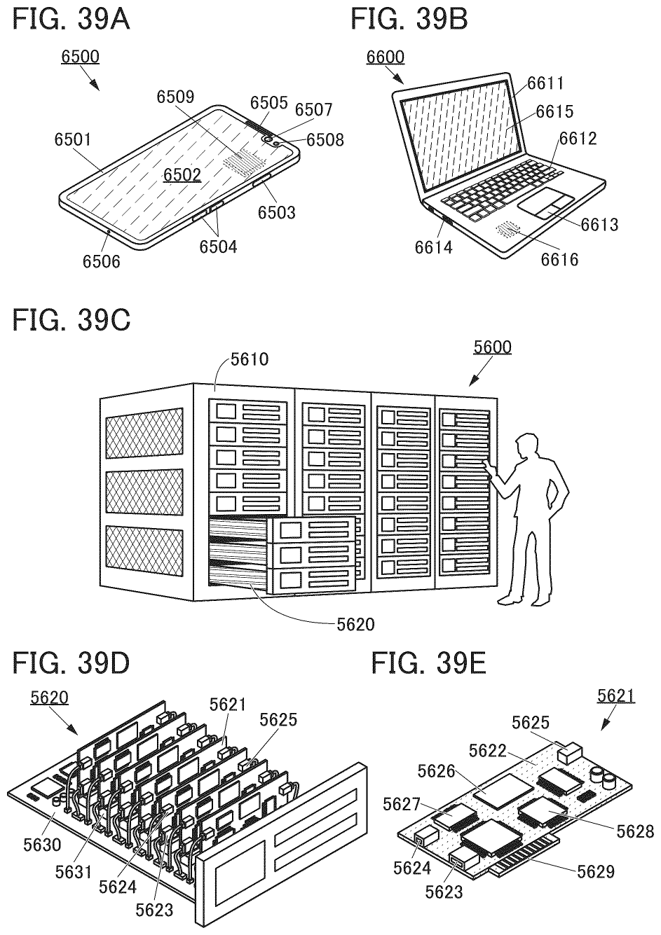

FIG. 39A is a perspective view of an electronic device 6500. The electronic device 6500 illustrated in FIG. 39A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, and a control device 6509, for example. Note that as the control device 6509, for example, one or more selected from a CPU, a GPU, and a memory device are included. The semiconductor device of one embodiment of the present invention can be used for the display portion 6502 or the control device 6509, for example. The semiconductor device of one embodiment of the present invention is preferably used for the control device 6509, in which case power consumption can be reduced.

FIG. 39B is a perspective view of an electronic device 6600. The electronic device 6600 illustrated in FIG. 39B is an information terminal that can be used as a laptop personal computer. The electronic device 6600 includes a housing 6611, a keyboard 6612, a pointing device 6613, an external connection port 6614, a display portion 6615, and a control device 6616, for example. Note that as the control device 6616, for example, one or more selected from a CPU, a GPU, and a memory device are included. The semiconductor device of one embodiment of the present invention can be used for the control device 6509 or the control device 6616, for example. The semiconductor device of one embodiment of the present invention is preferably used for the control device 6616, in which case power consumption can be reduced.

### [Large Computer]

FIG. 39C is a perspective view of a large computer 5600. In the large computer 5600 illustrated in FIG. 39C, a plurality of rack mount computers 5620 are stored in a rack 5610. Note that the large computer 5600 may be referred to as a supercomputer.

FIG. 39D is a perspective view illustrating a structure example of the computer 5620. In FIG. 39D, the computer 5620 includes a motherboard 5630. The motherboard 5630 includes a plurality of slots 5631 and a plurality of connection terminals (not illustrated). A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 39E is an example of a processing board provided with a CPU, a GPU, a memory device, and the like, for example. The PC card 5621 includes a board 5622. The board 5622 includes the connection terminals 5623, 5624, and 5625, semiconductor devices 5626, 5627, and 5628, and a connection terminal 5629. Note that FIG. 39E also illustrates semiconductor devices other than the semiconductor devices 5626, 5627, and 5628, and the following description of the semiconductor devices 5626, 5627, and 5628 can be referred to for those semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe (Peripheral Component Interconnect Express).

The connection terminal 5623, the connection terminal 5624, and the connection terminal 5625 can each serve as, for example, an interface for performing electric power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is high-definition multimedia interface (HDMI, registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the above-described electronic component 5730 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the above-described electronic component 5700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be used for space equipment, such as devices processing and storing information, for example.

The semiconductor device of one embodiment of the present invention can include an OS transistor. A change in electrical characteristics of the OS transistor due to exposure to radiation is small. That is, the OS transistor is highly resistant to radiation, and thus is suitably used even in an environment where radiation can enter. For example, the OS transistor is suitably used in outer space.

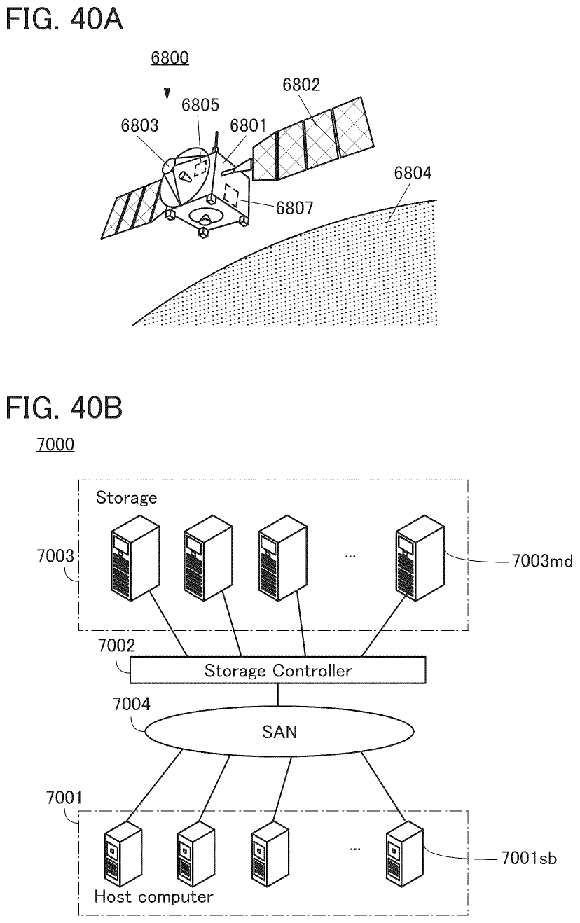

FIG. 40A illustrates an artificial satellite 6800 as an example of space equipment. The artificial satellite 6800 includes a body 6801, a solar panel 6802, an antenna 6803, a secondary battery 6805, and a control device 6807. In FIG. 40A, a planet 6804 in outer space is illustrated as an example. Note that although outer space refers to, for example, space at an altitude greater than or equal to 100 km, the outer space described in this specification and the like may also include thermosphere, mesosphere, and stratosphere.

Although not illustrated in FIG. 40A, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is more than 100 times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel 6802 is not irradiated with sunlight or the situation where the solar panel 6802 is irradiated with a slight amount of sunlight, the amount of electric power generated by the solar panel 6802 is small. Accordingly, a sufficient amount of electric power required for operation of the artificial satellite 6800 may be difficult to generate. In order to operate the artificial satellite 6800 even in the situation where the amount of electric power generated by the solar panel 6802 is small, the artificial satellite 6800 is preferably provided with the secondary battery 6805. Note that such a solar panel 6802 is referred to as a solar cell module in some cases.

The artificial satellite 6800 can generate a signal. The signal is transmitted through the antenna 6803. The signal can be received by a ground-based receiver or another artificial satellite, for example. For example, when the signal transmitted by the artificial satellite 6800 is received by a receiver, the position of the receiver can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807. A change in electrical characteristics of the OS transistor due to exposure to radiation is smaller than a change in electrical characteristics of a Si transistor. Thus, the OS transistor has high reliability and thus can be suitably used even in an environment where radiation can enter.

That is, the OS transistor has an excellent effect of being highly resistant to radiation as compared with a Si transistor.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described here as an example of the space equipment, one embodiment of the present invention is not limited to the artificial satellite. The semiconductor device of one embodiment of the present invention can be used for space equipment such as a spacecraft, a space capsule, or a space probe, for example.

### [Data Center]

The semiconductor device of one embodiment of the present invention can be used for, for example, a storage system in a data center or the like. The data center is required to perform long-term management of data such as guarantee of data immutability, for example. In the case where data is managed for a long term, it is necessary to increase the scale of data center facility for installation of storages and servers for storing an enormous amount of data, stable electric power for data retention, cooling equipment for data retention, or the like, for example.

With the use of the semiconductor device of one embodiment of the present invention for a storage system in a data center, electric power used for retaining data can be reduced and the semiconductor device for retaining data can be reduced in size. Accordingly, reductions in sizes of the storage system and the power supply for retaining data, downscaling of the cooling equipment, and the like can be achieved, for example. Therefore, space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the peripheral module can be reduced. Furthermore, by using the semiconductor device of one embodiment of the present invention, a data center that operates stably even in a high temperature environment can be formed. Thus, the reliability of the data center can be increased.

FIG. 40B illustrates a storage system that can be used in a data center. A storage system 7000 illustrated in FIG. 40B includes a plurality of servers 7001sb as a host 7001 (indicated as “Host Computer” in the drawing). The storage system 7000 includes a plurality of memory devices 7003md as a storage 7003 (indicated as “Storage” in the drawing). In addition, the host 7001 and the storage 7003 are connected to each other through a storage area network 7004 (indicated as “SAN” in the drawing) and a storage control circuit 7002 (indicated as “Storage Controller” in the drawing).

The host 7001 corresponds to a computer which accesses data stored in the storage 7003. The host 7001 may be connected to another host 7001 through a network.

The data access speed, i.e., the time taken for writing and reading data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time for data writing and reading.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential corresponding to data can reduce the frequency of refreshing the cache memory, so that power consumption of the cache memory can be reduced. Furthermore, with a structure in which memory cell arrays are stacked, the cache memory can be downsized.

By employing the semiconductor device of one embodiment of the present invention in any one or more selected from an electronic component, an electronic device, a large computer, space equipment, and a data center, power consumption can be reduced. Although there is a growing demand for more energy accompanying with higher performance and higher integration degree of semiconductor devices, the use of the semiconductor device of one embodiment of the present invention can thus reduce the emission amount of greenhouse gas typified by carbon dioxide (CO₂). Furthermore, the semiconductor device of one embodiment of the present invention has low power consumption and thus is effective as a global warming countermeasure.

The structures, configurations, methods, and the like described in this embodiment can be used in combination as appropriate with the structures, configurations, methods, and the like described in the other embodiments and the like.

### Example

In this example, a memory device that was actually fabricated will be described. The fabricated memory device has a structure in which memory cells each including a capacitor and an OS transistor that includes an oxide semiconductor in a channel formation region are stacked over a CMOS circuit including a Si transistor that includes part of a silicon substrate in a channel formation region. The fabricated memory device has the above-described structure illustrated in FIG. 1, FIG. 15, and the like in Embodiment 1. Thus, the description is sometimes omitted as appropriate in this example because the description of the above embodiment and the like can be referred to as appropriate. Note that the memory device is referred to as a “3D OS DRAM” in some cases.

### <Oxide Semiconductor Film>

The oxide semiconductor used in the OS transistor included in the fabricated memory device will be described.

An oxide semiconductor film used in the fabricated memory device is a metal oxide including indium (In), gallium (Ga), and zinc (Zn) (IGZO) and has an atomic ratio of the metal elements of In:Ga:Zn=1:1:1 and a CAAC structure (a structure in which the c-axis is aligned in the direction perpendicular to the formation surface). In the fabricated memory device, an oxide semiconductor (also referred to as ALD-IGZO/SP-IGZO) film in which an IGZO (also referred to as ALD-IGZO) film deposited by an ALD method was stacked over an IGZO (also referred to as SP-IGZO) film deposited by a sputtering method (the stacking is also referred to as deposition of a complex film) was used.

For the deposition of the SP-IGZO, an IGZO ceramic target with an atomic ratio of the metal elements being In:Ga:Zn=1:1:1.2 was used. A magnetron sputtering method using a radio frequency (RF) power source was used. A mixed gas of argon (Ar) and oxygen (O₂) was used as a gas at the time of deposition. Note that IGZO having a CAAC structure was formed by heating the substrate during the deposition.

An organic compound gas of In, Ga, and Zn was used as a raw material for the deposition of the ALD-IGZO. In that case, deposition conditions (e.g., cycle time) were adjusted so that the atomic ratio of the metal elements can be In:Ga:Zn=1:1:1.

The composition of the oxide semiconductor film was evaluated.

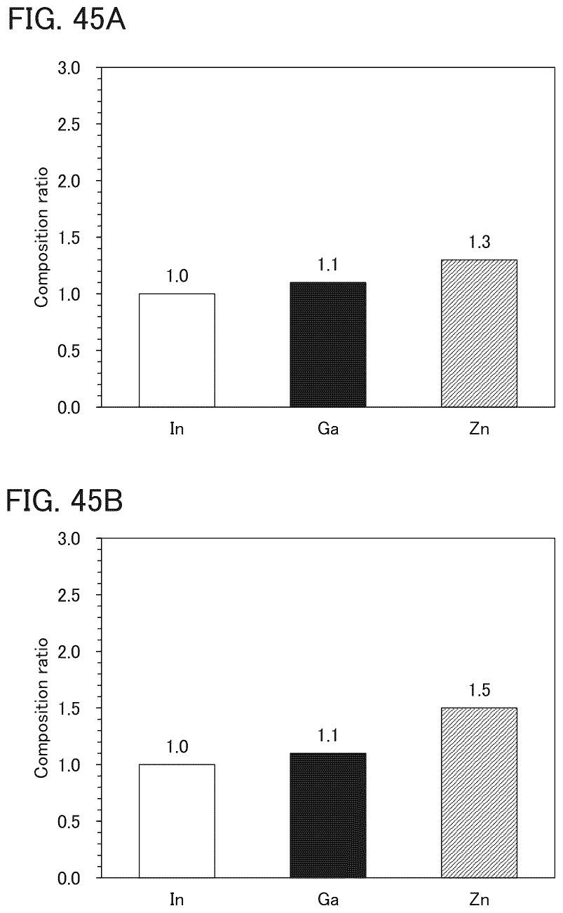

FIGS. 45A and 45B show the results of analyzing the compositions of the oxide semiconductor films by ICP-MS. FIG. 45A is a graph in which the atomic ratio (composition ratio) of the metal elements of the SP-IGZO film is normalized with the atomic ratio of In, and FIG. 45B is a graph in which the atomic ratio of the metal elements of the ALD-IGZO film is normalized with the atomic ratio of In.

The results show that the atomic ratio of the SP-IGZO film is In:Ga:Zn=1.0:1.1:1.3 and the atomic ratio of the ALD-IGZO film is In:Ga:Zn=1.0:1.1:1.5; the films have substantially the same composition.

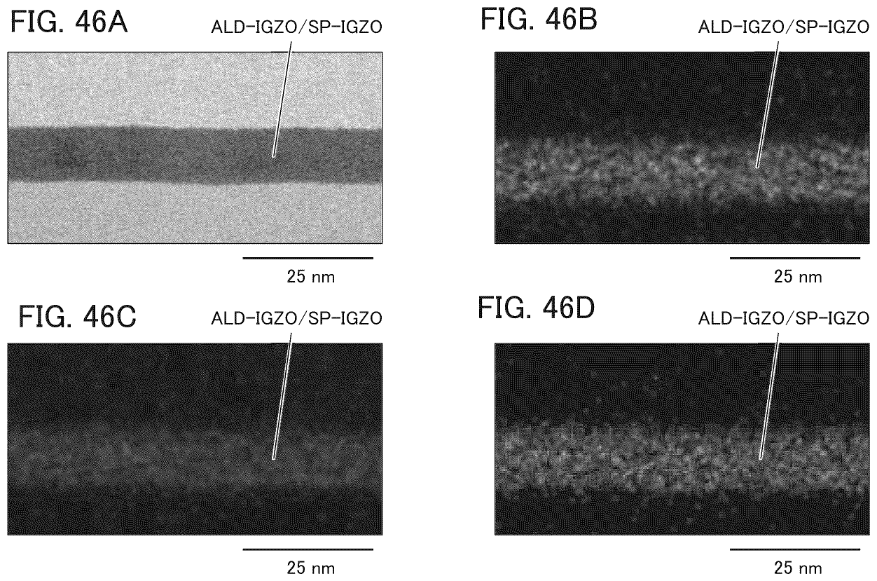

FIGS. 46A to 46D show the results of analyzing the oxide semiconductor film by scanning transmission electron microscope-energy dispersive X-ray spectroscopy (STEM-EDX). A sample of the oxide semiconductor film used for STEM-EDX analysis is a sample of an ALD-IGZO/SP-IGZO film in which a 5-nm-thick ALD-IGZO film is stacked over a 5-nm-thick SP-IGZO film. FIG. 46A is a STEM image of the sample, and FIGS. 46B, 46C, and 46D are, respectively, element mapping images of In, Ga, and Zn included in the sample.

Because there is no difference in the concentration distribution of the metal elements in the ALD-IGZO/SP-IGZO film and it is difficult to clearly observe the interface between the ALD-IGZO film and the SP-IGZO film, determining the boundary between the films is difficult.

From the above, it was confirmed that even when the ALD-IGZO film was stacked over the SP-IGZO film, the composition of each of the films hardly changed.

The crystallinity of the oxide semiconductor film was evaluated.

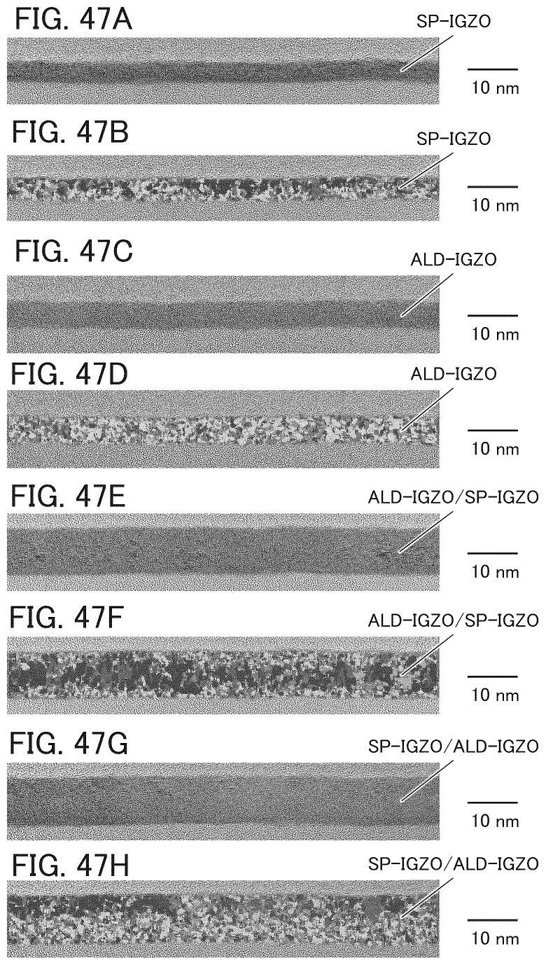

FIGS. 47A to 47H show the results of evaluating the crystal orientation of oxide semiconductor films. FIG. 47A is a cross-sectional TEM image of an SP-IGZO film, and FIG. 47B is a crystal orientation mapping image obtained from the cross-sectional TEM image. FIG. 47C is a cross-sectional TEM image of an ALD-IGZO film, and FIG. 47D is a crystal orientation mapping image obtained from the cross-sectional TEM image. FIG. 47E is a cross-sectional TEM image of an ALD-IGZO/SP-IGZO film, and FIG. 47F is a crystal orientation mapping image obtained from the cross-sectional TEM image. FIG. 47G is a cross-sectional TEM image of an SP-IGZO/ALD-IGZO film (an oxide semiconductor film in which an SP-IGZO film is stacked over an ALD-IGZO film), and FIG. 47H is a crystal orientation mapping image obtained from the cross-sectional TEM image. In the crystal orientation mapping image, the direction of the crystal axis with respect to the formation surface of the oxide semiconductor film is shown by gray scale; when the direction is closer to 90°, the c-axis alignment is higher.

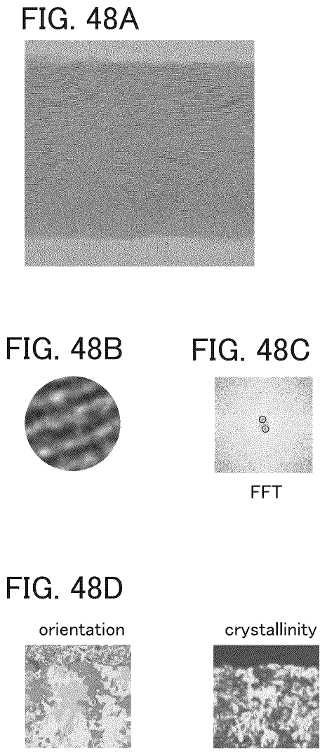

Here, a method for obtaining a crystal orientation mapping image from a cross-sectional TEM image is described with reference to FIGS. 48A to 48D. First, a spot image with a 1.0-nm diameter as shown in FIG. 48B was extracted from a cross-sectional TEM image of an oxide semiconductor film shown in FIG. 48A. Next, fast Fourier transform (FFT) was performed on the extracted spot image, so that an FFT pattern shown in FIG. 48C was obtained. A spot derived from crystallinity of the oxide semiconductor film was calculated by the FFT, and the degree of crystallinity and orientation at the spot image extracted from the spot were determined. In this manner, mapping images of orientation and crystallinity of the oxide semiconductor film as shown in FIG. 48D were obtained.

The results revealed that the SP-IGZO film had low c-axis alignment in the vicinity of an interface with the silicon oxide film in the initial stage of deposition and has increased c-axis alignment as the deposition proceeds. The ALD-IGZO film had low c-axis alignment as a whole. In the ALD-IGZO/SP-IGZO film, the ALD-IGZO film as well as the SP-IGZO film had high c-axis alignment. In the SP-IGZO/ALD-IGZO film, only the SP-IGZO film had c-axis alignment. These results indicate that an ALD-IGZO/SP-IGZO film had higher c-axis alignment than the films of the other structures. This is probably because the crystal growth of the ALD-IGZO film proceeds under the influence of the orientation of the SP-IGZO film.

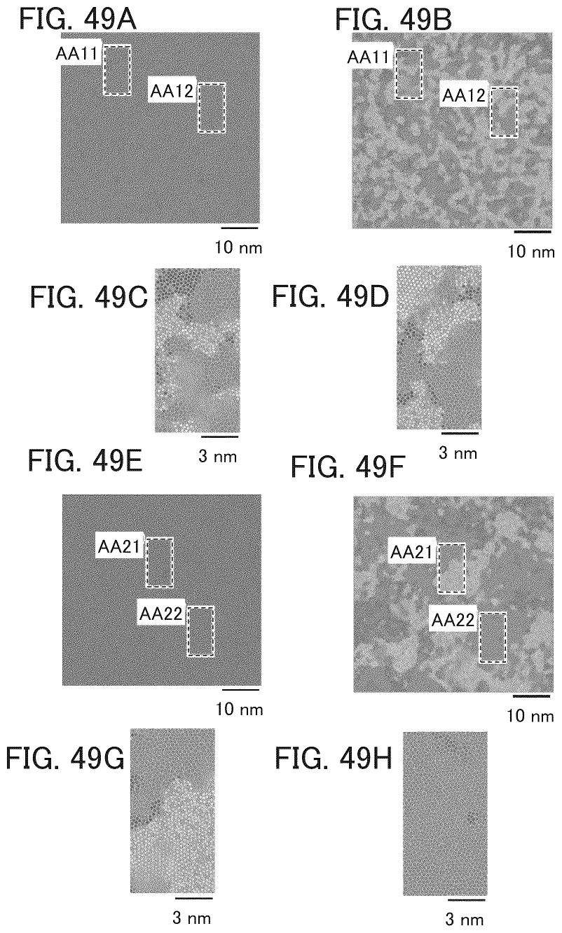

FIGS. 49A to 49H show the results of evaluating the crystal states of oxide semiconductor films. FIG. 49A is a plan-view TEM image of an SP-IGZO film, FIG. 49B is a mapping image showing hexagonal lattice distribution obtained from the plan-view TEM image, and FIGS. 49C and 49D are respectively enlarged views of the vicinity of a region AA11 and the vicinity of a region AA12 in FIGS. 49A and 49B. Note that the thickness of the SP-IGZO film is 5 nm. FIG. 49E is a plan-view TEM image of an ALD-IGZO/SP-IGZO film, FIG. 49F is a mapping image showing hexagonal lattice distribution obtained from the plan-view TEM image, and FIGS. 49G and 49H are respectively enlarged views of the vicinity of a region AA21 and the vicinity of a region AA22 in FIGS. 49E and 49F. Note that in the ALD-IGZO/SP-IGZO film, the thickness of the SP-IGZO film is 5 nm and the thickness of the ALD-IGZO film is 5 nm.

Here, a method for obtaining a mapping image of hexagonal lattice distribution from a plan-view TEM image is described. First, FFT was performed on the entire plan-view TEM image, and only components with high symmetry were extracted by application of a filter. The reverse FFT was performed to determine the arrangement of lattice points by utilizing pattern recognition by a computer program. Next, a regular hexagon in an appropriate size was placed with respect to the extracted lattice points, and the rotation angle of the regular hexagon was optimized to minimize the distance between the lattice points and the vertexes of the regular hexagon, whereby the orientation angle of the lattice points in the plane was determined.

It was confirmed that the crystal domain had grown significantly in the ALD-IGZO/SP-IGZO film. It was also confirmed that the crystal state was such that the crystal domains were continuously connected to each other.

From the above, it can be said that the ALD-IGZO/SP-IGZO film can have a favorable CAAC structure even with a small thickness.

The band diagram of the oxide semiconductor film was evaluated.

A method for measuring a band diagram is described. As samples, an SP-IGZO film and an ALD-IGZO film, each formed over a silicon substrate, were used. First, the difference between the bonding energy of In3d5/2 and the energy of the valence band maximum was calculated by XPS. The difference in energy was 442.03 eV in the case of the SP-IGZO film and 441.98 eV in the case of the ALD-IGZO film, and the difference in energy between both of the films was 0.05 eV. Next, the complex refractive index was calculated by spectroscopic ellipsometry, and the band gap was calculated by a Tauc plot. The band gap was 3.144 eV in the case of the SP-IGZO film and 3.028 eV in the case of the ALD-IGZO film. From these values, the energy of the conduction band minimum was calculated. Since the energy from the vacuum level to the conduction band minimum corresponds to the electron affinity, it was found that the electron affinity of the ALD-IGZO film was higher than the electron affinity of the SP-IGZO film by 0.17 eV. This indicates that in the ALD-IGZO/SP-IGZO film, electrons move from the SP-IGZO film to the ALD-IGZO film and a current is likely to flow through the ALD-IGZO film. Thus, a current is less likely to flow through the SP-IGZO film in the initial stage of deposition with a slightly low c-axis alignment, so that the influence of interface states can be reduced.

The Hall effect of the oxide semiconductor film was evaluated.

A method for measuring the Hall effect is described. As samples, three kinds of films, a SP-IGZO film, an ALD-IGZO film, and an ALD-IGZO/SP-IGZO film, which were formed over a quartz substrate, were used. Note that the thickness of the SP-IGZO film sample was 10 nm. The thickness of the ALD-IGZO film sample was 10 nm. The thickness of the ALD-IGZO/SP-IGZO film sample was such that the thickness of the SP-IGZO film was 5 nm and the thickness of the ALD-IGZO film was 5 nm. First, the samples were divided into 12-mm squares, and 200-nm-thick Ti—Al electrodes were deposited at four corners of each film surface with the use of a metal mask. Next, a measurement probe of a Hall effect measurement equipment was applied to the electrodes, and measurement by a Van der Pauw method was performed at a room temperature environment. Note that samples with different carrier concentrations were prepared by changing the conditions of the post-baking treatment after the deposition.

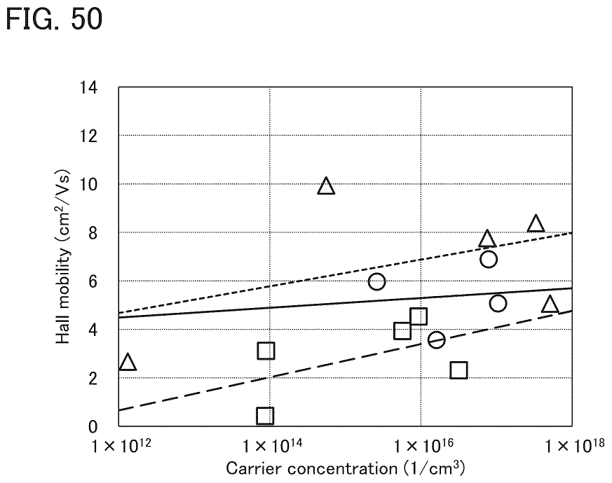

FIG. 50 is a graph showing results of evaluating the Hall effect of the oxide semiconductor films. In FIG. 50, the horizontal axis represents carrier concentration and the vertical axis represents Hall effect mobility (Hall mobility). In FIG. 50, evaluation results of the ALD-IGZO/SP-IGZO film are shown by circles and solid lines, those of the SP-IGZO film are shown by squares and dashed lines, and those of the ALD-IGZO film are shown by triangles and dotted lines.

When comparing the samples having the same carrier concentration in this manner, the Hall effect mobility of the SP-IGZO film was the lowest, the Hall effect mobility of the ALD-IGZO/SP-IGZO film was the second highest, and the Hall effect mobility of the ALD-IGZO film was the highest. Thus, it can be said that the film structure of the ALD-IGZO/SP-IGZO film offers favorable on-state characteristics when being used by a transistor as compared with the film structure of the SP-IGZO film.

The coverage with the oxide semiconductor films was evaluated.

A method for evaluating the coverage is described. A sample was formed in the following manner: a silicon oxynitride film was deposited over a silicon substrate by a plasma CVD method, a trench structure with a height of approximately 95 nm and a width of approximately 60 nm was formed by patterning and etching, and an SP-IGZO film or an ALD-IGZO film was deposited thereover. The coverage in several places of the trench structure in a cross-sectional STEM image of the sample was calculated.

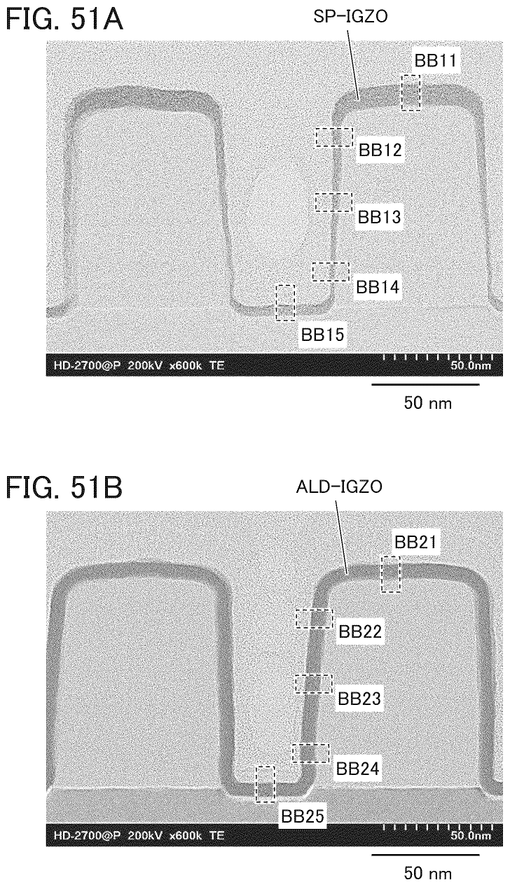

FIGS. 51A and 51B show the results of evaluating the coverage with the oxide semiconductor films. FIG. 51A is a cross-sectional STEM image of the case where the SP-IGZO film was deposited, and FIG. 51B is a cross-sectional STEM image of the case where the ALD-IGZO film was deposited. The thickness of the deposited SP-IGZO film is 10.0 nm in the vicinity of a region BB11 that is the top surface area of the trench structure, 3.9 nm in the vicinity of a region BB12 that is the upper side surface area, 2.9 nm in the vicinity of a region BB13 that is the middle side surface area, 2.2 nm in the vicinity of a region BB14 that is the lower side surface area, and 4.6 nm in the vicinity of a region BB15 that is the bottom surface area. When the coverage in the vicinity of the region BB11 is regarded as 100%, the coverage is 39% in the vicinity of the region BB12, 29% in the vicinity of the region BB13, 22% in the vicinity of the region BB14, and 46% in the vicinity of the region BB15. The thickness of the deposited ALD-IGZO film is 6.6 nm in the vicinity of a region BB21 that is the top surface area of the trench structure, 6.7 nm in the vicinity of a region BB22 that is the upper side surface area, 6.7 nm in the vicinity of a region BB23 that is the middle side surface area, 6.6 nm in the vicinity of a region BB24 that is the lower side surface area, and 5.9 nm in the vicinity of a region BB25 that is the bottom surface area. When the coverage in the vicinity of the region BB21 is regarded as 100%, the coverage is 100% in the vicinity of the region BB22, 102% in the vicinity of the region BB23, 100% in the vicinity of the region BB24, and 89% in the vicinity of the region BB25. Thus, it was confirmed that the ALD-IGZO film had a sufficient thickness even on the side surface area of the trench structure and had an extremely higher coverage than the SP-IGZO film.

From the above, it can be said that the use of the ALD-IGZO/SP-IGZO film enables formation of a thinner film than the use of the SP-IGZO film. A thin oxide semiconductor film is preferable in terms of easy carrier control and miniaturization of a transistor. Thus, it can be said that the use of the ALD-IGZO/SP-IGZO film offers favorable on-state characteristics of a transistor.

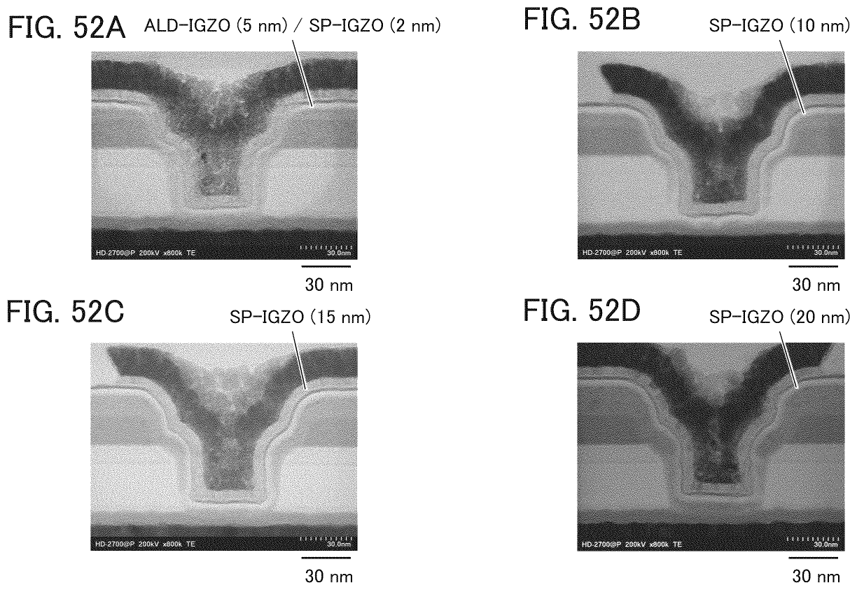

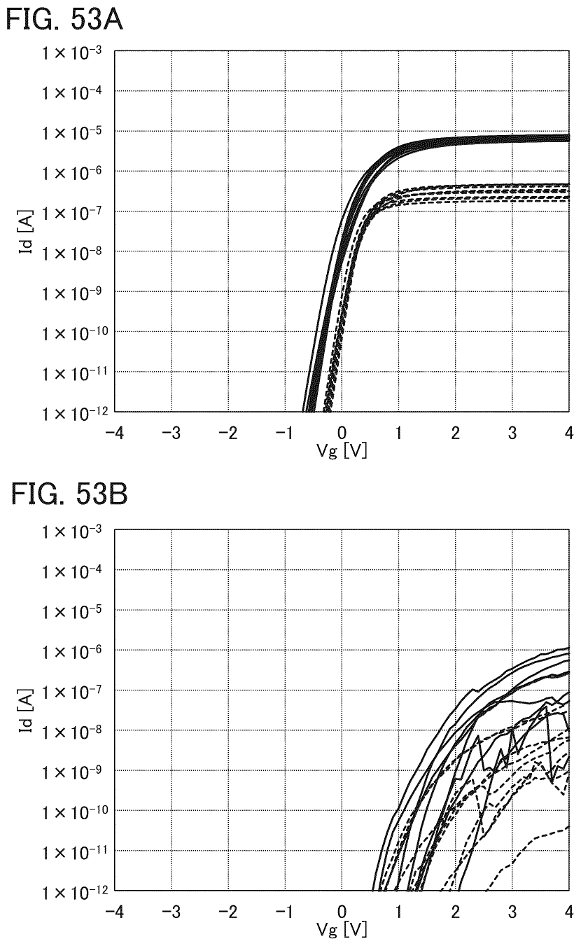

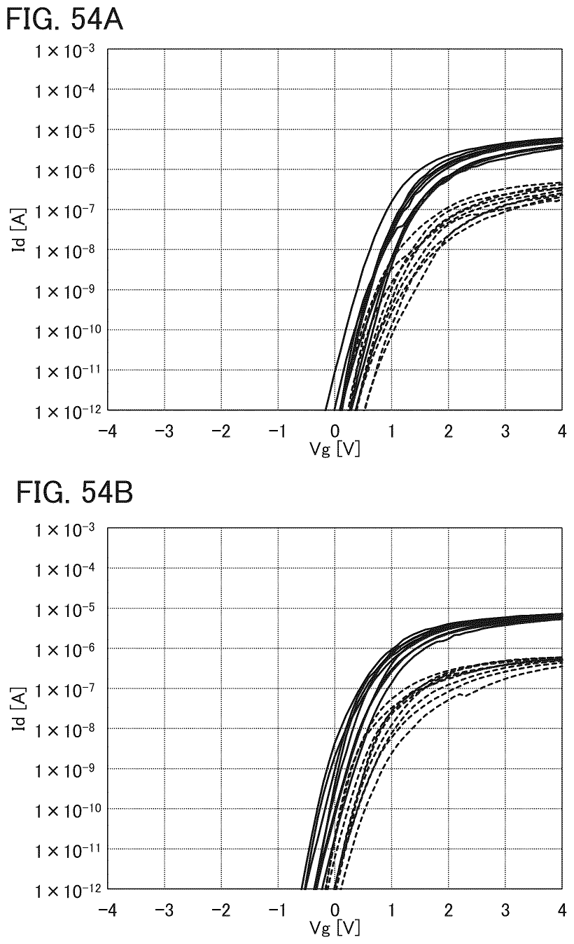

FIGS. 52A to 52D are cross-sectional STEM images of vertical OS transistors such as the above-described transistor 600 illustrated in FIGS. 18A and 18B and the like in Embodiment 2. FIGS. 53A, 53B, 54A, and 54B show Id-Vg characteristics of the transistors. FIGS. 52A and 53A respectively show the cross-sectional STEM image and Id-Vg characteristics of the vertical OS transistor formed using an ALD-IGZO/SP-IGZO film in which the thickness of the ALD-IGZO film is 5 nm and the thickness of the SP-IGZO film is 2 nm. FIGS. 52B and 53B respectively show the cross-sectional STEM image and Id-Vg characteristics of the vertical OS transistor formed using a 10-nm-thick SP-IGZO film. FIGS. 52C and 54A respectively show the cross-sectional STEM image and Id-Vg characteristics of the vertical OS transistor formed using a 15-nm-thick SP-IGZO film. FIGS. 52D and 54B respectively show the cross-sectional STEM image and Id-Vg characteristics of the vertical OS transistor formed using a 20-nm-thick SP-IGZO film.

The Id-Vg characteristics were measured with a semiconductor parameter analyzer in a room temperature environment. Here, a drain current Id at a source potential Vs of 0 V and a gate potential Vg ranging from −4 V to 4 V is shown. Note that the solid line represents the Id-Vg characteristics of the case where 1.2 V was applied as the drain potential Vd, and the dotted line represents the Id-Vg characteristics of the case where 0.1 V was applied as the drain potential Vd, and measurement results of nine transistors are shown for each case. Here, the measurement was performed in the following manner: the source potential Vs was supplied to the lower S/D electrode (corresponding to the conductor 630 in the above-described transistor 600) of the vertical OS transistor, the drain potential Vd was supplied to the upper S/D electrode (corresponding to the conductor 660 in the above-described transistor 600), and the gate potential Vg was supplied to a gate electrode (corresponding to the conductor 670 in the above-described transistor 600).

From the above, it was confirmed that the vertical OS transistor using the ALD-IGZO/SP-IGZO film can have a sufficient thickness of a channel formation region and favorable on-state characteristics.

### <Vertical OS Transistor>

Next, the vertical OS transistor used in the fabricated memory device will be described.

A vertical OS transistor such as the above-described transistor 600 illustrated in FIGS. 42A to 42C or the like in Embodiment 2 was fabricated using an ALD-IGZO/SP-IGZO film. In other words, a vertical OS transistor having a structure in which the gate electrode was pulled up (also referred to as a pulled-up gate structure in some cases) was employed for the purpose of reducing the resistance of the gate electrode and reducing the parasitic capacitance. Note that the channel hole diameter of the fabricated vertical OS transistor (corresponding to the maximum width D of the opening 648 in the above-described transistor 600) was set to 60 nm. To increase the controllability of carriers by the gate electric field, the thickness of a spacer (corresponding to the insulator 640 in the above-described transistor 600) between the lower S/D electrode and the upper S/D electrode (this thickness corresponds to the channel length L in the above-described transistor 600) was set to 95 nm.

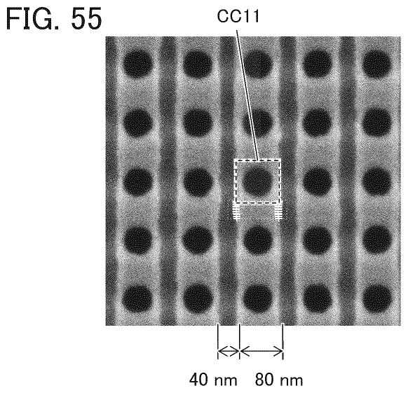

FIG. 55 shows a critical dimension-scanning electron microscope (CD-SEM) image of a plurality of vertical OS transistors formed in a matrix. The plurality of vertical OS transistors were able to be formed such that the area occupied by one vertical OS transistor (corresponding to a region CC11) was 80 nm×80 nm and the distance between two adjacent vertical OS transistors was 40 nm. That is, it was confirmed that the vertical OS transistors can be arranged at a density of 69.4/μm².

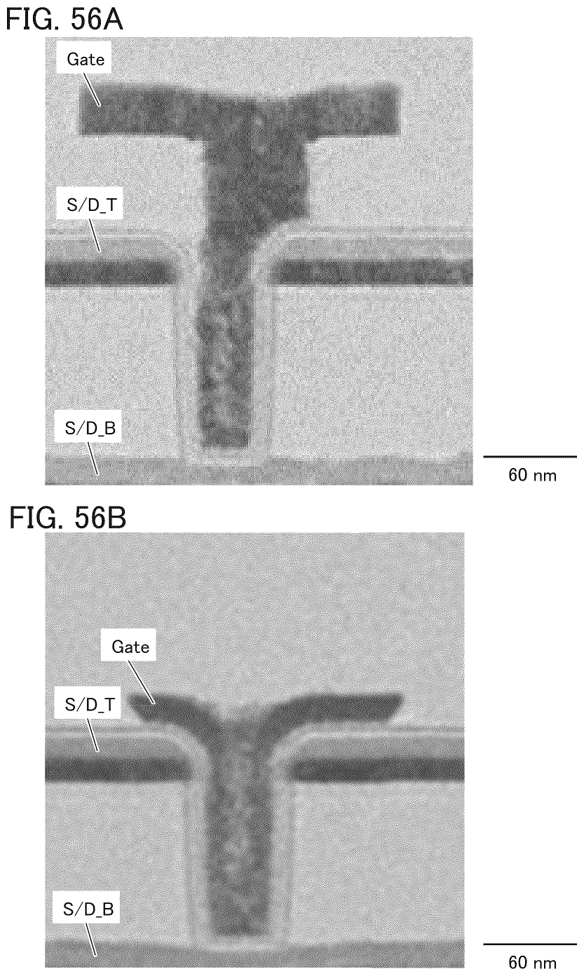

FIGS. 56A and 56B are cross-sectional STEM images of vertical OS transistors formed over a lower S/D electrode (S/D_B). FIG. 56A is a cross-sectional STEM image of the vertical OS transistor having a structure where the gate electrode (Gate) is pulled up (i.e., with the pulled-up gate structure), and FIG. 56B is a cross-sectional STEM image of the vertical OS transistor not having the structure where the gate electrode is pulled up (i.e., without the pulled-up gate structure). The fabricated memory device employed the pulled-up gate structure illustrated in FIG. 56A in which an insulator (corresponding to the insulator 676 in the above-described transistor 600) is inserted between a gate insulating film (corresponding to the insulator 672 in the above-described transistor 600) and an upper S/D electrode (S/D_T).

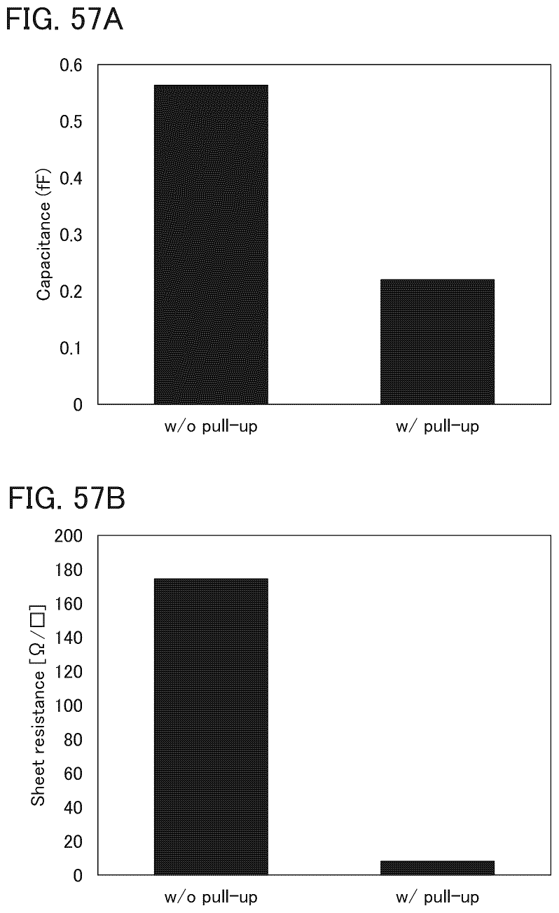

FIG. 57A is a graph comparing the gate capacitance including parasitic capacitance of a gate electrode (Capacitance) between the case having the pulled-up gate structure (w/pull-up) and the case not having the pulled-up gate structure (w/o pull-up). FIG. 57B is a graph comparing the sheet resistance of the gate electrode between the case having the pulled-up gate structure (w/pull-up) and the case not having the pulled-up gate structure (w/o pull-up). The gate capacitance including parasitic capacitance of the gate electrode of the case having the pulled-up gate structure was lower than that of the case not having the pulled-up gate structure by approximately 61%. In addition, the sheet resistance of the gate electrode of the case having the pulled-up gate structure was lower than that of the case not having the pulled-up gate structure by approximately 95%.

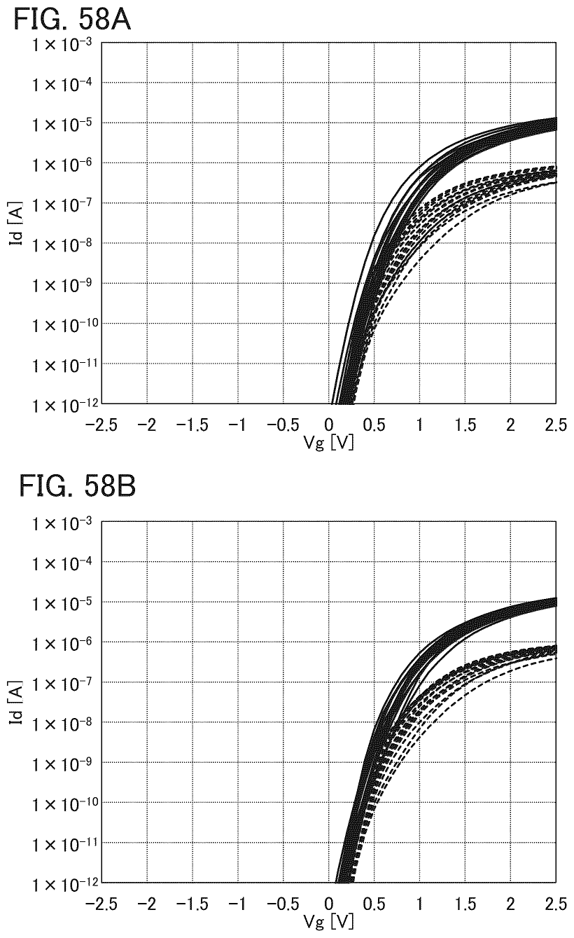

FIG. 58A shows the Id-Vg characteristics of the transistor having the pulled-up gate structure. FIG. 58B shows the Id-Vg characteristics of the transistor not having the pulled-up gate structure. The Id-Vg characteristics were measured with a semiconductor parameter analyzer in a room temperature environment. Here, a drain current Id when a source potential Vs of 0 V is applied and the gate potential Vg is varied from −4 V to 4 V is shown. Note that the gate potential Vg shown in the graphs is in the range of −2.5 V to 2.5 V. Note that the solid line represents the Id-Vg characteristics of the case where 1.2 V was applied as the drain potential Vd, and the dotted line represents the Id-Vg characteristics of the case where 0.1 V was applied as the drain potential Vd, and measurement results of 16 transistors are shown for each case. Note that the measurement was performed in the following manner: the source potential Vs was supplied to the lower S/D electrode of the vertical OS transistor, the drain potential Vd was supplied to the upper S/D electrode, and the gate potential Vg was supplied to the gate electrode. According to FIGS. 58A and 58B, the transistors with and without the pulled-up gate structure both had substantially the same Id-Vg characteristics.

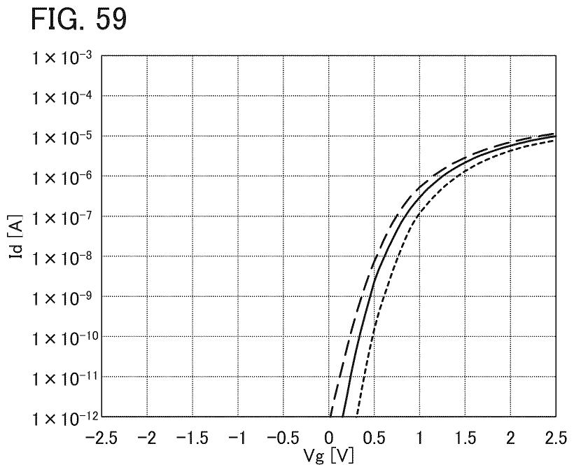

FIG. 59 shows Id-Vg characteristics of the transistor having the pulled-up gate structure measured at various ambient temperatures. The Id-Vg characteristics were measured with a semiconductor parameter analyzer. Here, a drain current Id at a source potential Vs of 0 V, a drain potential Vd of 1.2 V, and a gate potential Vg ranging from −2.5 V to 2.5 V is shown. Note that the solid line represents the Id-Vg characteristics of the case where measurement was performed in a 27° C. environment, the dashed line represents the Id-Vg characteristics of the case where measurement was performed in a 85° C. environment, and the dotted line represents the Id-Vg characteristics of the case where measurement was performed in a −40° C. environment. Here, the measurement was performed in the following manner: the source potential Vs was supplied to the lower S/D electrode of the vertical OS transistor, the drain potential Vd was supplied to the upper S/D electrode, and the gate potential Vg was supplied to a gate electrode. FIG. 59 shows that the threshold voltage (here, the gate potential when the drain current is 1 pA) is higher than 0 V even in the 85° C. environment, which demonstrates that the transistor has normally-off characteristics. Furthermore, the drain current Id in the off state was lower than 1 pA, which is the lower limit of the current value that can be detected by the semiconductor parameter analyzer, and it was confirmed that the off-state current was extremely low.

Here, a method for quantitatively evaluating the extremely low off-state current of the transistor is described. As a DUT (Device Under Test) that is an evaluation target, parallel connected 20,000 transistors were prepared. First, −1 V, 0 V, and 0.8 V were respectively applied to the gate terminal, the source terminal, and the drain terminal of each of the transistors in the DUT. Next, the drain terminal was brought into a floating state, and a change over time in the potential of the drain terminal was observed with the source follower circuit. The off-state current Ioff of the transistors in the DUT was calculated with the equation, the off state current Ioff=parasitic capacitance Cfn of the drain terminal×a potential change ΔVfn/measurement time T. Note that the parasitic capacitance Cfn and the potential change ΔVfn over the measurement time T were measured in advance.

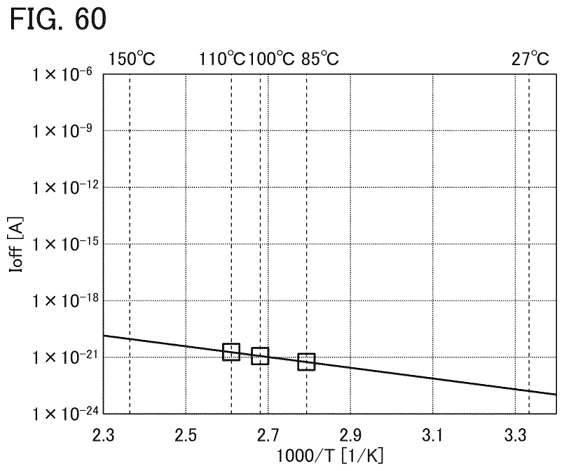

FIG. 60 shows an Arrhenius plot of the calculated off-state current of the transistor having the pulled-up gate structure. In FIG. 60, the horizontal axis represents the inverse of temperature T (1000/T) and the vertical axis represents the off-state current Ioff per transistor. Here, the calculated values of the off-state currents in the environments at 110° C., 100° C., and 85° C. are plotted. Square plots show the calculated values of the off-state currents, and the solid line is a regression line obtained from these calculated values. FIG. 60 shows that the off-state current per transistor is 5.62×10⁻²² A in a 85° C. environment, which demonstrates that the transistor has an extremely low off-state current.

### <3D OS DRAM>

Next, the fabricated memory device (sometimes referred to as a 3D OS DRAM) is described.

A memory device having a memory capacity of 512 kbit was fabricated using a vertical OS transistor with the pulled-up gate structure. The fabricated memory device has a structure similar to that of the above-described memory device 700 illustrated in FIG. 15 or the like in Embodiment 1, and includes a memory cell having a structure similar to that of the above-described memory cell 111 illustrated in FIG. 1 or the like in Embodiment 1. The memory cell has a structure similar to that of the above-described semiconductor device 200 illustrated in FIGS. 42A to 42C or the like in Embodiment 2. That is, a capacitor having a 3D structure (which means a trench-type MIM structure here), which is a cell capacitor (the capacitor corresponds to the capacitor 690 in the above-described semiconductor device 200) was formed above a CMOS circuit using Si transistors, and a vertical OS transistor (corresponding to the transistor 600 in the above-described semiconductor device 200), which is an access transistor, was formed over the capacitor. By stacking the vertical OS transistor over the capacitor having the 3D structure, a memory cell array with a cell size of 4F2 with the above-described layout illustrated in FIG. 22A or 22B in Embodiment 2 was achieved. Note that in the fabricated memory device, each memory cell was connected to a common plate terminal to which a constant potential was supplied.

The fabricated memory device includes a memory array (corresponding to the memory array portion 721 in the above-described memory device 700) and a peripheral circuit (corresponding to the peripheral circuit portion 722 in the above-described memory device 700). The memory array has a memory capacity of 512 kbit. The memory array includes 16 memory subarrays arranged in the column direction and has a memory capacity of 32 kbit per memory subarray. The memory subarray includes 1,024 sense amplifiers arranged in the row direction, and 32 memory cells are connected to each of the sense amplifiers.

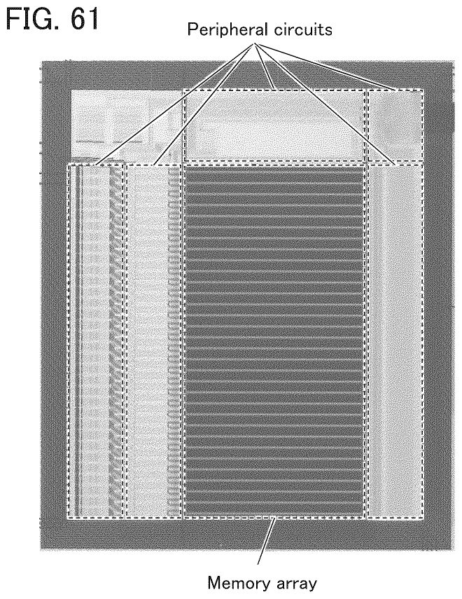

FIG. 61 shows an optical micrograph of the fabricated memory device in a top view. As shown in the figure, a memory array and peripheral circuits were formed.

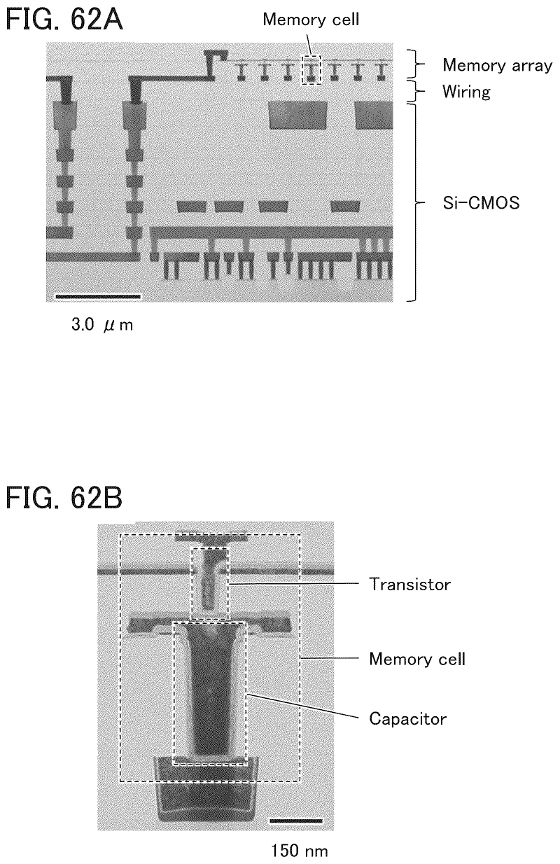

FIG. 62A is a cross-sectional STEM image of part of the fabricated memory device. FIG. 62B is an enlarged view of the vicinity of a memory cell in FIG. 62A. It was confirmed that a wiring layer (Wiring) was formed above a CMOS circuit (Si-CMOS) using Si transistors, and a memory array provided with a plurality of memory cells was formed above the wiring layer. In addition, it was confirmed that a capacitor having a 3D structure was formed in the memory cell and a vertical OS transistor having a pulled-up gate structure was formed over the capacitor.

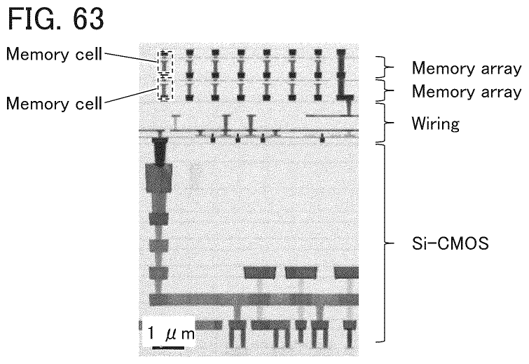

It was also confirmed that the memory cells can be stacked as illustrated in FIG. 63.

The fabricated memory device was evaluated.

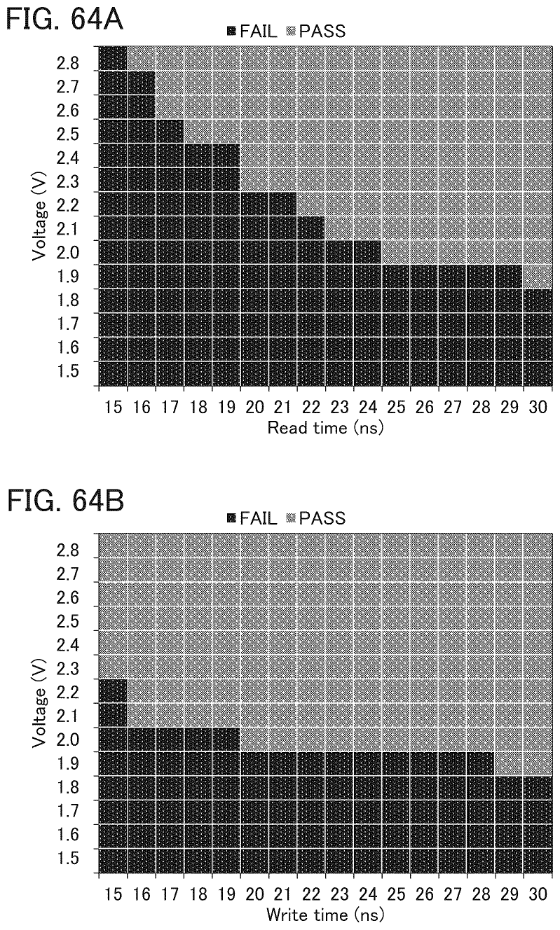

FIGS. 64A and 64B show shmoo plots of the fabricated memory device. Here, results (PASS or FAIL) of evaluating data read time and data write time by changing the voltage of a signal supplied to a word line in a 1.5-2.8 V range in increments of 0.1 V in a room temperature environment are shown. PASS means a normal bit rate of 99% or higher obtained, and FAIL means a normal bit rate of 99% or higher not obtained. Note that the data read time was a period from the start of a rise of the signal supplied to the word line to the start of operation of the sense amplifier. The data write time was a period from the start of a change in data supplied to the bit line to the completion of a fall of the signal supplied to the word line. As for data reading, it was found that when the voltage of the signal supplied to the word line was 2.8 V, reading was possible at a read time of 16 ns. As for data writing, when the voltage of the signal supplied to the word line was 2.3 V, writing was possible at a write time of 15 ns.

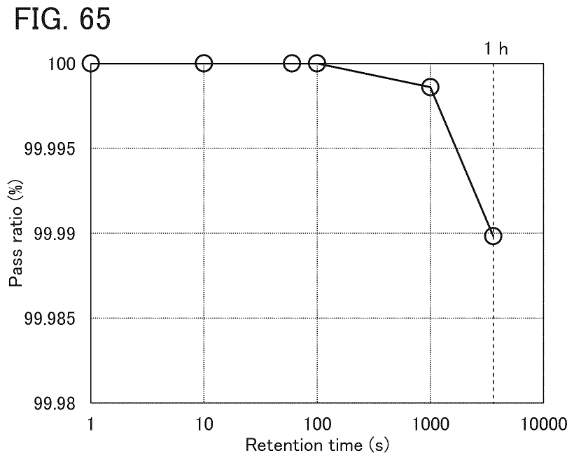

FIG. 65 is a graph showing results of evaluating retention characteristics (data retention characteristics) of the fabricated memory device under an 85° C. environment. In FIG. 65, the horizontal axis represents retention time and the vertical axis represents a normal bit rate (Pass ratio). Note that in the evaluation of the retention characteristics, the normal bit rate was calculated in such a manner that 2.0 V was supplied to the word line for writing data, −1.3 V was supplied to the word line for data retention, and then after the retention time elapsed, 2.0 V was supplied to the word line for reading data. The results of the retention characteristics were such that the normal bit rate after one hour (1 h) was 99.99%, and it was confirmed that data can be retained with refresh operations at a frequency of once an hour or less than once an hour.

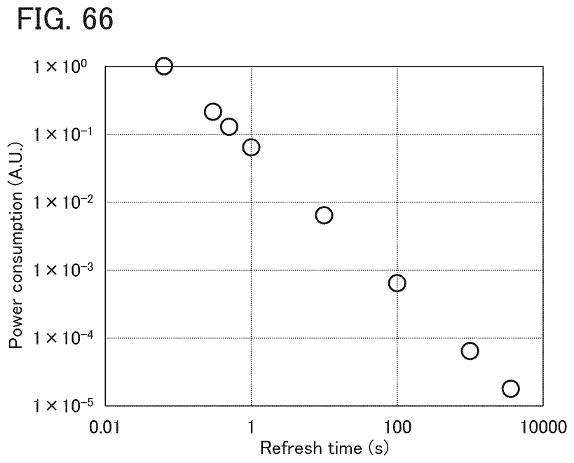

FIG. 66 is a graph showing results of estimating power consumption of the fabricated memory device. In FIG. 66, the horizontal axis represents the time interval between refresh operations (Refresh time), and the vertical axis represents estimated power consumption. Note that in the estimation of power consumption, the fabricated memory device was assumed to operate with an active period of 1% and a standby period of 99%. According to the estimation results, the power consumption can be reduced by approximately 5 digits by setting the time interval between refresh operations to one hour.

The memory device described in this example can be combined as appropriate with any of the structures described in the above embodiments, for example.

(Notes on Description of this Specification and the Like)

The following are notes on the description of the foregoing embodiments and the structures in the embodiments.

The expression “connection” in this specification includes “electrical connection”, for example. When the expression “electrical connection” is used to specify the connection relation of a circuit element as an object, “electrical connection” includes “direct connection” and “indirect connection”, for example. The expression “A and B are directly connected” means that A and B are connected to each other without a circuit element (e.g., a transistor or a switch; a wiring is not a circuit element) therebetween, for example. Meanwhile, the expression “A and B are indirectly connected” means that A and B are connected to each other with at least one circuit element therebetween, for example.

Here, in the case where a connection relation is specified as “A and B are indirectly connected”, the following connection relations are included, for example. That is, on the assumption that a circuit is in operation, the circuit can be specified as “A and B are indirectly connected” as an object when electric signal transmission and reception, potential interaction, or the like between A and B occurs at some point during the operation period of the circuit. Note that even when neither electric signal transmission and reception nor potential interaction between A and B occurs at some point during the operation of the circuit, the circuit can be specified as “A and B are indirectly connected” as long as electric signal transmission and reception or potential interaction between A and B occurs at another point during the operation period of the circuit. Note that the expression “A and B are indirectly connected” specifies the connection relation of a circuit element as an object. Thus, even when a circuit is not supplied with a power supply voltage and is not in operation, for example, the circuit can be specified as “A and B are indirectly connected” as an object (note that this specification is limited to, for example, the case where electric signal transmission and reception, potential interaction, or the like between A and B occurs during the operation period of the circuit when the circuit is supplied with a power supply voltage to be in operation).

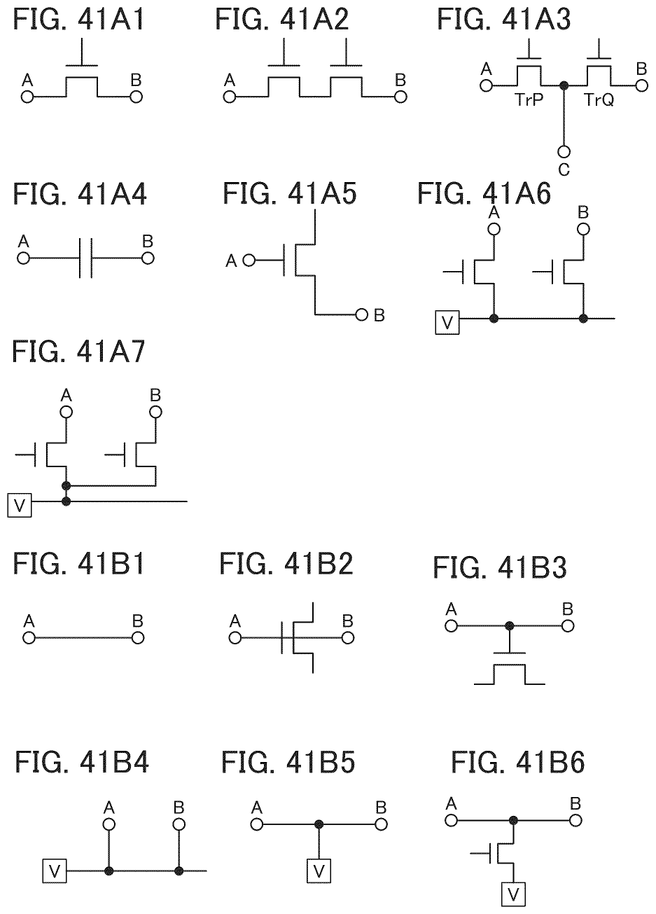

Specific examples of the case of “indirect connection” are described below. First, examples of the case where the expression “A and B are indirectly connected” can be used include the case where A and B are connected to each other through a source and a drain of at least one transistor as in FIG. 41A1 and FIG. 41A2. Another example thereof is the case where A and B are connected to each other with at least one switch therebetween. In the case where the expression “A and B are indirectly connected” can be used, one transistor between A and B is brought into the on state, the conduction state, or the state where a current can flow at least once on the assumption that a circuit is in operation. The case where the expression “A and B are indirectly connected” can be used may include a period at which the one transistor between A and B is brought into the off state or the non-conduction state. In the case where the expression “A and B are indirectly connected” can be used, each of a plurality of transistors between A and B is brought into the on state, the conduction state, or the state where a current can flow at least once when the plurality of transistors are connected between A and B on the assumption that a circuit is in operation. That is, in the case where the expression “A and B are indirectly connected” can be used, it is not necessary that all of the plurality of transistors be brought into the on state, the conduction state, or the state where a current can flow at the same time. Accordingly, in the case where the expression “A and B are indirectly connected” can be used, the plurality of transistors between A and B may be brought into the off state or the non-conduction state at the same time or at different times. As another example, when A and C are connected to each other through a source and a drain of a transistor TrP and B and C are connected to each other through a source and a drain of a transistor TrQ as illustrated in FIG. 41A3, it can be specified as “A and C are indirectly connected”, “B and C are indirectly connected”, or “A and B are indirectly connected”. Note that in the case where a constant potential V is supplied to C from a power source, GND, or the like as described later, the expression “A and C are indirectly connected” or “B and C are indirectly connected” can be used; however, the expression “A and B are indirectly connected” cannot be used.

The examples of the cases where the expression “indirect connection” can be used and cannot be used are described above, and another example of the case where the expression “indirect connection” cannot be used is described below. Even when electric signal transmission and reception, potential interaction, or the like between A and B occurs during the operation period of the circuit, the expression “A and B are indirectly connected” cannot be used in some cases exceptionally. Examples of the exceptional case include the case where A and B are connected to each other with an insulator therebetween. That is, in the case where A and B are connected to each other with an insulator therebetween, the expression “A and B are indirectly connected” cannot be used. A specific example of the case where A and B are connected to each other with an insulator therebetween is the case where a capacitor is connected between A and B as in FIG. 41A4. Another example thereof is the case where there is a gate insulating film of a transistor or the like between A and B as in FIG. 41A5. In that case, the expression “A (a gate of the transistor) and B (a source or a drain of the transistor) are indirectly connected” cannot be used.

Another example of the case where the expression “A and B are indirectly connected” cannot be used is the case where neither electric signal transmission and reception nor potential interaction between A and B occurs. For example, a plurality of transistors are connected through their sources and drains on the path from A to B and a constant potential V is supplied from a power source, GND, or the like to a node between one of the transistors and another one of the transistors as in FIGS. 41A6 and 41A7. In that case, the expression “A and B are indirectly connected” cannot be used; however, the expression “A and V are indirectly connected” or “B and V are indirectly connected” can be used. Note that in FIG. 41A3, when A and C are connected to each other through the source and the drain of the transistor TrP, B and C are connected to each other through the source and the drain of the transistor TrQ, and a constant potential V is supplied to C from a power source, a GND, or the like, the same connection relation as that in FIG. 41A6 and FIG. 41A7 is established; thus, the expression “A and B are indirectly connected” cannot be used; however, the expression “A and C are indirectly connected” or “B and C are indirectly connected” can be used.

The examples of “indirect connection” are described above. The specification of “indirect connection” is included in the specification of “electrical connection”, for example; thus in the case where the expression “A and B are indirectly connected” is used, the expression “A and B are electrically connected” can also be used.

Next, specific examples of the case of “direct connection” are described. Examples of the case where the expression “A and B are directly connected” can be used include the case where A and B are connected to each other without a circuit element therebetween as in FIGS. 41B1, 41B2, and 41B3. When A and B are connected to a power source, GND, or the like from which a constant potential V is supplied without a circuit element therebetween as in FIGS. 41B4 and 41B5, the expression “A and B are directly connected”, “A and V are directly connected”, or “B and V are directly connected” can be used. Note that when A (or B) is connected to a constant potential V through a source and a drain of a transistor as in FIG. 41B6, the expression “A and B are directly connected” can also be used. Note that A and V or B and V are connected to each other through the source and the drain of the transistor and thus they cannot be regarded as being in direct connection, and the expression “A and V are indirectly connected” or “B and V are indirectly connected” can be used.

The examples of “direct connection” are described above. The specification of “direct connection” is included in the specification of “electrical connection”, for example; thus in the case where the expression “A and B are directly connected” is used, the expression “A and B are electrically connected” can also be used.

Even when independent components are connected to each other in a circuit diagram, one component has functions of a plurality of components in some cases. For example, when part of a wiring also serves as an electrode, one conductive film has functions of both components: a function of the wiring and a function of the electrode. Thus, “connection” in this specification and the like includes in its category such a case where one conductive film has functions of a plurality of components.

In this specification and the like, a “resistor element” can be, for example, a circuit element, a wiring, or the like having a resistance higher than 0Ω. Therefore, in this specification and the like, a “resistor element” includes a wiring having a resistance, a transistor in which a current flows from the drain to the source, a diode, and a coil, for example. Thus, the term “resistor element” can be replaced with the terms “resistor,” “load,” or “region having a resistance”; conversely, the terms “resistor,” “load,” or “region having a resistance” can be sometimes replaced with the term “resistor element,” for example. The resistance can be, for example, preferably higher than or equal to 1 mΩ and lower than or equal to 10Ω, further preferably higher than or equal to 5 mΩ and lower than or equal to 5Ω, still further preferably higher than or equal to 10 mΩ and lower than or equal to 1Ω. As another example, the resistance may be higher than or equal to 1Ω and less than or equal to 1×10⁹Ω.

In the case where a wiring is used as a resistor, the resistivity is sometimes determined depending on the length of the wiring. Alternatively, a conductor with resistivity different from that of a conductor used as a wiring is sometimes used as a resistor. Alternatively, in the case where a semiconductor is used as a resistor, the resistivity of the resistor is sometimes determined by doping a semiconductor with an impurity.

In this specification and the like, a “capacitor” can be, for example, a circuit element having a capacitance higher than 0 F, a region of a wiring having a capacitance higher than 0 F, parasitic capacitance, or gate capacitance of a transistor. Therefore, a “capacitor” in this specification and the like is not limited to a circuit element that has a pair of electrodes and a dielectric between the electrodes. The “capacitor” includes parasitic capacitance generated between wirings or gate capacitance generated between a gate and one of a source and a drain in a transistor, for example. The terms “capacitor,” “parasitic capacitance,” or “gate capacitance” can be replaced with the term “capacitance,” for example; conversely, the term “capacitance” can be replaced with the terms “capacitor,” “parasitic capacitance,” or “gate capacitance,” for example. The term “a pair of electrodes” of a capacitor can be replaced with the terms “a pair of conductors,” “a pair of conductive region,” or “a pair of regions,” for example. Note that the capacitance value can be higher than or equal to 0.05 fF and lower than or equal to 10 pF, for example. For example, the capacitance value may be higher than or equal to 1 pF and lower than or equal to 10 μF.

A transistor in this specification and the like has at least three terminals including a gate (also referred to as a gate terminal, a gate region, or a gate electrode), a source (also referred to as a source terminal, a source region, or a source electrode), and a drain (also referred to as a drain terminal, a drain region, or a drain electrode). The transistor has a region where a channel is formed (also referred to as a channel formation region) between the drain and the source. The transistor enables a current to flow between the source and the drain through the channel formation region. The channel formation region refers to a region through which a current mainly flows. The gate is a control terminal controlling the amount of current flowing through the channel formation region between the source and the drain. Two terminals serving as the source and the drain are input/output terminals of the transistor.

Functions of the two input/output terminals of the transistor depend on the conductivity type (n-channel type or p-channel type) of the transistor and the levels of potentials applied to the three terminals of the transistor, and one of the two terminals serves as a source and the other serves as a drain. In some cases, functions of the source and the drain are replaced with each other when the direction of current flow is changed in circuit operation, for example. Therefore, the terms “source” and “drain” can be used interchangeably in this specification and the like. In this specification and the like, the terms “one of a source and a drain” (or a first electrode or a first terminal) and “the other of the source and the drain” (or a second electrode or a second terminal) are used to describe the connection relation of a transistor.

Depending on the structure, a transistor may include a back gate in addition to the above three terminals. In that case, in this specification and the like, one of the gate and the back gate of the transistor may be referred to as a first gate and the other of the gate and the back gate of the transistor may be referred to as a second gate. In some cases, the terms “gate” and “back gate” can be replaced with each other in one transistor. In the case where a transistor includes three or more gates, the gates may be referred to as a first gate, a second gate, and a third gate, for example, in this specification and the like.

In this specification and the like, a transistor with a multi-gate structure having two or more gate electrodes can be used as a transistor. The transistor with a multi-gate structure has a structure in which a plurality of transistors are connected in series because the channel formation regions are connected in series. The transistor with a multi-gate structure thus enables the lower off-state current and the higher withstand voltage (improved reliability). In the transistor with a multi-gate structure, the current between the drain and the source does not change much even if the voltage between the drain and the source changes at the time of operation in a saturation region, so that a flat slope of voltage-current characteristics can be obtained. A transistor having the voltage-current characteristics with a flat slope can achieve an ideal current source circuit or an active load having an extremely high resistance. Accordingly, the transistor having the voltage-current characteristics with a flat slope can be used to achieve a differential circuit, a current mirror circuit, or the like having excellent properties.

In this specification and the like, a single circuit element shown in a circuit diagram may include a plurality of circuit elements. For example, a single resistor shown in a circuit diagram may be two or more resistors connected to each other in series. For another example, a single capacitor shown in a circuit diagram may be two or more capacitors connected to each other in parallel. For another example, a single transistor shown in a circuit diagram may be two or more transistors which are connected to each other in series and whose gates are connected to each other. For another example, a single switch shown in a circuit diagram may be a switch including two or more transistors which are connected to each other in series or in parallel and whose gates are connected to each other.

In this specification and the like, a node can be referred to as a “terminal,” a “wiring,” an “electrode,” a “conductive layer,” a “conductor,” or an “impurity region” depending on the circuit structure and the device structure, for example. For example, a “terminal,” a “wiring,” or the like can be referred to as a “node.”

In this specification and the like, “voltage” and “potential” can be replaced with each other as appropriate. The term “voltage” refers to a potential difference from a reference potential. When the reference potential is a ground potential, for example, “voltage” can be replaced with “potential.” Note that the ground potential does not necessarily mean 0 V. A potential has a relative value. In other words, a potential supplied to a wiring, a potential applied to a circuit and the like, or a potential output from a circuit and the like, for example, changes depending on the reference potential.

In this specification and the like, the terms “high-level potential” (also referred to as H potential or H) and “low-level potential” (also referred to as L potential or L) do not represent a particular potential. For example, in the case where two wirings are both described as “functioning as a wiring for supplying a high-level potential,” the levels of the high-level potentials that these wirings supply are not necessarily equal to each other. Similarly, in the case where two wirings are both described as “functioning as a wiring for supplying a low-level potential,” the levels of the low-level potentials that these wirings supply are not necessarily equal to each other.

In this specification and the like, “a current” means a charge transfer phenomenon (electrical conduction). For example, the expression “electrical conduction of positively charged particles is caused” can be rephrased as “electrical conduction of negatively charged particles is caused in the opposite direction.” Therefore, unless otherwise specified, a current in this specification and the like refers to an electric charge transfer (electrical conduction) caused by carrier movement. Therefore, unless otherwise specified, a current in this specification and the like refers to an electric charge transfer phenomenon (electrical conduction) caused by carrier movement. Examples of the carrier here include an electron, a hole, an anion, a cation, and a complex ion. Note that the type of the carrier differs between systems where a current flows (e.g., a semiconductor, a metal, an electrolyte solution, and a vacuum). The “direction of a current” in a wiring or the like, for example, refers to the direction in which a positive carrier moves, and the amount of a current is expressed as a positive value. In other words, the direction in which a negative carrier moves is opposite to the direction of current, and the amount of negative carriers is expressed as a negative current amount. Thus, in the case where the polarity of a current (or the direction of a current) is not specified in this specification and the like, the expression “a current flows from an element A to an element B” can be replaced with “a current flows from an element B to an element A,” for example. The expression “a current is input to an element A” can be replaced with “a current is output from an element A,” for example,

Ordinal numbers such as “first,” “second,” and “third” in this specification and the like are used in order to avoid confusion among components. Thus, the terms do not limit the number of components. The terms do not limit the order of components, either. For example, a “first” component in one embodiment in this specification and the like can be referred to as a “second” component in other embodiments, claims, or the like. For another example, a “first” component in one embodiment in this specification and the like can be omitted in other embodiments, claims, or the like.

In this specification and the like, terms for describing arrangement, such as “over,” “under,” “above,” and “below,” are sometimes used for convenience to describe the positional relation between components with reference to drawings, for example. The positional relation between components is changed as appropriate in accordance with the direction in which the components are described. Thus, the terms for describing arrangement used in this specification and the like can be, without limitation thereto, replaced with other terms as appropriate. For example, the expression “an insulator over (on) a top surface of a conductor” can be replaced with the expression “an insulator on a bottom surface of a conductor” when the direction of a diagram showing these components is rotated by 180°. Moreover, the expression “an insulator over (on) an upper surface of a conductor” can be replaced with the expression “an insulator on a left surface (or a right surface) of a conductor” when the direction of a diagram showing these components is rotated by 90°.

The terms such as “over,” “above,” “under,” and “below” do not necessarily mean that a component is placed directly on or under and directly in contact with another component. For example, the expression “electrode B over insulating layer A” does not necessarily mean that the electrode B is on and in direct contact with the insulating layer A, and can mean the case where another component is provided between the insulating layer A and the electrode B.

In this specification and the like, components arranged in a matrix and their positional relation are sometimes described using terms such as “row” and “column,” for example. The positional relation between components is changed as appropriate in accordance with the direction in which the components are described. Thus, for example, the terms such as “row” and “column” used in this specification and the like can be, without limitation thereto, replaced with other terms as appropriate. For example, the term “row direction” can be replaced with the term “column direction” when the direction of the diagram is rotated by 90°.

The term “overlap,” for example, in this specification and the like does not limit a state such as the stacking order of components. For example, the expression “the electrode B overlapping with the insulating layer A” is not limited to the state where the electrode B is formed over the insulating layer A. For example, the expression “electrode B overlapping with insulating layer A” includes the case where the electrode B is formed under the insulating layer A and the case where the electrode B is formed on the right (or left) side of the insulating layer A.

The term “adjacent” or “proximity” in this specification and the like does not necessarily mean that a component is directly in contact with another component. For example, the expression “electrode B adjacent to insulating layer A” does not necessarily mean that the electrode B is formed in direct contact with the insulating layer A and can mean the case where another component is provided between the insulating layer A and the electrode B.

In this specification and the like, the terms “film” and “layer,” for example, can be interchanged with each other in some cases. For example, the term “conductive layer” can be changed to the term “conductive film” in some cases. For example, the term “insulating film” can be changed into the term “insulating layer” in some cases. For example, the term “film” or “layer” can be replaced with a word not including the term in some cases. For example, the term “conductive layer” or “conductive film” can be changed into the term “conductor” in some cases. Furthermore, the term “conductor” can be changed into the term “conductive layer” or “conductive film” in some cases. For example, in some cases, the term “insulating layer” or “insulating film” can be changed into the term “insulator” in some cases. Furthermore, the term “insulator” can be changed into the term “insulating layer” or “insulating film” in some cases.

In this specification and the like, for example, the terms “electrode,” “wiring,” and “terminal” do not have functional limitations. For example, an “electrode” is used as part of a wiring in some cases, and vice versa. Furthermore, the term “electrode” or “wiring” can also mean a combination of a plurality of electrodes or wirings provided in an integrated manner, for example. For another example, a “terminal” can be used as part of a wiring or an electrode, and vice versa. Furthermore, the term “terminal” includes the case where a plurality of “electrodes,” “wirings,” “terminals,” and the like are formed in an integrated manner, for example. Thus, for example, an “electrode” can be part of a “wiring” or a “terminal”. Furthermore, a “terminal” can be part of a “wiring” or an “electrode”. Moreover, the terms “electrode”, “wiring”, and “terminal” are sometimes replaced with the term “region”, for example.

In this specification and the like, for example, the term “signal line”, “power supply line”, or the like can be changed into the term “wiring” in some cases. For example, the term “potential” that is applied to a wiring can be changed into the term “signal” or the like in some cases. Inversely, for example, the term “signal” or the like can be changed into the term “potential” in some cases.

In this specification and the like, a “switch” includes a plurality of terminals and has a function of switching (selecting) electrical continuity and discontinuity between the terminals. For example, in the case where a switch includes two terminals and electrical continuity is established between the two terminals, the switch is in a “conduction state” or an “on state”. In the case where electrical continuity is not established between the two terminals, the switch is in a “non-conduction state” or an “off state”. Note that switching to one of a conduction state and a non-conduction state or maintaining one of a conduction state and a non-conduction state is sometimes referred to as “controlling a conduction state”.

That is, a switch has a function of controlling whether a current flows therethrough or not. Alternatively, a switch has a function of selecting and changing a current path. As the switch, an electrical switch or a mechanical switch can be used, for example. That is, a switch is not limited to a particular element.

Note that as a kind of a switch, there is a switch which is normally in a non-conduction state and brought into a conduction state by controlling a conduction state; such a switch is referred to as an “A contact” in some cases. Furthermore, as another kind of a switch, there is a switch which is normally in a conduction state and brought into a non-conduction state by controlling a conduction state; such a switch is referred to as a “B contact” in some cases.

Examples of an electrical switch include a transistor (e.g., a bipolar transistor and a MOS transistor), a diode (e.g., a PN diode, a PIN diode, a Schottky diode, a metal-insulator-metal (MIM) diode, a metal-insulator-semiconductor (MIS) diode, and a diode-connected transistor), and a logic circuit in which such elements are combined. In the case where a transistor operates just as a switch, there is no particular limitation on the polarity (conductivity type) of the transistor.

An example of a mechanical switch is a switch using a microelectromechanical systems (MEMS) technology. Such a switch includes an electrode that can be moved mechanically, and its conduction or non-conduction is selected with movement of the electrode.

The “channel length” of a transistor in this specification and the like sometimes refers to the distance between the source and the drain in a region where the channel is formed or a region where the gate overlaps with the semiconductor (or a portion of the semiconductor where a current flows when the transistor is on), for example.

The “channel width” of a transistor in this specification and the like sometimes refers to the length of a portion where the source and the drain face each other in a region where the channel is formed or a region where the gate overlaps with the semiconductor (or a portion of the semiconductor where a current flows when the transistor is on), for example.

In this specification and the like, the term “substrate,” “wafer,” “die,” or the like does not limit a function of a component, for example. The terms “substrate,” “wafer,” “die,” and the like can be interchanged with each other depending on the case, for example.

In this specification and the like, the term “parallel” does not necessarily refer to the case where components are exactly parallel. Hence, for example, the term “parallel” can be replaced with the term “substantially parallel,” “roughly parallel,” “practically parallel,” or the like as appropriate. The terms “parallel,” “substantially parallel,” “roughly parallel,” or “practically parallel” may be used in the case where the angle between two straight lines or planes is greater than or equal to −5° and less than or equal to 5°, greater than or equal to −10° and less than or equal to 10°, or greater than or equal to −30° and less than or equal to 30°. Accordingly, “parallel” sometimes refers to “parallel or roughly parallel,” for example. Similarly, the term “perpendicular” does not necessarily refer to the case where components are exactly perpendicular to each other. Hence, for example, the term “perpendicular” can be replaced with the term “substantially perpendicular,” “roughly perpendicular,” “practically perpendicular,” or the like as appropriate. The terms “perpendicular,” “substantially perpendicular,” “roughly perpendicular,” or “practically perpendicular” may be used in the case where the angle between two straight lines or planes is greater than or equal to 85° and less than or equal to 95°, greater than or equal to 80° and less than or equal to 100°, or greater than or equal to 60° and less than or equal to 120°. Accordingly, “perpendicular” sometimes refers to “perpendicular or roughly perpendicular,” for example.

The term “level with” in this specification and the like means a structure having the same level from a reference surface (e.g., a flat surface such as a substrate surface) in a cross-sectional view. For example, in a manufacturing process of a semiconductor device, planarization treatment is performed, whereby the surface(s) of a single layer or a plurality of layers are exposed in some cases. In this case, the surfaces on which the planarization treatment is performed are at the same level from the reference surface. However, the surfaces of the plurality of layers on which the planarization treatment is performed are at the levels that are not exactly the same depending on a treatment apparatus, a treatment method, or a material of the surfaces, used for the planarization treatment in some cases. This case is also regarded as being “level with” in this specification and the like. For example, the term “level with” also means a structure where two layers (a first layer and a second layer here) at different levels from the reference surface have top-surface levels differing by 20 nm or less. Accordingly, “level with” sometimes refers to “level with or roughly level with,” for example.

In this specification and the like, the expression “an end portion is aligned with another end portion” means that at least outlines of stacked layers partly overlap with each other in a top view. For example, in a manufacturing process of a semiconductor device, the case of patterning or partly patterning an upper layer and a lower layer with the use of the same mask pattern is included in the expression. The expression “an end portion is aligned with another end portion” also includes the case where the outlines do not completely overlap with each other; for instance, the outline of the upper layer may be positioned inside or outside the outline of the lower layer. This case is also the structure meant by expression “an end portion is aligned with another end portion” in this specification and the like. Accordingly, “an end portion is aligned with another end portion” sometimes refers to “an end portion is aligned or roughly aligned with another end portion,” for example.

In this specification and the like, the terms “identical,” “the same,” “equal,” “concurrent”, “align”, “uniform,” and the like (including synonyms thereof) used in describing, for example, calculation values and measurement values or in describing objects, methods, events, and the like that can be converted into calculation values or measurement values allow for a margin of error of ±20% unless otherwise specified. Therefore, for example, “identical” means “identical” or “roughly identical”, “the same” means “the same or roughly the same”, “equal” means “equal or roughly equal”, “concurrent” means “concurrent or roughly concurrent”, “align” means “align or roughly align”, and “uniform” means “uniform or roughly uniform” in some cases.

In this specification and the like, an impurity in a semiconductor refers to, for example, an element other than the main component of the semiconductor. For example, an element with a concentration lower than 0.1 atomic % is an impurity. By containing an impurity, a semiconductor may have increased density of defect states, decreased carrier mobility, or decreased crystallinity, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include (contained also in water), lithium, sodium, silicon, boron, phosphorus, carbon, and nitrogen. Entry of an impurity may cause oxygen vacancies in an oxide semiconductor, for example.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like, for example. For example, a metal oxide used as a semiconductor in a channel formation region of a transistor is referred to as an oxide semiconductor in some cases. That is, a metal oxide included in a channel formation region of a transistor that has at least one of an amplifying function, a rectifying function, and a switching function can be referred to as a metal oxide semiconductor. The term “OS transistor” can be replaced with a transistor including a metal oxide or an oxide semiconductor.

In this specification and the like, a metal oxide containing nitrogen is also called a metal oxide in some cases. In addition, a metal oxide containing nitrogen may be referred to as a metal oxynitride.

In the drawings for this specification and the like, arrows indicating the X direction, the Y direction, and the Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

This application is based on Japanese Patent Application Serial No. 2023-192403 filed with Japan Patent Office on Nov. 10, 2023 and Japanese Patent Application Serial No. 2024-021899 filed with Japan Patent Office on Feb. 16, 2024, the entire contents of which are hereby incorporated by reference.

What is claimed is:

1. A memory device comprising:
a memory array comprising a first memory cell; and
a peripheral circuit comprising a first driver circuit,
wherein the first memory cell comprises a first transistor and a first capacitor,
wherein one of a source and a drain of the first transistor is electrically connected to one terminal of the first capacitor,
wherein the other of the source and the drain of the first transistor is electrically connected to a first bit line,
wherein a gate of the first transistor is electrically connected to a first word line,
wherein the other terminal of the first capacitor is electrically connected to the first driver circuit,
wherein the first driver circuit is configured to output a first potential, output a second potential in conjunction with a timing when a potential of a selection signal that is supplied to the first word line changes, and output a third potential in conjunction with a timing when a potential of data that is supplied to the first bit line changes,
wherein a direction of change from the first potential to the second potential is opposite to a direction in which the potential of the selection signal changes, and
wherein a direction of change from the first potential to the third potential is opposite to a direction in which the potential of the data changes.

2. A memory device comprising:
a memory array comprising a first memory cell and a second memory cell; and
a peripheral circuit comprising a first driver circuit and a second driver circuit,
wherein the first memory cell comprises a first transistor and a first capacitor,
wherein the second memory cell comprises a second transistor and a second capacitor,
wherein one of a source and a drain of the first transistor is electrically connected to one terminal of the first capacitor,
wherein the other of the source and the drain of the first transistor is electrically connected to a first bit line,
wherein a gate of the first transistor is electrically connected to a first word line,
wherein the other terminal of the first capacitor is electrically connected to the first driver circuit,
wherein one of a source and a drain of the second transistor is electrically connected to one terminal of the second capacitor,
wherein the other of the source and the drain of the second transistor is electrically connected to the first bit line,
wherein a gate of the second transistor is electrically connected to a second word line,
wherein the other terminal of the second capacitor is electrically connected to the second driver circuit,
wherein the first driver circuit is configured to output a signal whose potential changes in a direction opposite to a direction in which a potential of a selection signal that is supplied to the first word line changes, and
wherein the second driver circuit is configured to output a signal whose potential changes in a direction opposite to a direction in which a potential of a selection signal that is supplied to the second word line changes.

3. A memory device comprising:
a memory array comprising a first memory cell and a second memory cell; and
a peripheral circuit comprising a first driver circuit and a second driver circuit,
wherein the first memory cell comprises a first transistor and a first capacitor,
wherein the second memory cell comprises a second transistor and a second capacitor,
wherein one of a source and a drain of the first transistor is electrically connected to one terminal of the first capacitor,
wherein the other of the source and the drain of the first transistor is electrically connected to a first bit line,
wherein a gate of the first transistor is electrically connected to a first word line,
wherein the other terminal of the first capacitor is electrically connected to the first driver circuit,
wherein one of a source and a drain of the second transistor is electrically connected to one terminal of the second capacitor,
wherein the other of the source and the drain of the second transistor is electrically connected to a second bit line,
wherein a gate of the second transistor is electrically connected to the first word line,
wherein the other terminal of the second capacitor is electrically connected to the second driver circuit,
wherein the first driver circuit is configured to output a signal whose potential changes in a direction opposite to a direction in which a potential of data that is supplied to the first bit line changes, and
wherein the second driver circuit is configured to output a signal whose potential changes in a direction opposite to a direction in which a potential of data that is supplied to the second bit line changes.

4. A memory device comprising:
a memory array comprising a first memory cell, a second memory cell, a third memory cell, and a fourth memory cell; and
a peripheral circuit comprising a first driver circuit, a second driver circuit, a third driver circuit, and a fourth driver circuit,
wherein the first memory cell comprises a first transistor and a first capacitor,
wherein the second memory cell comprises a second transistor and a second capacitor,
wherein the third memory cell comprises a third transistor and a third capacitor,
wherein the fourth memory cell comprises a fourth transistor and a fourth capacitor,
wherein one of a source and a drain of the first transistor is electrically connected to one terminal of the first capacitor,
wherein the other of the source and the drain of the first transistor is electrically connected to a first bit line,
wherein a gate of the first transistor is electrically connected to a first word line,
wherein the other terminal of the first capacitor is electrically connected to the first driver circuit,
wherein one of a source and a drain of the second transistor is electrically connected to one terminal of the second capacitor,
wherein the other of the source and the drain of the second transistor is electrically connected to the first bit line,
wherein a gate of the second transistor is electrically connected to a second word line,
wherein the other terminal of the second capacitor is electrically connected to the second driver circuit,
wherein one of a source and a drain of the third transistor is electrically connected to one terminal of the third capacitor,
wherein the other of the source and the drain of the third transistor is electrically connected to a second bit line,
wherein a gate of the third transistor is electrically connected to the first word line,
wherein the other terminal of the third capacitor is electrically connected to the third driver circuit,
wherein one of a source and a drain of the fourth transistor is electrically connected to one terminal of the fourth capacitor,
wherein the other of the source and the drain of the fourth transistor is electrically connected to the second bit line,
wherein a gate of the fourth transistor is electrically connected to the second word line, and
wherein the other terminal of the fourth capacitor is electrically connected to the fourth driver circuit.

5. The memory device according to claim 1, wherein the first transistor comprises an oxide semiconductor in a channel formation region.

6. The memory device according to claim 1, wherein the first transistor is over the first capacitor.

7. The memory device according to claim 6, further comprising:
a first conductor;
a second conductor over the first conductor; and
a third conductor over the second conductor,
wherein the first conductor comprises the other terminal of the first capacitor,
wherein the second conductor comprises the one terminal of the first capacitor and the one of the source and the drain of the first transistor, and
wherein the third conductor comprises the other of the source and the drain of the first transistor.

8. The memory device according to claim 1, wherein the memory array is over the peripheral circuit.

9. The memory device according to claim 2, wherein the first transistor comprises an oxide semiconductor in a channel formation region.

10. The memory device according to claim 2, wherein the first transistor is over the first capacitor.

11. The memory device according to claim 10, further comprising:
a first conductor;
a second conductor over the first conductor; and
a third conductor over the second conductor,
wherein the first conductor comprises the other terminal of the first capacitor,
wherein the second conductor comprises the one terminal of the first capacitor and the one of the source and the drain of the first transistor, and
wherein the third conductor comprises the other of the source and the drain of the first transistor.

12. The memory device according to claim 2, wherein the memory array is over the peripheral circuit.

13. The memory device according to claim 3, wherein the first transistor comprises an oxide semiconductor in a channel formation region.

14. The memory device according to claim 3, wherein the first transistor is over the first capacitor.

15. The memory device according to claim 14, further comprising:
a first conductor;
a second conductor over the first conductor; and
a third conductor over the second conductor,
wherein the first conductor comprises the other terminal of the first capacitor,
wherein the second conductor comprises the one terminal of the first capacitor and the one of the source and the drain of the first transistor, and
wherein the third conductor comprises the other of the source and the drain of the first transistor.

16. The memory device according to claim 3, wherein the memory array is over the peripheral circuit.

17. The memory device according to claim 4, wherein the first transistor comprises an oxide semiconductor in a channel formation region.

18. The memory device according to claim 4, wherein the first transistor is over the first capacitor.

19. The memory device according to claim 18, further comprising:
a first conductor;
a second conductor over the first conductor; and
a third conductor over the second conductor,
wherein the first conductor comprises the other terminal of the first capacitor,
wherein the second conductor comprises the one terminal of the first capacitor and the one of the source and the drain of the first transistor, and
wherein the third conductor comprises the other of the source and the drain of the first transistor.

20. The memory device according to claim 4, wherein the memory array is over the peripheral circuit.
